(19) United States
(12) Patent Application Publication
(10) Pub. No.: US 2024/0196746 A1
(43) Pub. Date: Jun. 13, 2024

(54) ORGANIC COMPOUND, ORGANIC ELECTROLUMINESCENT DEVICE, AND ELECTRONIC APPARATUS

(71) Applicant: Shaanxi Lighte Optoelectronics Material Co., Ltd., Xi'an (CN)

(72) Inventors: Qiqi NIE, Xi'an (CN); Youngkook KIM, Xi'an (CN); Heming ZHANG, Xi'an (CN)

(21) Appl. No.: 18/280,214

(22) PCT Filed: Mar. 15, 2022
(86) PCT No.: PCT/CN2022/081038

§ 371 Date: Sep. 2, 2023

(30) Foreign Application Priority Data
Jul. 1, 2021 (CN) 202110746037.9

(51) Int. Cl. H10K 85/60; C07F 5/02; C09K 11/06

(52) U.S. Cl. CPC H10K 85/658; C07F 5/027; C09K 11/06; H10K 50/11

(57) ABSTRACT

The present disclosure relates to an organic compound, an organic electroluminescent device using the same, and an electronic apparatus. The organic compound has a structure obtained by fusing a formula (1) with one or two Ar groups. The Ar group is selected from the group consisting of groups shown in formulae (2-1) to (2-5). The organic compound can be used in an organic electroluminescent device and can improve the performance of the organic electroluminescent device.

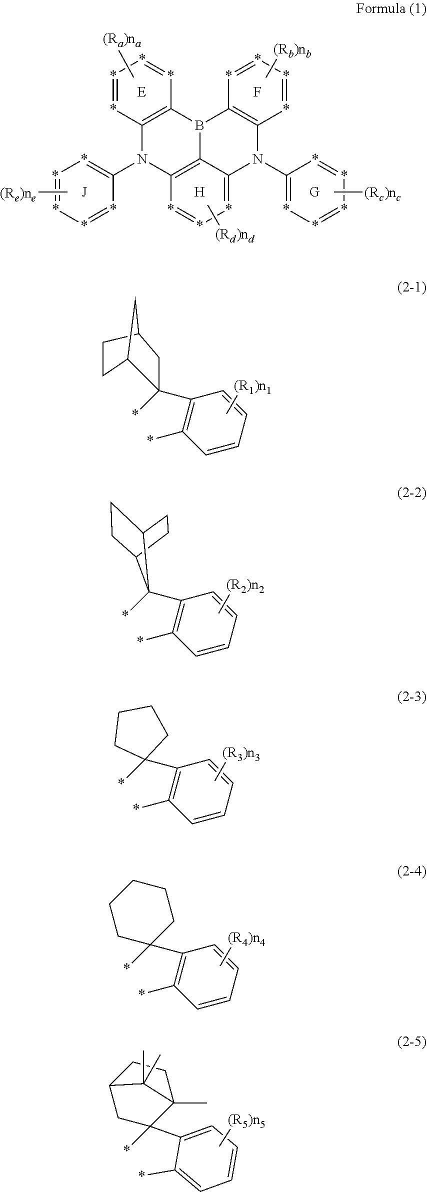

### CROSS REFERENCE TO RELATED APPLICATIONS

This application claims the priority of Chinese patent application No. 202110746037.9, filed on Jul. 1, 2021, the contents of which are incorporated herein by reference in their entirety as part of the present disclosure.

### TECHNICAL FIELD

The present disclosure relates to the technical field of organic materials, in particular to an organic compound, an organic electroluminescent device using the same, and an electronic apparatus.

### BACKGROUND

A structure of an organic electroluminescent device generally includes a cathode and an anode which are disposed oppositely, and a functional layer disposed between the cathode and the anode. The functional layer consists of one or more organic film layers. Among the layers containing an organic compound, there are a light-emitting layer, or a charge transport/injection layer that transports or injects holes, electrons, etc., and the like, and various organic materials suitable for these layers have been developed.

In the organic electroluminescent device, holes and electrons which are injected from the anode and the cathode are recombined in the light-emitting layer, and the energy generated at this time is derived in the form of light. After the holes and the electrons are recombined, a singlet excited state and a triplet excited state are generated in a ratio of 1:3 according to the spin statistical rule. In the case of using a fluorescent material, only the singlet excited state in these excited states can be utilized, and thus the maximum internal quantum efficiency is only 25%, which becomes the largest obstacle to improve the internal quantum efficiency.

In recent years, the development of organic electroluminescence with high internal quantum efficiency by using triplet-triplet-fusion (TTF) has become a material development trend. TTF is the phenomenon of generating one molecule in a singlet excited state from two molecules in a triplet excited state. By using the phenomenon, the singlet excited state can be produced from the generated triplet excited state of 75%, and the maximum internal quantum efficiency becomes 62.5%.

In the prior art, CN111699191A discloses a class of blue light guest materials, and the disclosed compounds still have some problems. In view of the above, in order to improve the performance of the organic electroluminescent device, there is an urgent need to develop a blue light guest material having excellent performance.

### SUMMARY

In view of the above problems existing in the prior art, an object of the present disclosure is to provide an organic compound, an organic electroluminescent device using the same, and an electronic apparatus. The organic compound can be used in the organic electroluminescent device to improve the performance of the organic electroluminescent device.

In order to achieve the above object, in a first aspect of the present disclosure, provided is an organic compound, having a structure obtained by fusing a formula (1) with one or two Ar groups:

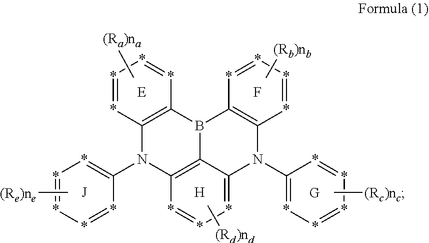

“*” indicates a site where the structure shown in formula (1) is fused with the Ar group;

the Ar group is selected from the group consisting of groups shown in formulae (2-1) to (2-5):

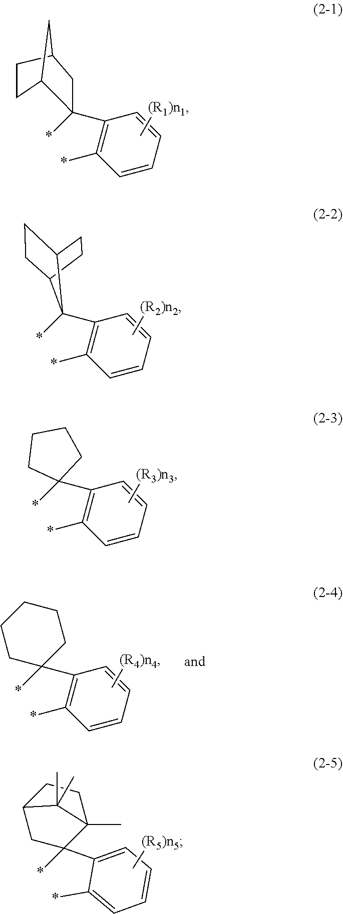

the Ar group is fused to any two adjacent * positions in a ring E, a ring F, a ring G, a ring H and a ring J in the formula (1);

when the number of the Ar group is two, the two Ar groups are the same or different;

each Rₐ, each R_{b}, each R_{c}, each R_{d} and each Rₑ are the same or different from each other, and are each independently selected from deuterium, a halogen group, cyano, substituted or unsubstituted alkyl with 1 to 20 carbon atoms, substituted or unsubstituted cycloalkyl with 3 to 20 carbon atoms, substituted or unsubstituted aryl with 6 to 20 carbon atoms, substituted or unsubstituted heteroaryl with 3 to 20 carbon atoms, substituted or unsubstituted trialkylsilyl with 3 to 20 carbon atoms, substituted or unsubstituted haloalkyl with 1 to 20 carbon atoms, substituted or unsubstituted triarylsilyl with 18 to 24 carbon atoms, substituted or unsubstituted alkoxy with 1 to 20 carbon atoms, and substituted or unsubstituted alkylthio with 1 to 20 carbon atoms;

nₐ represents the number of Rₐ, and is selected from 0, 1, 2, 3 or 4, and when nₐ is greater than 1, any two Rₐ are the same or different;

n_{b} represents the number of R_{b}, and is selected from 0, 1, 2, 3 or 4, and when n_{b} is greater than 1, any two R_{b} are the same or different;

n_{c} represents the number of R_{c}, and is selected from 0, 1, 2, 3, 4 or 5, and when n_{c} is greater than 1, any two R_{c} are the same or different;

n_{d} represents the number of R_{d}, and is selected from 0, 1, 2 or 3, and when n_{d} is greater than 1, any two R_{d} are the same or different;

nₑ represents the number of Rₑ, and is selected from 0, 1, 2, 3, 4 or 5, and when nₑ is greater than 1, any two Rₑ are the same or different;

each R₁, each R₂, each R₃, each R₄ and each R₅ are the same or different from each other, and are each independently selected from deuterium, a halogen group, cyano, trialkylsilyl with 3 to 12 carbon atoms, triarylsilyl with 18 to 24 carbon atoms, alkyl with 1 to 10 carbon atoms, cycloalkyl with 3 to 10 carbon atoms, alkoxy with 1 to 10 carbon atoms, aryl with 6 to 20 carbon atoms or heteroaryl with 3 to 20 carbon atoms;

n₁ represents the number of R₁, n₂ represents the number of R₂, n₃ represents the number of R₃, n₄ represents the number of R₄, n₅ represents the number of R₅, and the n₁, the n₂, the n₃, the n₄ and the n₅ are each independently selected from 0, 1, 2, 3 or 4; and

substituents in the Rₐ, the R_{b}, the R_{c}, the R_{d} and the Rₑ are the same or different from each other, and are each independently selected from: deuterium, a halogen group, cyano, heteroaryl with 3 to 12 carbon atoms, aryl with 6 to 12 carbon atoms, trialkylsilyl with 3 to 12 carbon atoms, alkyl with 1 to 10 carbon atoms, haloalkyl with 1 to 10 carbon atoms, cycloalkyl with 3 to 10 carbon atoms, heterocycloalkyl with 2 to 10 carbon atoms, alkoxy with 1 to 10 carbon atoms, alkylthio with 1 to 10 carbon atoms, aryloxy with 6 to 12 carbon atoms, arylthio with 6 to 12 carbon atoms, alkylsulfonyl with 6 to 12 carbon atoms, trialkylphosphino with 3 to 12 carbon atoms, or trialkylboryl with 3 to 12 carbon atoms.

In a second aspect of the present disclosure, provided is an organic electroluminescent device, including an anode and a cathode which are oppositely disposed, and a functional layer disposed between the anode and the cathode, where the functional layer includes the organic compound according to the first aspect of the present disclosure; and

preferably, the functional layer includes an organic light-emitting layer including the organic compound.

In a third aspect of the present disclosure, provided is an electronic apparatus, including the organic electroluminescent device according to the second aspect of the present disclosure.

The present disclosure provides the organic compound having a norborneol-fluorene structure, or a cyclohexane-fluorene structure, or a cyclopentane-fluorene structure, so that the organic compound provided by the present disclosure can improve the carrier transport efficiency and the service life of the organic electroluminescent device by improving the electron density of the conjugated system of the fluorene ring and the entire nitrogen-containing compound, and increasing the hole transport efficiency of the nitrogen-containing compound; and the organic compound provided by the present disclosure combines the norborneol-fluorene structure, or the cyclohexane-fluorene structure, or the cyclopentane-fluorene structure with a solid ring centered on the boron element, so that the carrier stability can be effectively increased, and the luminescent performance of the organic electroluminescent device can be improved.

Other features and advantages of the present disclosure will be described in detail in the subsequent specific embodiments.

### BRIEF DESCRIPTION OF THE DRAWINGS

The accompanying drawings are used to provide a further understanding of the present disclosure and constitute a part of the description, and are used to explain the present disclosure together with the following specific embodiments, but do not constitute limitations on the present disclosure. In the drawings:

FIG. 1 is a structural schematic diagram of an organic electroluminescent device according to an embodiment of the present disclosure.

FIG. 2 is a structural schematic diagram of an electronic apparatus according to an embodiment of the present disclosure.

### DESCRIPTION OF REFERENCE SIGNS

100, anode; 200, cathode; 300, functional layer; 310, hole injection layer; 320, hole transport layer; 321, first hole transport layer; 322, second hole transport layer; 330, organic light-emitting layer; 340, electron transport layer; 350, electron injection layer; and 400, electronic apparatus.

### DETAILED DESCRIPTION

The specific embodiments of the present disclosure are described in detail below in combination with the drawings. It should be understood that the specific embodiments described here are only used to illustrate and interpret the present disclosure, but not to limit the present disclosure.

In a first aspect of the present disclosure, provided is an organic compound, having a structure obtained by fusing a formula (1) with one or two Ar groups:

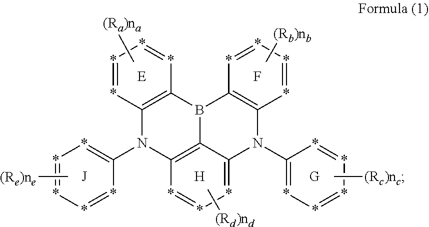

“*” indicates a site where the structure shown in formula (1) is fused with the Ar group;

the Ar group is selected from the group consisting of groups shown in formulae (2-1) to (2-5):

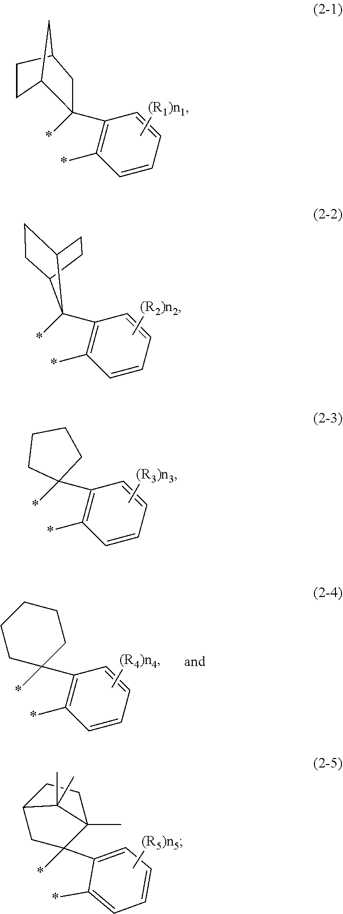

the Ar group is fused to any two adjacent * positions in a ring E, a ring F, a ring G, a ring H or a ring J in the formula (1);

when the number of the Ar group is two, the two Ar groups are the same or different;

each Rₐ, each R_{b}, each R_{c}, each R_{d} and each Rₑ are the same or different from each other, and are each independently selected from deuterium, a halogen group, cyano, substituted or unsubstituted alkyl with 1 to 20 carbon atoms, substituted or unsubstituted cycloalkyl with 3 to 20 carbon atoms, substituted or unsubstituted aryl with 6 to 20 carbon atoms, substituted or unsubstituted heteroaryl with 3 to 20 carbon atoms, substituted or unsubstituted trialkylsilyl with 3 to 20 carbon atoms, substituted or unsubstituted haloalkyl with 1 to 20 carbon atoms, substituted or unsubstituted triarylsilyl with 18 to 24 carbon atoms, substituted or unsubstituted alkoxy with 1 to 20 carbon atoms, and substituted or unsubstituted alkylthio with 1 to 20 carbon atoms;

nₐ represents the number of Rₐ, and is selected from 0, 1, 2, 3 or 4, and when nₐ is greater than 1, any two Rₐ are the same or different;

n_{b} represents the number of R_{b}, and is selected from 0, 1, 2, 3 or 4, and when n_{b} is greater than 1, any two R_{b} are the same or different;

n_{c} represents the number of R_{c}, and is selected from 0, 1, 2, 3, 4 or 5, and when n_{c} is greater than 1, any two R_{c} are the same or different;

n_{d} represents the number of R_{d}, and is selected from 0, 1, 2 or 3, and when n_{d} is greater than 1, any two R_{d} are the same or different;

nₑ represents the number of Rₑ, and is selected from 0, 1, 2, 3, 4 or 5, and when nₑ is greater than 1, any two Rₑ are the same or different;

each R₁, each R₂, each R₃, each R₄ and each R₅ are the same or different from each other, and are each independently selected from deuterium, a halogen group, cyano, trialkylsilyl with 3 to 12 carbon atoms, triarylsilyl with 18 to 24 carbon atoms, alkyl with 1 to 10 carbon atoms, cycloalkyl with 3 to 10 carbon atoms, alkoxy with 1 to 10 carbon atoms, aryl with 6 to 20 carbon atoms or heteroaryl with 3 to 20 carbon atoms;

n₁ represents the number of R₁, n₂ represents the number of R₂, n₃ represents the number of R₃, n₄ represents the number of R₄, n₅ represents the number of R₅, and the n₁, the n₂, the n₃, the n₄ and the n₅ are each independently selected from 0, 1, 2, 3 or 4; and

substituents in the Rₐ, the R_{b}, the R_{c}, the R_{d} and the Rₑ are the same or different from each other, and are each independently selected from: deuterium, a halogen group, cyano, heteroaryl with 3 to 12 carbon atoms, aryl with 6 to 12 carbon atoms, trialkylsilyl with 3 to 12 carbon atoms, alkyl with 1 to 10 carbon atoms, haloalkyl with 1 to 10 carbon atoms, cycloalkyl with 3 to 10 carbon atoms, heterocycloalkyl with 2 to 10 carbon atoms, alkoxy with 1 to 10 carbon atoms, alkylthio with 1 to 10 carbon atoms, aryloxy with 6 to 12 carbon atoms, arylthio with 6 to 12 carbon atoms, alkylsulfonyl with 6 to 12 carbon atoms, trialkylphosphino with 3 to 12 carbon atoms, or trialkylboryl with 3 to 12 carbon atoms.

In the present disclosure, the adopted description modes “each . . . is independently”, “. . . is respectively and independently” and “. . . is independently selected from” can be interchanged, and should be understood in a broad sense, which means that in different groups, specific options expressed between the same symbols do not influence each other, or in a same group, specific options expressed between the same symbols do not influence each other.

For example, the meaning of

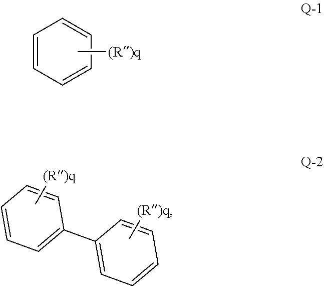

wherein each q is independently 0, 1, 2 or 3, and each R″ is independently selected from hydrogen, deuterium, fluorine and chlorine” is as follows: a formula Q-1 represents that q substituents R″ exist on a benzene ring, each R″ can be the same or different, and options of each R″ do not influence each other; and a formula Q-2 represents that each benzene ring of biphenyl has q substituents R″, the number q of the substituents R″ on the two benzene rings can be the same or different, each R″ can be the same or different, and options of each R″ do not influence each other.

In the present disclosure, the term such as “substituted or unsubstituted” means that a functional group described behind the term may have or do not have a substituent (in the following, the substituent is collectively referred to as Rc in order to facilitate description). For example, the “substituted or unsubstituted aryl” refers to aryl having the substituent Rc or unsubstituted aryl. The above substituent, i.e., Rc may be, for example, deuterium, a halogen group, cyano, heteroaryl with 3 to 12 carbon atoms, aryl with 6 to 12 carbon atoms, trialkylsilyl with 3 to 12 carbon atoms, alkyl with 1 to 10 carbon atoms, haloalkyl with 1 to 10 carbon atoms, cycloalkyl with 3 to 10 carbon atoms, heterocycloalkyl with 2 to 10 carbon atoms, alkoxy with 1 to 10 carbon atoms, alkylthio with 1 to 10 carbon atoms, aryloxy with 6 to 12 carbon atoms, arylthio with 6 to 12 carbon atoms, alkylsulfonyl with 6 to 12 carbon atoms, trialkylphosphino with 3 to 12 carbon atoms, or trialkylboryl with 3 to 12 carbon atoms. In the present disclosure, a “substituted” functional group may be substituted by one or two or more substituents in the Rc; when two substituents Rc are connected to a same atom, the two substituents Rc may independently be present; and when two adjacent substituents Rc are present on the functional group, the two adjacent substituents Rc may independently be present.

In the present disclosure, the number of carbon atoms in a substituted or unsubstituted functional group refers to the number of all carbon atoms. For example, if Rₐ is selected from substituted aryl with 20 carbon atoms, then the number of all carbon atoms of the aryl and sub stituents on the aryl is 20.

In the present disclosure, aryl refers to an optional functional group or substituent derived from an aromatic carbocyclic ring. The aryl may be monocyclic aryl (e.g., phenyl) or polycyclic aryl, in other words, the aryl can be monocyclic aryl, fused aryl, two or more monocyclic aryl conjugatedly connected through carbon-carbon bonds, monocyclic aryl and fused aryl which are conjugatedly connected through a carbon-carbon bond, and two or more fused aryl conjugatedly connected through carbon-carbon bonds. That is, unless otherwise noted, two or more aromatic groups conjugatedly connected through carbon-carbon bonds can also be regarded as the aryl of the present disclosure. The aryl does not contain heteroatoms such as B, N, O, S, P, Se and Si. In the present disclosure, examples of the aryl may include, but are not limited to, phenyl, naphthyl, anthryl, biphenyl, terphenyl, quaterphenyl, quinquephenyl, benzo[9,10]phenanthryl, pyrenyl, benzofluoranthenyl, chrysenyl, and the like. The “substituted or unsubstituted aryl” of the present disclosure can contain 6 to 20 carbon atoms, and in some embodiments, the number of carbon atoms in the aryl can be 6 to 12. The number of carbon atoms of the substituted or unsubstituted aryl may be 6, 12, 13, 14, 15, 18 or 20, and of course, the number of carbon atoms may also be other numbers, which will not be listed here.

In the present disclosure, the substituted aryl may be that one or two or more hydrogen atoms in the aryl are substituted by groups such as a deuterium atom, a halogen group, cyano, aryl, heteroaryl, trialkylsilyl, alkyl, cycloalkyl, alkoxy, alkylthio and the like. It should be understood that the number of carbon atoms in the substituted aryl refers to the total number of carbon atoms of the aryl and substituents on the aryl, for example, a substituted aryl with 18 carbon atoms means that the total number of carbon atoms of the aryl and substituents is 18.

In the present disclosure, specific examples of aryl as a substituent include, but are not limited to, phenyl, naphthyl, anthryl, phenanthryl, biphenyl, terphenyl, dimethylfluorenyl and the like.

In the present disclosure, the heteroaryl refers to a monovalent aromatic ring or its derivative containing at least one heteroatom in a ring, and the heteroatom can be at least one of B, O, N, P, Si, Se and S. The heteroaryl may be monocyclic heteroaryl or polycyclic heteroaryl, in other words, the heteroaryl may be a single aromatic ring system or a plurality of aromatic ring systems conjugatedly connected through carbon-carbon bonds, and any aromatic ring system is one aromatic monocyclic ring or one aromatic fused ring. For example, the heteroaryl may include thienyl, furyl, pyrrolyl, imidazolyl, thiazolyl, oxazolyl, oxadiazolyl, triazolyl, pyridyl, bipyridyl, pyrimidinyl, triazinyl, acridinyl, pyridazinyl, pyrazinyl, quinolyl, quinazolinyl, quinoxalinyl, phenothiazinyl, phenoxazinyl, phthalazinyl, pyridinopyrimidyl, pyridinopyrazinyl, pyrazinopyrazinyl, isoquinolyl, indolyl, carbazolyl, benzoxazolyl, benzimidazolyl, benzothiazolyl, benzocarbazolyl, benzothienyl, dibenzothienyl, thienothienyl, benzofuryl, phenanthrolinyl, isoxazolyl, thiadiazolyl, benzothiazolyl, phenothiazinyl, dibenzofuryl and N-arylcarbazolyl (e.g., N-phenylcarbazolyl), N-heteroarylcarbazolyl (e.g., N-pyridylcarbazolyl), N-alkylcarbazolyl (e.g., N-methylcarbazolyl), and the like, but is not limited to this. Wherein the thienyl, furyl, phenanthrolinyl and the like are heteroaryl of the single aromatic ring system, and the N-arylcarbazolyl and N-heteroarylcarbazolyl are heteroaryl of the plurality of aromatic ring systems conjugatedly connected through carbon-carbon bonds. The “substituted or unsubstituted heteroaryl” of the present disclosure may contain 3 to 20 carbon atoms. For example, the number of carbon atoms of the substituted or unsubstituted heteroaryl may be 3, 4, 5, 7, 12, 13, 18 or 20, and of course, the number of carbon atoms may also be other numbers, which will not be listed here.

In the present disclosure, the substituted heteroaryl may be that one or two or more hydrogen atoms in the heteroaryl are substituted by groups such as a deuterium atom, a halogen group, cyano, aryl, heteroaryl, trialkylsilyl, alkyl, cycloalkyl, alkoxy, alkylthio and the like. It should be understood that the number of carbon atoms of the substituted heteroaryl refers to the total number of carbon atoms of heteroaryl and substituents on the heteroaryl.

In the present disclosure, specific examples of heteroaryl as a substituent include, but are not limited to, pyridyl, dibenzofuranyl, dibenzothienyl, and the like.

In the present disclosure, the alkyl with 1 to 20 carbon atoms can be linear alkyl or branched alkyl. Specifically, the alkyl with 1 to 20 carbon atoms can be linear alkyl with 1 to 20 carbon atoms or branched alkyl with 3 to 20 carbon atoms. The number of carbon atoms may be, for example, 1, 2, 3, 4, 5, 6, 7, 8, 9, 10, 11, 12, 13, 14, 15, 16, 17, 18, 19 or 20. Specific examples of the alkyl with 1 to 20 carbon atoms include, but are not limited to, methyl, ethyl, n-propyl, isopropyl, n-butyl, isobutyl, tert-butyl, n-pentyl, isopentyl, neopentyl, n-hexyl, heptyl, n-octyl, 2-ethylhexyl, nonyl, decyl or 3,7-dimethyloctyl and the like.

In the present disclosure, the halogen group can be fluorine, chlorine, bromine or iodine.

In the present disclosure, specific examples of haloalkyl with 1 to 20 carbon atoms include, but are not limited to, trifluoromethyl and the like.

In the present disclosure, specific examples of the trialkylsilyl with 3 to 20 carbon atoms include, but are not limited to, trimethylsilyl or triethylsilyl and the like.

In the present disclosure, specific examples of the cycloalkyl with 3 to 20 carbon atoms include, but are not limited to, cyclopentyl, cyclohexyl, norbornyl or adamantyl, and the like.

In the present disclosure, an unpositioned connecting bond refers to a single bond

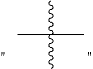

extending from a ring system, which means that one end of the connecting bond can be connected with any position in the ring system through which the bond penetrates, and the other end of the connecting bond is connected with the remaining part of a compound molecule.

For example, as shown in the following formula (f), naphthyl represented by the formula (f) is connected to other positions of a molecule through two unpositioned connecting bonds penetrating a dicyclic ring, and its meaning includes any one possible connecting mode represented by formulae (f-1) to (f-10).

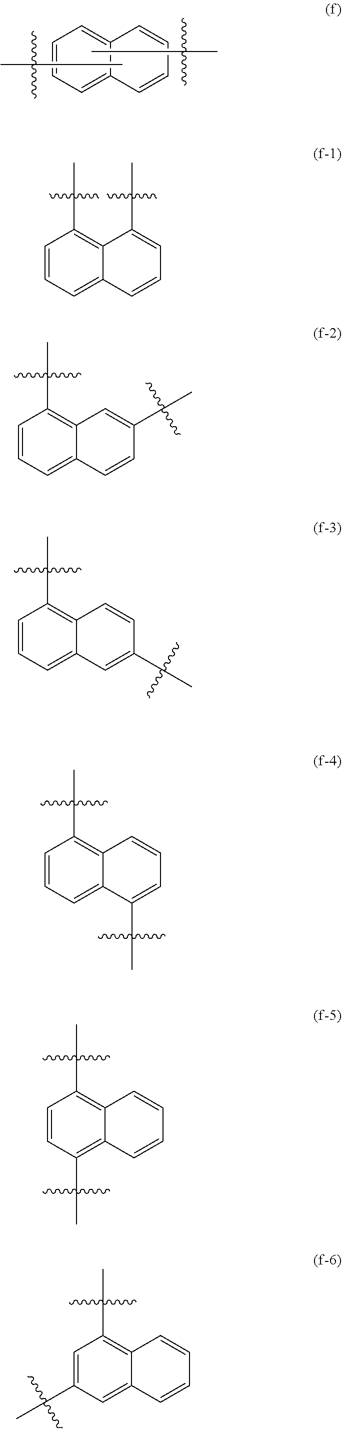

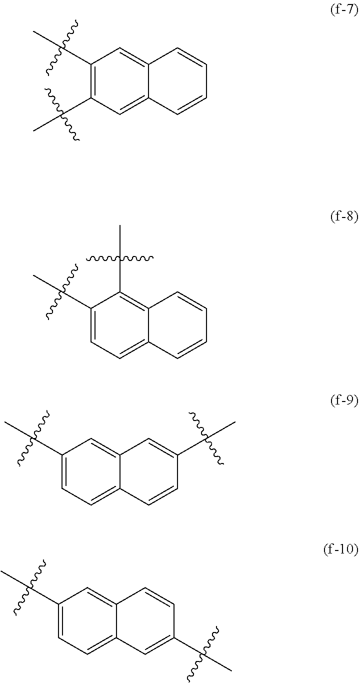 [SMILES: *c1cc2ccccc2cc1* ; *c1ccc2ccccc2c1* ; *c1ccc2ccc(*)cc2c1 ; *c1ccc2cc(*)ccc2c1]

For example, as shown in the following formula (X′), dibenzofuranyl represented by the formula (X′) is connected with other positions of a molecule through one unpositioned connecting bond extending from the middle of a benzene ring on one side, and its meaning includes any one possible connecting mode represented by formulae (X′-1) to (X′-4).

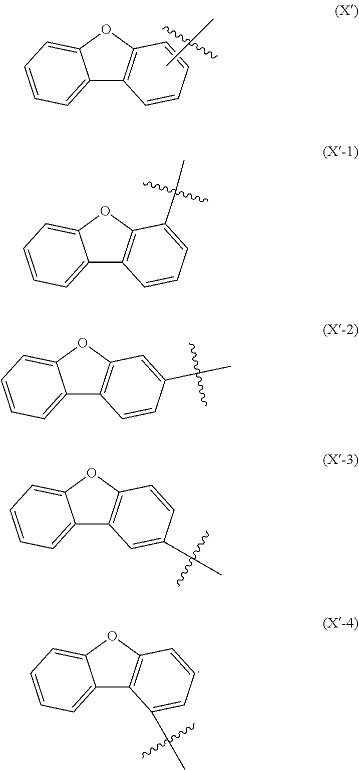

An unpositioned substituent in the present disclosure refers to a substituent connected through a single bond extending from the center of a ring system, which means that the substituent can be connected to any possible position in the ring system. For example, as shown in the following formula (Y), a substituent R′ represented by the formula (Y) is connected with a quinoline ring through one unpositioned connecting bond, and its meaning includes any possible connecting mode represented by formulae (Y-1) to (Y-7).

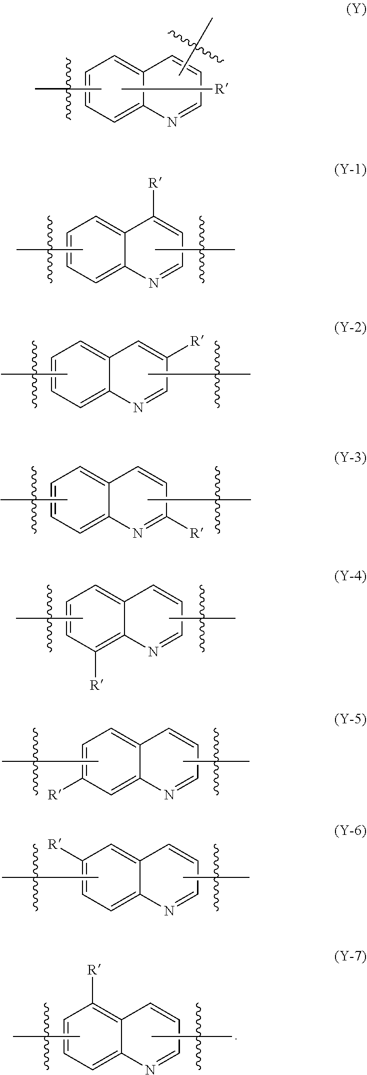

In some embodiments of the present disclosure, the organic compound is selected from the group consisting of structures represented by formulae K to Q below:
the formula K is obtained by fusing any one of a ring F, a ring G or a ring H in a formula (1-1) below with one of the Ar groups;
the formula L is obtained by separately fusing a ring E and a ring F in a formula (1-2) below with one of the Ar groups, and the two Ar groups are the same or different;
the formula M is obtained by separately fusing a ring F and a ring G in a formula (1-3) below with one of the Ar groups, and the two Ar groups are the same or different;
the formula N is obtained by separately fusing a ring F and a ring H in a formula (1-4) below with one of the Ar groups, and the two Ar groups are the same or different;
the formula O is obtained by separately fusing a ring G and a ring H in a formula (1-5) below with one of the Ar groups, and the two Ar groups are the same or different;
the formula P is obtained by separately fusing a ring E and a ring G in a formula (1-6) below with one of the Ar groups, and the two Ar groups are the same or different;
the formula Q is obtained by separately fusing a ring G and a ring J in a formula (1-7) below with one of the Ar groups, and the two Ar groups are the same or different; and
the structure represented by the formula (1-1), the formula (1-2), the formula (1-3), the formula (1-4), the formula (1-5), the formula (1-6), or the formula (1-7) is shown below:

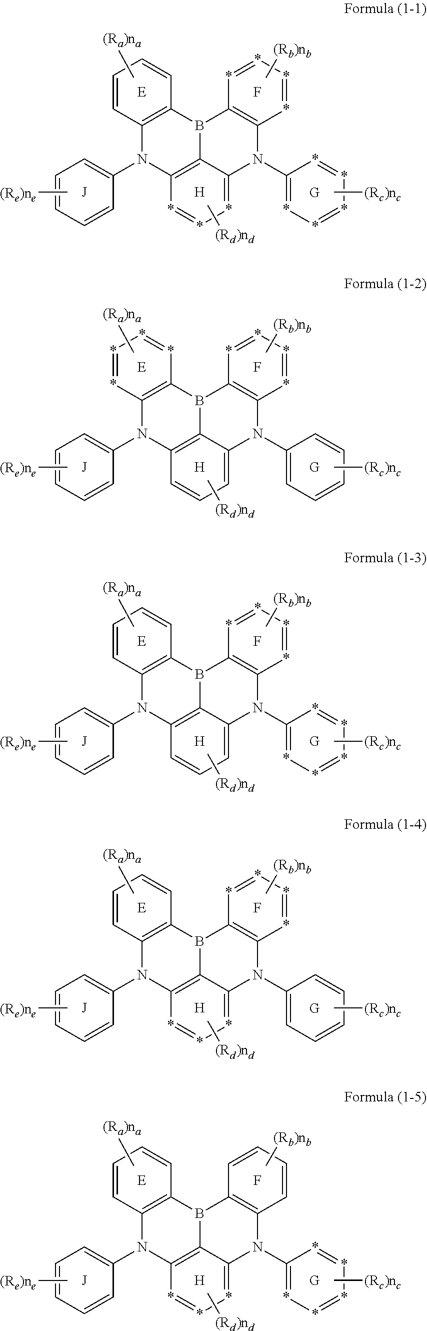

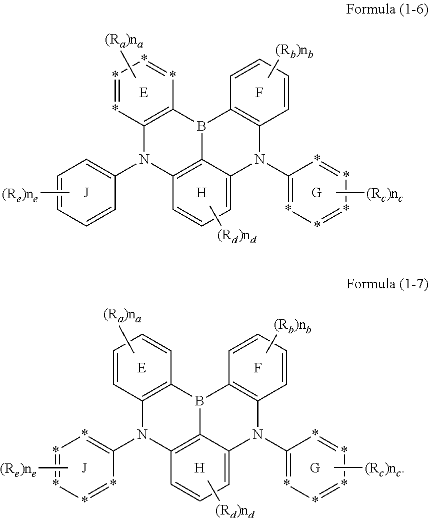

In some embodiments of the present disclosure, in the formula K, the Ar group fused with the ring F is selected from

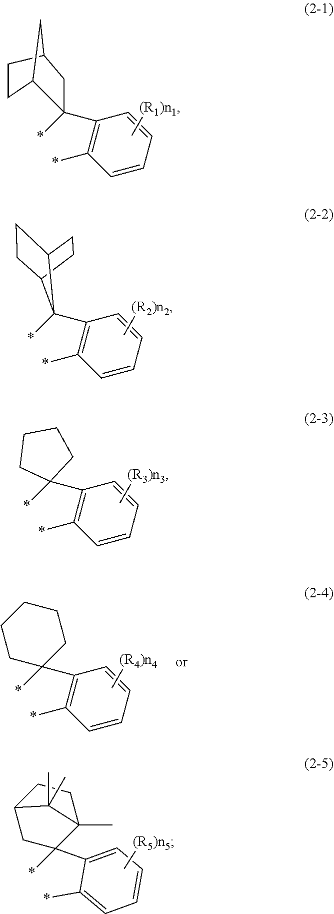

and

in the formula K, the Ar group fused with the ring G is selected from

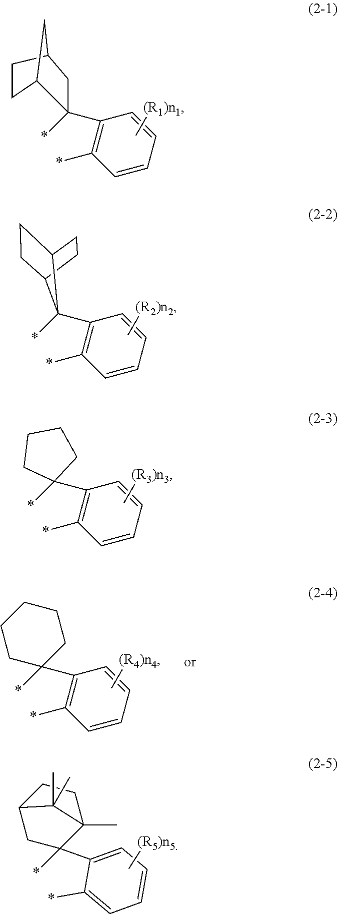

In some embodiments of the present disclosure, in the formula L, the Ar group fused with the ring E is selected from

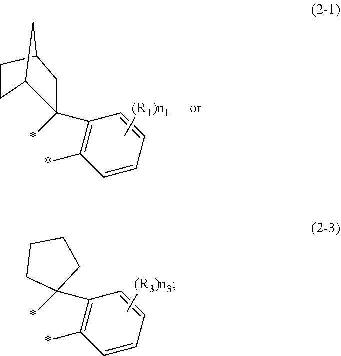

in the formula L, the Ar group fused with the ring F is selected from

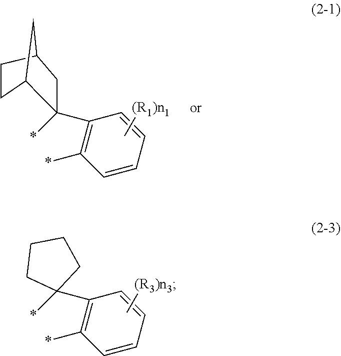

in some embodiments of the present disclosure, in the formula P, the Ar group fused with the ring E is selected from

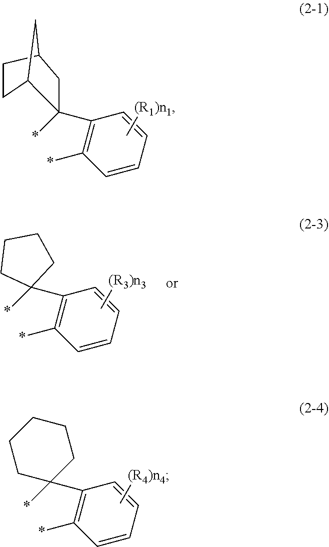

in the formula P, the Ar group fused with the ring G is selected from

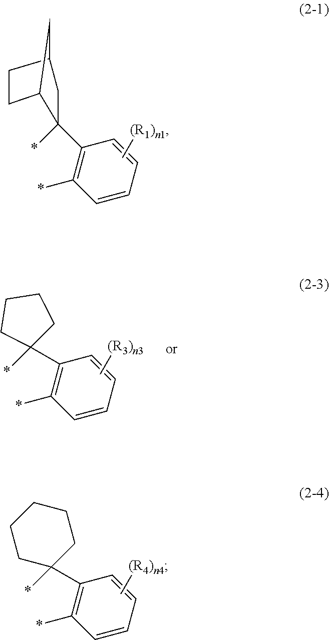

in some embodiments of the present disclosure, in the formula Q, the Ar group fused with the ring G is selected from

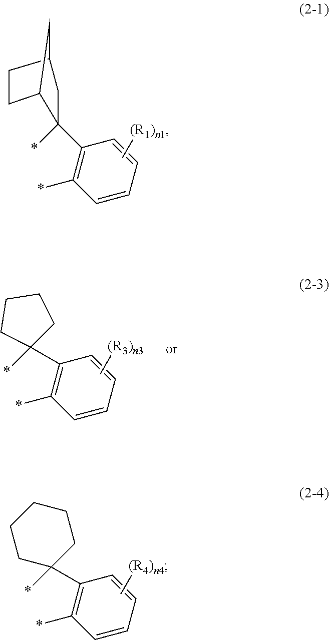

and

in the formula Q, the Ar group fused with the ring J is selected from

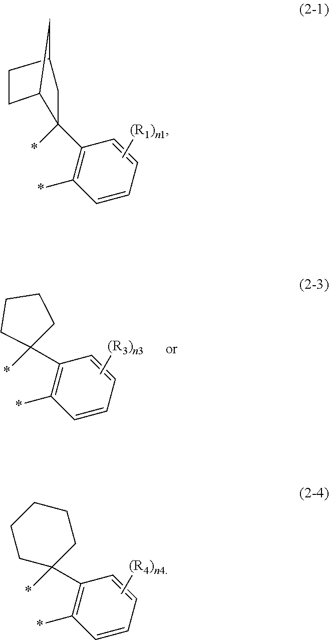

In some embodiments of the present disclosure, the Rₐ, the R_{b}, the R_{c}, the R_{d}, and the Rₑ are the same or different from each other, and are each independently selected from deuterium, a halogen group, cyano, alkyl with 1 to 5 carbon atoms, substituted or unsubstituted aryl with 6 to 15 carbon atoms, substituted or unsubstituted heteroaryl with 5 to 12 carbon atoms, trialkylsilyl with 3 to 6 carbon atoms, and haloalkyl with 1 to 5 carbon atoms.

Optionally, sub stituents in the Rₐ, the R_{b}, the R_{c}, the R_{d} and the Rₑ are the same or different from each other, and are each independently selected from deuterium, a halogen group, cyano or alkyl with 1 to 5 carbon atoms, trialkylsilyl with 3 to 6 carbon atoms or haloalkyl with 1 to 5 carbon atoms.

Further optionally, the substituents in the Rₐ, the R_{b}, the R_{c}, the R_{d} and the Rₑ are the same or different from each other, and are each independently selected from deuterium, a halogen group, cyano or alkyl with 1 to 5 carbon atoms.

Specifically, specific examples of the substituents in the Rₐ, the R_{b}, the R_{c}, the R_{d} and the Rₑ include, but are not limited to, deuterium, fluorine, cyano, methyl, ethyl, n-propyl, isopropyl, tert-butyl, trimethylsilyl or trifluoromethyl.

In other embodiments of the present disclosure, the Rₐ, the R_{b}, the R_{c}, the R_{d} and the Rₑ are the same or different from each other, and are each independently selected from deuterium, fluorine, cyano, methyl, ethyl, n-propyl, isopropyl, tert-butyl, trimethylsilyl, trifluoromethyl, substituted or unsubstituted phenyl, substituted or unsubstituted naphthyl, substituted or unsubstituted phenanthryl, and substituted or unsubstituted biphenyl.

In some embodiments of the present disclosure, the Rₐ, the R_{b}, the R_{c}, the R_{d} and the Rₑ are the same or different from each other, and are each independently selected from deuterium, cyano, fluorine, alkyl with 1 to 5 carbon atoms, trialkylsilyl with 3 to 6 carbon atoms, haloalkyl with 1 to 5 carbon atoms, and a substituted or unsubstituted group W, wherein the unsubstituted group W is selected from the group consisting of the following groups:

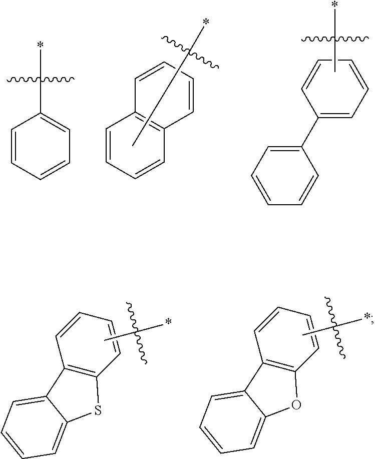

wherein the substituted group W has one or two or more substituents each independently selected from deuterium, fluorine, cyano, methyl, ethyl, n-propyl, isopropyl, tert-butyl, trimethylsilyl or trifluoromethyl; and when the number of the substituents of the group W is greater than 1, the substituents are the same or different.

Optionally, the Rₐ, the R_{b}, the R_{c}, the R_{d} and the Rₑ are the same or different from each other, and are each independently selected from deuterium, fluorine, cyano, methyl, ethyl, n-propyl, isopropyl, tert-butyl, trimethylsilyl, trifluoromethyl or the group consisting of the following groups:

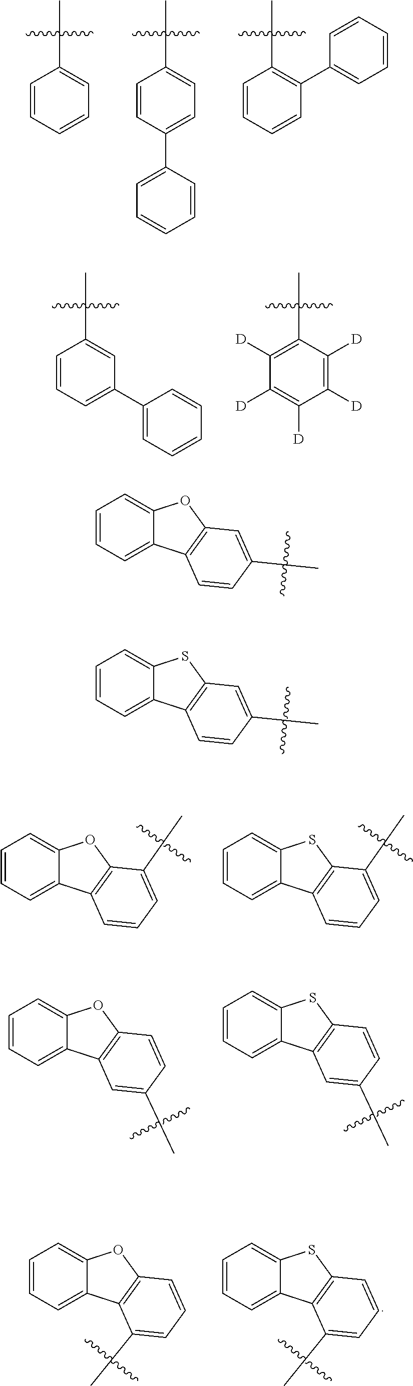

In one embodiment of the present disclosure, the n₁, the n₂, the n₃, the n₄ and the n₅ are all 0.

In one specific embodiment of the present disclosure, the organic compound is selected from the following compounds:

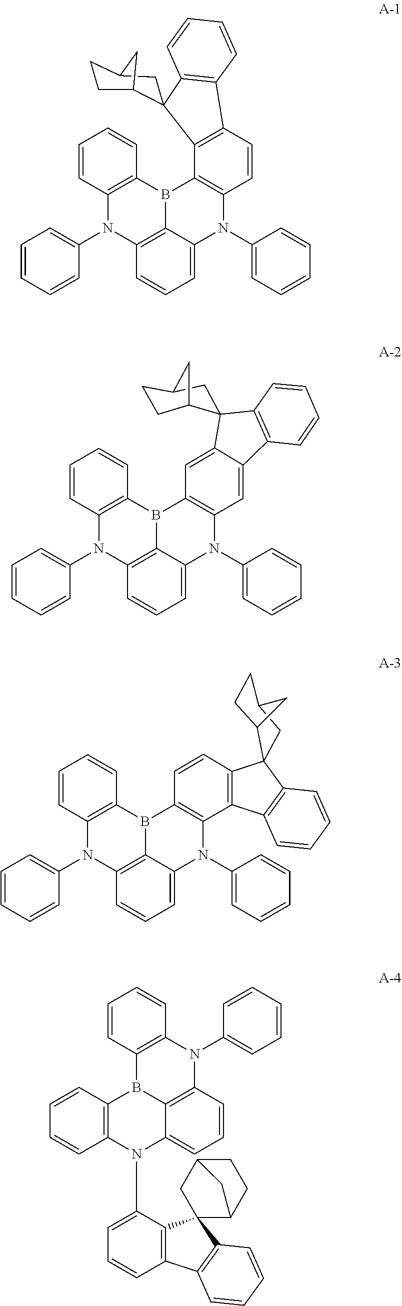 [SMILES: c1ccc(N2c3ccccc3B3c4c2cccc4N(c2ccccc2)c2ccc4c(c23)C2(CC3CCC2C3)c2ccccc2-4)cc1 ; c1ccc(N2c3ccccc3B3c4cc5c(cc4N(c4ccccc4)c4cccc2c43)-c2ccccc2C52CC3CCC2C3)cc1 ; c1ccc(N2c3ccccc3B3c4ccc5c(c4N(c4ccccc4)c4cccc2c43)-c2ccccc2C52CC3CCC2C3)cc1 ; c1ccc(N2c3ccccc3B3c4ccccc4N(c4cccc5c4[C@@]4(CC6CCC4C6)c4ccccc4-5)c4cccc2c43)cc1]

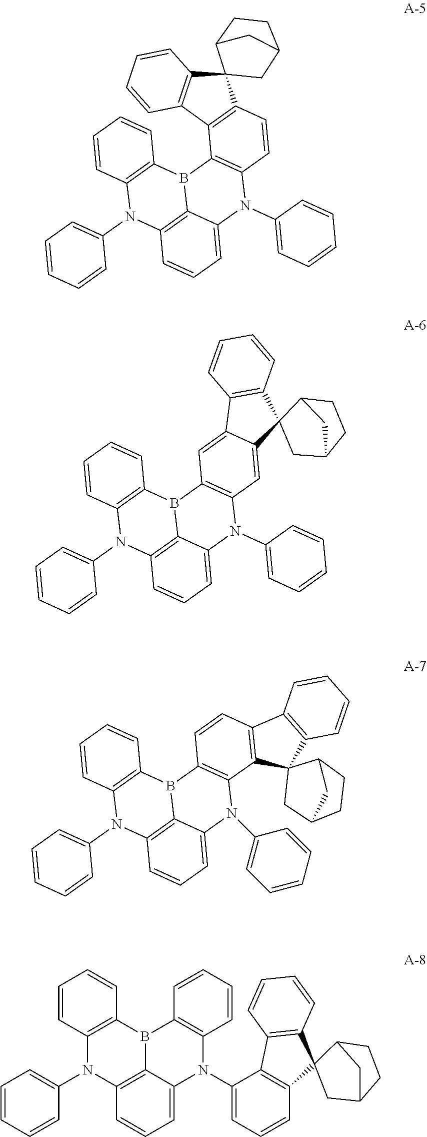

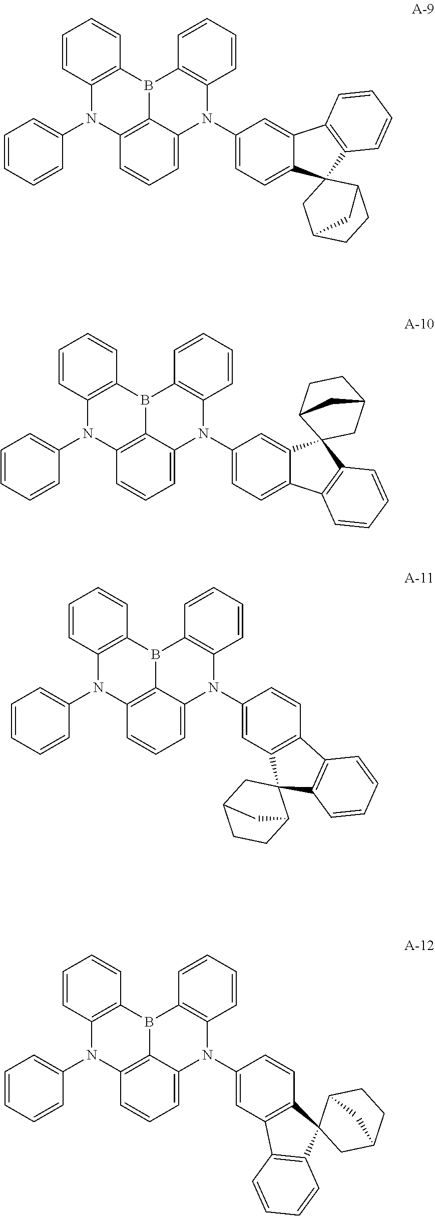 [SMILES: c1ccc(N2c3ccccc3B3c4ccccc4N(c4ccc5c(c4)-c4ccccc4[C@]54C[C@@H]5CCC4C5)c4cccc2c43)cc1 ; c1ccc(N2c3ccccc3B3c4ccccc4N(c4ccc5c(c4)[C@]4(C[C@H]6CC[C@@H]4C6)c4ccccc4-5)c4cccc2c43)cc1 ; c1ccc(N2c3ccccc3B3c4ccccc4N(c4ccc5c(c4)[C@]4(CC6CC[C@H]4C6)c4ccccc4-5)c4cccc2c43)cc1 ; c1ccc(N2c3ccccc3B3c4ccccc4N(c4ccc5c(c4)-c4ccccc4[C@]54C[C@@H]5CC[C@H]4C5)c4cccc2c43)cc1]

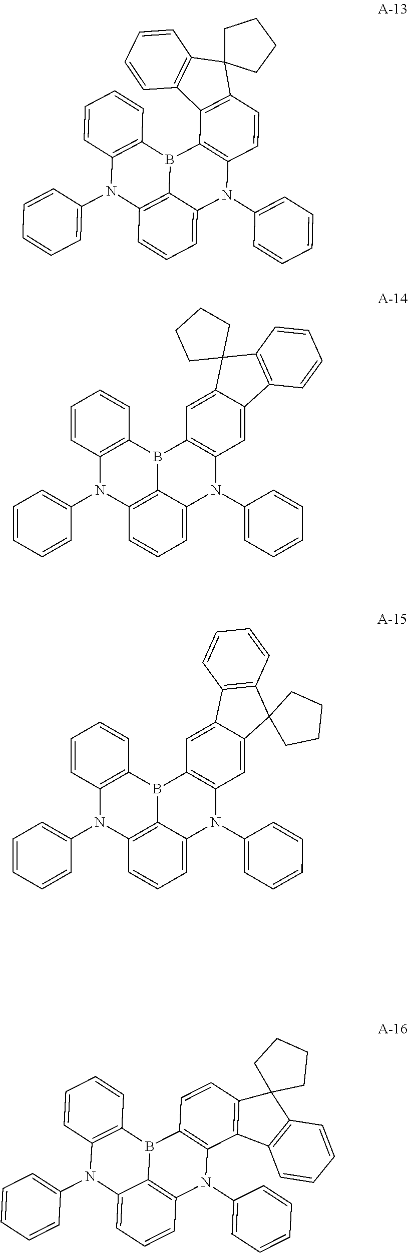 [SMILES: c1ccc(N2c3ccccc3B3c4c2cccc4N(c2ccccc2)c2ccc4c(c23)-c2ccccc2C42CCCC2)cc1 ; c1ccc(N2c3ccccc3B3c4cc5c(cc4N(c4ccccc4)c4cccc2c43)-c2ccccc2C52CCCC2)cc1 ; c1ccc(N2c3ccccc3B3c4cc5c(cc4N(c4ccccc4)c4cccc2c43)C2(CCCC2)c2ccccc2-5)cc1 ; c1ccc(N2c3ccccc3B3c4ccc5c(c4N(c4ccccc4)c4cccc2c43)-c2ccccc2C52CCCC2)cc1]

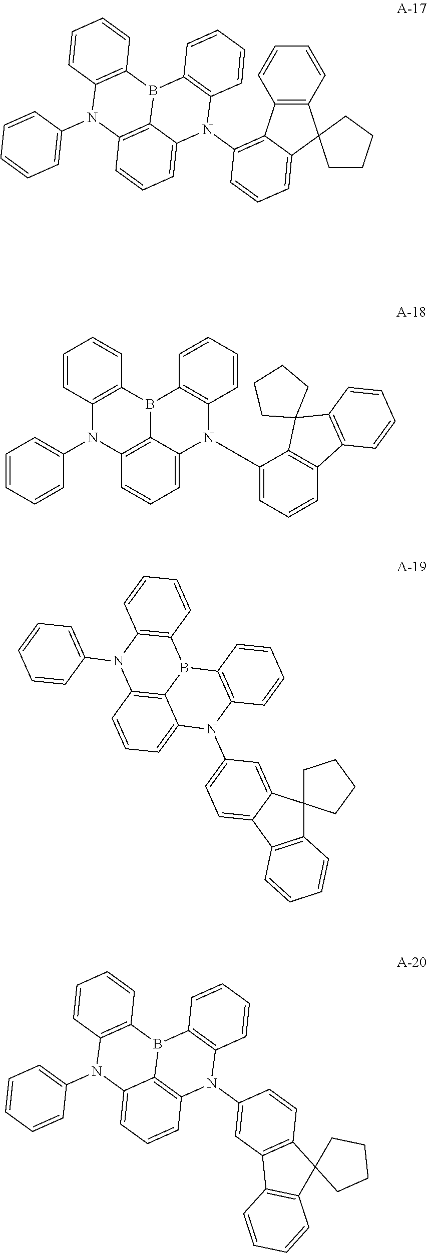 [SMILES: c1ccc(N2c3ccccc3B3c4ccccc4N(c4cccc5c4-c4ccccc4C54CCCC4)c4cccc2c43)cc1 ; c1ccc(N2c3ccccc3B3c4ccccc4N(c4cccc5c4C4(CCCC4)c4ccccc4-5)c4cccc2c43)cc1 ; c1ccc(N2c3ccccc3B3c4ccccc4N(c4ccc5c(c4)C4(CCCC4)c4ccccc4-5)c4cccc2c43)cc1 ; c1ccc(N2c3ccccc3B3c4ccccc4N(c4ccc5c(c4)-c4ccccc4C54CCCC4)c4cccc2c43)cc1]

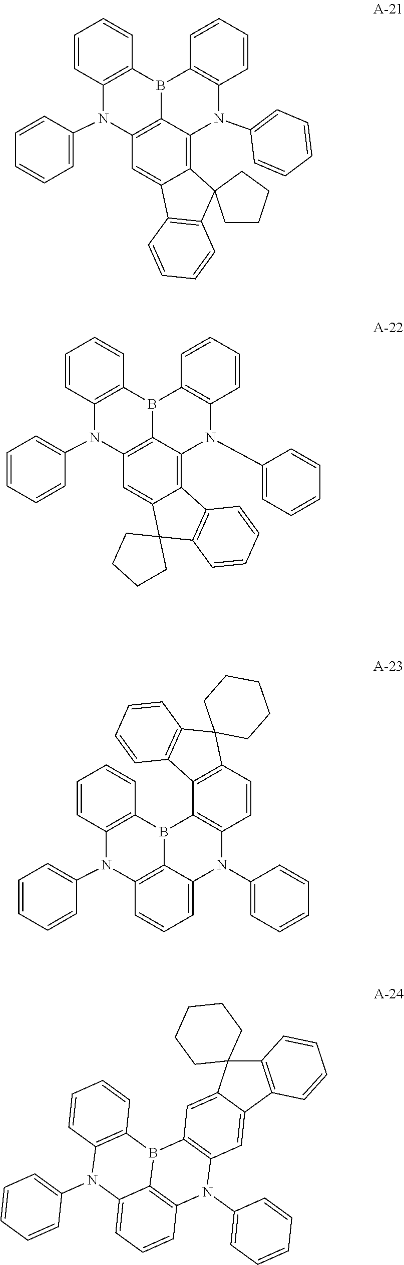 [SMILES: c1ccc(N2c3ccccc3B3c4ccccc4N(c4ccccc4)c4c3c2cc2c4C3(CCCC3)c3ccccc3-2)cc1 ; c1ccc(N2c3ccccc3B3c4ccccc4N(c4ccccc4)c4c3c2cc2c4-c3ccccc3C23CCCC3)cc1 ; c1ccc(N2c3ccccc3B3c4c2cccc4N(c2ccccc2)c2ccc4c(c23)-c2ccccc2C42CCCCC2)cc1 ; c1ccc(N2c3ccccc3B3c4cc5c(cc4N(c4ccccc4)c4cccc2c43)-c2ccccc2C52CCCCC2)cc1]

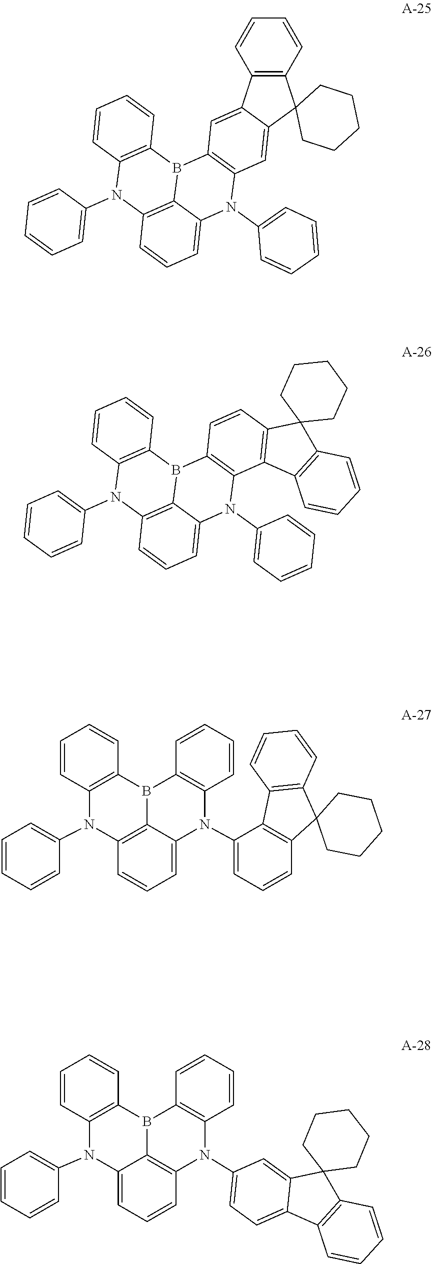 [SMILES: c1ccc(N2c3ccccc3B3c4cc5c(cc4N(c4ccccc4)c4cccc2c43)C2(CCCCC2)c2ccccc2-5)cc1 ; c1ccc(N2c3ccccc3B3c4ccc5c(c4N(c4ccccc4)c4cccc2c43)-c2ccccc2C52CCCCC2)cc1 ; c1ccc(N2c3ccccc3B3c4ccccc4N(c4cccc5c4-c4ccccc4C54CCCCC4)c4cccc2c43)cc1 ; c1ccc(N2c3ccccc3B3c4ccccc4N(c4ccc5c(c4)C4(CCCCC4)c4ccccc4-5)c4cccc2c43)cc1]

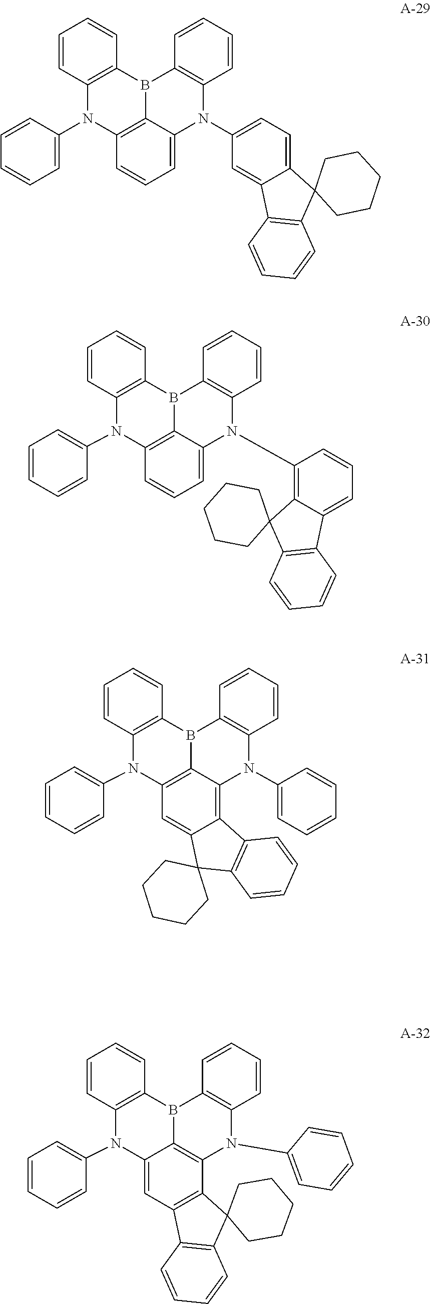 [SMILES: c1ccc(N2c3ccccc3B3c4ccccc4N(c4ccc5c(c4)-c4ccccc4C54CCCCC4)c4cccc2c43)cc1 ; c1ccc(N2c3ccccc3B3c4ccccc4N(c4cccc5c4C4(CCCCC4)c4ccccc4-5)c4cccc2c43)cc1 ; c1ccc(N2c3ccccc3B3c4ccccc4N(c4ccccc4)c4c3c2cc2c4-c3ccccc3C23CCCCC3)cc1 ; c1ccc(N2c3ccccc3B3c4ccccc4N(c4ccccc4)c4c3c2cc2c4C3(CCCCC3)c3ccccc3-2)cc1]

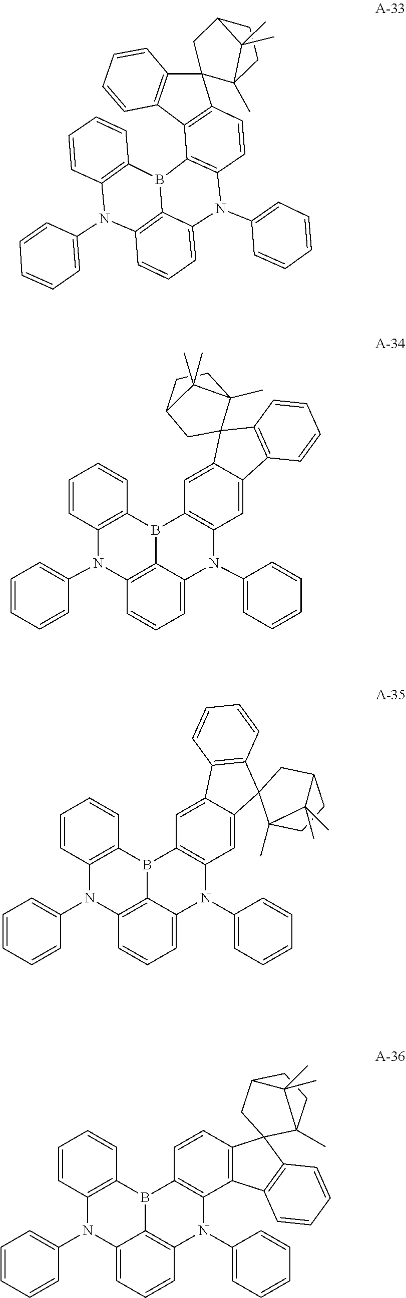 [SMILES: CC1(C)C2CCC1(C)C1(C2)c2ccccc2-c2c1ccc1c2B2c3ccccc3N(c3ccccc3)c3cccc(c32)N1c1ccccc1 ; CCC1CC2(c3ccccc3-c3cc4c(cc32)B2c3ccccc3N(c3ccccc3)c3cccc(c32)N4c2ccccc2)C(C)(CC)C1(C)C ; CC1(C)C2CCC1(C)C1(C2)c2ccccc2-c2cc3c(cc21)N(c1ccccc1)c1cccc2c1B3c1ccccc1N2c1ccccc1 ; CC1(C)C2CCC1(C)C1(C2)c2ccccc2-c2c1ccc1c2N(c2ccccc2)c2cccc3c2B1c1ccccc1N3c1ccccc1]

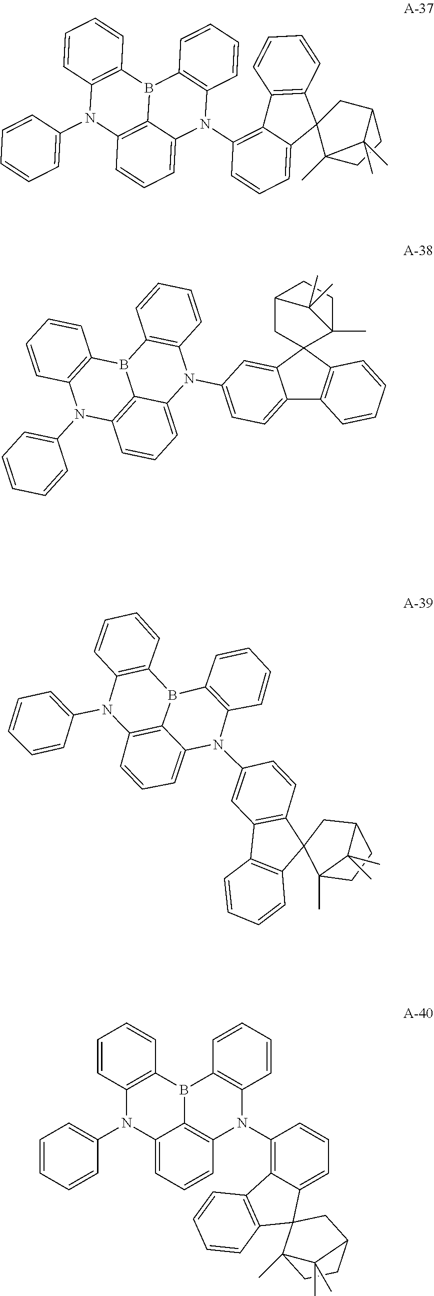 [SMILES: CC1(C)C2CCC1(C)C1(C2)c2ccccc2-c2c(N3c4ccccc4B4c5ccccc5N(c5ccccc5)c5cccc3c54)cccc21 ; CC1(C)C2CCC1(C)C1(C2)c2ccccc2-c2ccc(N3c4ccccc4B4c5ccccc5N(c5ccccc5)c5cccc3c54)cc21 ; CC1(C)C2CCC1(C)C1(C2)c2ccccc2-c2cc(N3c4ccccc4B4c5ccccc5N(c5ccccc5)c5cccc3c54)ccc21 ; CC1(C)C2CCC1(C)C1(C2)c2ccccc2-c2c(N3c4ccccc4B4c5ccccc5N(c5ccccc5)c5cccc3c54)cccc21]

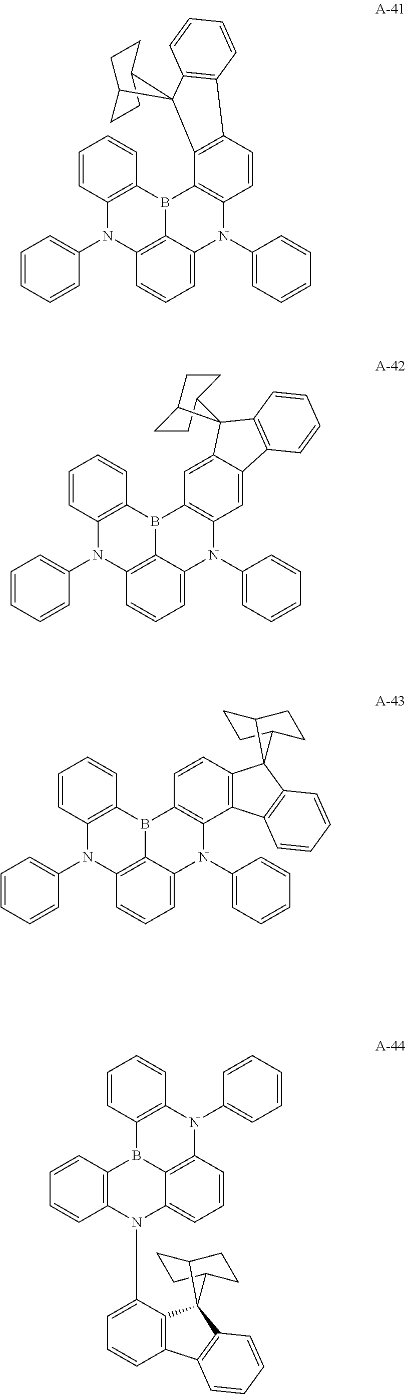

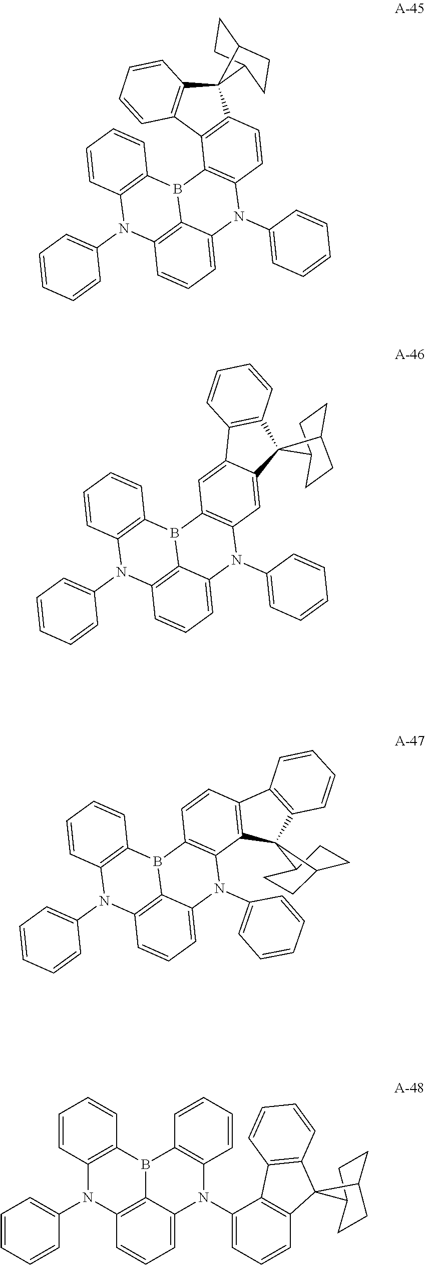

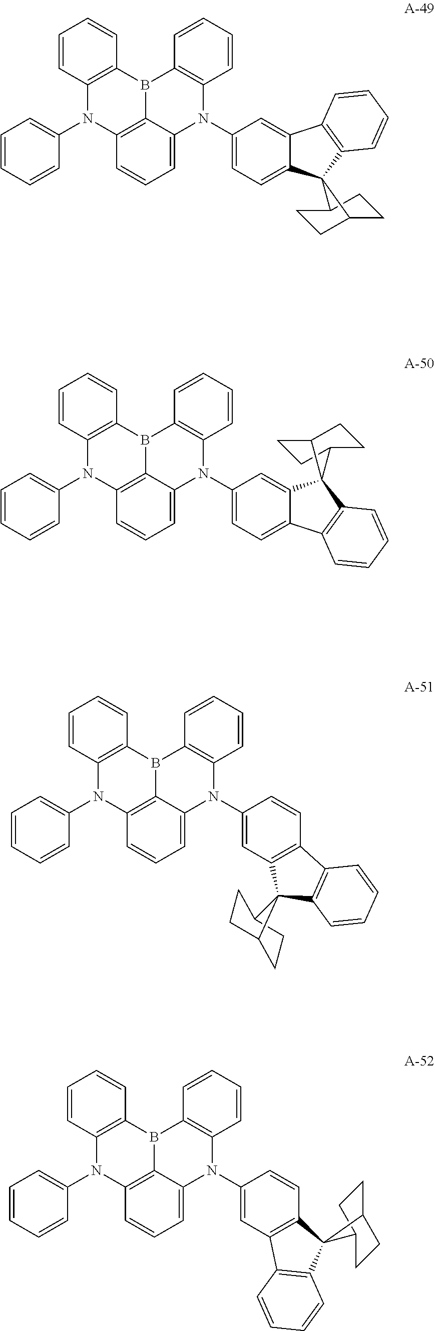

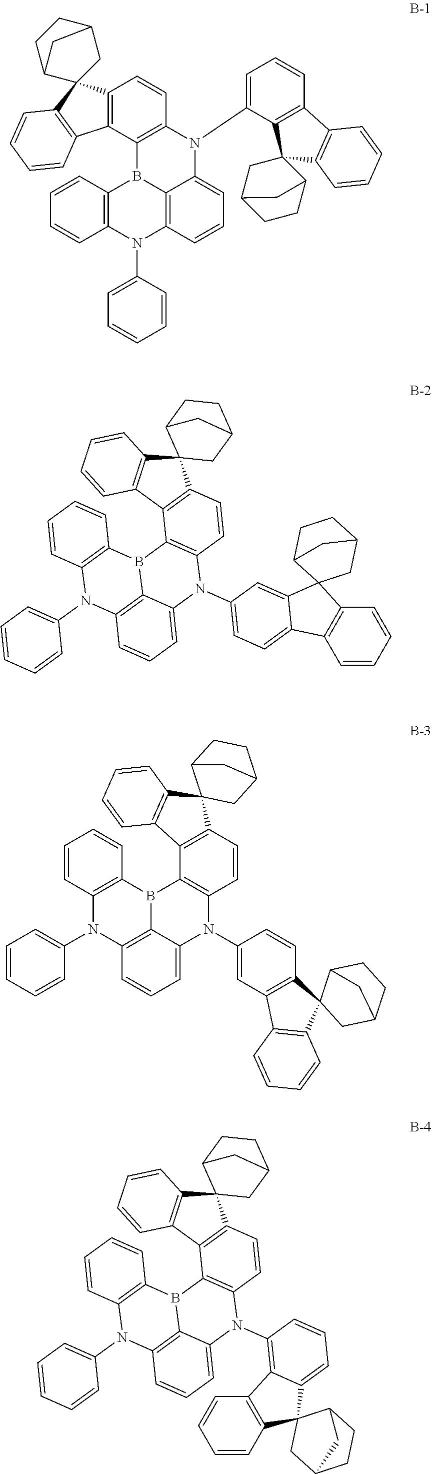 [SMILES: c1ccc(N2c3ccccc3B3c4c2cccc4N(c2cccc4c2[C@@]2(CC5CCC2C5)c2ccccc2-4)c2ccc4c(c23)-c2ccccc2[C@@]42CC3CCC2C3)cc1 ; c1ccc(N2c3ccccc3B3c4c2cccc4N(c2ccc4c(c2)C2(CC5CCC2C5)c2ccccc2-4)c2ccc4c(c23)-c2ccccc2[C@@]42CC3CCC2C3)cc1 ; c1ccc(N2c3ccccc3B3c4c2cccc4N(c2ccc4c(c2)-c2ccccc2[C@]42CC4CCC2C4)c2ccc4c(c23)-c2ccccc2[C@@]42CC3CCC2C3)cc1 ; c1ccc(N2c3ccccc3B3c4c2cccc4N(c2cccc4c2-c2ccccc2[C@@]42C[C@@H]4CCC2C4)c2ccc4c(c23)-c2ccccc2[C@@]42CC3CCC2C3)cc1]

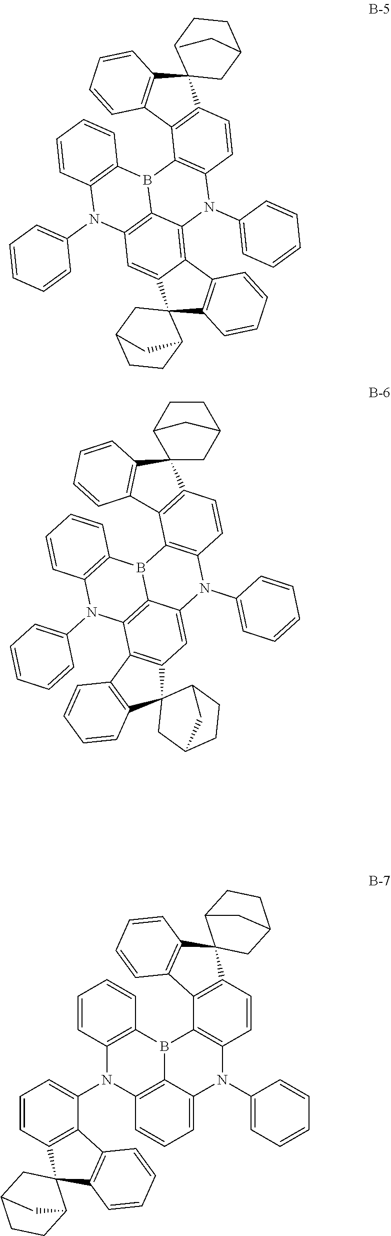

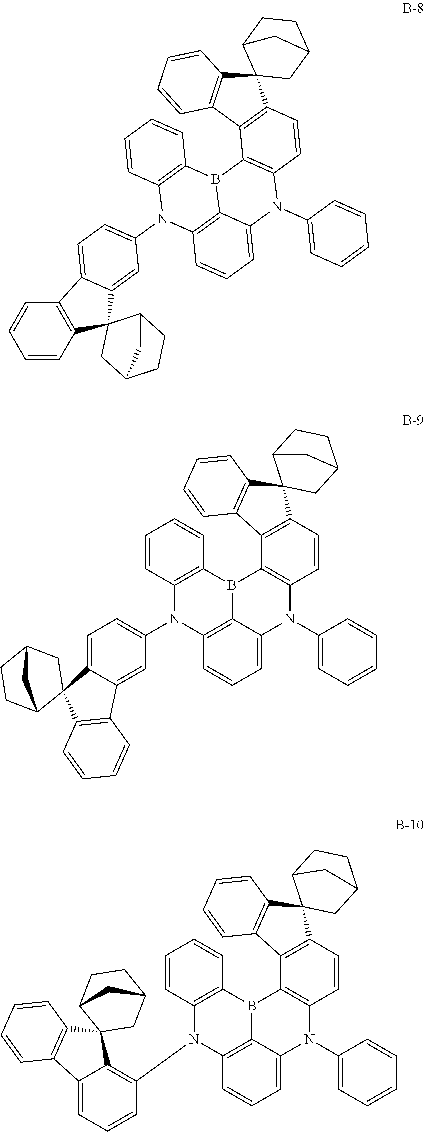 [SMILES: c1ccc(N2c3cccc4c3B(c3ccccc3N4c3ccc4c(c3)[C@]3(C[C@@H]5CCC3C5)c3ccccc3-4)c3c2ccc2c3-c3ccccc3[C@@]23CC2CCC3C2)cc1 ; c1ccc(N2c3cccc4c3B(c3ccccc3N4c3ccc4c(c3)-c3ccccc3[C@]43C[C@H]4CC[C@@H]3C4)c3c2ccc2c3-c3ccccc3[C@@]23CC2CCC3C2)cc1 ; c1ccc(N2c3cccc4c3B(c3ccccc3N4c3cccc4c3[C@@]3(C[C@H]5CC[C@@H]3C5)c3ccccc3-4)c3c2ccc2c3-c3ccccc3[C@@]23CC2CCC3C2)cc1]

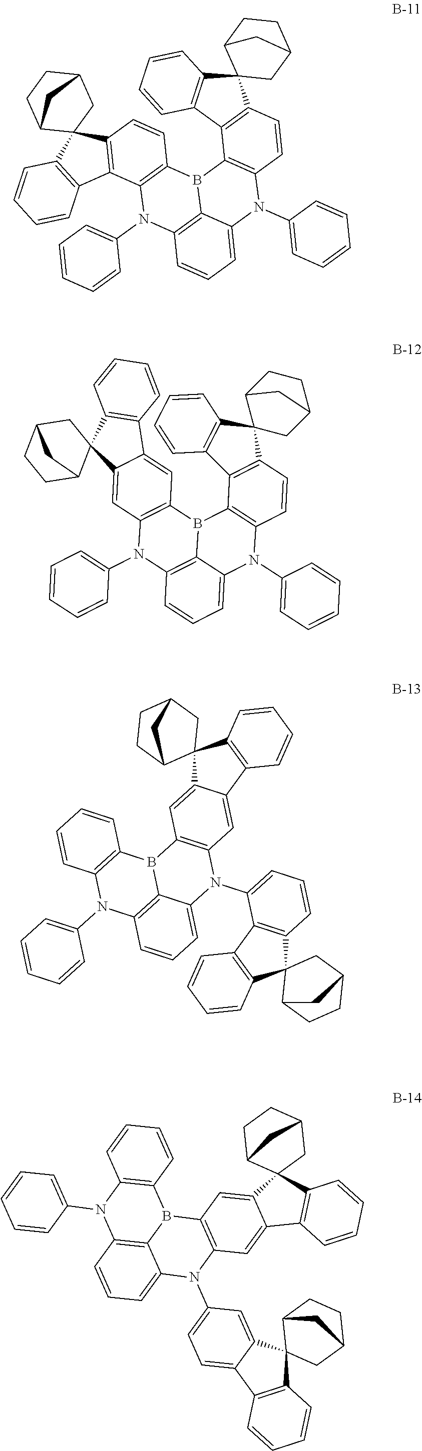 [SMILES: c1ccc(N2c3cccc4c3B(c3ccc5c(c3N4c3ccccc3)-c3ccccc3[C@]53C[C@H]4CC[C@@H]3C4)c3c2ccc2c3-c3ccccc3[C@@]23CC2CCC3C2)cc1 ; c1ccc(N2c3cc4c(cc3B3c5c2cccc5N(c2ccccc2)c2ccc5c(c23)-c2ccccc2[C@@]52CC3CCC2C3)-c2ccccc2[C@]42C[C@H]3CCC2C3)cc1 ; c1ccc(N2c3ccccc3B3c4cc5c(cc4N(c4cccc6c4-c4ccccc4[C@]64C[C@@H]6CCC4C6)c4cccc2c43)-c2ccccc2[C@@]52C[C@H]3CC[C@@H]2C3)cc1 ; c1ccc(N2c3ccccc3B3c4cc5c(cc4N(c4ccc6c(c4)[C@]4(C[C@H]7CC[C@@H]4C7)c4ccccc4-6)c4cccc2c43)-c2ccccc2[C@@]52C[C@H]3CC[C@@H]2C3)cc1]

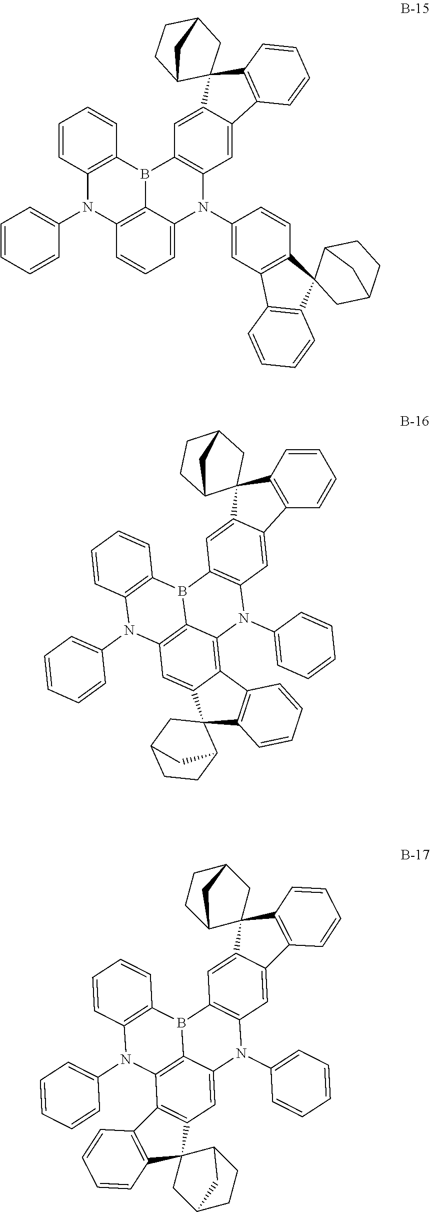 [SMILES: c1ccc(N2c3ccccc3B3c4cc5c(cc4N(c4ccc6c(c4)-c4ccccc4[C@]64CC6CCC4C6)c4cccc2c43)-c2ccccc2[C@@]52C[C@H]3CC[C@@H]2C3)cc1 ; c1ccc(N2c3ccccc3B3c4cc5c(cc4N(c4ccccc4)c4c3c2cc2c4-c3ccccc3[C@@]23CC2CC[C@H]3C2)-c2ccccc2[C@@]52C[C@H]3CC[C@@H]2C3)cc1 ; c1ccc(N2c3cc4c(cc3B3c5ccccc5N(c5ccccc5)c5c3c2cc2c5-c3ccccc3[C@@]23C[C@@H]2CCC3C2)[C@]2(C[C@H]3CC[C@@H]2C3)c2ccccc2-4)cc1]

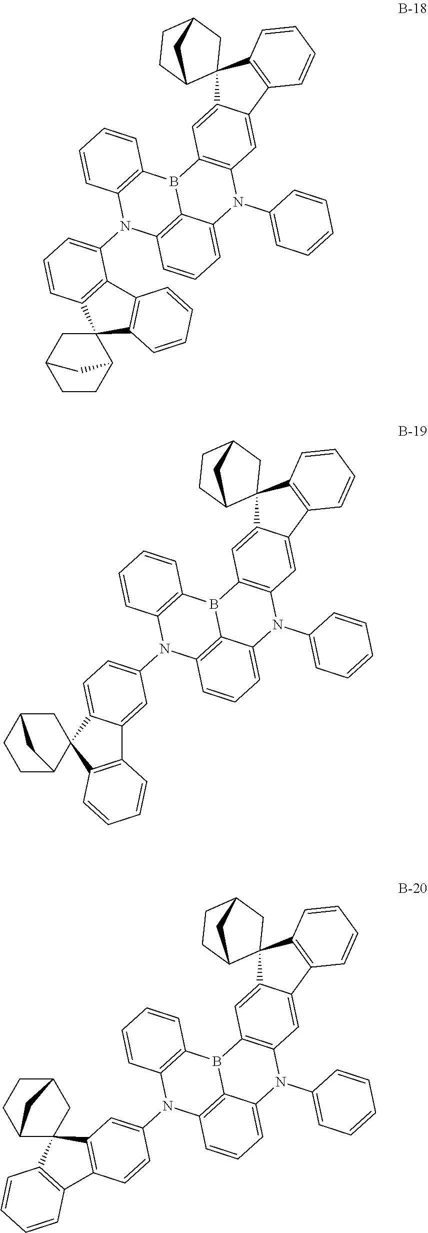 [SMILES: c1ccc(N2c3cc4c(cc3B3c5ccccc5N(c5cccc6c5-c5ccccc5[C@@]65CC6CC[C@H]5C6)c5cccc2c53)[C@]2(C[C@H]3CC[C@@H]2C3)c2ccccc2-4)cc1 ; c1ccc(N2c3cc4c(cc3B3c5ccccc5N(c5ccc6c(c5)-c5ccccc5[C@@]65C[C@H]6CCC5C6)c5cccc2c53)[C@]2(C[C@H]3CC[C@@H]2C3)c2ccccc2-4)cc1 ; c1ccc(N2c3cc4c(cc3B3c5ccccc5N(c5ccc6c(c5)[C@@]5(C[C@H]7CC[C@@H]5C7)c5ccccc5-6)c5cccc2c53)[C@]2(C[C@H]3CC[C@@H]2C3)c2ccccc2-4)cc1]

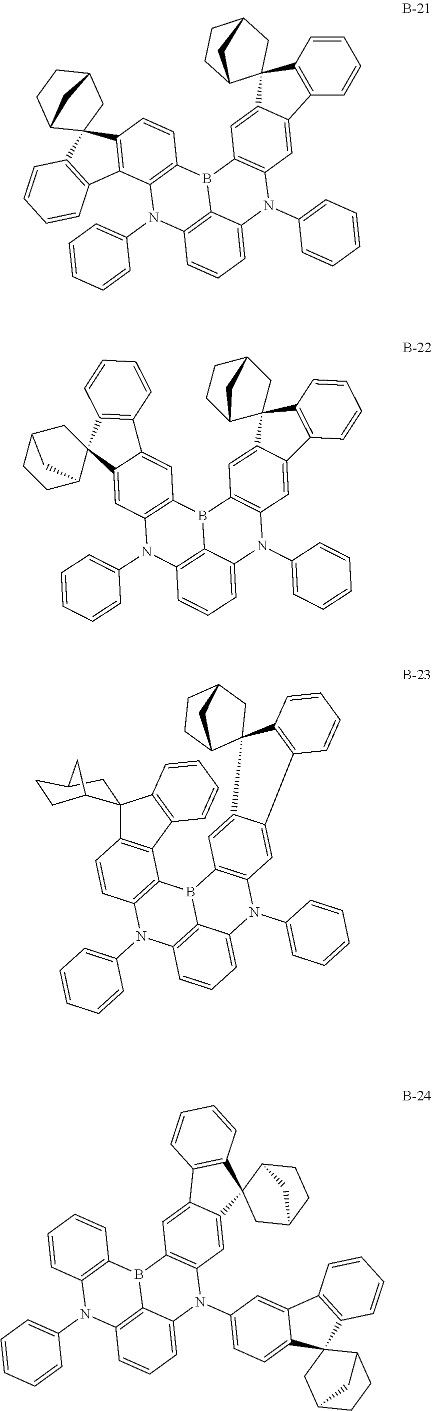 [SMILES: c1ccc(N2c3cc4c(cc3B3c5ccc6c(c5N(c5ccccc5)c5cccc2c53)-c2ccccc2[C@]62C[C@H]3CC[C@@H]2C3)[C@]2(C[C@H]3CC[C@@H]2C3)c2ccccc2-4)cc1 ; c1ccc(N2c3cc4c(cc3B3c5cc6c(cc5N(c5ccccc5)c5cccc2c53)[C@@]2(CC3CC[C@H]2C3)c2ccccc2-6)[C@]2(C[C@H]3CC[C@@H]2C3)c2ccccc2-4)cc1 ; c1ccc(N2c3cc4c(cc3B3c5c2cccc5N(c2ccccc2)c2ccc5c(c23)-c2ccccc2C52CC3CCC2C3)[C@]2(C[C@H]3CC[C@@H]2C3)c2ccccc2-4)cc1 ; c1ccc(N2c3ccccc3B3c4cc5c(cc4N(c4ccc6c(c4)-c4ccccc4[C@]64C[C@@H]6CCC4C6)c4cccc2c43)[C@]2(C[C@@H]3CC[C@H]2C3)c2ccccc2-5)cc1]

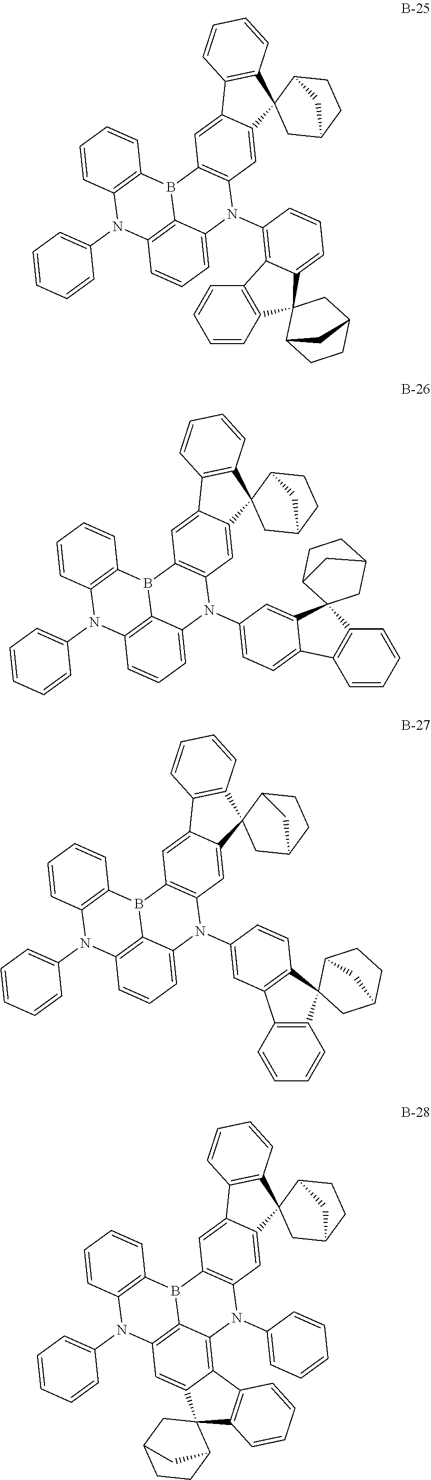 [SMILES: c1ccc(N2c3ccccc3B3c4cc5c(cc4N(c4cccc6c4-c4ccccc4[C@@]64C[C@@H]6CC[C@H]4C6)c4cccc2c43)[C@]2(C[C@@H]3CC[C@H]2C3)c2ccccc2-5)cc1 ; c1ccc(N2c3ccccc3B3c4cc5c(cc4N(c4ccc6c(c4)[C@@]4(CC7CCC4C7)c4ccccc4-6)c4cccc2c43)[C@]2(C[C@@H]3CC[C@H]2C3)c2ccccc2-5)cc1 ; c1ccc(N2c3ccccc3B3c4cc5c(cc4N(c4ccc6c(c4)-c4ccccc4[C@]64C[C@@H]6CC[C@H]4C6)c4cccc2c43)[C@@]2(C[C@@H]3CCC2C3)c2ccccc2-5)cc1 ; c1ccc(N2c3ccccc3B3c4cc5c(cc4N(c4ccccc4)c4c3c2cc2c4-c3ccccc3[C@@]23CC2CC[C@H]3C2)[C@]2(C[C@@H]3CC[C@H]2C3)c2ccccc2-5)cc1]

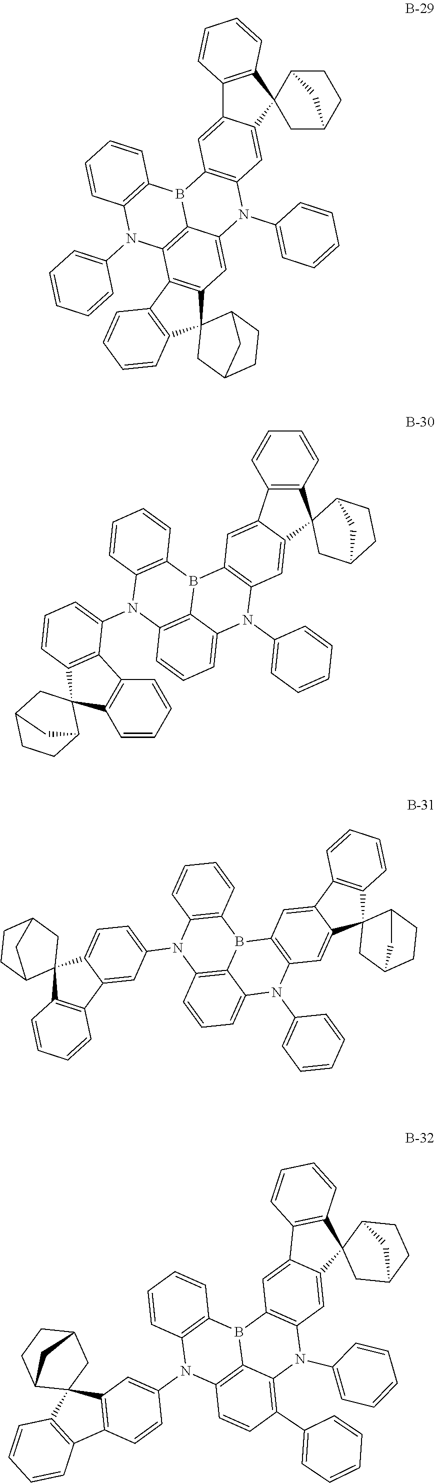 [SMILES: c1ccc(N2c3cc4c(cc3B3c5ccccc5N(c5ccccc5)c5c3c2cc2c5-c3ccccc3[C@]23CC2CCC3C2)-c2ccccc2[C@@]42C[C@@H]3CC[C@H]2C3)cc1 ; c1ccc(N2c3cc4c(cc3B3c5ccccc5N(c5cccc6c5-c5ccccc5[C@@]65CC6CC[C@H]5C6)c5cccc2c53)-c2ccccc2[C@@]42C[C@@H]3CC[C@H]2C3)cc1 ; c1ccc(N2c3cc4c(cc3B3c5ccccc5N(c5ccc6c(c5)-c5ccccc5[C@@]65CC6CCC5C6)c5cccc2c53)-c2ccccc2[C@]42C[C@@H]3CCC2C3)cc1 ; c1ccc(-c2ccc3c4c2N(c2ccccc2)c2cc5c(cc2B4c2ccccc2N3c2ccc3c(c2)[C@@]2(C[C@H]4CC[C@@H]2C4)c2ccccc2-3)-c2ccccc2[C@@]52C[C@@H]3CC[C@H]2C3)cc1]

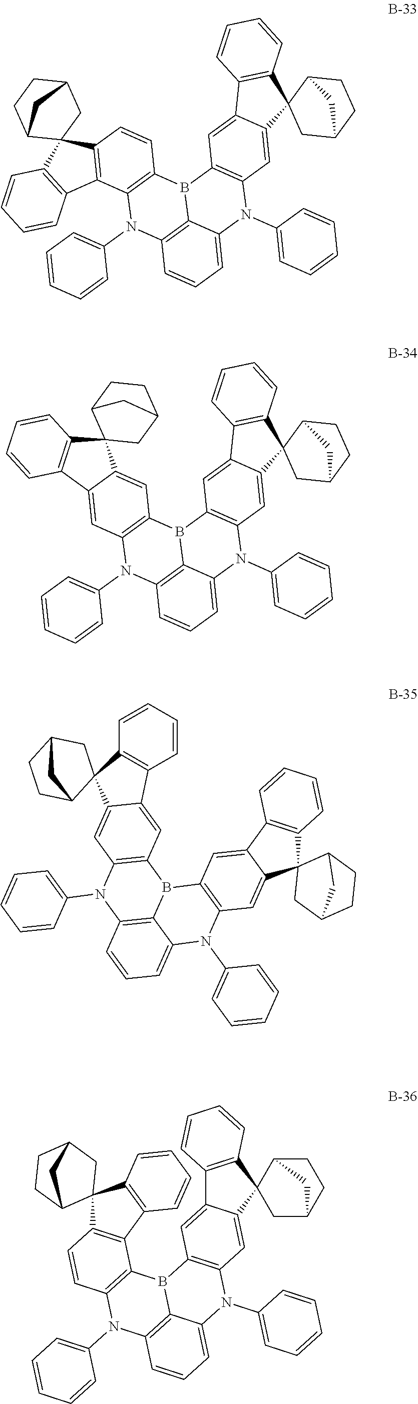 [SMILES: c1ccc(N2c3cc4c(cc3B3c5ccc6c(c5N(c5ccccc5)c5cccc2c53)-c2ccccc2[C@]62C[C@H]3CC[C@@H]2C3)-c2ccccc2[C@@]42C[C@@H]3CC[C@H]2C3)cc1 ; c1ccc(N2c3cc4c(cc3B3c5cc6c(cc5N(c5ccccc5)c5cccc2c53)[C@]2(C[C@@H]3CC[C@H]2C3)c2ccccc2-6)[C@]2(CC3CCC2C3)c2ccccc2-4)cc1 ; c1ccc(N2c3cc4c(cc3B3c5cc6c(cc5N(c5ccccc5)c5cccc2c53)[C@]2(C[C@H]3CC[C@@H]2C3)c2ccccc2-6)-c2ccccc2[C@]42C[C@@H]3CCC2C3)cc1 ; c1ccc(N2c3cc4c(cc3B3c5c2cccc5N(c2ccccc2)c2ccc5c(c23)-c2ccccc2[C@@]52C[C@H]3CC[C@@H]2C3)-c2ccccc2[C@@]42C[C@@H]3CC[C@H]2C3)cc1]

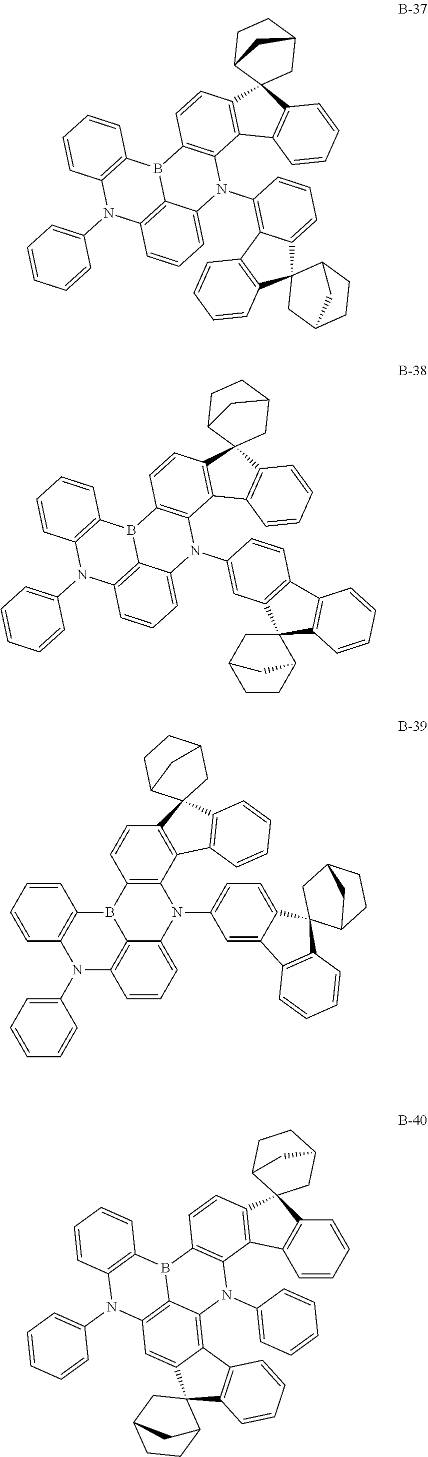 [SMILES: c1ccc(N2c3ccccc3B3c4ccc5c(c4N(c4cccc6c4-c4ccccc4[C@@]64C[C@@H]6CCC4C6)c4cccc2c43)-c2ccccc2[C@@]52C[C@H]3CC[C@@H]2C3)cc1 ; c1ccc(N2c3ccccc3B3c4ccc5c(c4N(c4ccc6c(c4)[C@]4(CC7CC[C@H]4C7)c4ccccc4-6)c4cccc2c43)-c2ccccc2[C@]52CC3CCC2C3)cc1 ; c1ccc(N2c3ccccc3B3c4ccc5c(c4N(c4ccc6c(c4)-c4ccccc4[C@]64C[C@@H]6CCC4C6)c4cccc2c43)-c2ccccc2[C@]52CC3CCC2C3)cc1 ; c1ccc(N2c3ccccc3B3c4ccc5c(c4N(c4ccccc4)c4c3c2cc2c4-c3ccccc3[C@@]23C[C@H]2CCC3C2)-c2ccccc2[C@@]52C[C@@H]3CCC2C3)cc1]

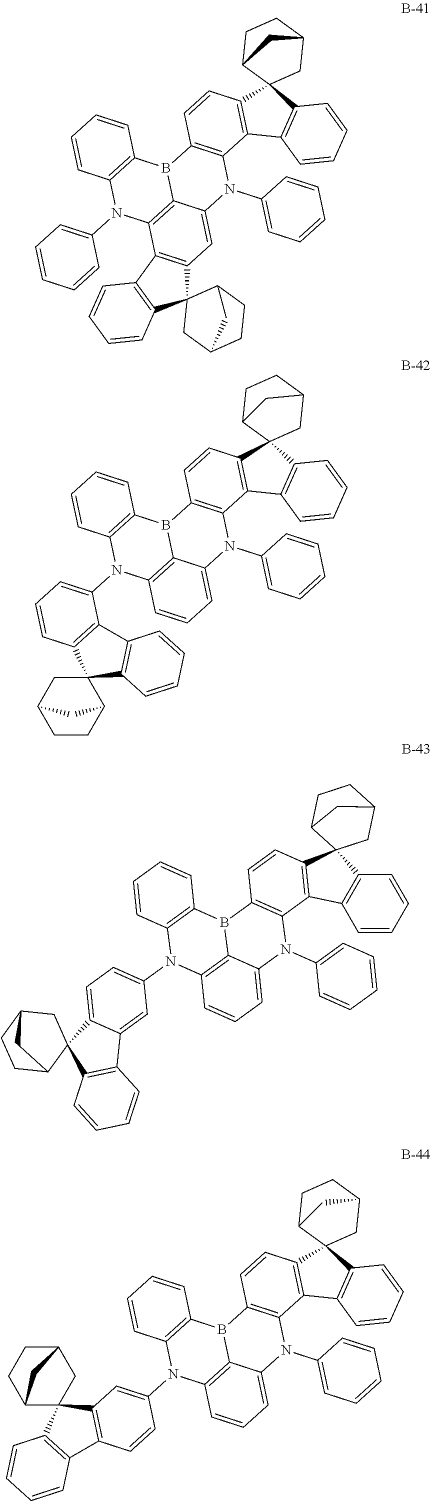

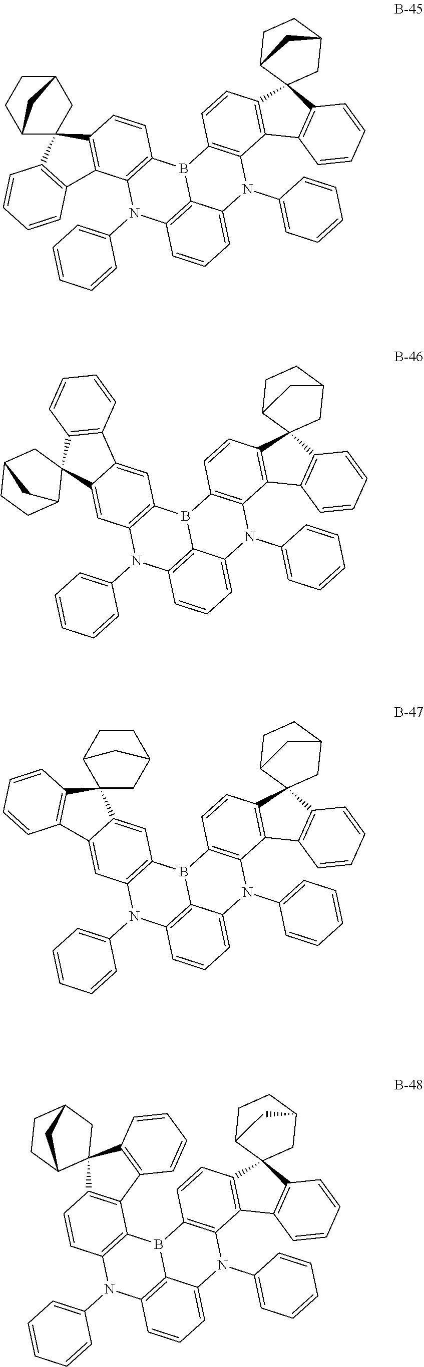 [SMILES: c1ccc(N2c3cccc4c3B(c3ccc5c(c32)-c2ccccc2[C@@]52C[C@H]3CC[C@@H]2C3)c2ccc3c(c2N4c2ccccc2)-c2ccccc2[C@]32C[C@H]3CC[C@@H]2C3)cc1 ; c1ccc(N2c3cc4c(cc3B3c5ccc6c(c5N(c5ccccc5)c5cccc2c53)-c2ccccc2[C@]62CC3CCC2C3)-c2ccccc2[C@]42C[C@H]3CCC2C3)cc1 ; c1ccc(N2c3cc4c(cc3B3c5ccc6c(c5N(c5ccccc5)c5cccc2c53)-c2ccccc2[C@]62CC3CCC2C3)[C@]2(CC3CCC2C3)c2ccccc2-4)cc1 ; c1ccc(N2c3cccc4c3B(c3ccc5c(c3N4c3ccccc3)-c3ccccc3[C@@]53C[C@@H]4CCC3C4)c3c2ccc2c3-c3ccccc3[C@@]23C[C@H]2CC[C@@H]3C2)cc1]

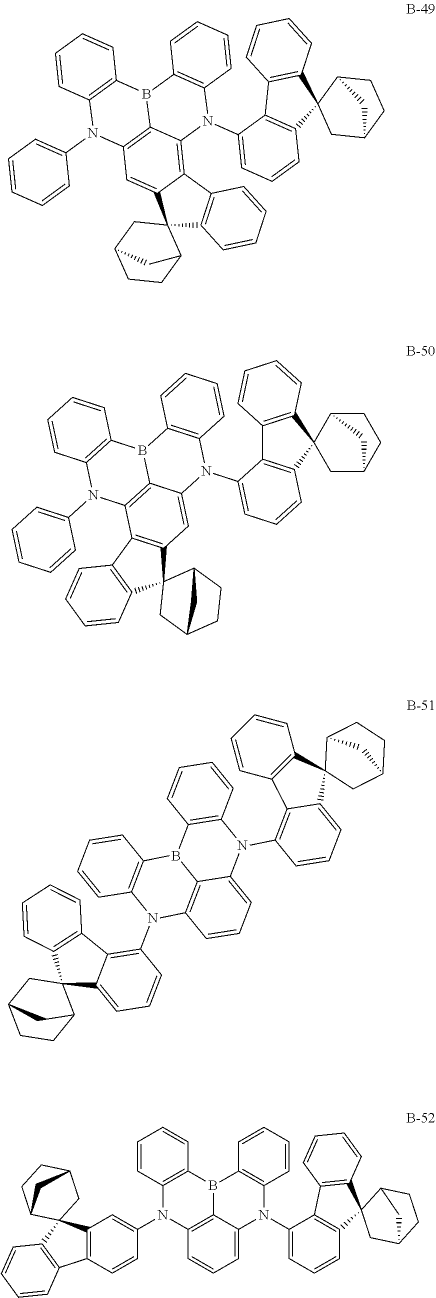 [SMILES: c1ccc(N2c3ccccc3B3c4ccccc4N(c4cccc5c4-c4ccccc4[C@@]54C[C@@H]5CC[C@H]4C5)c4c3c2cc2c4-c3ccccc3[C@]23C[C@@H]2CCC3C2)cc1 ; c1ccc(N2c3ccccc3B3c4ccccc4N(c4cccc5c4-c4ccccc4[C@@]54C[C@@H]5CC[C@H]4C5)c4cc5c(c2c43)-c2ccccc2[C@]52C[C@H]3CC[C@@H]2C3)cc1 ; c1ccc2c(c1)B1c3ccccc3N(c3cccc4c3-c3ccccc3[C@@]43C[C@@H]4CC[C@H]3C4)c3cccc(c31)N2c1cccc2c1-c1ccccc1[C@]21C[C@H]2CCC1C2 ; c1ccc2c(c1)B1c3ccccc3N(c3cccc4c3-c3ccccc3[C@@]43C[C@@H]4CCC3C4)c3cccc(c31)N2c1ccc2c(c1)[C@@]1(C[C@H]3CC[C@@H]1C3)c1ccccc1-2]

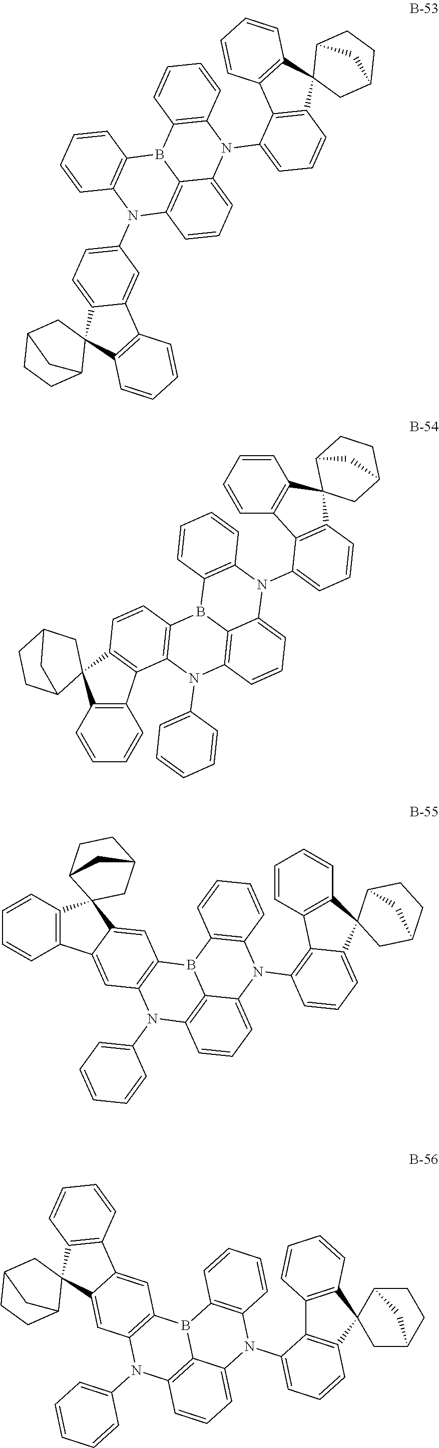 [SMILES: c1ccc2c(c1)B1c3ccccc3N(c3cccc4c3-c3ccccc3[C@@]43C[C@@H]4CC[C@H]3C4)c3cccc(c31)N2c1ccc2c(c1)-c1ccccc1[C@@]21CC2CCC1C2 ; c1ccc(N2c3cccc4c3B(c3ccccc3N4c3cccc4c3-c3ccccc3[C@@]43C[C@@H]4CC[C@H]3C4)c3ccc4c(c32)-c2ccccc2[C@@]42CC3CCC2C3)cc1 ; c1ccc(N2c3cc4c(cc3B3c5ccccc5N(c5cccc6c5-c5ccccc5[C@@]65C[C@@H]6CC[C@H]5C6)c5cccc2c53)[C@@]2(C[C@H]3CC[C@@H]2C3)c2ccccc2-4)cc1 ; c1ccc(N2c3cc4c(cc3B3c5ccccc5N(c5cccc6c5-c5ccccc5[C@@]65C[C@@H]6CC[C@H]5C6)c5cccc2c53)-c2ccccc2[C@]42CC3CCC2C3)cc1]

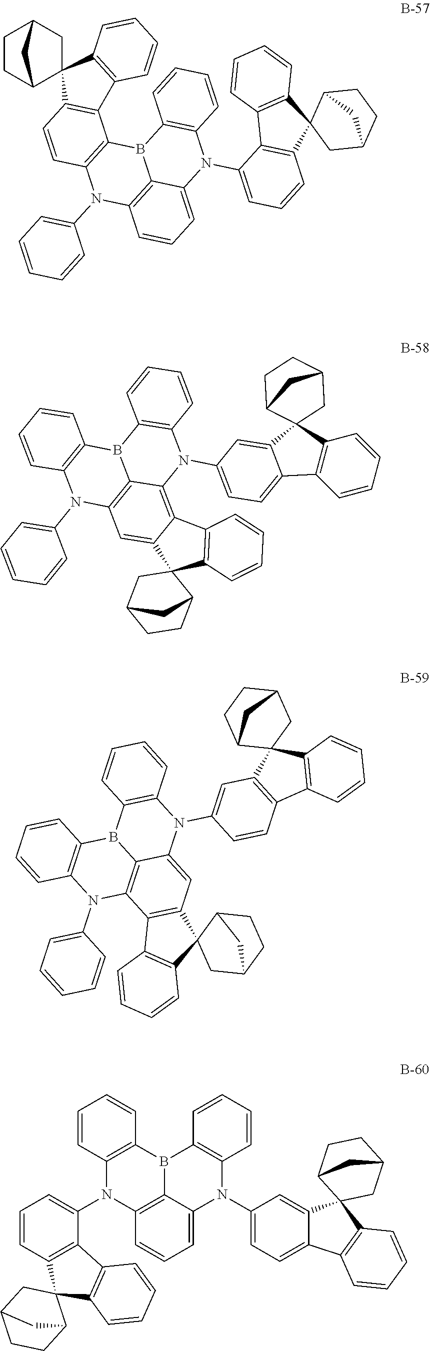 [SMILES: c1ccc(N2c3cccc4c3B(c3ccccc3N4c3cccc4c3-c3ccccc3[C@@]43C[C@@H]4CC[C@H]3C4)c3c2ccc2c3-c3ccccc3[C@@]23C[C@H]2CC[C@@H]3C2)cc1 ; c1ccc(N2c3ccccc3B3c4ccccc4N(c4ccc5c(c4)[C@]4(C[C@H]6CC[C@@H]4C6)c4ccccc4-5)c4c3c2cc2c4-c3ccccc3[C@@]23C[C@H]2CC[C@@H]3C2)cc1 ; c1ccc(N2c3ccccc3B3c4ccccc4N(c4ccc5c(c4)[C@]4(C[C@H]6CC[C@@H]4C6)c4ccccc4-5)c4cc5c(c2c43)-c2ccccc2[C@@]52C[C@@H]3CCC2C3)cc1 ; c1ccc2c(c1)B1c3ccccc3N(c3cccc4c3-c3ccccc3[C@@]43CC4CC[C@H]3C4)c3cccc(c31)N2c1ccc2c(c1)[C@]1(C[C@H]3CC[C@@H]1C3)c1ccccc1-2]

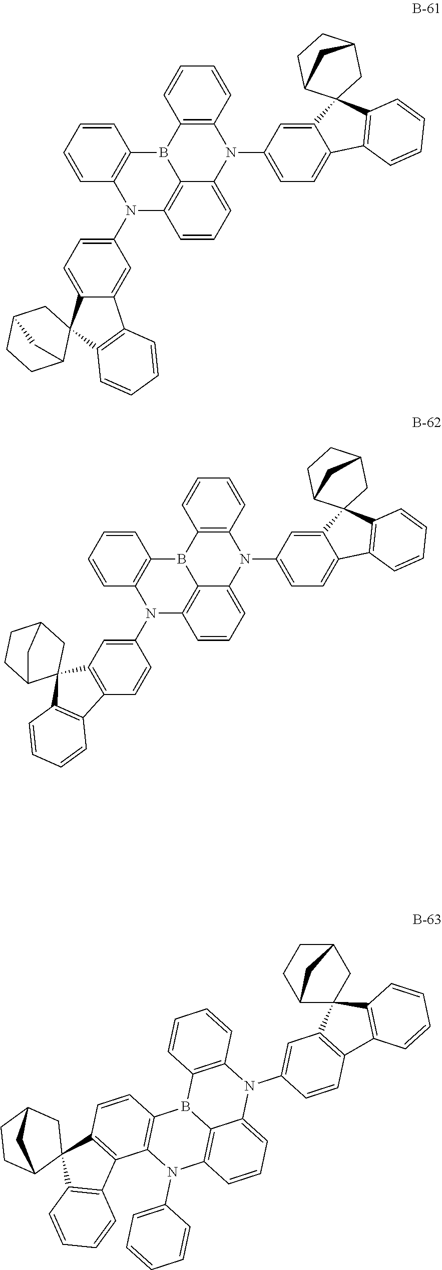 [SMILES: c1ccc2c(c1)B1c3ccccc3N(c3ccc4c(c3)[C@]3(C[C@H]5CC[C@@H]3C5)c3ccccc3-4)c3cccc(c31)N2c1ccc2c(c1)-c1ccccc1[C@]21C[C@@H]2CCC1C2 ; c1ccc2c(c1)B1c3ccccc3N(c3ccc4c(c3)[C@]3(C[C@H]5CC[C@@H]3C5)c3ccccc3-4)c3cccc(c31)N2c1ccc2c(c1)[C@]1(CC3CCC1C3)c1ccccc1-2 ; c1ccc(N2c3cccc4c3B(c3ccccc3N4c3ccc4c(c3)[C@]3(C[C@H]5CC[C@@H]3C5)c3ccccc3-4)c3ccc4c(c32)-c2ccccc2[C@]42C[C@H]3CC[C@@H]2C3)cc1]

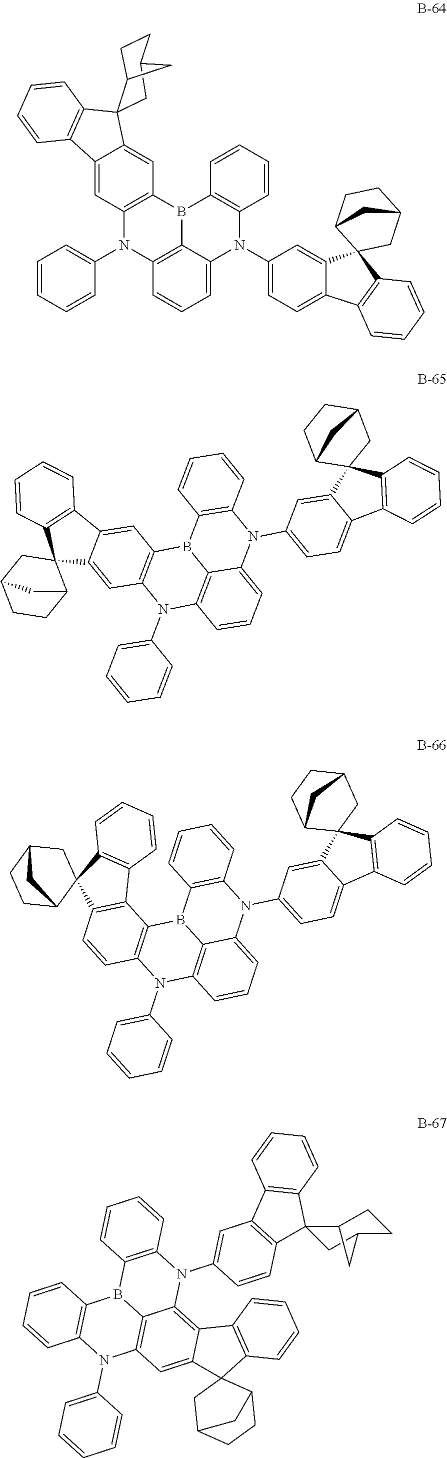 [SMILES: c1ccc(N2c3cc4c(cc3B3c5ccccc5N(c5ccc6c(c5)[C@]5(C[C@H]7CC[C@@H]5C7)c5ccccc5-6)c5cccc2c53)C2(CC3CCC2C3)c2ccccc2-4)cc1 ; c1ccc(N2c3cc4c(cc3B3c5ccccc5N(c5ccc6c(c5)[C@]5(C[C@H]7CC[C@@H]5C7)c5ccccc5-6)c5cccc2c53)-c2ccccc2[C@@]42C[C@@H]3CCC2C3)cc1 ; c1ccc(N2c3cccc4c3B(c3ccccc3N4c3ccc4c(c3)[C@]3(C[C@H]5CC[C@@H]3C5)c3ccccc3-4)c3c2ccc2c3-c3ccccc3[C@@]23C[C@H]2CC[C@@H]3C2)cc1 ; c1ccc(N2c3ccccc3B3c4ccccc4N(c4ccc5c(c4)-c4ccccc4C54CC5CCC4C5)c4c3c2cc2c4-c3ccccc3C23CC2CCC3C2)cc1]

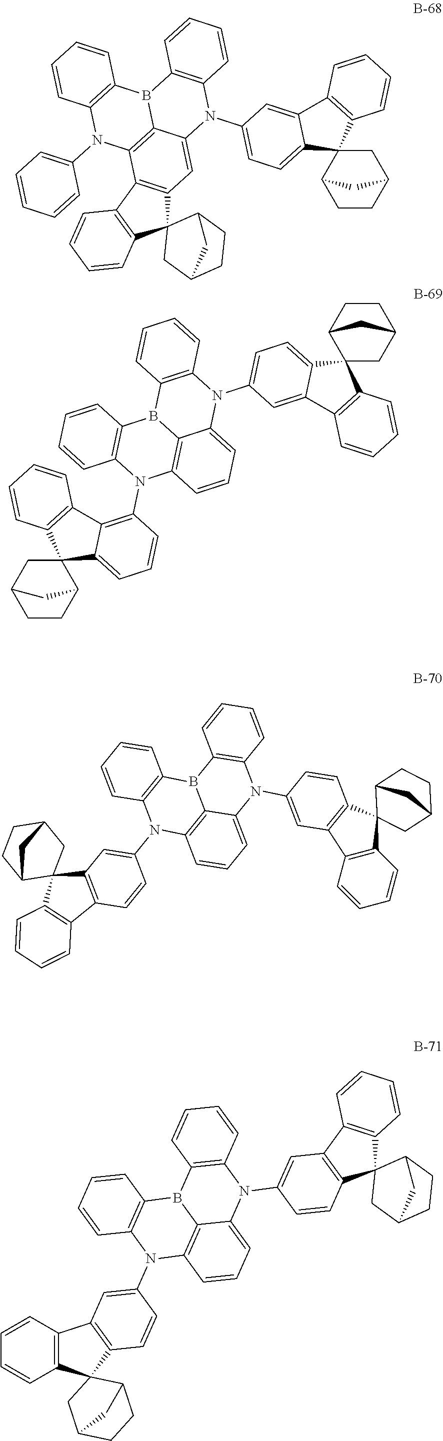

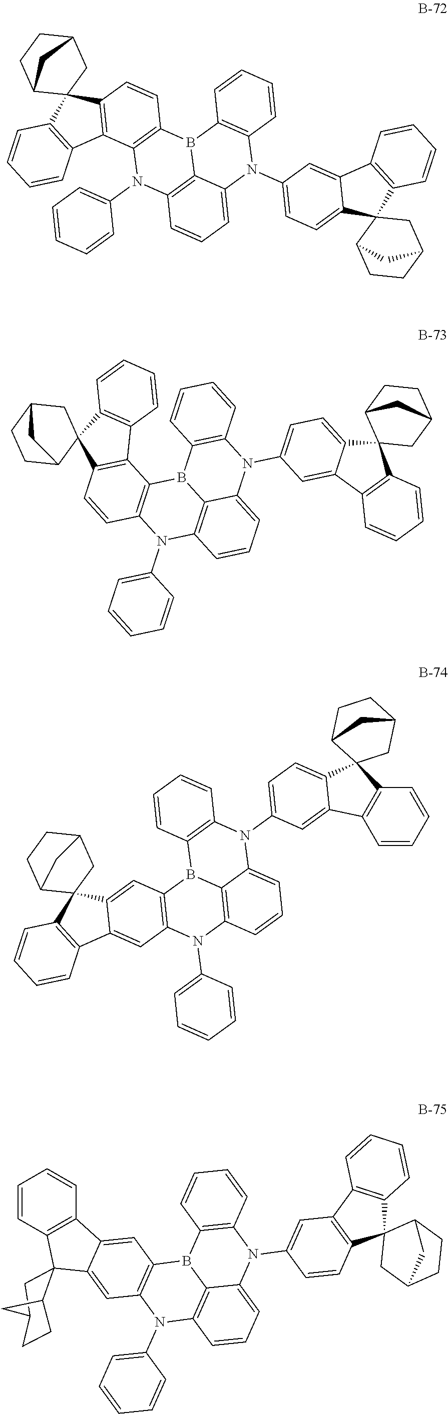 [SMILES: c1ccc(N2c3cccc4c3B(c3ccccc3N4c3ccc4c(c3)-c3ccccc3[C@@]43C[C@H]4CC[C@@H]3C4)c3ccc4c(c32)-c2ccccc2[C@]42C[C@H]3CC[C@@H]2C3)cc1 ; c1ccc(N2c3cccc4c3B(c3ccccc3N4c3ccc4c(c3)-c3ccccc3[C@@]43C[C@H]4CC[C@@H]3C4)c3c2ccc2c3-c3ccccc3[C@]23C[C@H]2CCC3C2)cc1 ; c1ccc(N2c3cc4c(cc3B3c5ccccc5N(c5ccc6c(c5)-c5ccccc5[C@@]65C[C@H]6CC[C@@H]5C6)c5cccc2c53)[C@]2(CC3CCC2C3)c2ccccc2-4)cc1 ; c1ccc(N2c3cc4c(cc3B3c5ccccc5N(c5ccc6c(c5)-c5ccccc5[C@]65C[C@@H]6CCC5C6)c5cccc2c53)-c2ccccc2C42CC3CCC2C3)cc1]

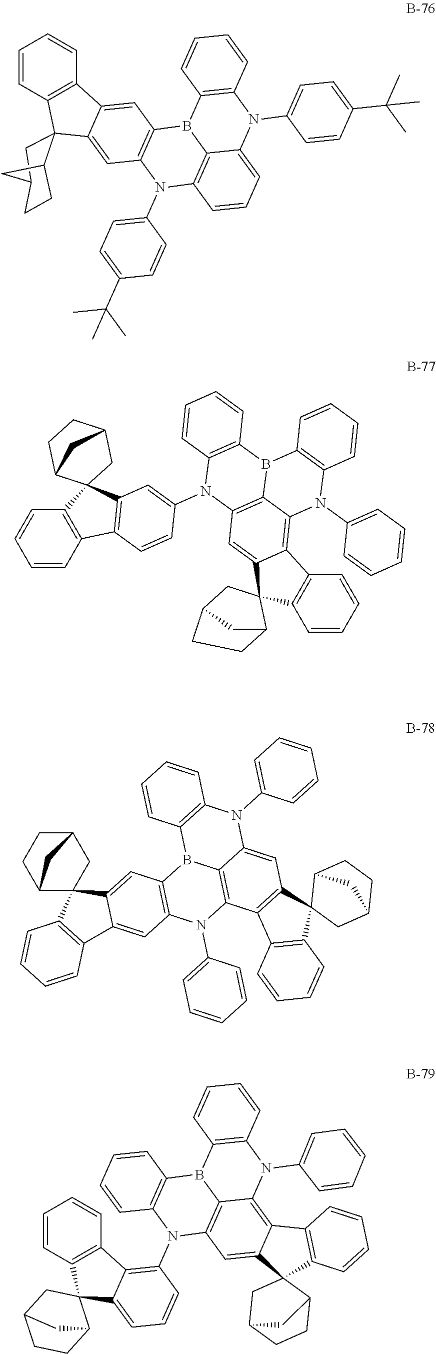 [SMILES: CC(C)(C)c1ccc(N2c3ccccc3B3c4cc5c(cc4N(c4ccc(C(C)(C)C)cc4)c4cccc2c43)C2(CC3CCC2C3)c2ccccc2-5)cc1 ; c1ccc(N2c3ccccc3B3c4ccccc4N(c4ccc5c(c4)[C@@]4(C[C@H]6CC[C@@H]4C6)c4ccccc4-5)c4cc5c(c2c43)-c2ccccc2[C@]52C[C@@H]3CCC2C3)cc1 ; c1ccc(N2c3ccccc3B3c4cc5c(cc4N(c4ccccc4)c4c3c2cc2c4-c3ccccc3[C@]23C[C@@H]2CC[C@H]3C2)-c2ccccc2[C@]52C[C@H]3CC[C@@H]2C3)cc1 ; c1ccc(N2c3ccccc3B3c4ccccc4N(c4cccc5c4-c4ccccc4[C@]54CC5CC[C@H]4C5)c4cc5c(c2c43)-c2ccccc2[C@]52C[C@@H]3CCC2C3)cc1]

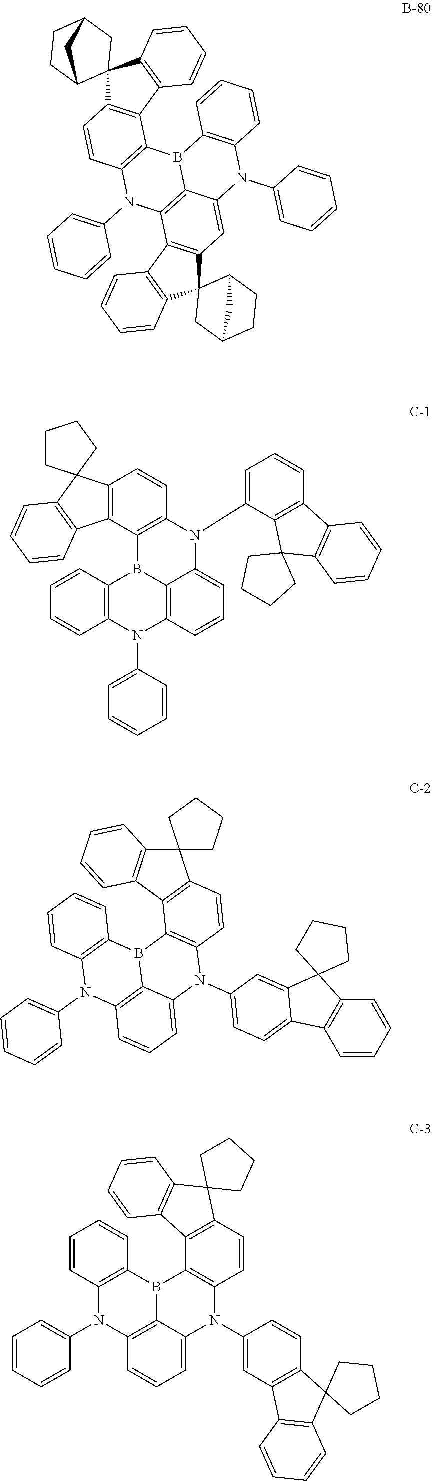 [SMILES: c1ccc(N2c3ccccc3B3c4c(ccc5c4-c4ccccc4[C@@]54C[C@H]5CC[C@@H]4C5)N(c4ccccc4)c4c3c2cc2c4-c3ccccc3[C@]23C[C@@H]2CC[C@H]3C2)cc1 ; c1ccc(N2c3ccccc3B3c4c2cccc4N(c2cccc4c2C2(CCCC2)c2ccccc2-4)c2ccc4c(c23)-c2ccccc2C42CCCC2)cc1 ; c1ccc(N2c3ccccc3B3c4c2cccc4N(c2ccc4c(c2)C2(CCCC2)c2ccccc2-4)c2ccc4c(c23)-c2ccccc2C42CCCC2)cc1 ; c1ccc(N2c3ccccc3B3c4c2cccc4N(c2ccc4c(c2)-c2ccccc2C42CCCC2)c2ccc4c(c23)-c2ccccc2C42CCCC2)cc1]

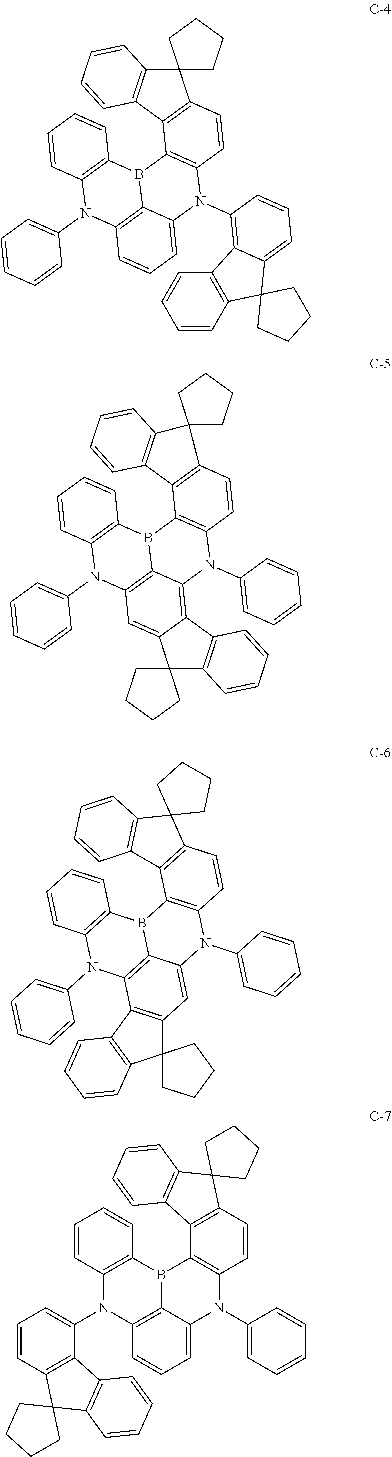

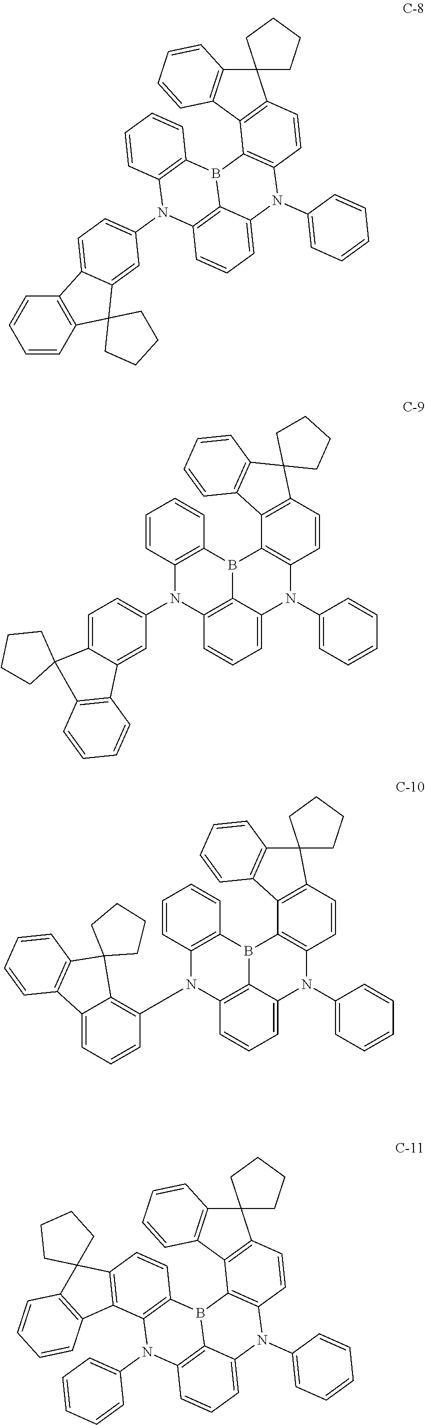 [SMILES: c1ccc(N2c3cccc4c3B(c3ccccc3N4c3ccc4c(c3)C3(CCCC3)c3ccccc3-4)c3c2ccc2c3-c3ccccc3C23CCCC3)cc1 ; c1ccc(N2c3cccc4c3B(c3ccccc3N4c3ccc4c(c3)-c3ccccc3C43CCCC3)c3c2ccc2c3-c3ccccc3C23CCCC3)cc1 ; c1ccc(N2c3cccc4c3B(c3ccccc3N4c3cccc4c3C3(CCCC3)c3ccccc3-4)c3c2ccc2c3-c3ccccc3C23CCCC3)cc1 ; c1ccc(N2c3cccc4c3B(c3ccc5c(c3N4c3ccccc3)-c3ccccc3C53CCCC3)c3c2ccc2c3-c3ccccc3C23CCCC3)cc1]

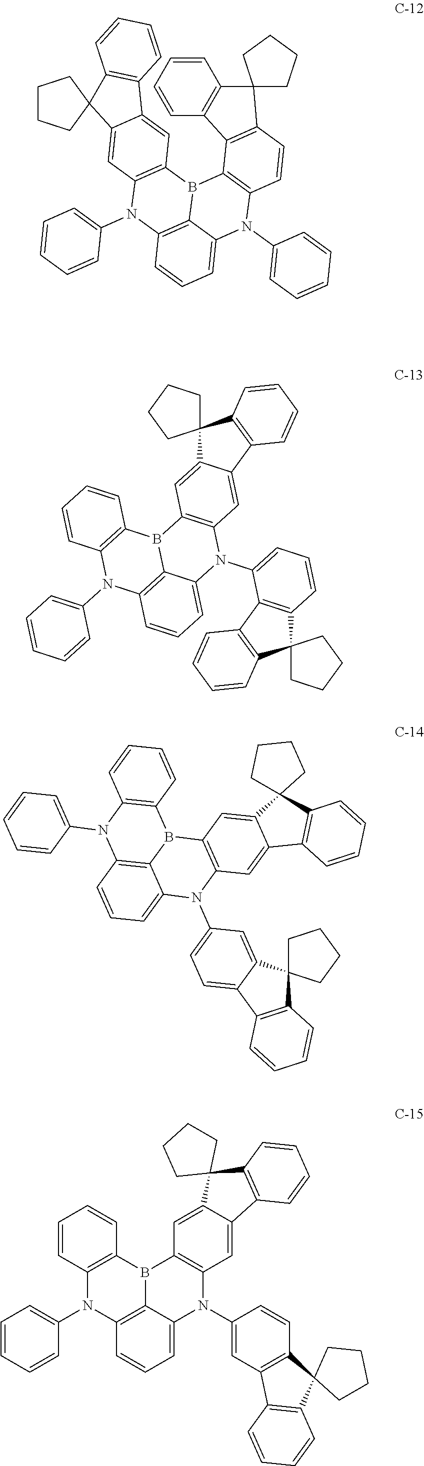

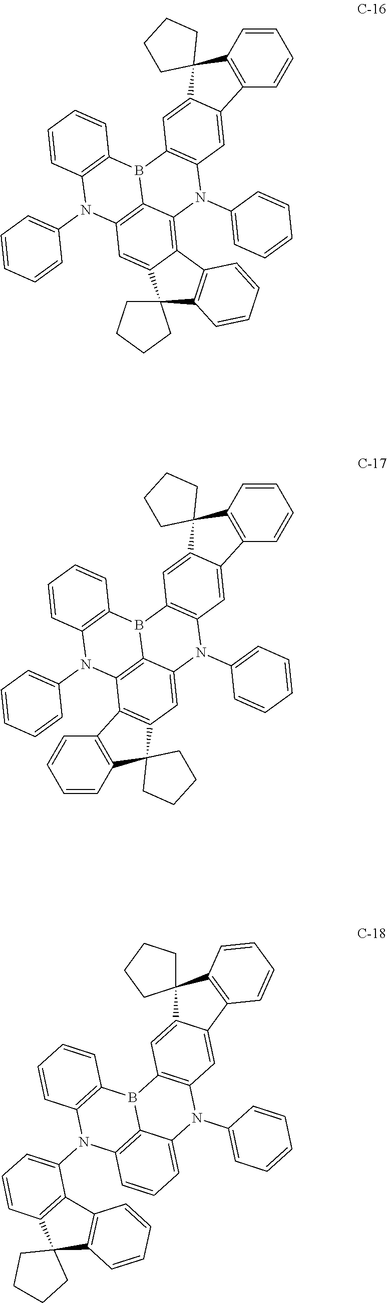

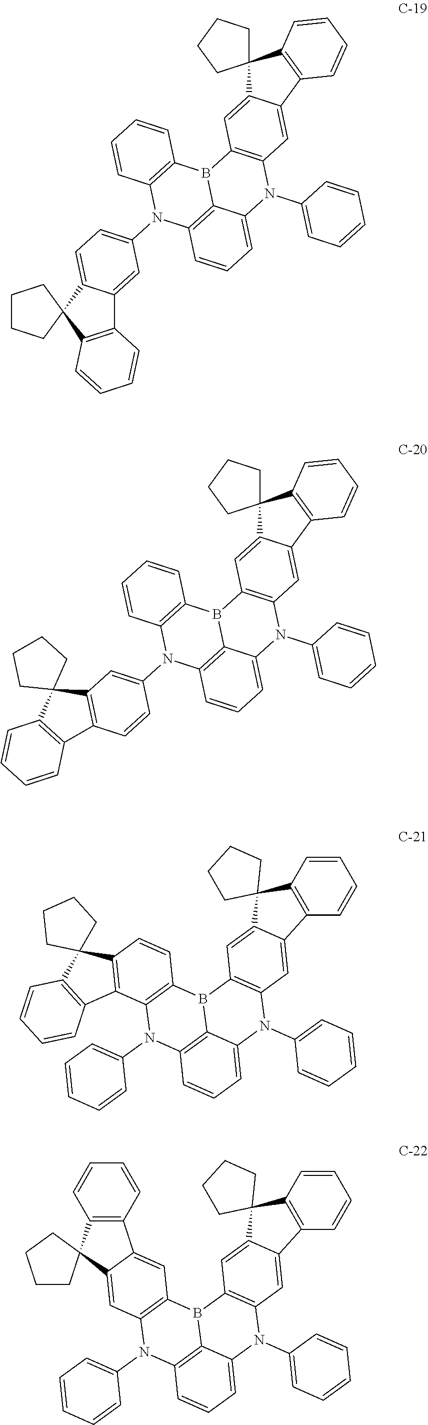

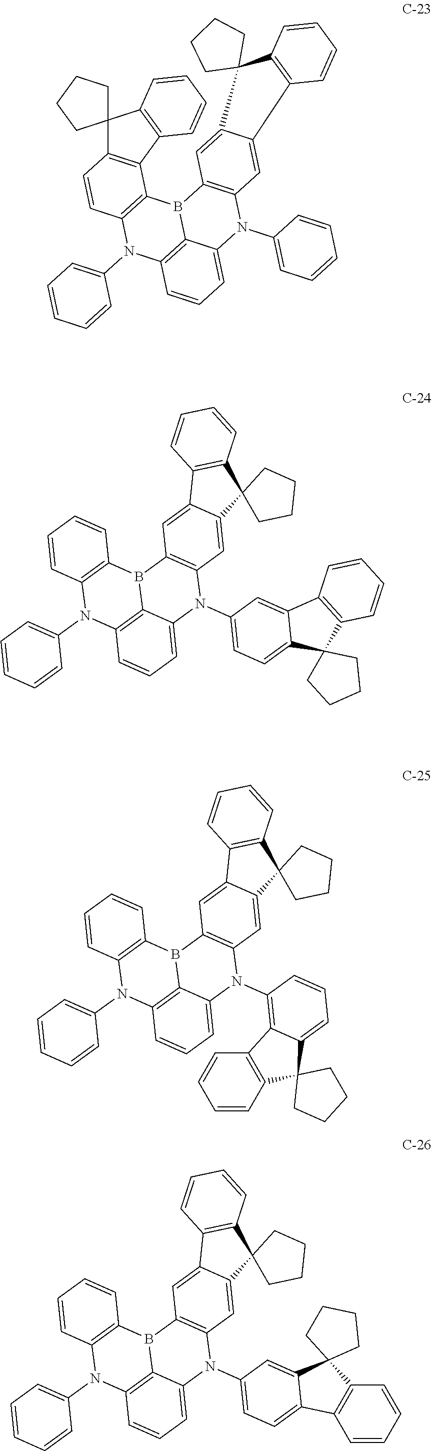

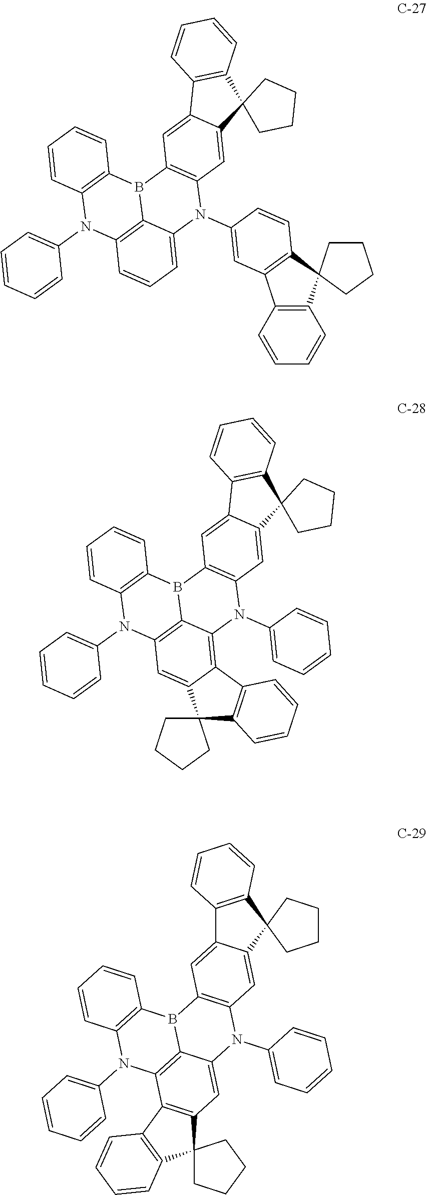

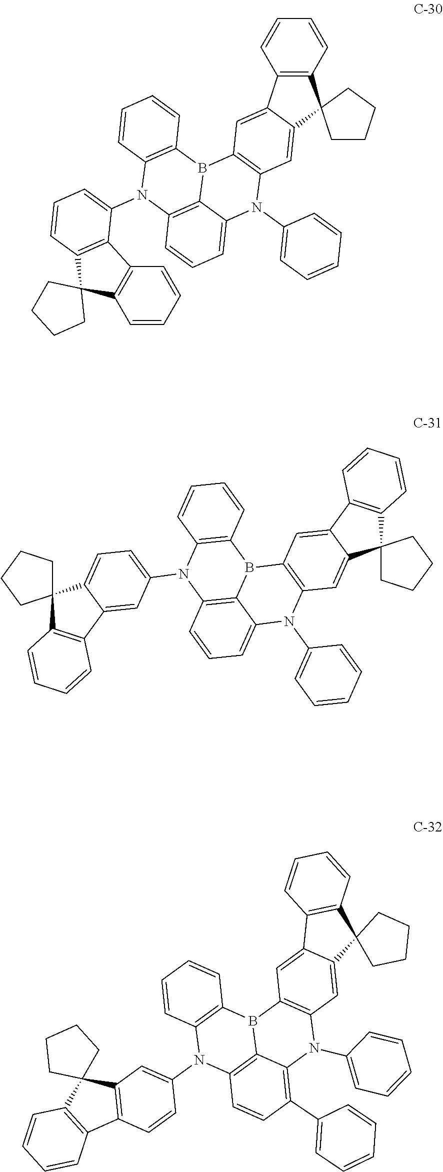

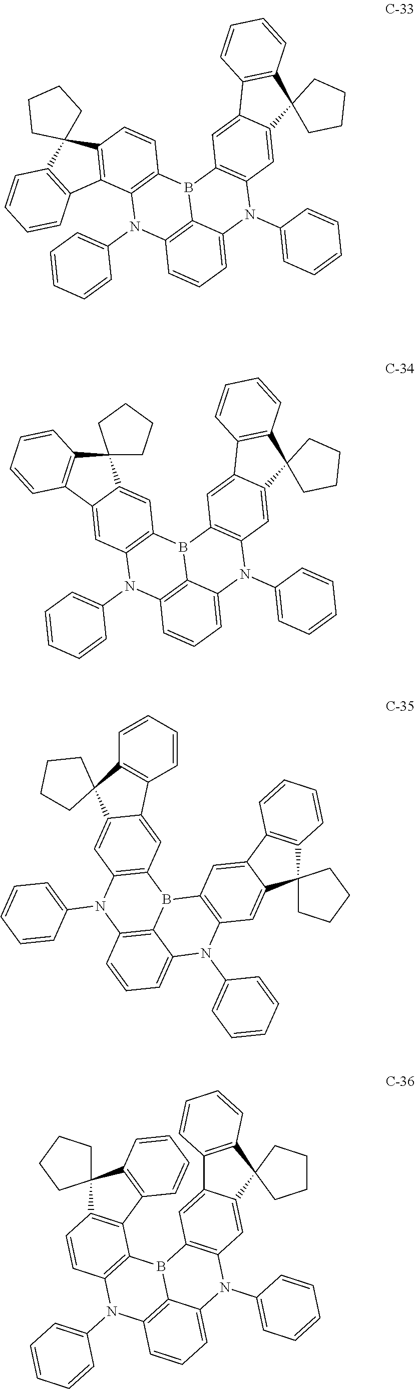 [SMILES: c1ccc(N2c3cc4c(cc3B3c5ccc6c(c5N(c5ccccc5)c5cccc2c53)-c2ccccc2[C@]62CCCC2)-c2ccccc2[C@@]42CCCC2)cc1 ; c1ccc(N2c3cc4c(cc3B3c5cc6c(cc5N(c5ccccc5)c5cccc2c53)[C@]2(CCCC2)c2ccccc2-6)[C@]2(CCCC2)c2ccccc2-4)cc1 ; c1ccc(N2c3cc4c(cc3B3c5cc6c(cc5N(c5ccccc5)c5cccc2c53)[C@]2(CCCC2)c2ccccc2-6)-c2ccccc2[C@@]42CCCC2)cc1 ; c1ccc(N2c3cc4c(cc3B3c5c2cccc5N(c2ccccc2)c2ccc5c(c23)-c2ccccc2[C@]52CCCC2)-c2ccccc2[C@@]42CCCC2)cc1]

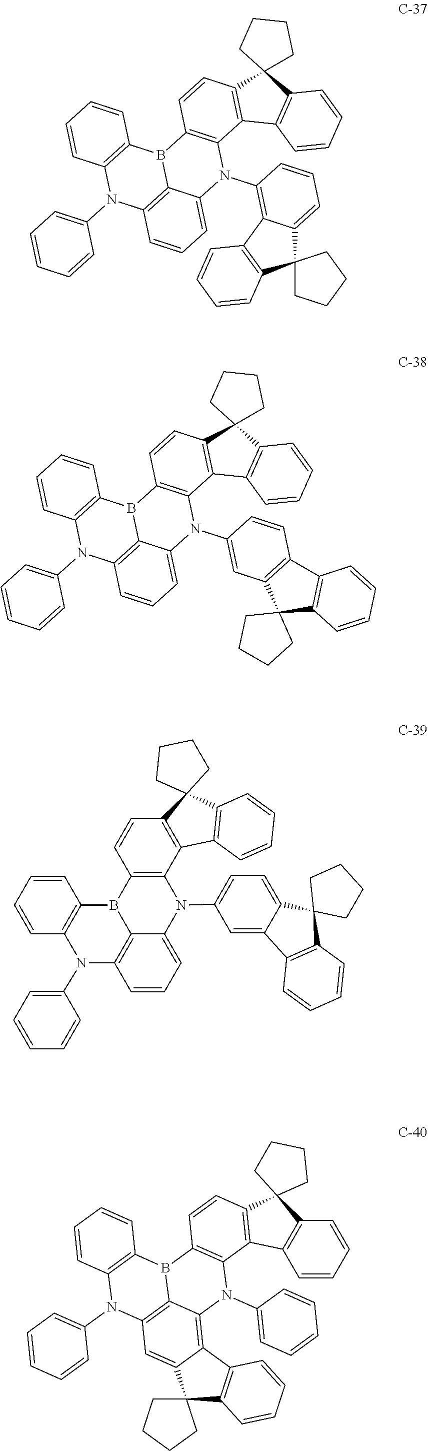

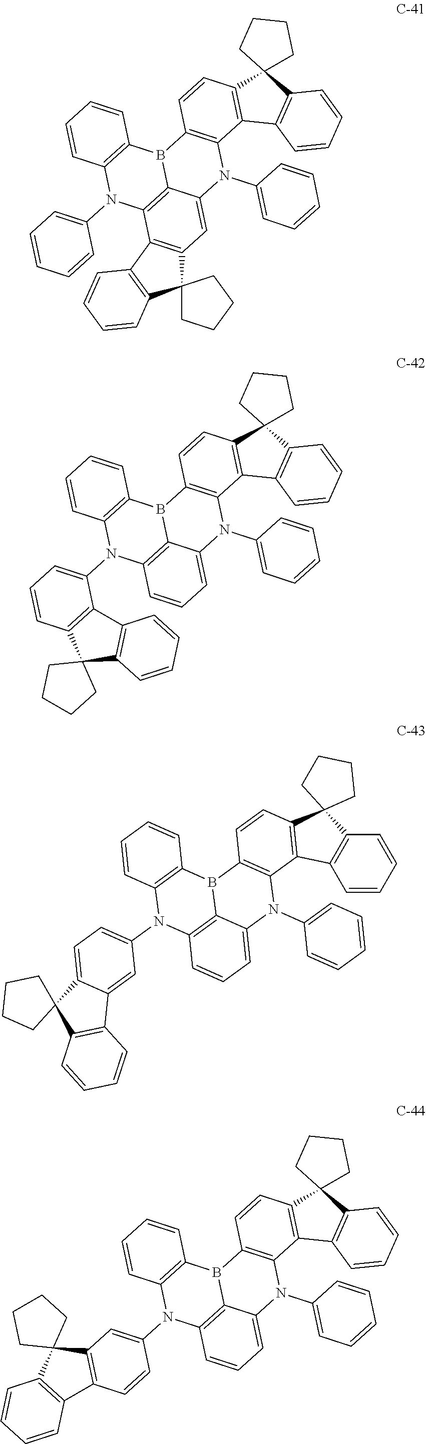

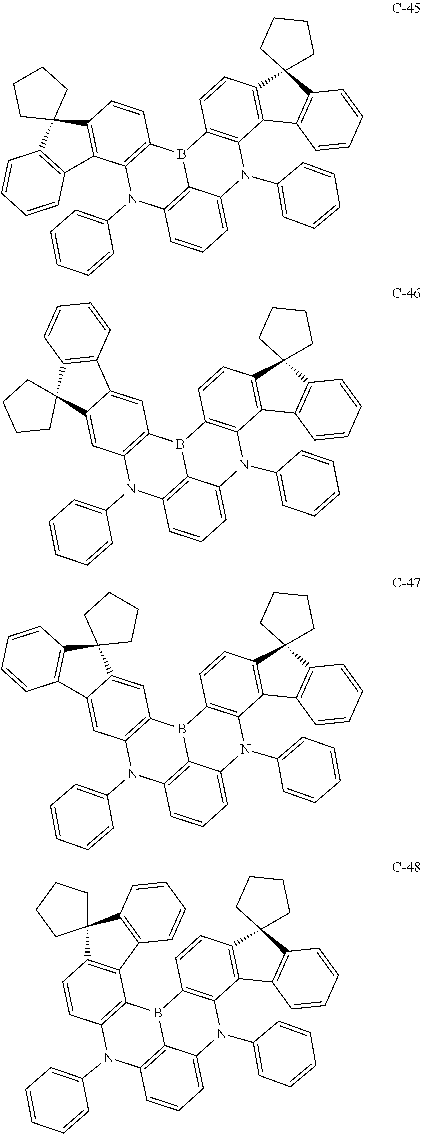

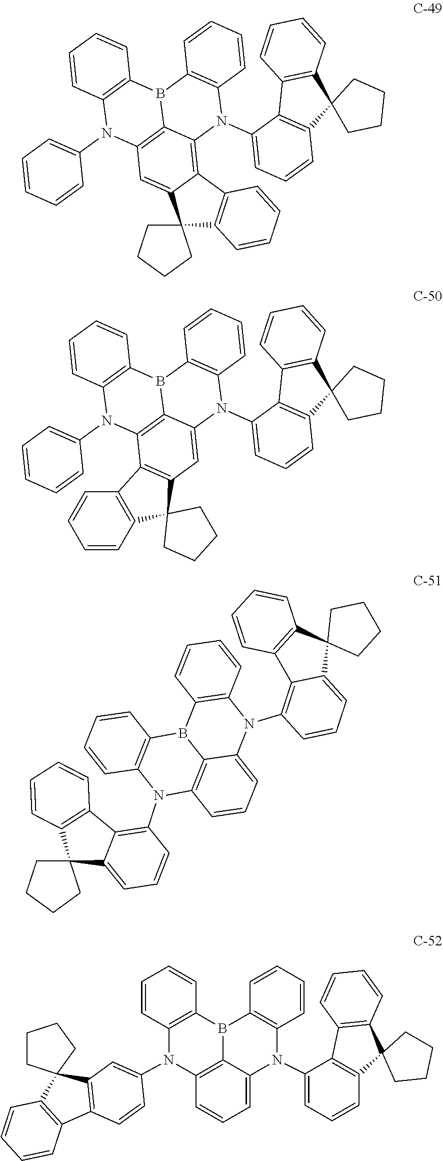

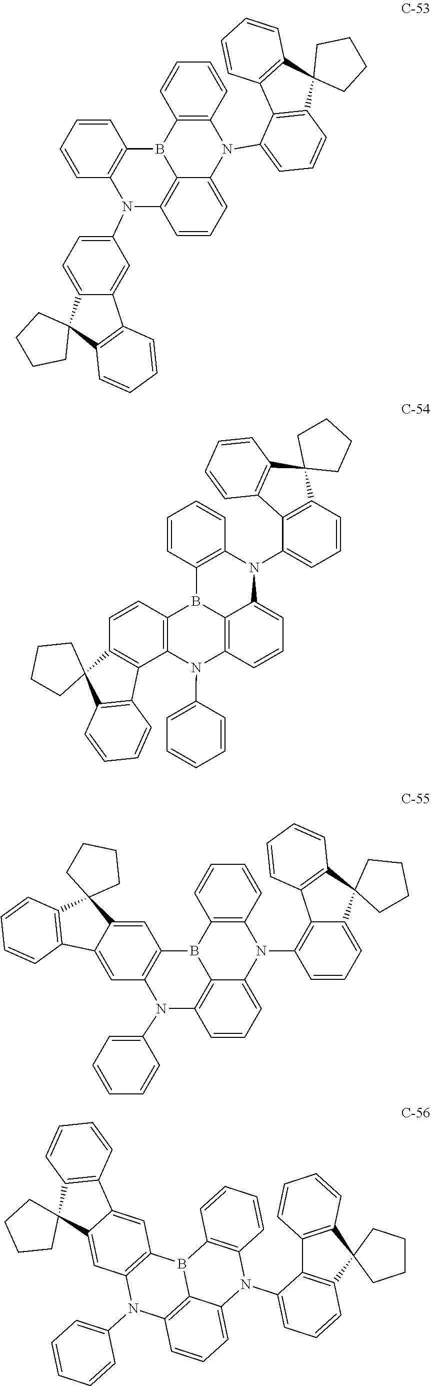

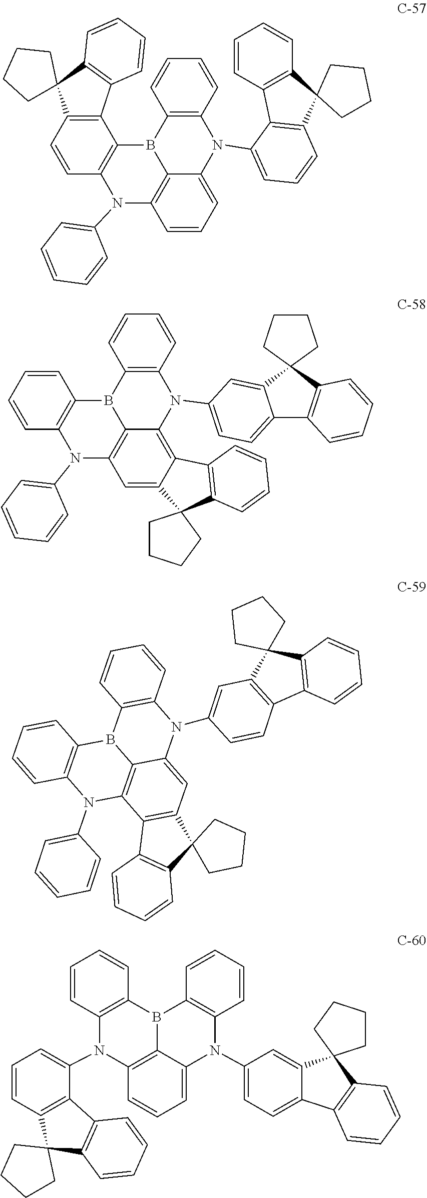

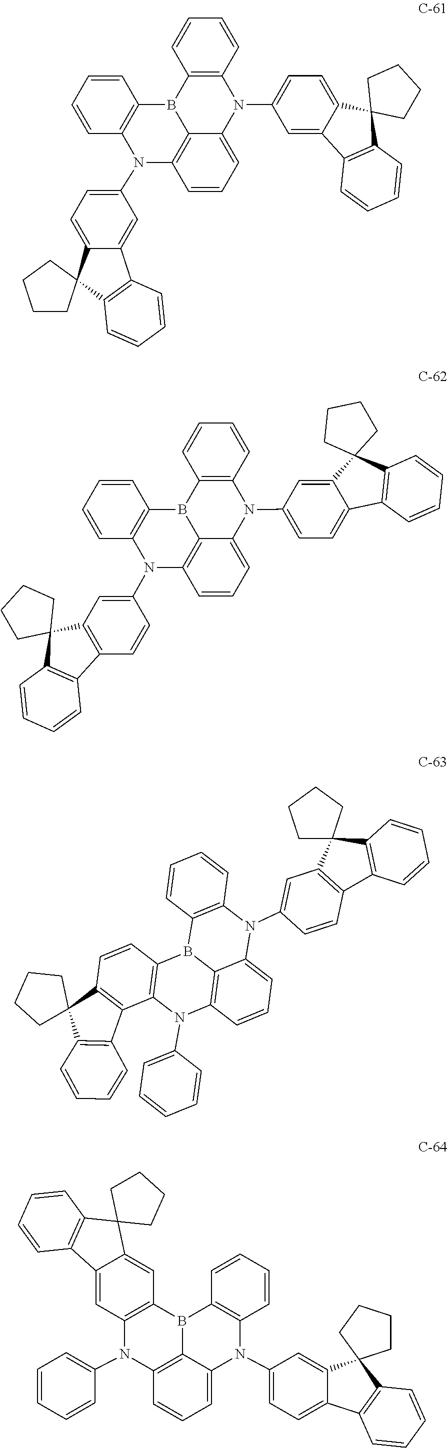

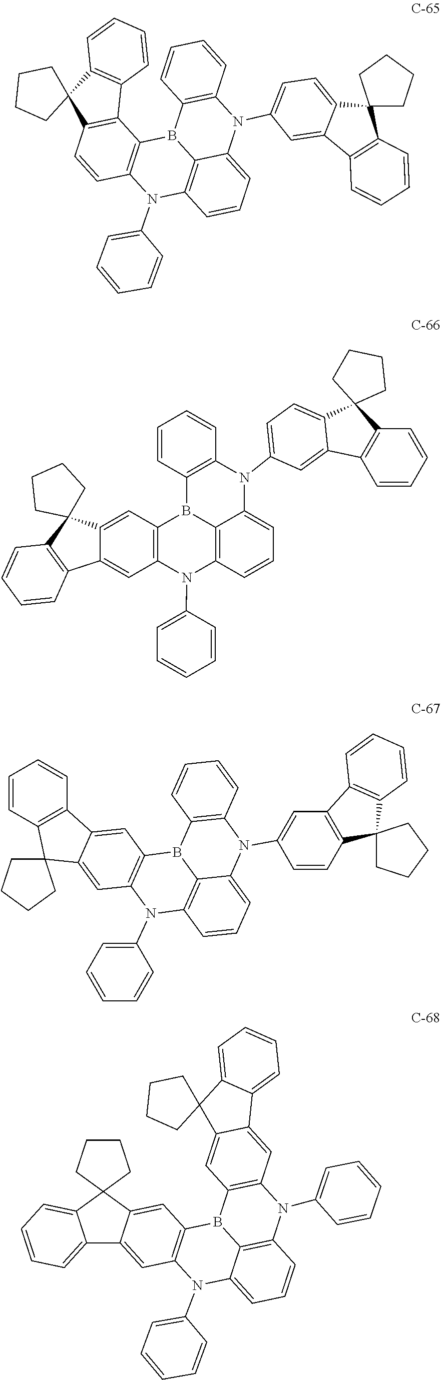

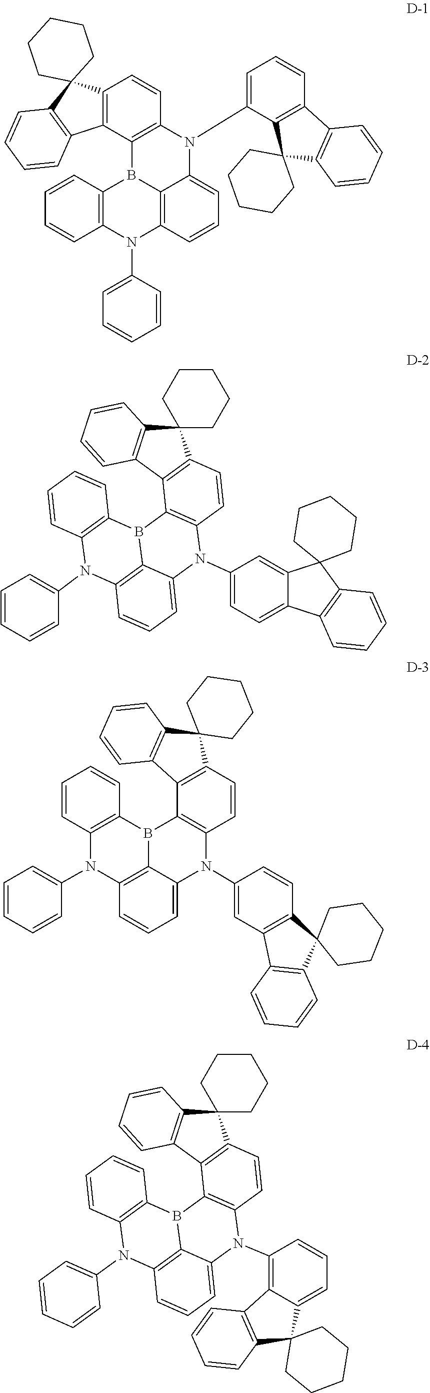

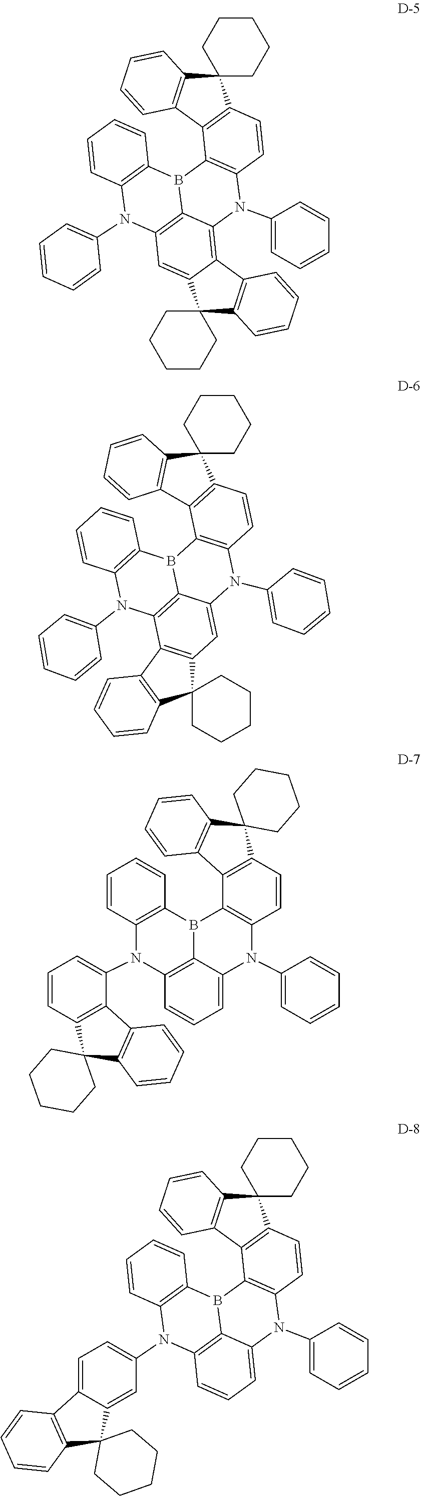

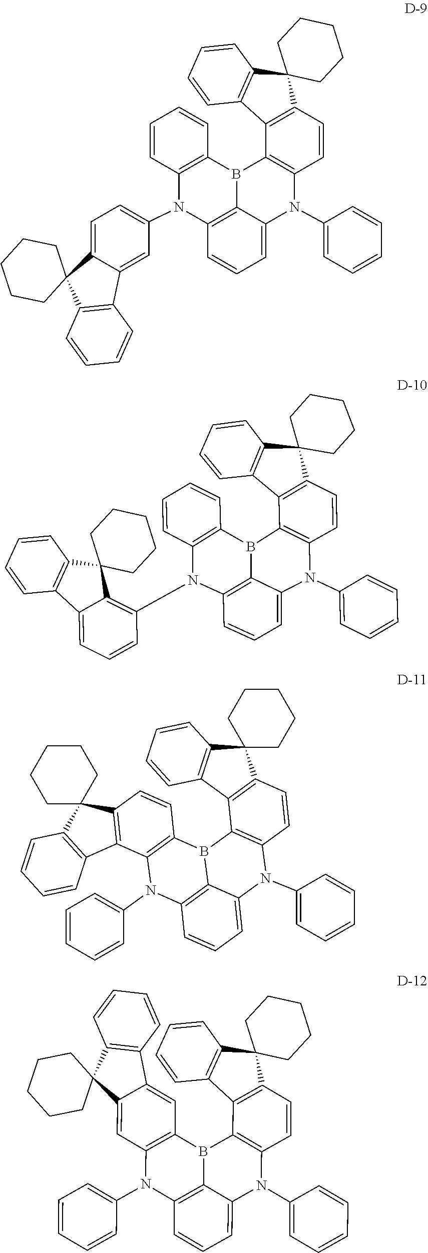

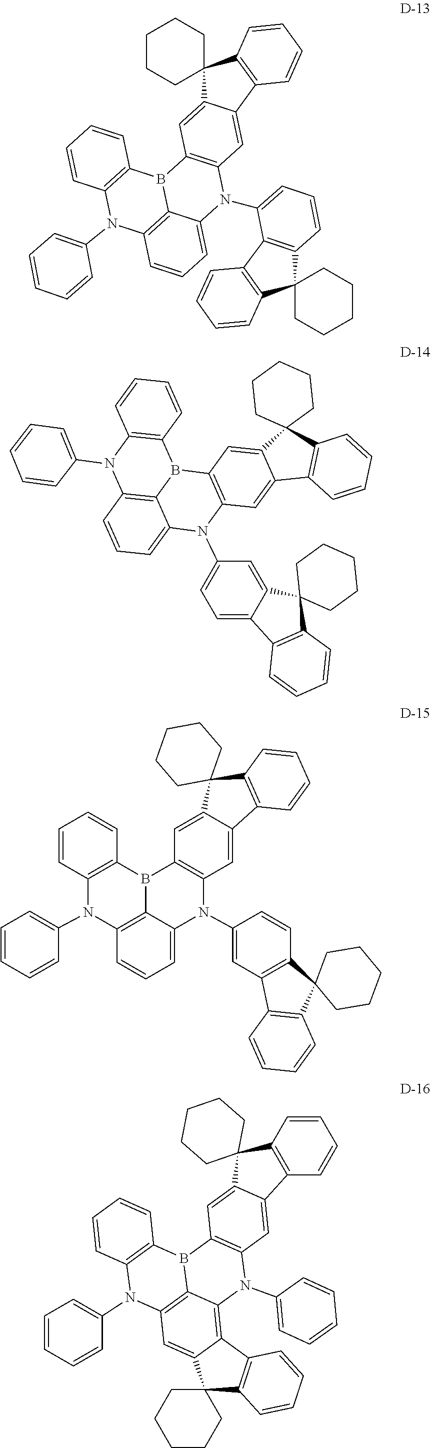

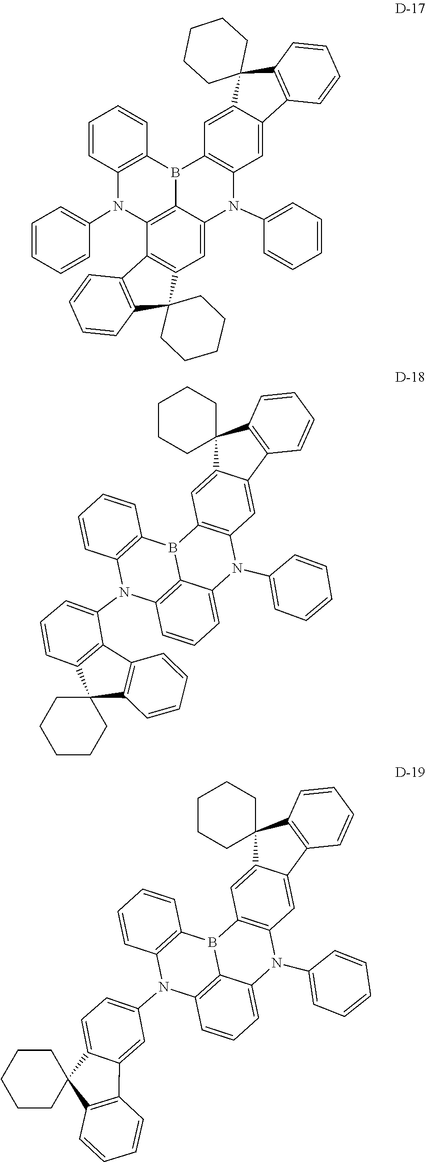

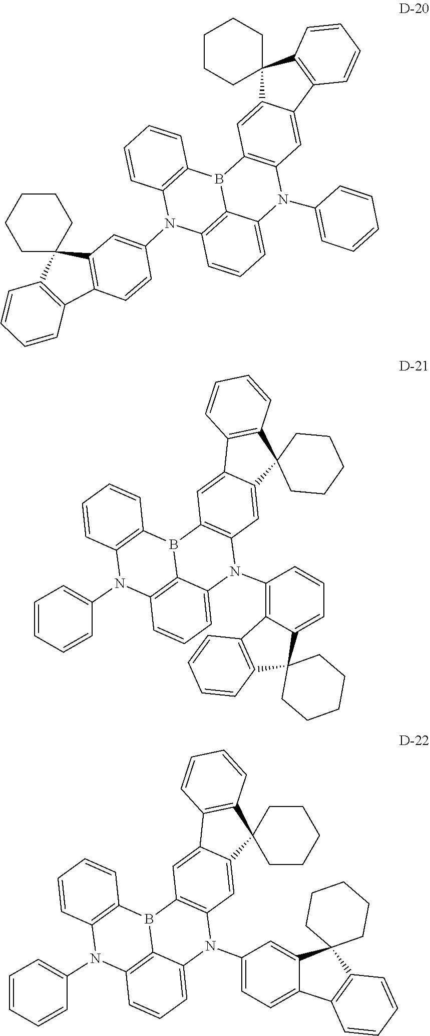

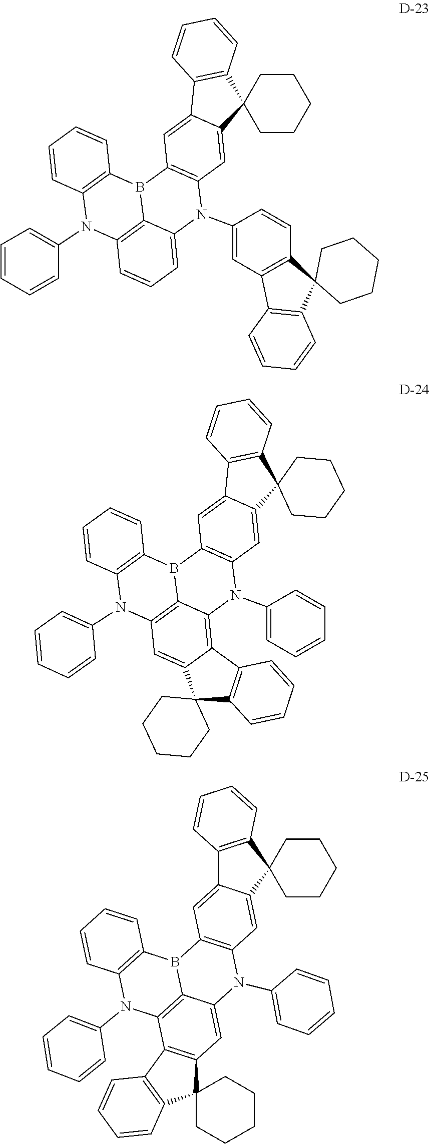

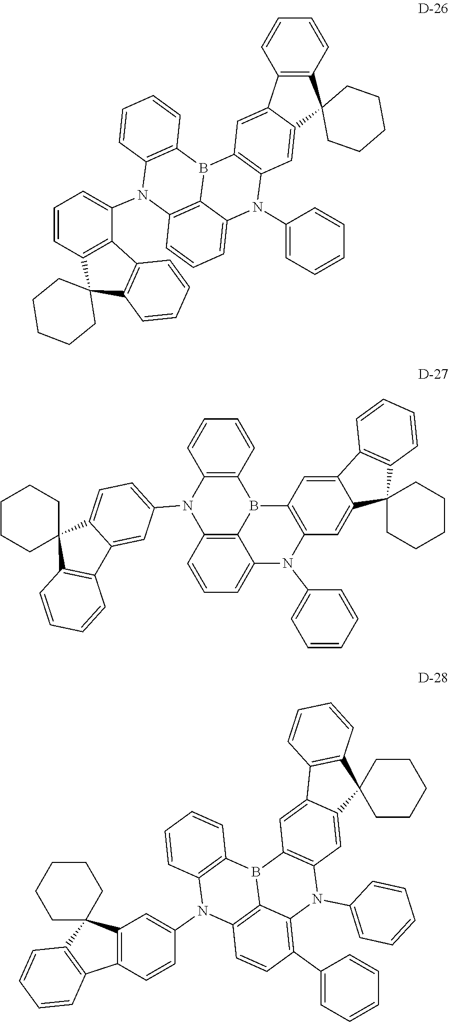

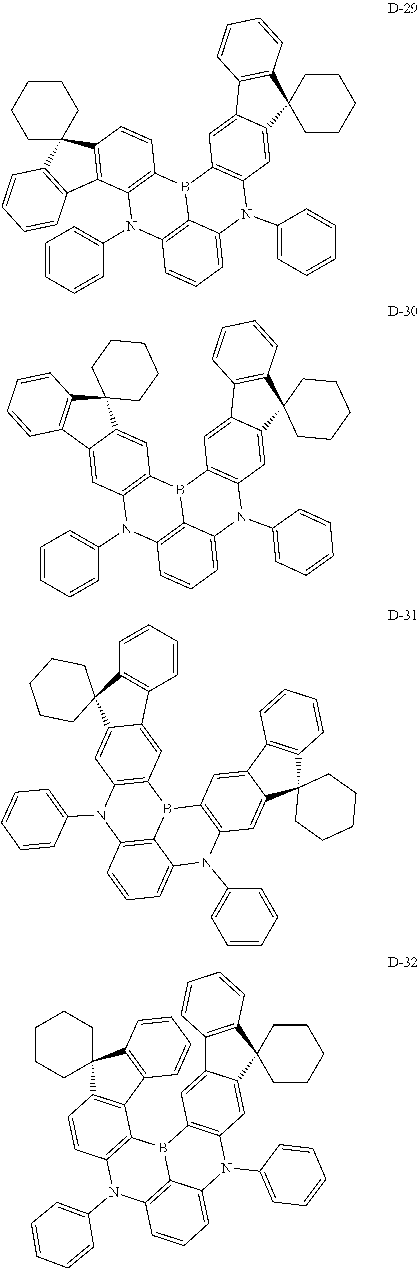

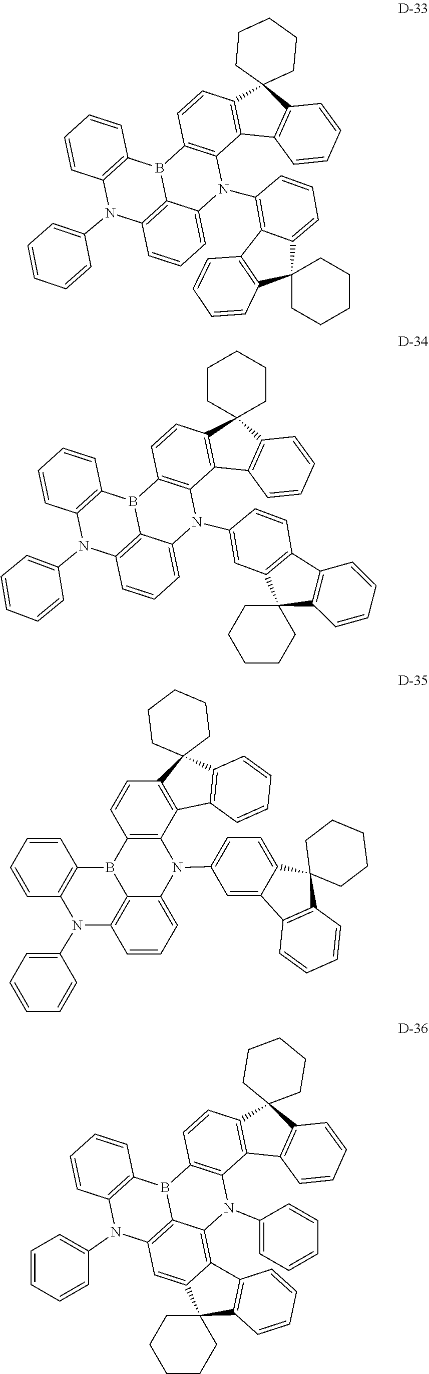

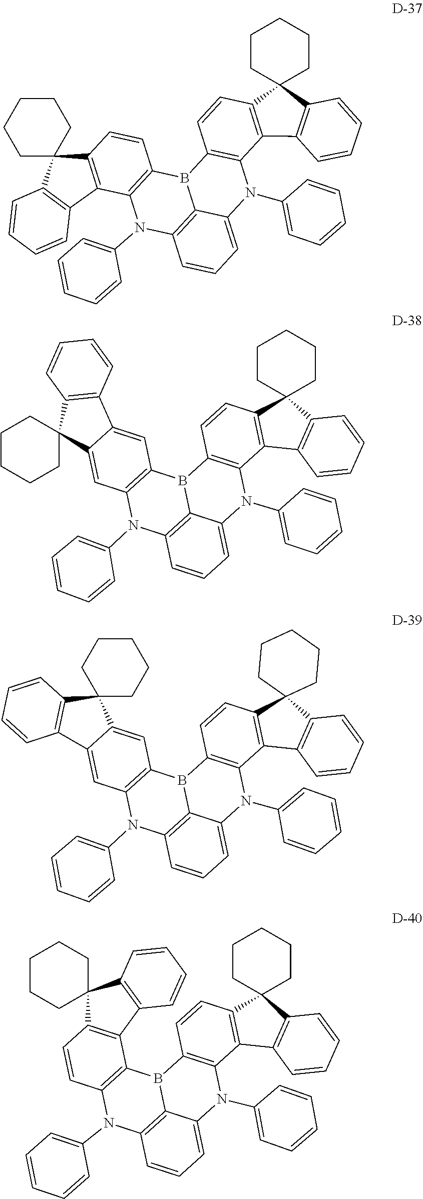

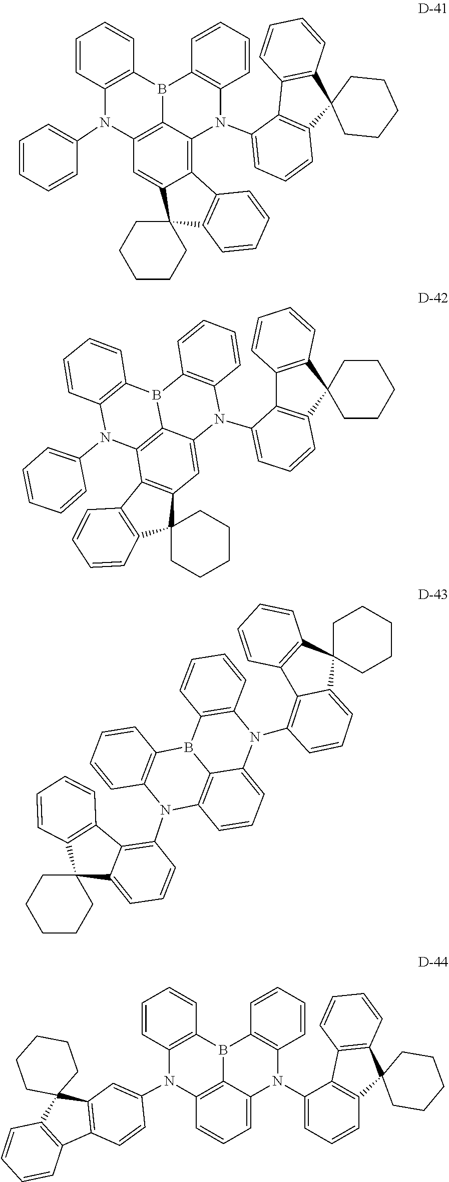

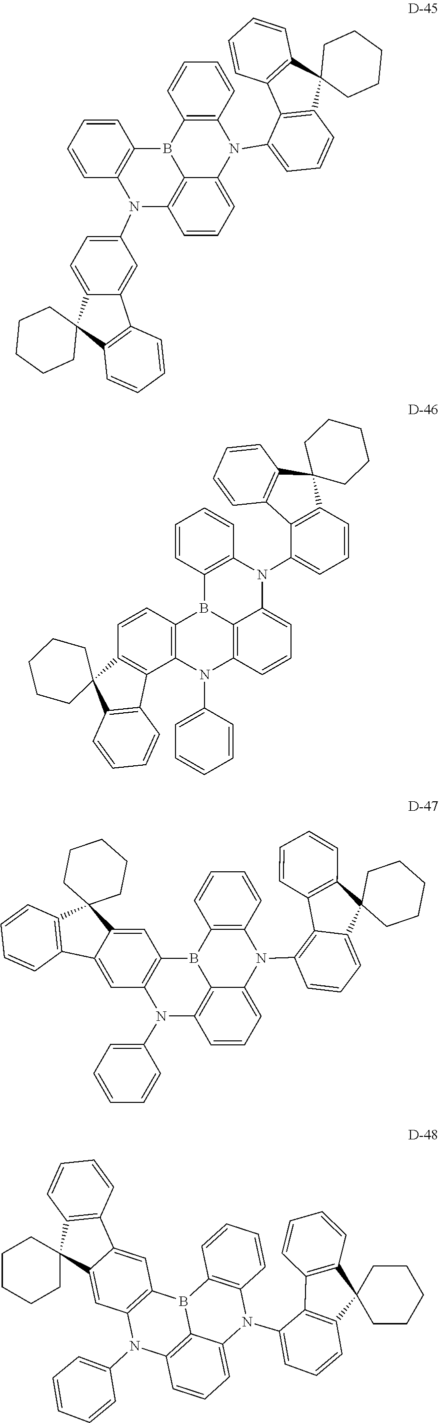

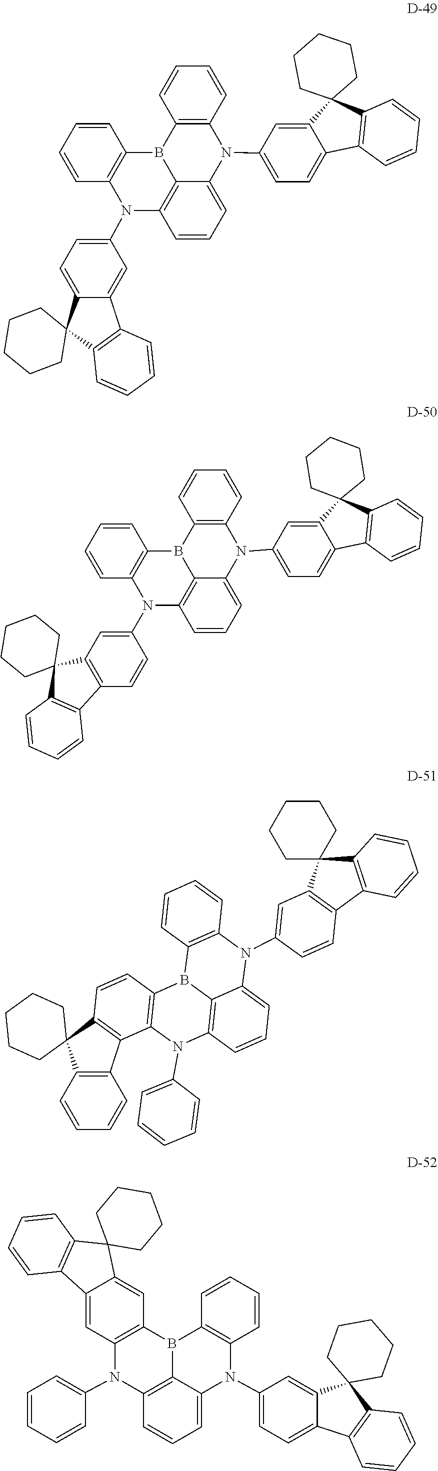

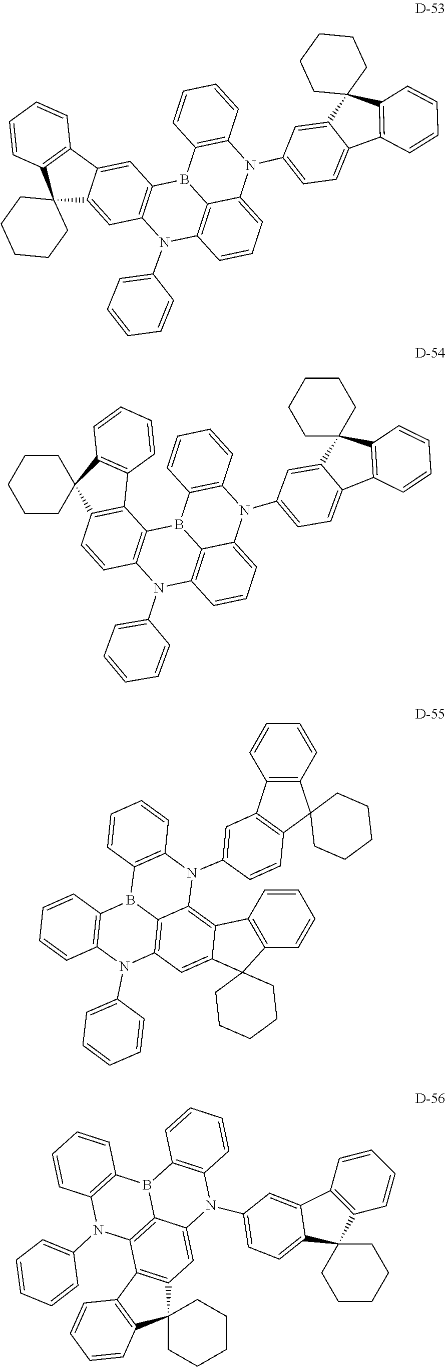

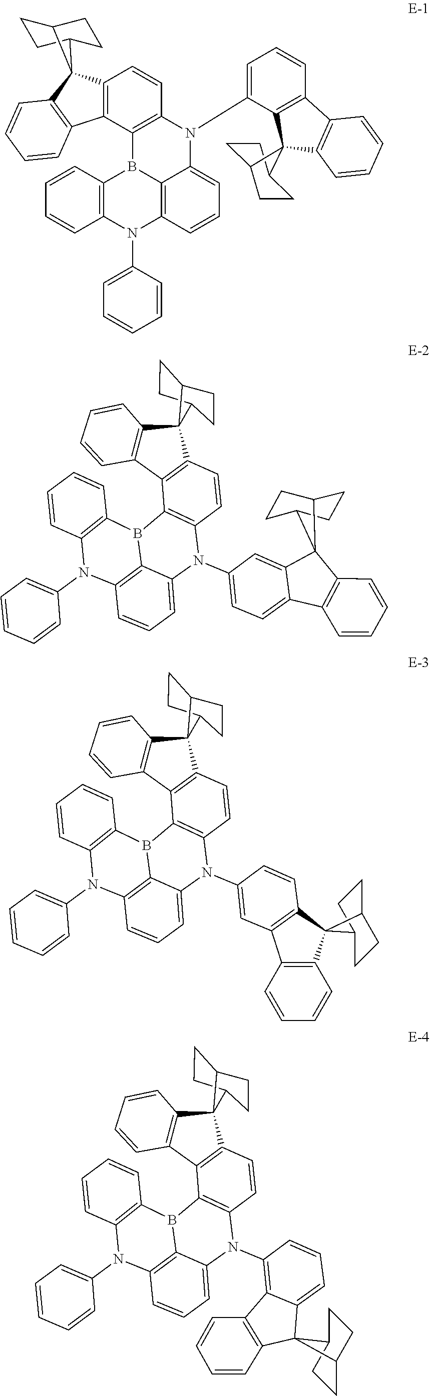

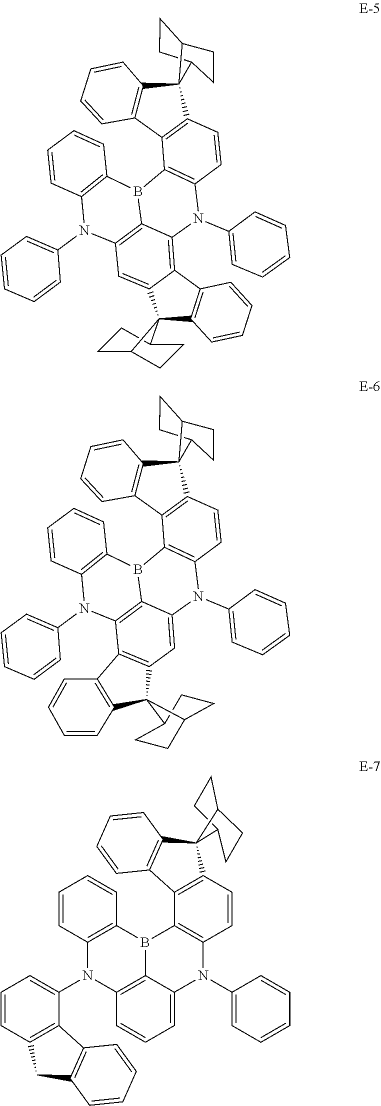

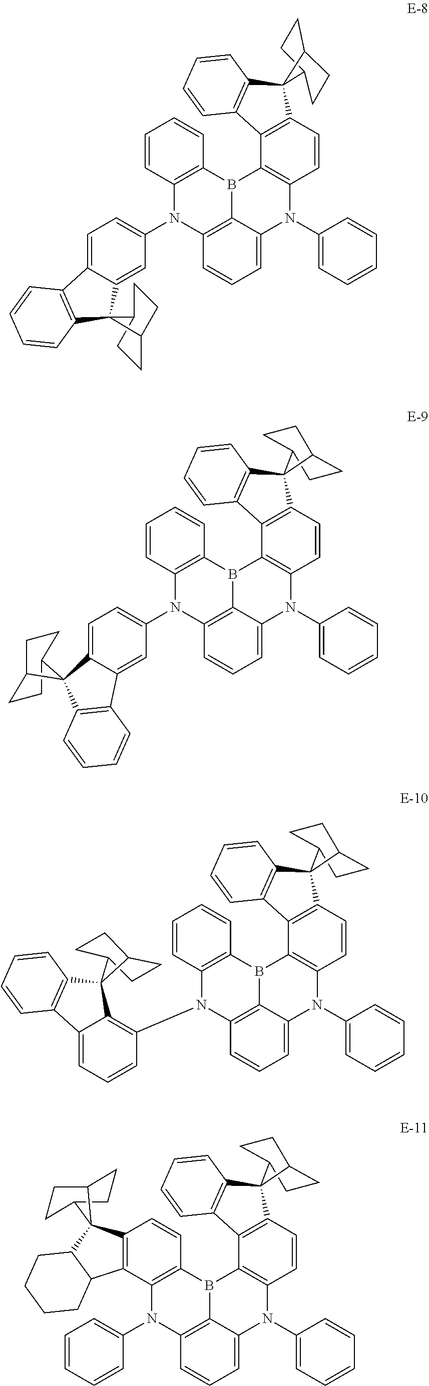

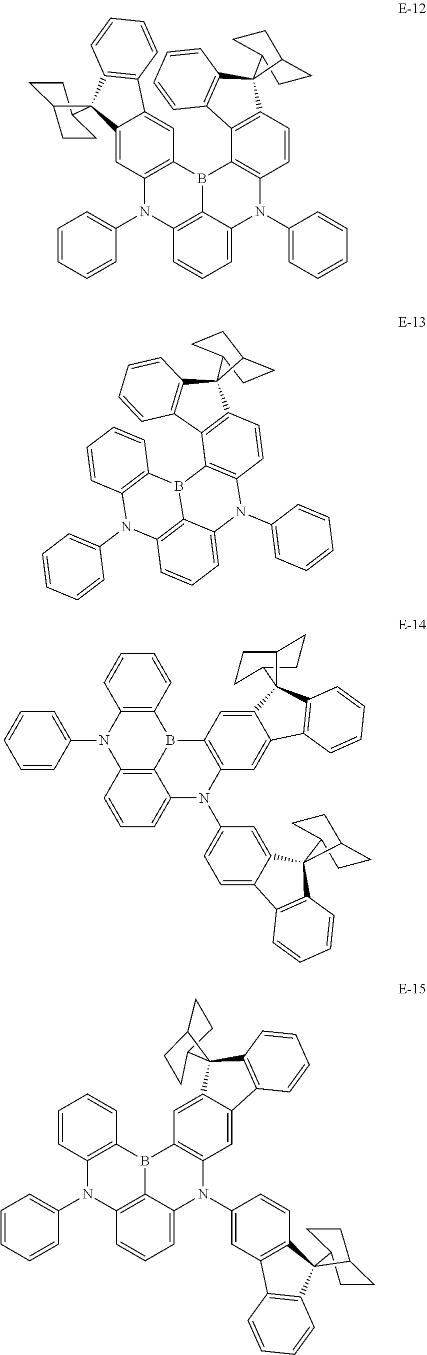

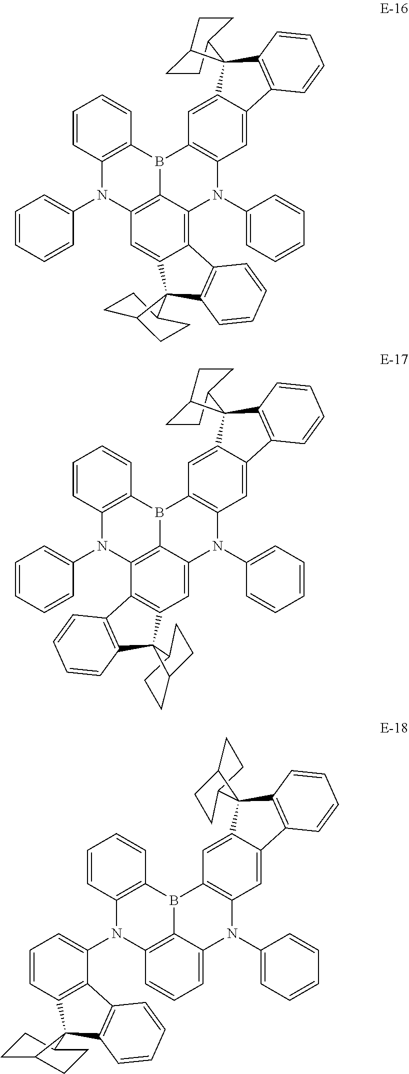

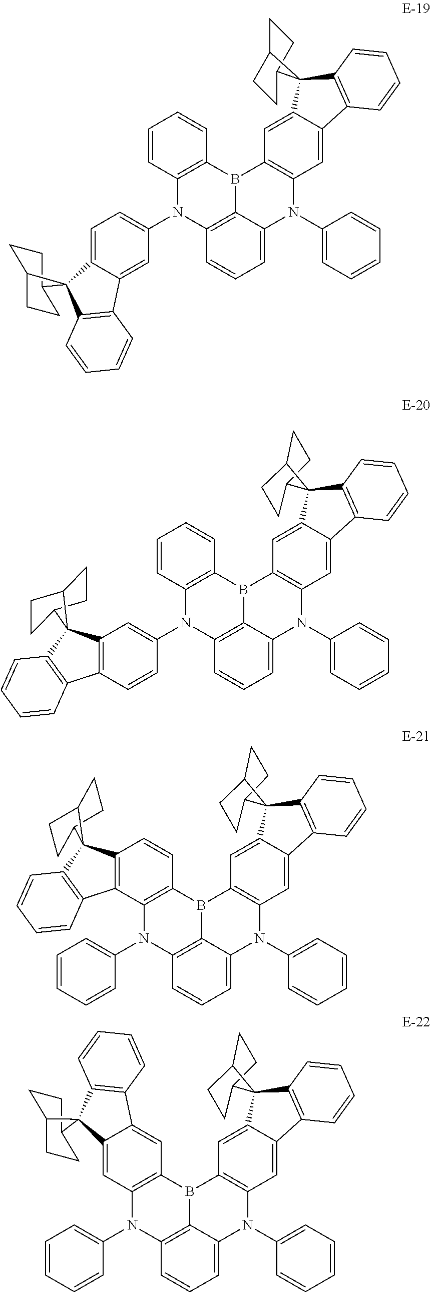

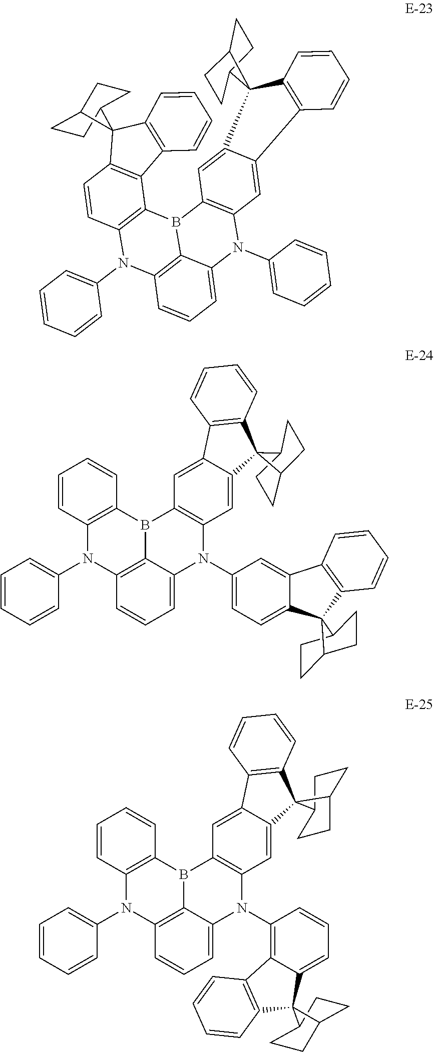

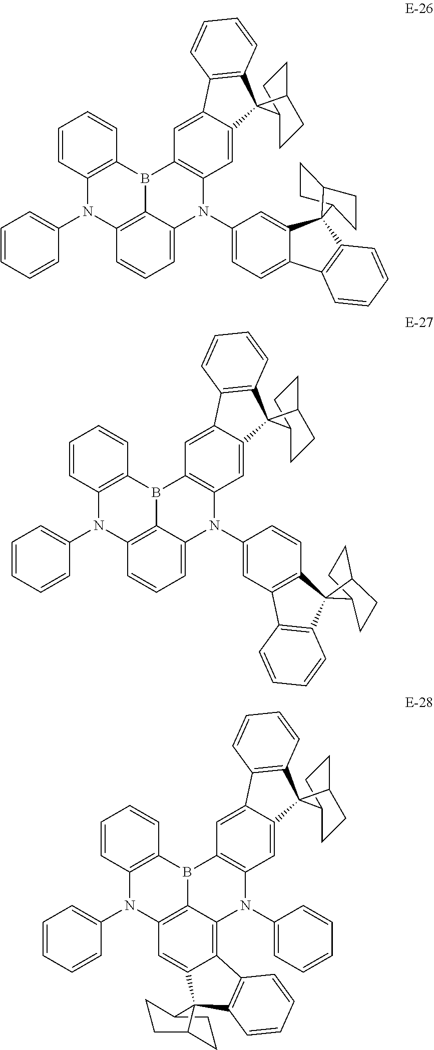

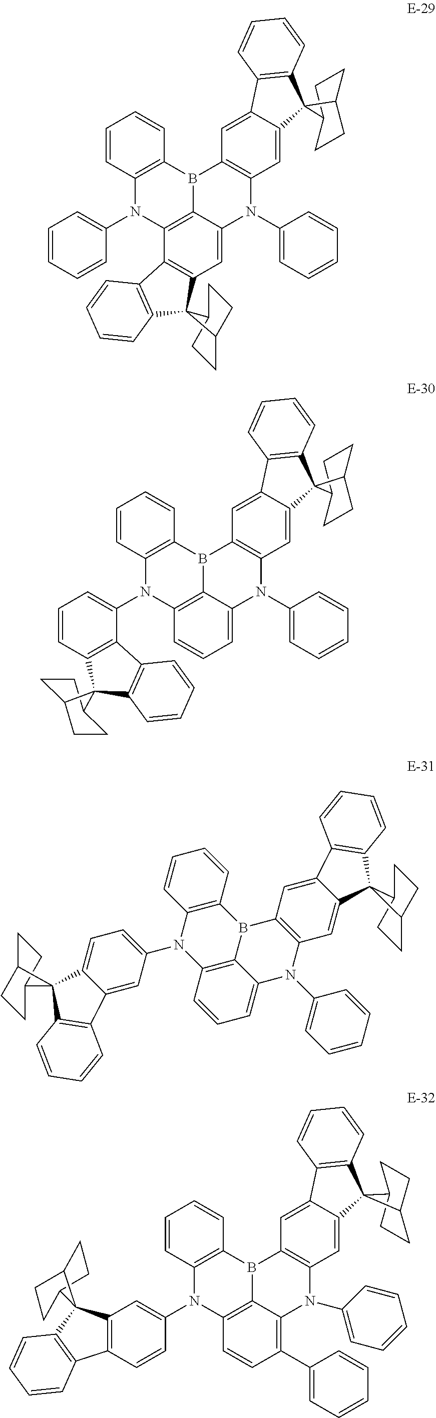

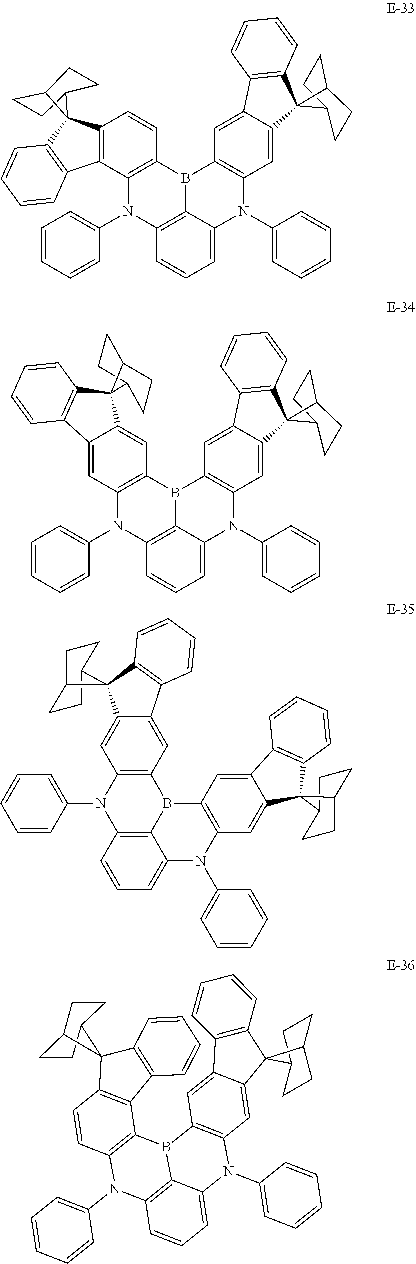

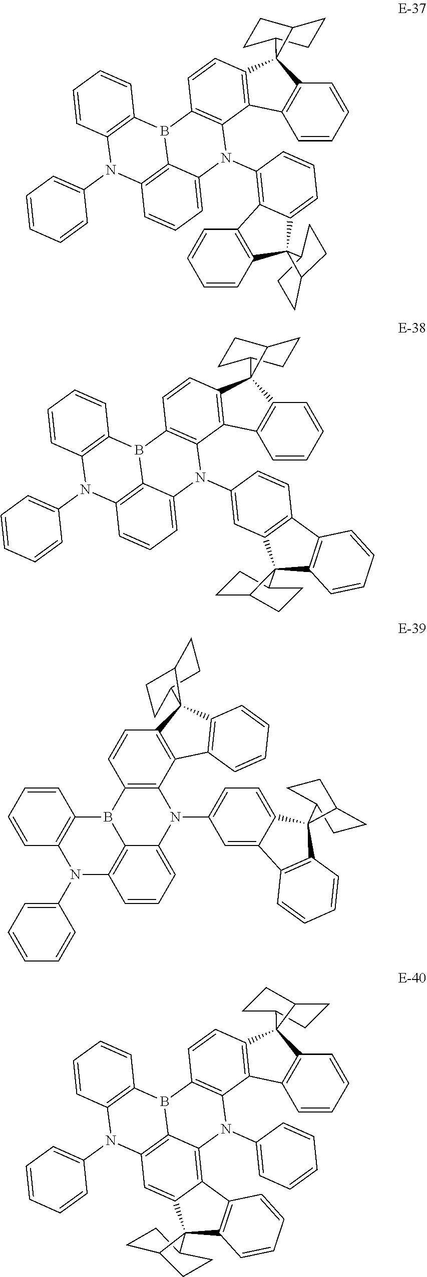

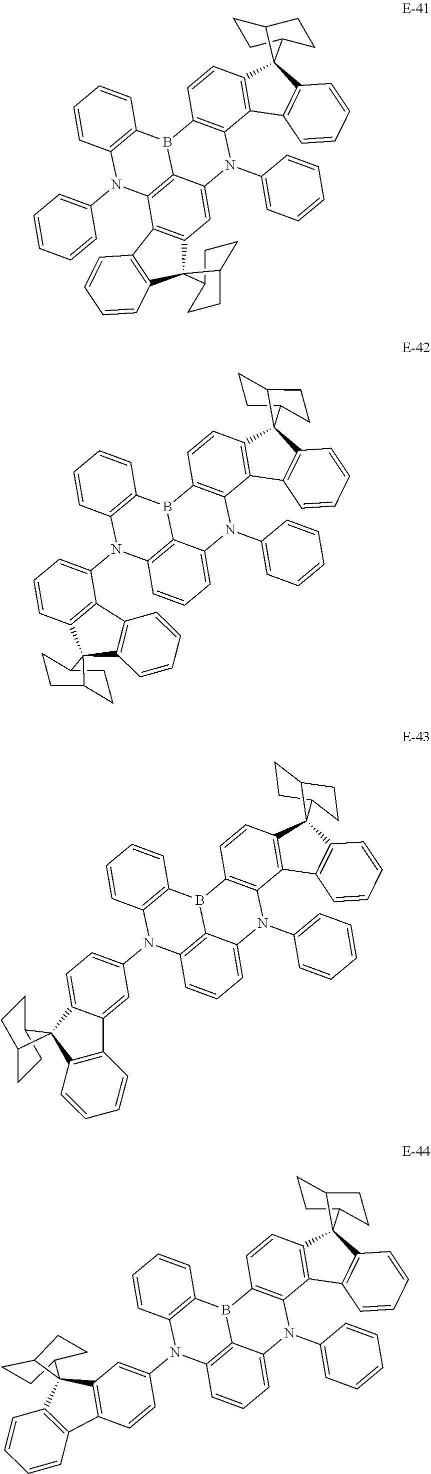

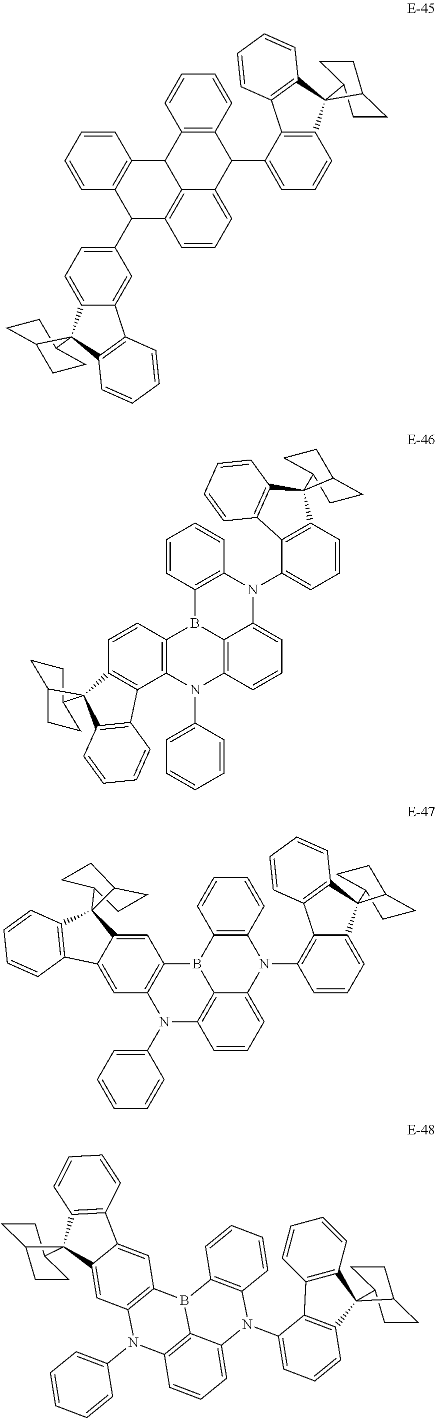

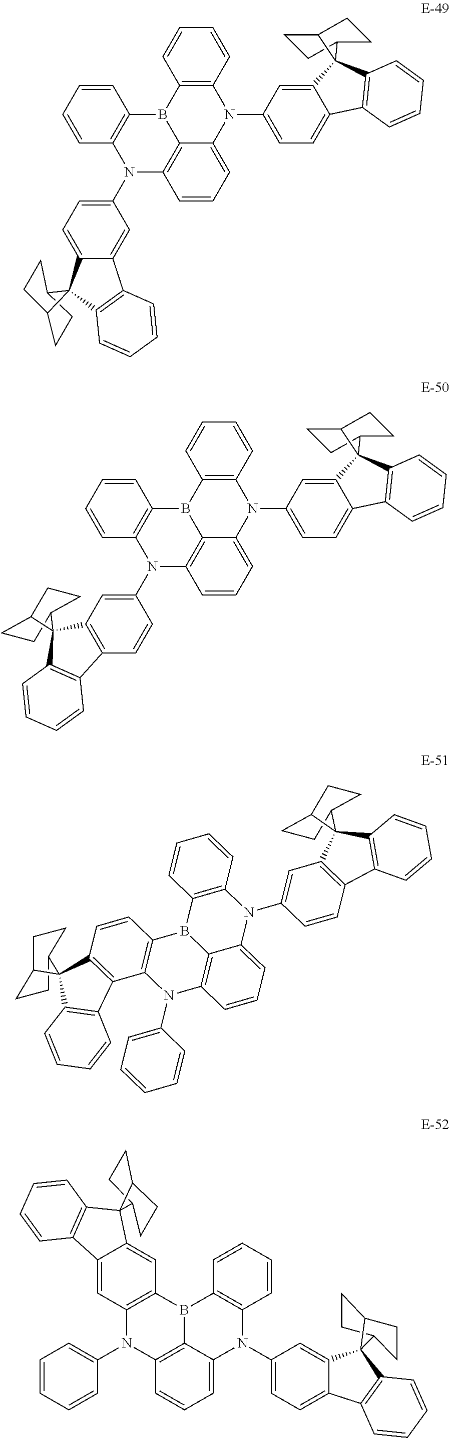

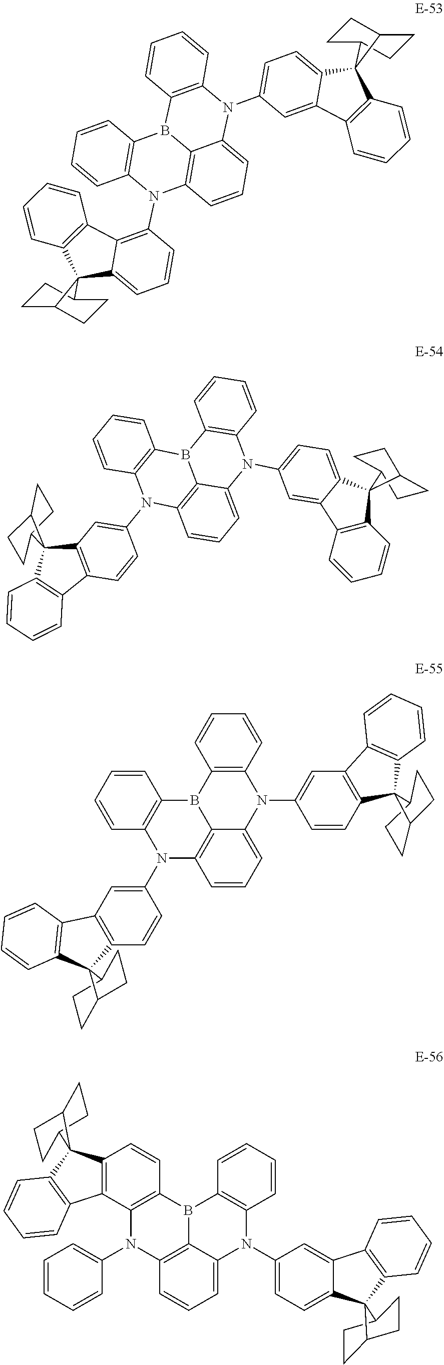

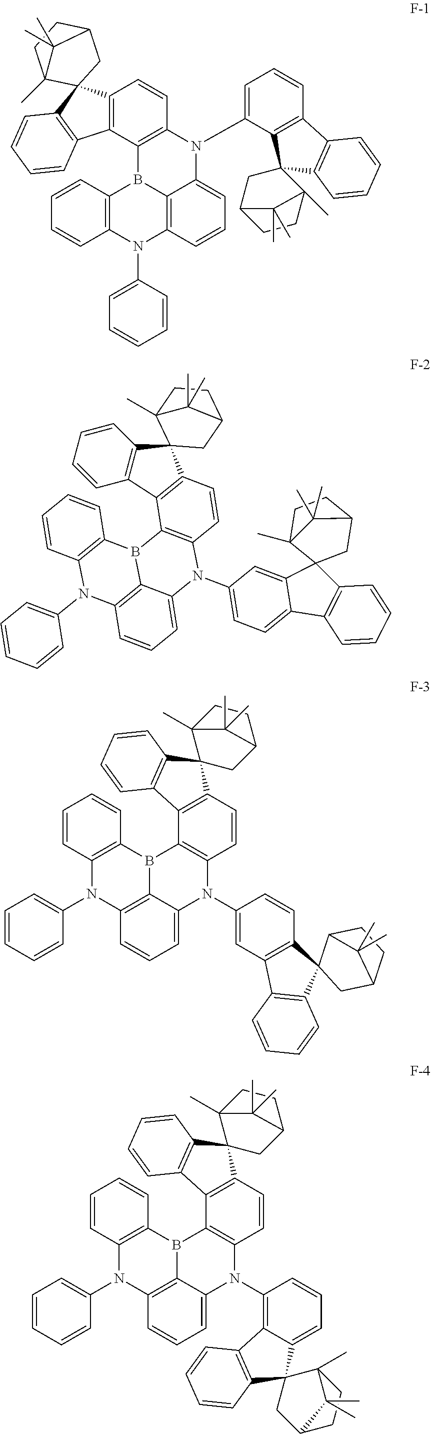

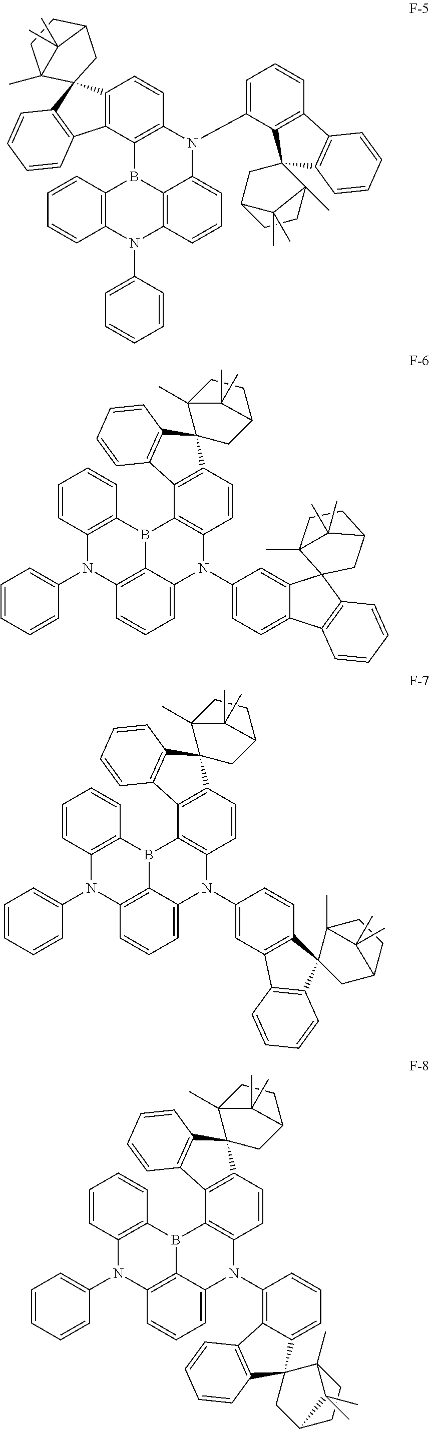

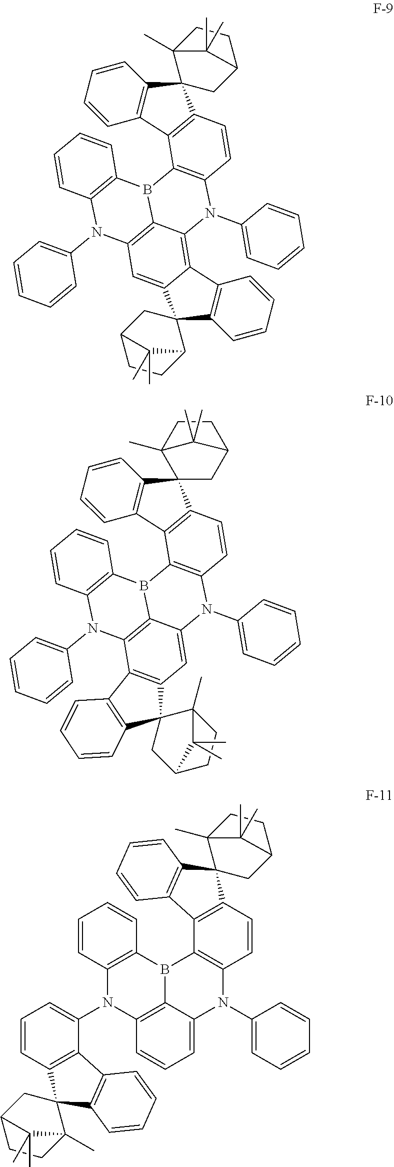

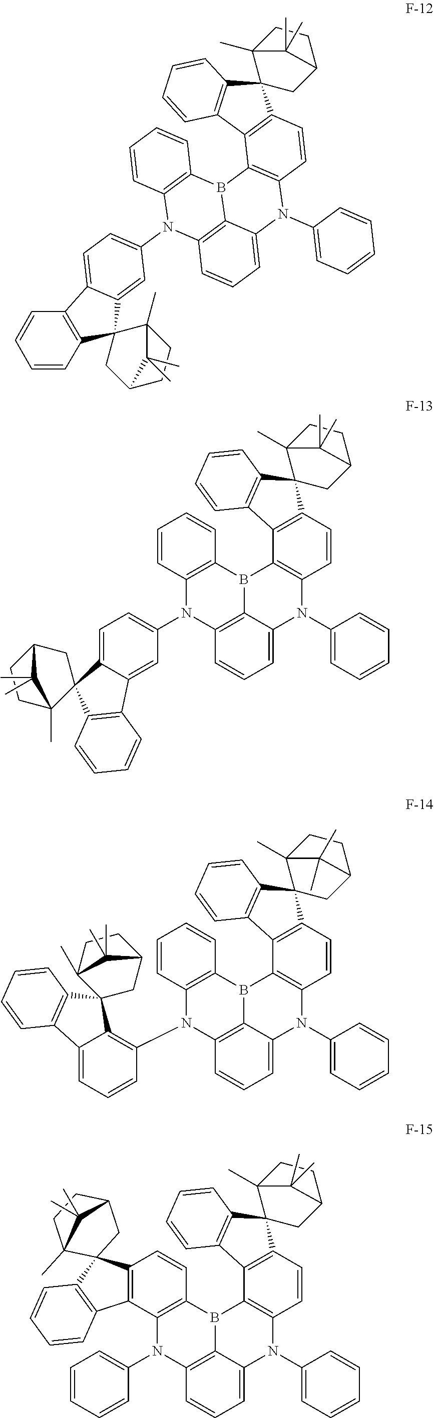

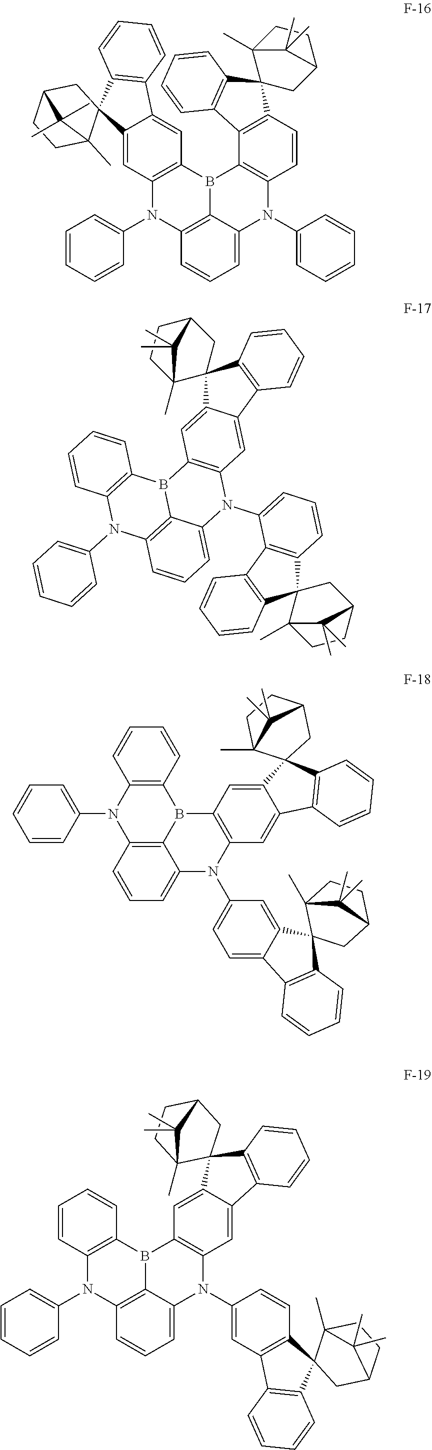

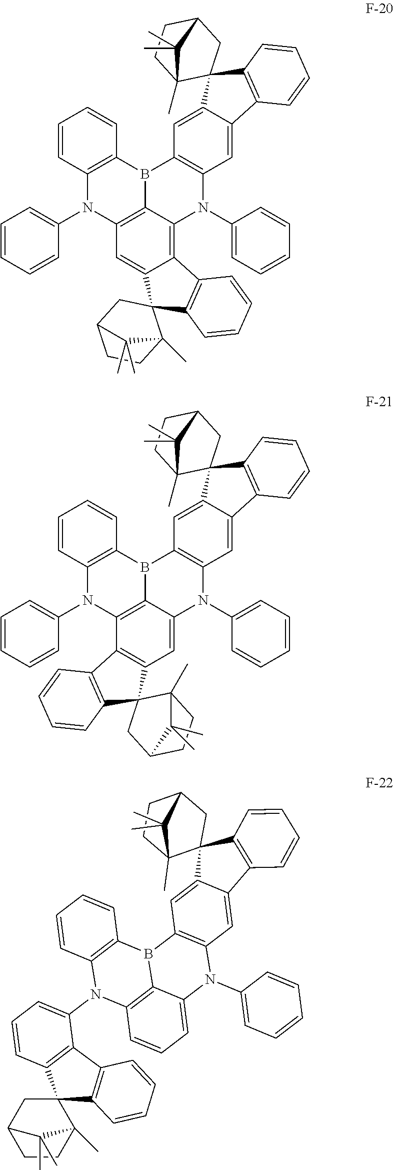

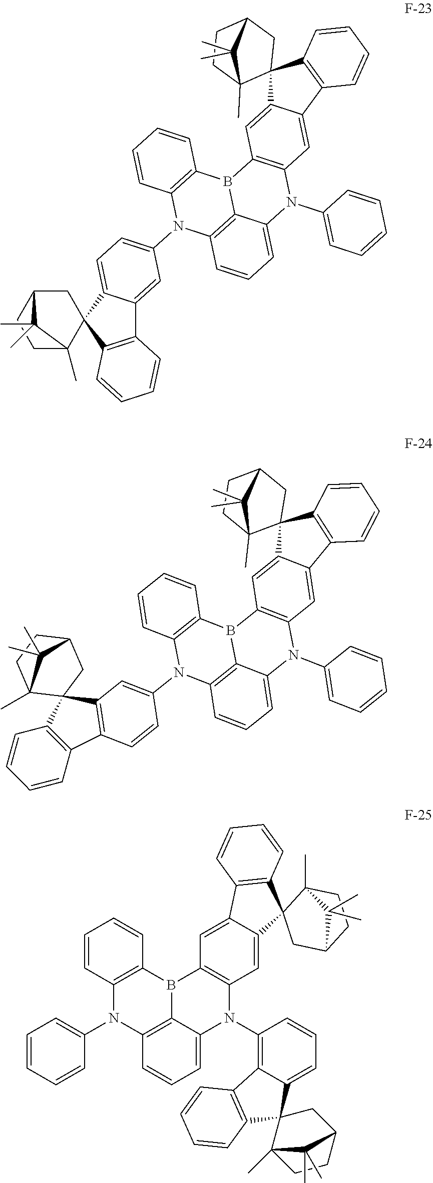 [SMILES: CC1(C)[C@@H]2CCC1(C)[C@@]1(C2)c2ccccc2-c2cc(N3c4ccccc4B4c5cc6c(cc5N(c5ccccc5)c5cccc3c54)-c3ccccc3[C@@]63C[C@H]4CC[C@]3(C)C4(C)C)ccc21 ; CC1(C)[C@@H]2CC[C@@]1(C)[C@@]1(C2)c2ccccc2-c2cc3c(cc21)B1c2ccccc2N(c2ccc4c(c2)[C@@]2(C[C@H]5CC[C@]2(C)C5(C)C)c2ccccc2-4)c2cccc(c21)N3c1ccccc1 ; CC1(C)[C@H]2CC[C@]1(C)[C@@]1(C2)c2ccccc2-c2cc3c(cc21)N(c1cccc2c1-c1ccccc1[C@@]21C[C@@H]2CC[C@@]1(C)C2(C)C)c1cccc2c1B3c1ccccc1N2c1ccccc1]

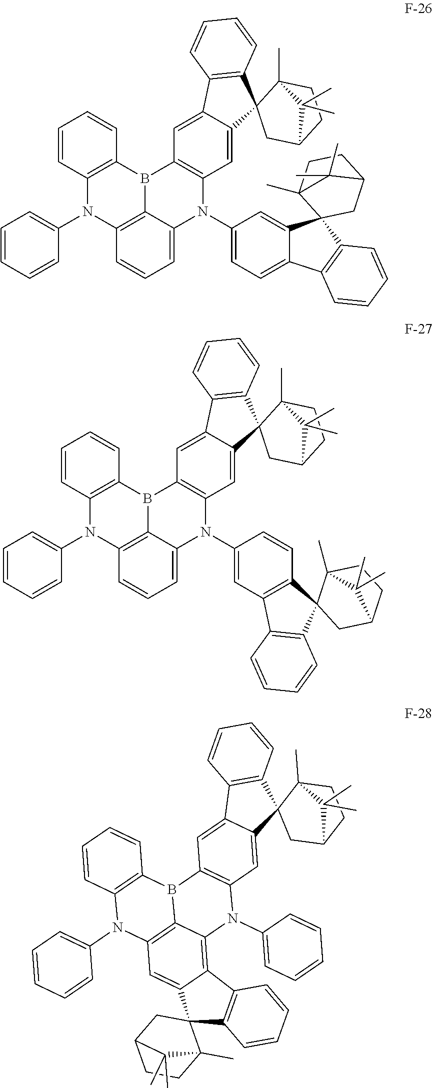

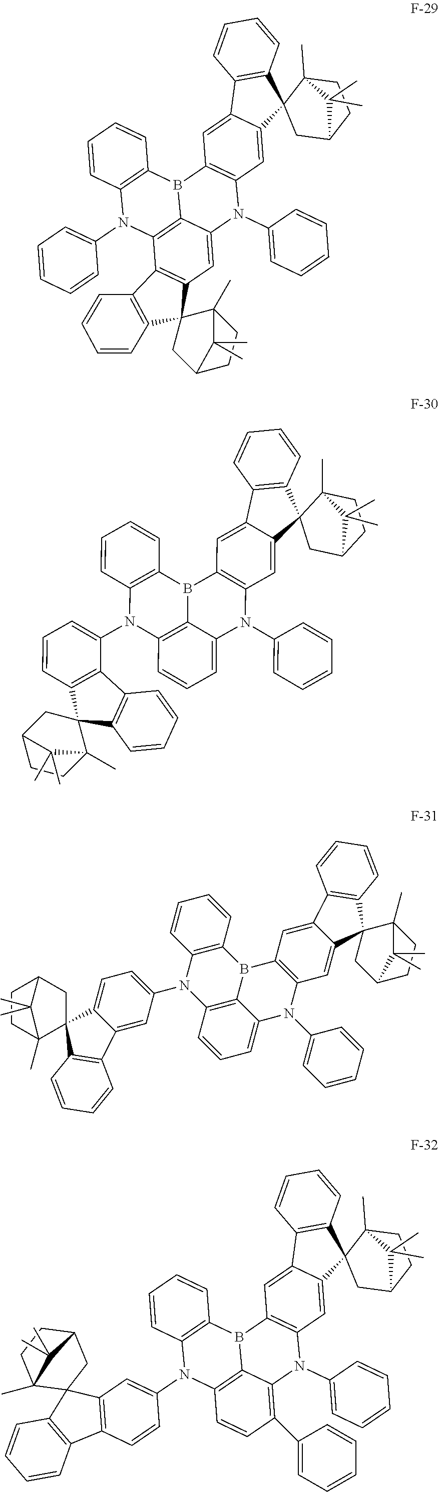

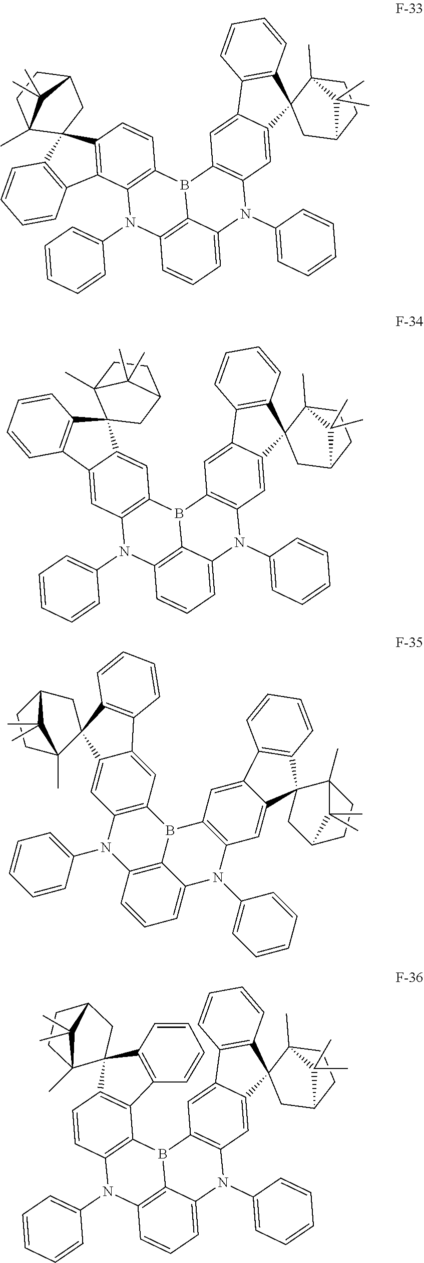

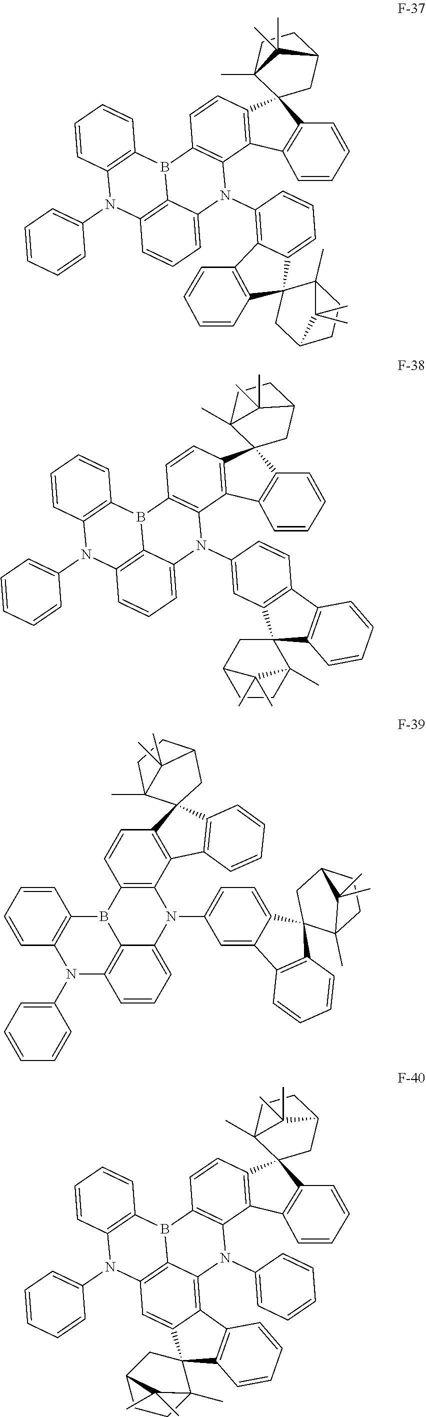

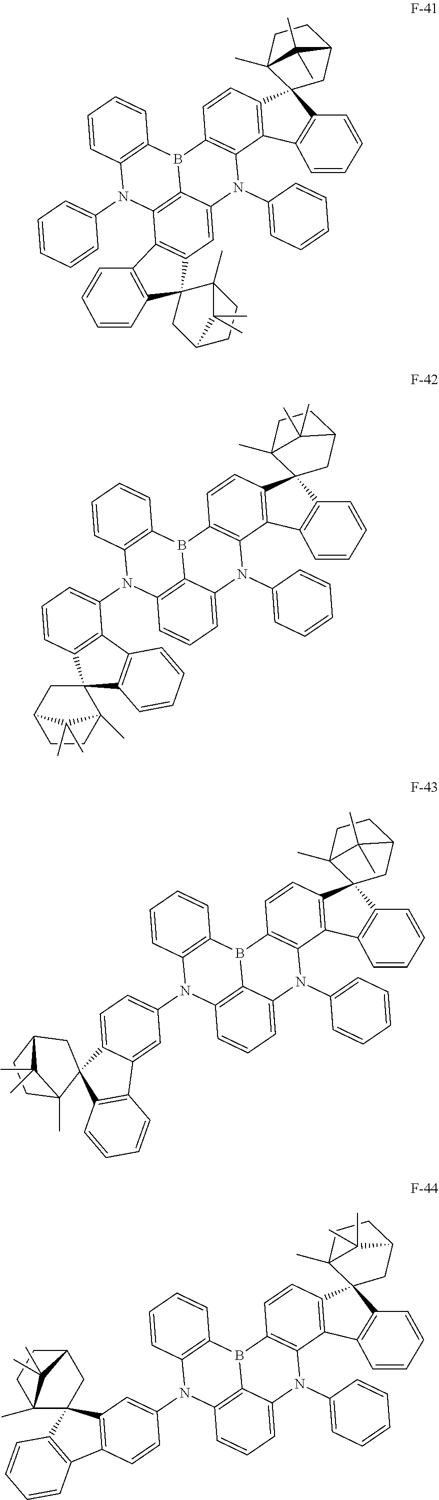

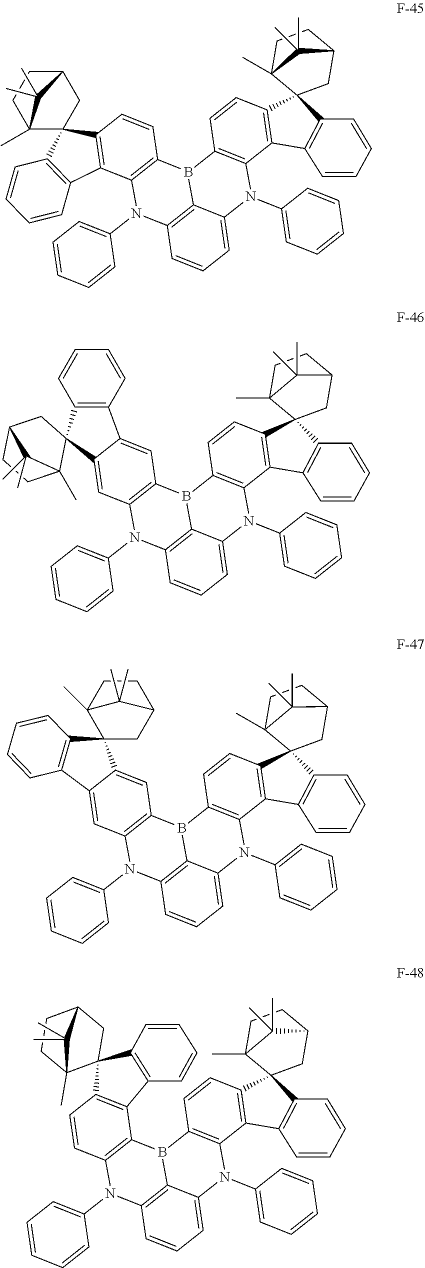

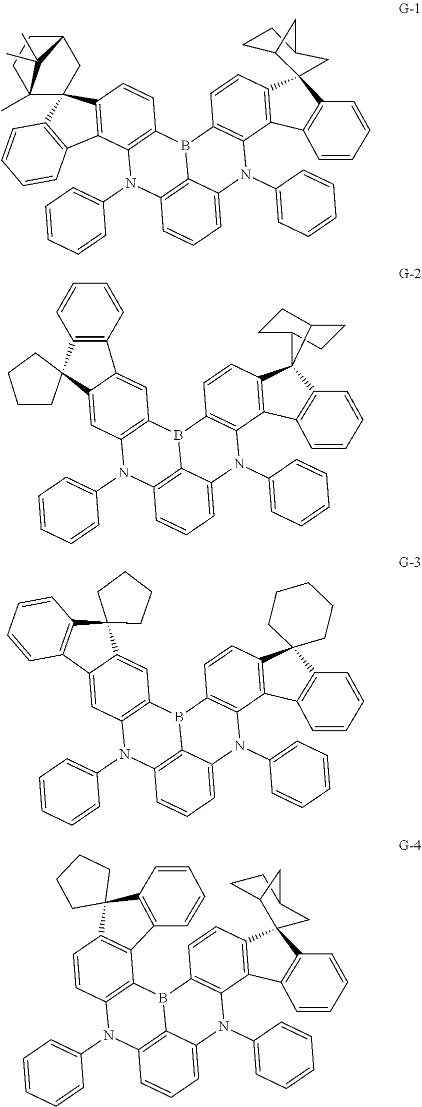

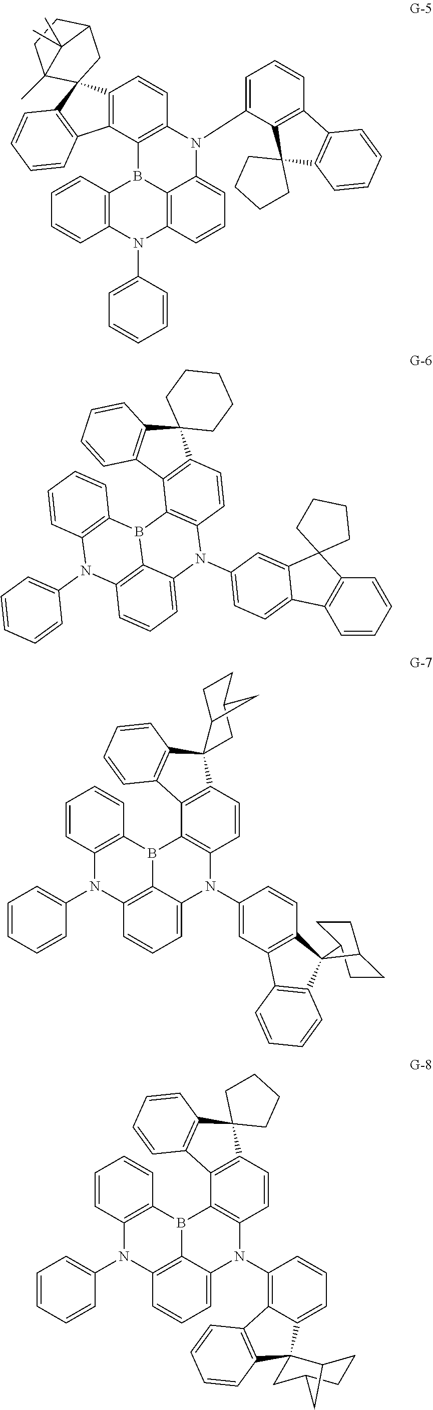

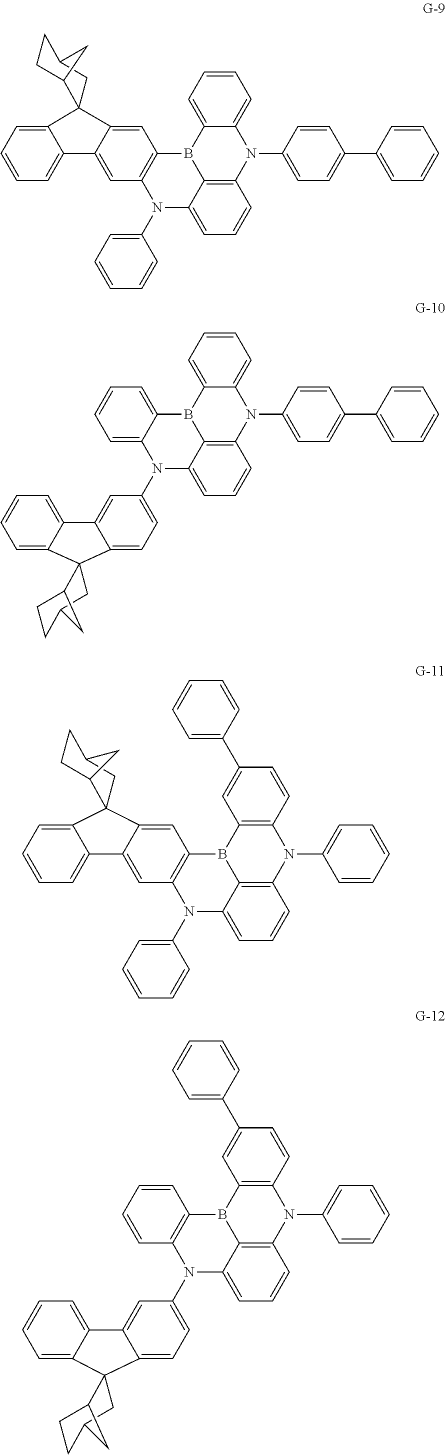

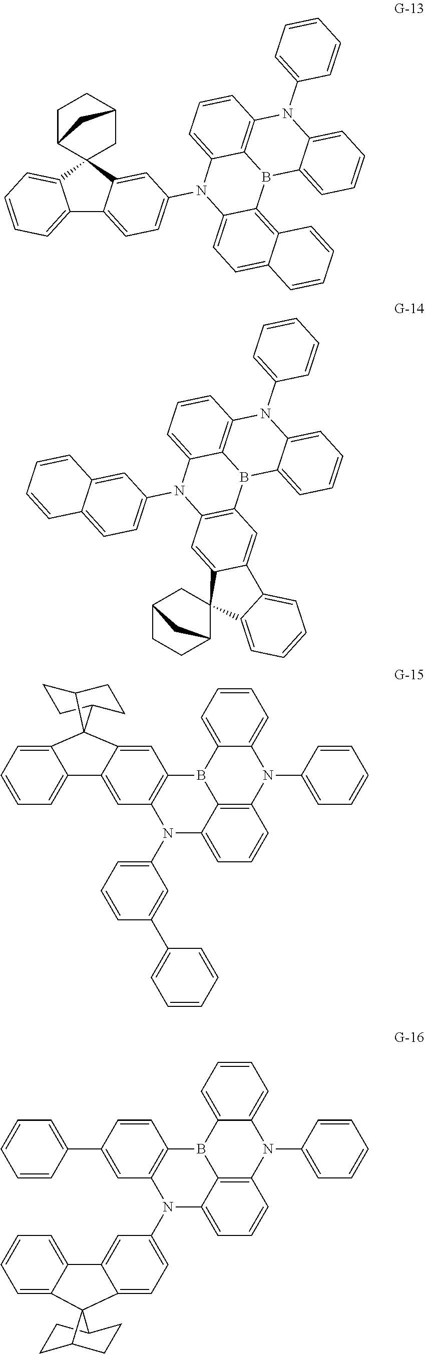

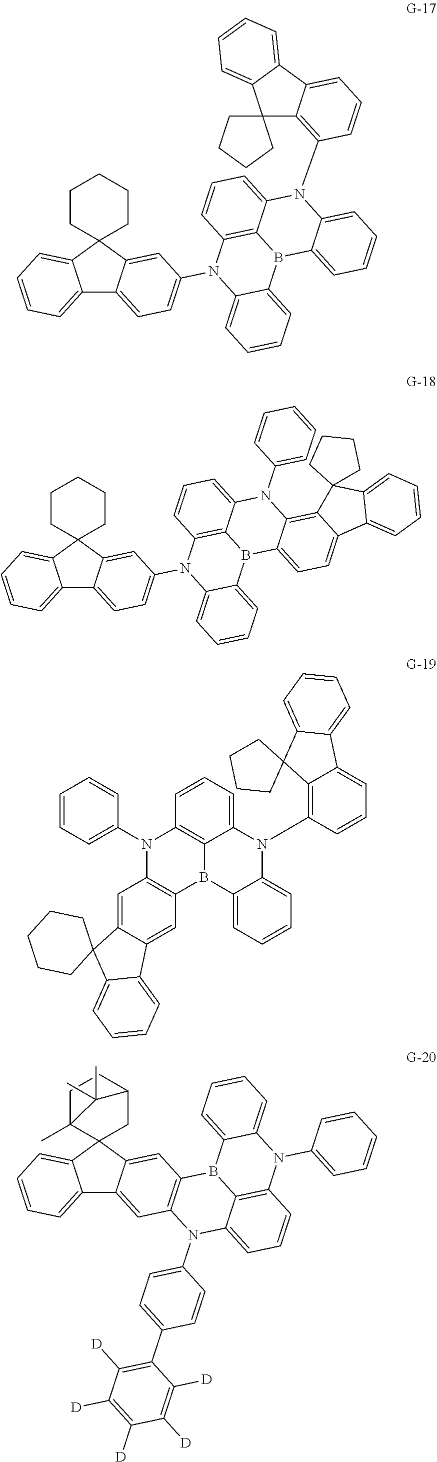

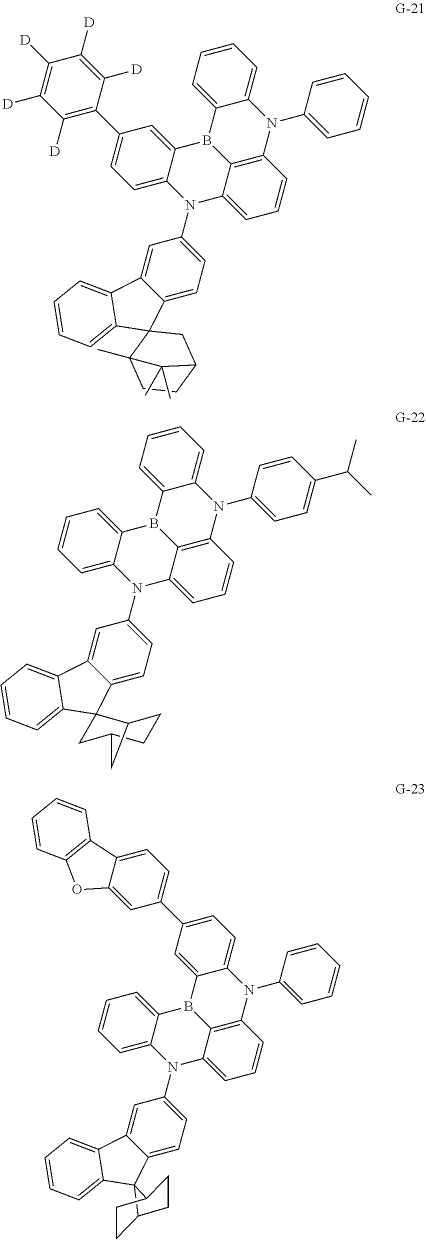

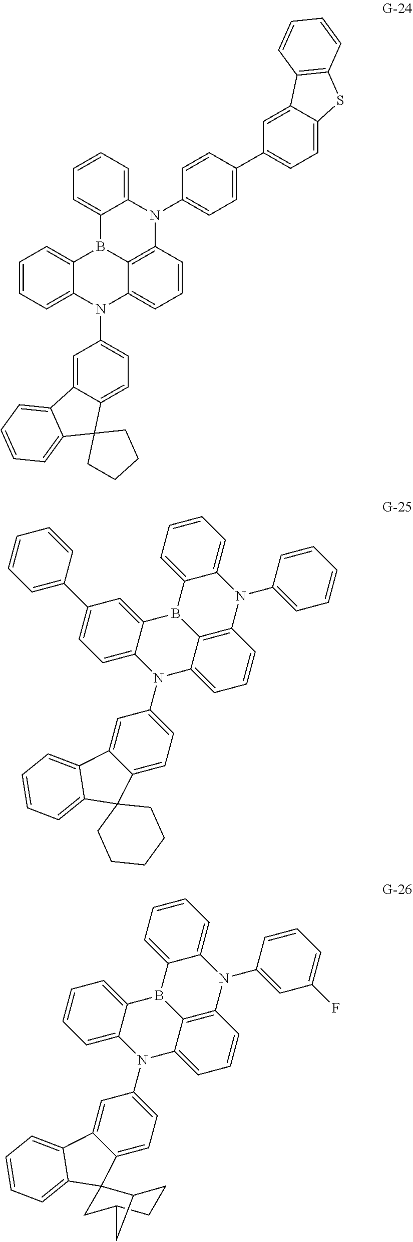

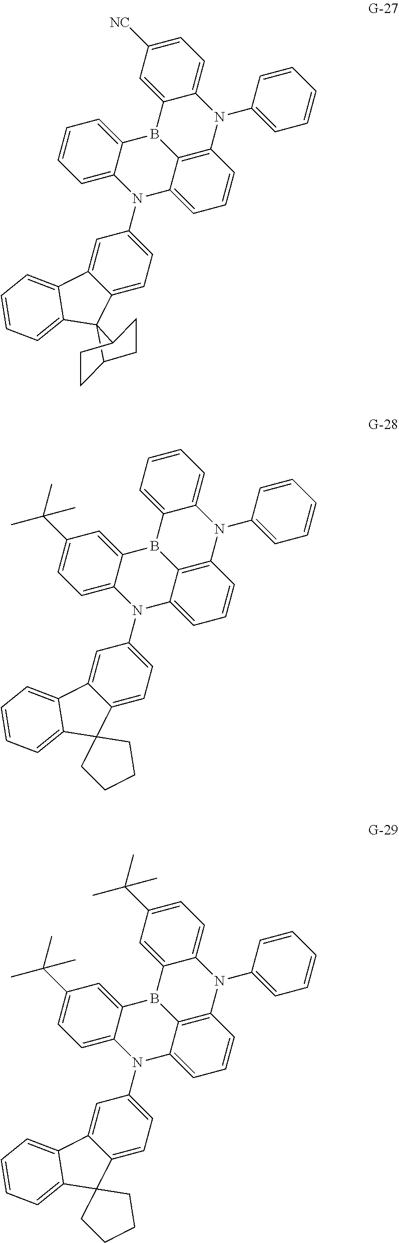 [SMILES: N#Cc1ccc2c(c1)B1c3ccccc3N(c3ccc4c(c3)-c3ccccc3C43C4CCC3CC4)c3cccc(c31)N2c1ccccc1 ; CC(C)(C)c1ccc2c(c1)B1c3ccccc3N(c3ccccc3)c3cccc(c31)N2c1ccc2c(c1)-c1ccccc1C21CCCC1 ; CC(C)(C)c1ccc2c(c1)B1c3cc(C(C)(C)C)ccc3N(c3ccc4c(c3)-c3ccccc3C43CCCC3)c3cccc(c31)N2c1ccccc1]

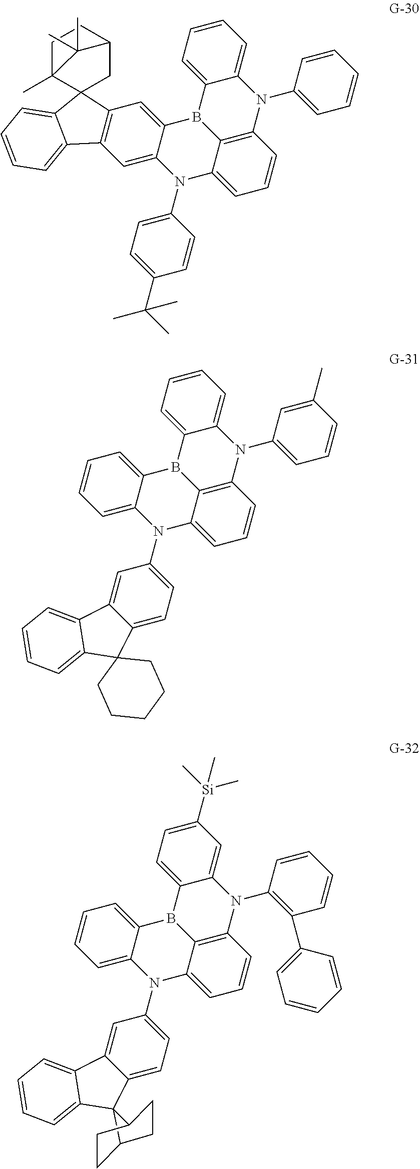

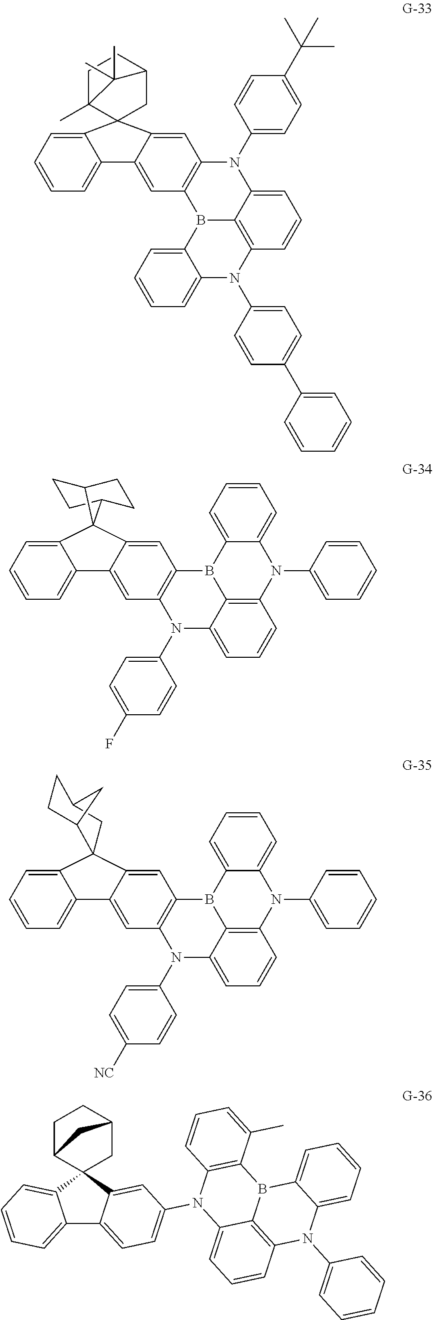

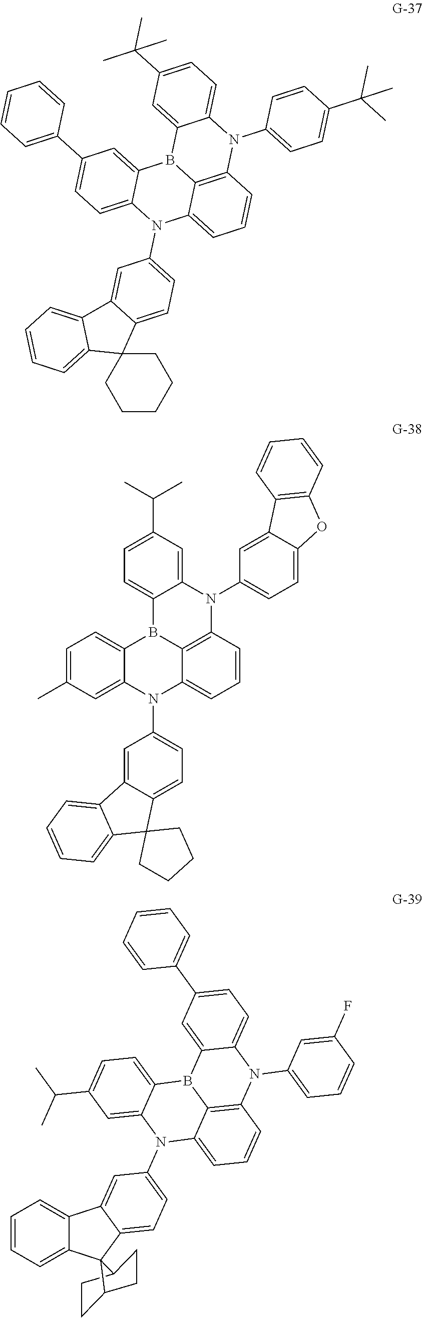

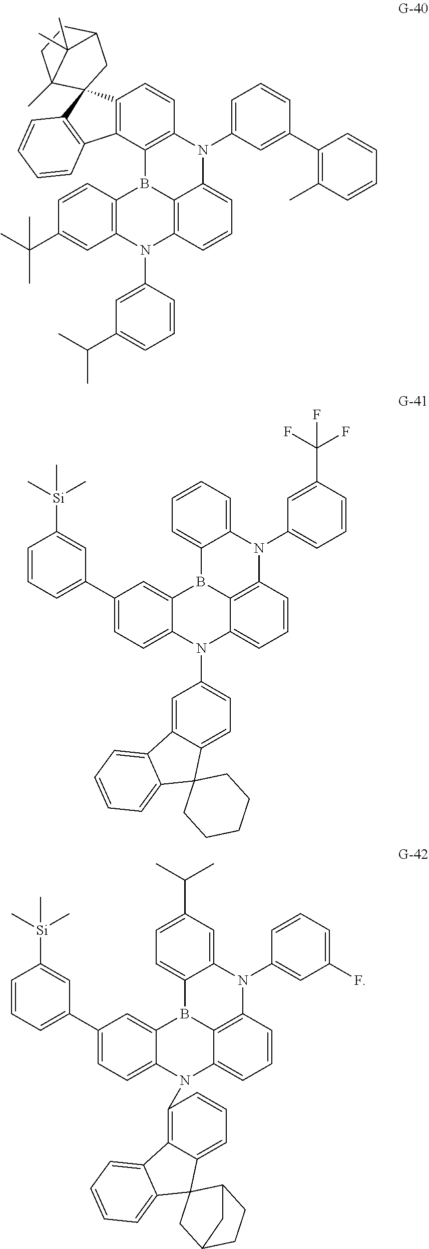

In a second aspect of the present disclosure, provided is an organic electroluminescent device, including an anode and a cathode which are oppositely disposed, and a functional layer disposed between the anode and the cathode; wherein the functional layer includes the organic compound according to the first aspect of the present disclosure.

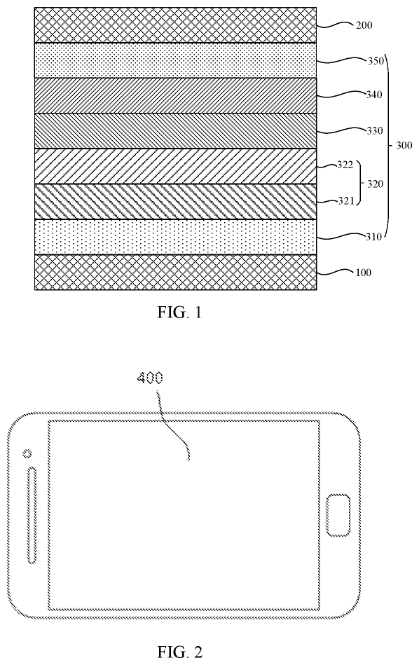

In one specific embodiment of the present disclosure, the organic electroluminescent device is preferably a blue organic electroluminescent device. As shown in FIG. 1, the organic electroluminescent device may include an anode 100, a first hole transport layer 321, a second hole transport layer 322, an organic light-emitting layer 330 as an energy conversion layer, an electron transport layer 340, and a cathode 200 which are sequentially stacked.

Optionally, the anode 100 includes the following anode materials, which are preferably materials having a large work function that facilitate hole injection into the functional layer. Specific examples of the anode materials include metals such as nickel, platinum, vanadium, chromium, copper, zinc, and gold, or their alloys; metal oxides such as zinc oxide, indium oxide, indium tin oxide (ITO) and indium zinc oxide (IZO); combined metals and oxides, such as ZnO:Al or SnO₂:Sb; or a conductive polymer such as poly(3-methylthiophene), poly[3,4-(ethylene-1,2-dioxy)thiophene] (PEDT), polypyrrole, and polyaniline, but are not limited to this. A transparent electrode containing indium tin oxide (ITO) as the anode is preferably included.

Optionally, the first hole transport layer 321 and the second hole transport layer 322 respectively include one or more hole transport materials, and the hole transport materials may be selected from a carbazole polymer, carbazole connected triarylamine compounds or other types of compounds, which are not specially limited in the present disclosure. For example, the first hole transport layer 321 may consist of a compound NPB and the second hole transport layer consists of a compound TcTa.

Optionally, the organic light-emitting layer 330 can be composed of a single light-emitting material, and can also include a host material and a doping material. Optionally, the organic light-emitting layer 330 is composed of the host material and the doping material, holes injected into the organic light-emitting layer 330 and electrons injected into the organic light-emitting layer 330 can be recombined in the organic light-emitting layer 330 to form excitons, the excitons transfer energy to the host material, the host material transfers energy to the doping material, and then the doping material can emit light.

The host material of the organic light-emitting layer 330 can be a metal chelated compound, a distyryl derivative, an aromatic amine derivative, a dibenzofuran derivative or other types of materials, which is not specially limited in the present disclosure. In one embodiment of the present disclosure, the host material is BH-1.

A guest material of the organic light-emitting layer 330 may be a compound having a condensed aryl ring or its derivative, a compound having a heteroaryl ring or its derivative, an aromatic amine derivative, or other materials, which is not specially limited in the present disclosure. In one embodiment of the present disclosure, the guest material of the organic light-emitting layer 330 contains the organic compound of the present disclosure.

In one specific embodiment of the present disclosure, the organic electroluminescent device is a blue organic electroluminescent device. The organic light-emitting layer is composed of a host material BH-1 and a guest material (the compound of the present disclosure).

The electron transport layer 340 can be of a single-layer structure or a multi-layer structure and can include one or more electron transport materials, and the electron transport materials can be selected from but are not limited to a benzimidazole derivative, an oxadiazole derivative, a quinoxaline derivative or other electron transport materials. In one embodiment of the present disclosure, the electron transport layer 340 may consist of ET-1 and LiQ.

In the present disclosure, the cathode 200 may include a cathode material, which is a material with a small work function that facilitates electron injection into the functional layer. Specific examples of the cathode material include, but are not limited to, metals such as magnesium, calcium, sodium, potassium, titanium, indium, yttrium, lithium, gadolinium, aluminum, silver, tin, and lead, or their alloys; or a multilayer material such as LiF/Al, Liq/Al, LiO₂/Al, LiF/Ca, LiF/Al, and BaF₂/Ca. A metal electrode including magnesium and silver as the cathode is preferably included.

Optionally, as shown in FIG. 1, a hole injection layer 310 can also be arranged between the anode 100 and the first hole transport layer 321, so that the capability of injecting holes into the first hole transport layer 321 is enhanced. The hole injection layer 310 can be made of a benzidine derivative, a starburst arylamine compound, a phthalocyanine derivative or other materials, which is not specially limited in the present disclosure. For example, the hole injection layer 310 may consist of HAT-CN.

Optionally, as shown in FIG. 1, an electron injection layer 350 can also be arranged between the cathode 200 and the electron transport layer 340 to enhance the ability of injecting electrons into the electron transport layer 340. The electron injection layer 350 may include an inorganic material such as an alkali metal sulfide, and an alkali metal halide, or may include a complex of an alkali metal and an organic substance. For example, the electron injection layer 350 may include Yb.

The organic electroluminescent device of the present disclosure is optionally a blue device.

In a third aspect of the present disclosure, provided is an electronic apparatus, including the organic electroluminescent device according to the second aspect of the present disclosure.

According to one embodiment, as shown in FIG. 2, the electronic apparatus is an electronic apparatus 400 including the organic electroluminescent device described above. The electronic apparatus 400 may be, for example, a display device, a lighting device, an optical communication device, or other type of electronic devices, and may include, for example, but is not limited to, a computer screen, a mobile phone screen, a television, electronic paper, an emergency lighting lamp, an optical module, and the like.

Compounds of which synthesis methods were not mentioned in the present disclosure were all commercially available raw material products.

An ICP-7700 mass spectrometer was used for analysis and detection of intermediates and compounds in the present disclosure.

A synthesis method of the organic compound of the present disclosure was specifically described below in combination with synthesis examples.

The synthesis method of the organic compound provided is not particularly limited in the present disclosure, and those skilled in the art can determine a proper synthesis method according to the organic compound provided by the present disclosure in combination with a preparation method provided in the synthesis examples of the present disclosure. In other words, for example, the synthesis examples of the present disclosure provide a preparation method for the organic compound, and the adopted raw materials can be obtained commercially or by a method well known in the art. All the organic compounds provided by the present disclosure can be obtained by those skilled in the art according to these exemplary preparation methods, and all specific preparation methods for preparing the organic compound are no longer detailed, which should not be understood by those skilled in the art as limiting the present disclosure.

### 1. Synthesis of Intermediates X-2 (X is a Variable, Specifically Shown Below)

The synthesis of the following intermediates X-2 was illustrated by taking an intermediate A-2 as an example.

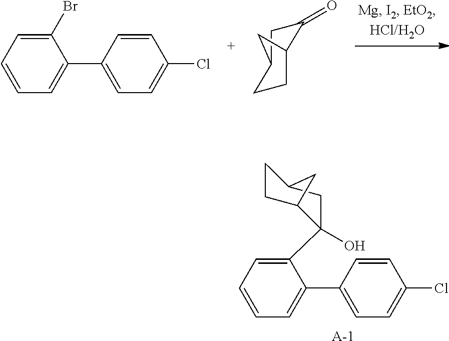

Magnesium ribbons (5.45, 224.3 mmol) and diethyl ether (100 mL) were placed in a dry round bottom flask under nitrogen protection, iodine (100 mg) was added, then a solution of 2′-bromo-4-chlorobiphenyl (50.00 g, 187.0 mmol) in diethyl ether (200 mL) was slowly added dropwise into the flask, and after the adding dropwise was completed, the mixture was heated to 35° C., and stirred for 3 hours; the resulting reaction solution was cooled to 0° C., a solution of 2-norbornanone (16.5 g, 149.5 mmol) in diethyl ether (200 mL) was slowly added dropwise, after the adding dropwise was completed, the mixture was heated to 35° C., and stirred for 6 hours, the resulting reaction solution was cooled to room temperature, 5% hydrochloric acid was added to pH<7, stirring was performed for 1 hour, diethyl ether (200 mL) was added for extraction, organic phases were combined, dried over anhydrous magnesium sulfate, and filtered, and a solvent was removed under reduced pressure; and the obtained crude product was purified by silica gel column chromatography using ethyl acetate/n-heptane (a volume ratio of 1:3) as a mobile phase to obtain an intermediate A-1 (34 g, yield: 76.0%) as a white solid.

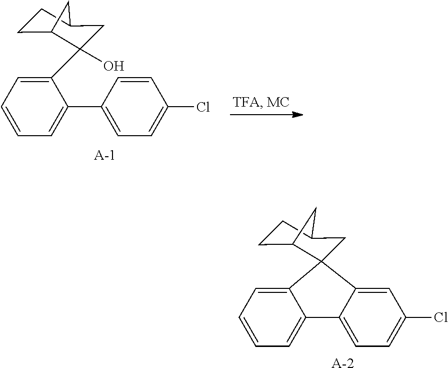

The intermediate A-1 (34 g, 113.78 mmol), trifluoroacetic acid (36.93 g, 380.6 mmol) and dichloromethane (300 mL) were added into a round bottom flask, the mixture was stirred under nitrogen protection for 2 hours; then an aqueous sodium hydroxide solution was added to the resulting reaction solution to pH=8, liquid separation was performed, an organic phase was dried over anhydrous magnesium sulfate, and filtered, and a solvent was removed under reduced pressure; and the obtained crude product was purified by recrystallization using dichloromethane/n-heptane (a volume ratio of 1:2) to obtain the intermediate A-2 (29.2 g, yield: 91.4%) as a white solid.

Referring to the synthesis method of the intermediate A-2, intermediates X-1 were prepared by the same synthesis method as that of the intermediate A-1 by using a raw material 1 shown in Table 1 below instead of 2′-bromo-4-chlorobiphenyl and a raw material 2 shown in Table 1 below instead of 2-norbornanone, and then intermediates X-2 (X=B-I) were prepared by using the same synthesis method as that of the intermediate A-2.

TABLE 1

| Intermediate | | | | |
|---|---|---|---|---|
| No. | Raw material 1 | Raw material 2 | Intermediate X-1 | Intermediate X-2 |
| B-2 | 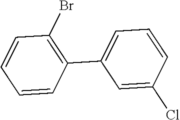 [SMILES: Clc1cccc(-c2ccccc2Br)c1] | 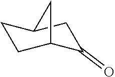 | 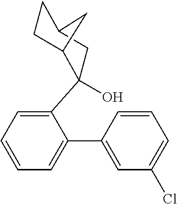 [SMILES: OC1(c2ccccc2-c2cccc(Cl)c2)CC2CCC1C2] | 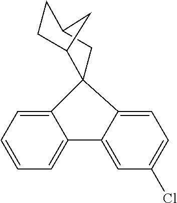 [SMILES: Clc1ccc2c(c1)-c1ccccc1C21CC2CCC1C2] |
| C-2 | 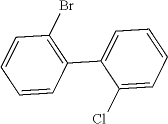 [SMILES: Clc1ccccc1-c1ccccc1Br] | 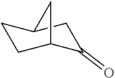 | 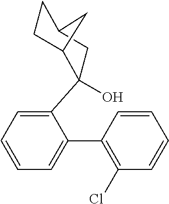 [SMILES: OC1(c2ccccc2-c2ccccc2Cl)CC2CCC1C2] | 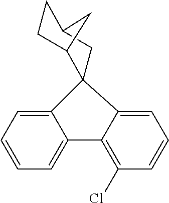 [SMILES: Clc1cccc2c1-c1ccccc1C21CC2CCC1C2] |
| D-2 | 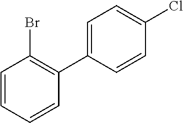 [SMILES: Clc1ccc(-c2ccccc2Br)cc1] | 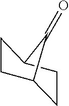 | 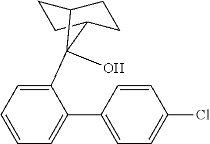 [SMILES: OC1(c2ccccc2-c2ccc(Cl)cc2)C2CCC1CC2] | 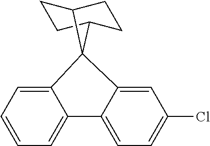 [SMILES: Clc1ccc2c(c1)C1(c3ccccc3-2)C2CCC1CC2] |
| E-2 | 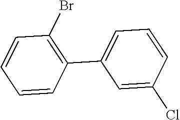 [SMILES: Clc1cccc(-c2ccccc2Br)c1] | 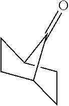 | 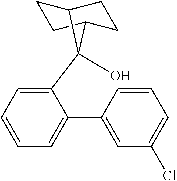 [SMILES: OC1(c2ccccc2-c2cccc(Cl)c2)C2CCC1CC2] | 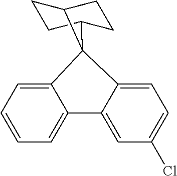 [SMILES: Clc1ccc2c(c1)-c1ccccc1C21C2CCC1CC2] |
| F-2 | 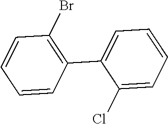 [SMILES: Clc1ccccc1-c1ccccc1Br] | 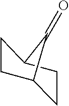 | 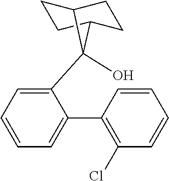 [SMILES: OC1(c2ccccc2-c2ccccc2Cl)C2CCC1CC2] | 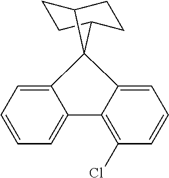 [SMILES: Clc1cccc2c1-c1ccccc1C21C2CCC1CC2] |
| G-2 | 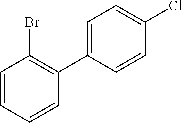 [SMILES: Clc1ccc(-c2ccccc2Br)cc1] | 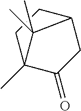 | 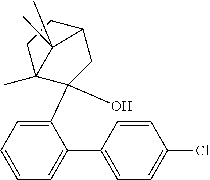 [SMILES: CC1(C)C2CCC1(C)C(O)(c1ccccc1-c1ccc(Cl)cc1)C2] | 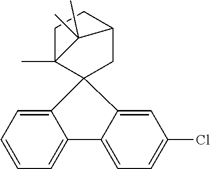 [SMILES: CC1(C)C2CCC1(C)C1(C2)c2ccccc2-c2ccc(Cl)cc21] |
| H-2 | 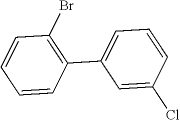 [SMILES: Clc1cccc(-c2ccccc2Br)c1] | 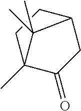 | 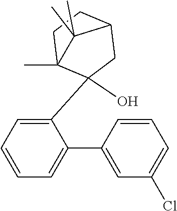 [SMILES: CC1(C)C2CCC1(C)C(O)(c1ccccc1-c1cccc(Cl)c1)C2] | 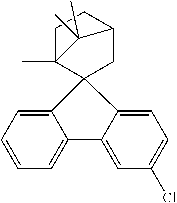 [SMILES: CC1(C)C2CCC1(C)C1(C2)c2ccccc2-c2cc(Cl)ccc21] |
| I-2 | 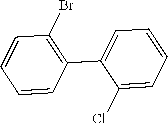 [SMILES: Clc1ccccc1-c1ccccc1Br] | 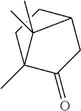 | 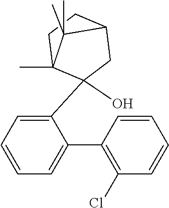 [SMILES: CC1(C)C2CCC1(C)C(O)(c1ccccc1-c1ccccc1Cl)C2] | 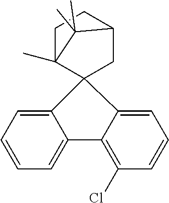 [SMILES: CC1(C)C2CCC1(C)C1(C2)c2ccccc2-c2c(Cl)cccc21] |

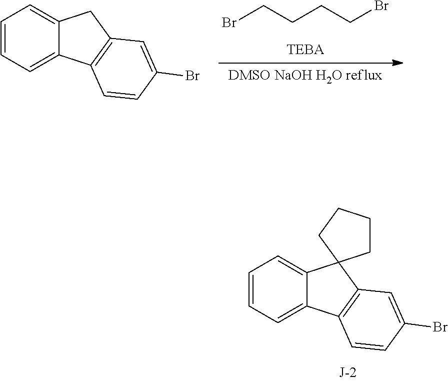 [SMILES: Brc1ccc2c(c1)Cc1ccccc1-2 ; BrCCCCBr ; Brc1ccc2c(c1)C1(CCCC1)c1ccccc1-2]

2-Bromo-9H-fluorene (50.0 g, 203.98 mmol), sodium hydroxide (35g, 446.76 mmol), dimethyl sulfoxide (500 mL), benzyltriethylammonium chloride (1.39 g, 6.12 mmol) and deionized water (100 mL) were added into a round bottom flask, the mixture was heated to 160° C. under the protection of nitrogen, and 1,4-dibromobutane (44 g, 203.98 mmol) was added while stirring; stirring was continued to be performed for 3 h, the resulting reaction solution was cooled to room temperature, toluene (200 mL) was added for extraction, organic phases were combined, dried over anhydrous magnesium sulfate, and filtered, and a solvent was removed under reduced pressure; and the obtained crude product was purified by silica gel column chromatography using toluene as a mobile phase to obtain an intermediate J-2 (57.0 g, yield: 93.4%) as a light yellow solid.

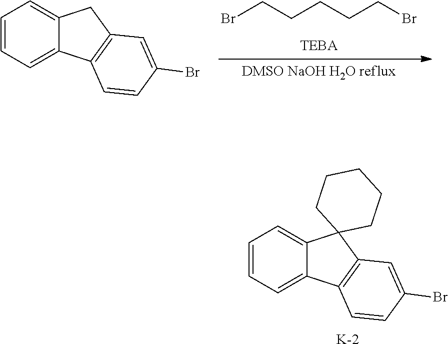

An intermediate K-2 was prepared according to the same synthesis method as that of the intermediate J-2 except that 1,5-dibromopentane was used instead of 1,4-dibromobutane.

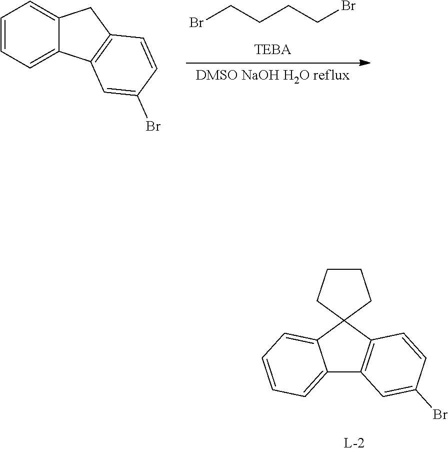 [SMILES: Brc1ccc2c(c1)-c1ccccc1C2 ; BrCCCCBr ; Brc1ccc2c(c1)-c1ccccc1C21CCCC1]

An intermediate L-2 was prepared by using the same synthesis method as that of the intermediate J-2 except that 3-bromo-9H-fluorene was used instead of 2-bromo-9H-fluorene.

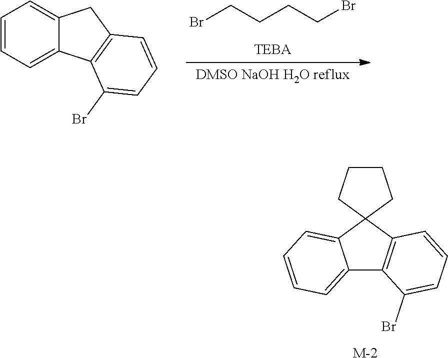

An intermediate M-2 was prepared by using the same synthesis method as that of the intermediate J-2 except that 4-bromo-9H-fluorene was used instead of 2-bromo-9H-fluorene.

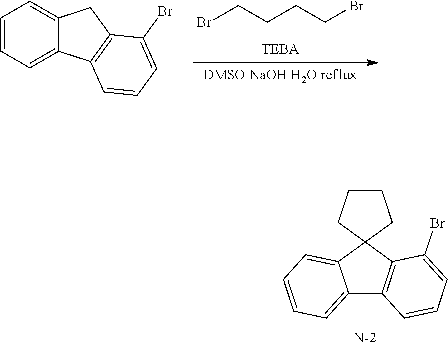

An intermediate N-2 was prepared by using the same synthesis method as that of the

intermediate J-2 except that 1-bromo-9H-fluorene was used instead of 2-bromo-9H-fluorene.

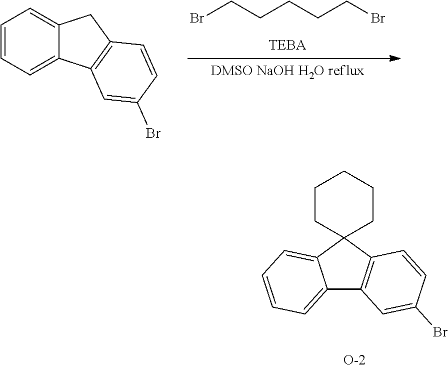

An intermediate O-2 was prepared according to the same synthesis method as that of the intermediate J-2 except that 3-bromo-9H-fluorene was used instead of 2-bromo-9H-fluorene and 1,5-dibromopentane was used instead of 1,4-dibromobutane.

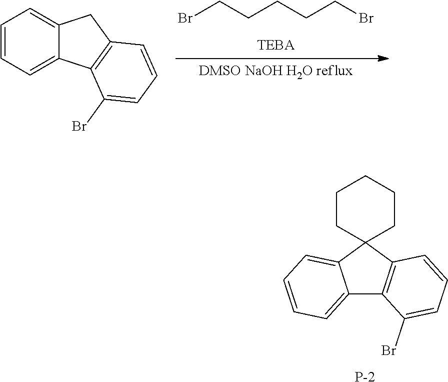

An intermediate P-2 was prepared according to the same synthesis method as that of the intermediate J-2 except that 4-bromo-9H-fluorene was used instead of 2-bromo-9H-fluorene and 1,5-dibromopentane was used instead of 1,4-dibromobutane.

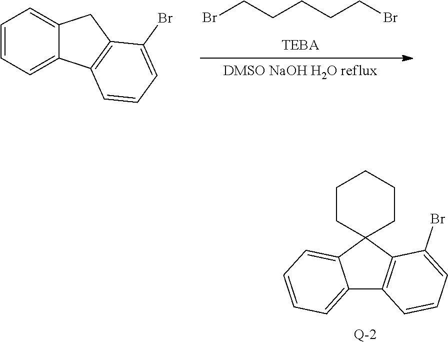

An intermediate Q-2 was prepared according to the same synthesis method as that of the intermediate J-2 except that 1-bromo-9H-fluorene was used instead of 2-bromo-9H-fluorene and 1,5-dibromopentane was used instead of 1,4-dibromobutane.

### 2. Synthesis of Intermediates SMN-Y (Y is a Variable, Specifically Shown Below)

The synthesis of the following intermediates SMN-Y was illustrated by taking an intermediate SMN-1 as an example.

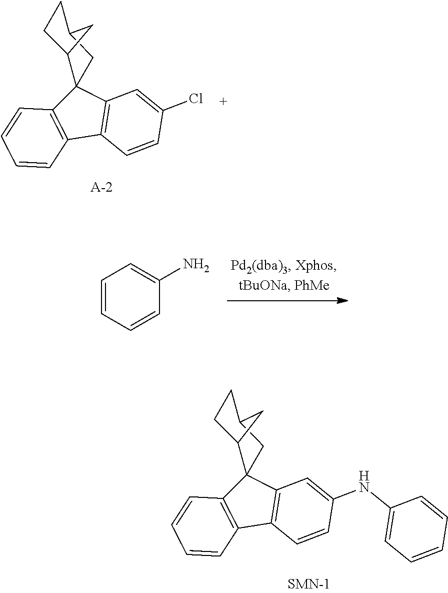

The intermediate A-2 (5 g, 17.8 mmol), aniline (1.82 g, 19.59 mmol), tris(dibenzylideneacetone)dipalladium (0.18 g, 0.16 mmol), 2-dicyclohexylphosphino-2′,4′,6′-triisopropylbiphenyl (0.35 g, 0.17 mmol) and sodium tert-butoxide (2.57 g, 26.71 mmol) were added to toluene (40 mL), the mixture was heated to 108° C. under nitrogen protection, and stirred for 3 h, then the mixture was cooled to room temperature, the resulting reaction solution was washed with water, dried over magnesium sulfate, and filtered, a solvent was removed from the obtained filtrate under reduced pressure, and a crude product was purified by recrystallization using a toluene system to obtain the intermediate SMN-1 (4.35 g, yield: 72.5%).

Referring to the synthesis method of the intermediate SMN-1, intermediates SMN-Y (Y=2 to 25) were prepared by the same synthesis method as that of the intermediate SMN-1 by using an intermediate X-2 (X=B to Q) shown in Table 2 below instead of the intermediate A-2 and a raw material 3 instead of aniline.

TABLE 2

| Intermediate | | | |
|---|---|---|---|
| No. | Intermediate X-2 | Raw material 3 | Intermediate SMN-Y |
| SMN-2 | 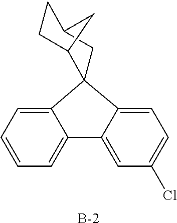 | 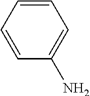 | 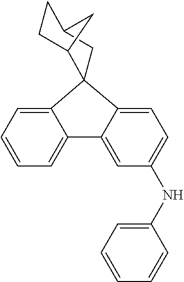 [SMILES: c1ccc(Nc2ccc3c(c2)-c2ccccc2C32CC3CCC2C3)cc1] |
| SMN-3 | 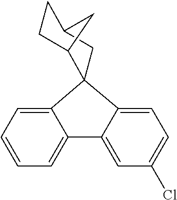 [SMILES: Clc1ccc2c(c1)-c1ccccc1C21CC2CCC1C2] | 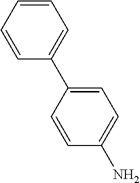 [SMILES: Nc1ccc(-c2ccccc2)cc1] | 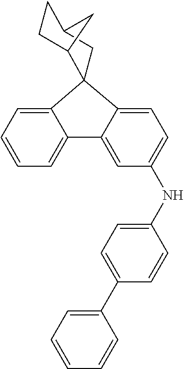 [SMILES: c1ccc(-c2ccc(Nc3ccc4c(c3)-c3ccccc3C43CC4CCC3C4)cc2)cc1] |
| SMN-4 | 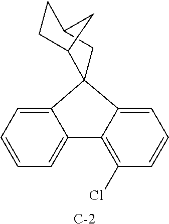 | 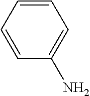 | 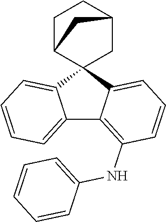 [SMILES: c1ccc(Nc2cccc3c2-c2ccccc2[C@]32C[C@H]3CC[C@@H]2C3)cc1] |
| SMN-5 | 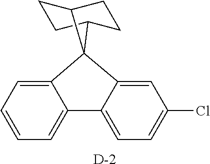 | 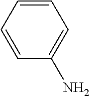 | 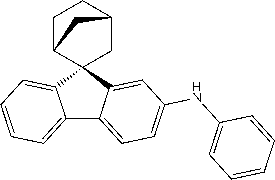 [SMILES: c1ccc(Nc2ccc3c(c2)[C@@]2(C[C@H]4CC[C@@H]2C4)c2ccccc2-3)cc1] |
| SMN-6 | 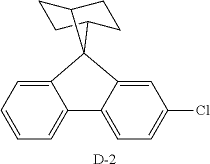 | 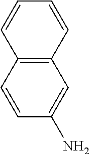 [SMILES: Nc1ccc2ccccc2c1] | 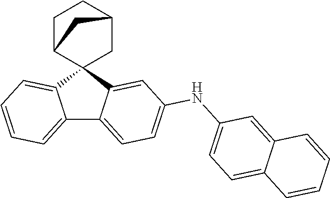 [SMILES: c1ccc2c(c1)-c1ccc(Nc3ccc4ccccc4c3)cc1[C@@]21C[C@H]2CC[C@@H]1C2] |
| SMN-7 | 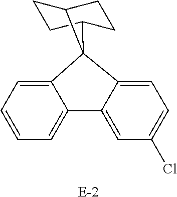 [SMILES: Clc1ccc2c(c1)-c1ccccc1C21C2CCC1CC2 ; "E-2"] | 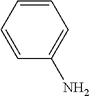 | 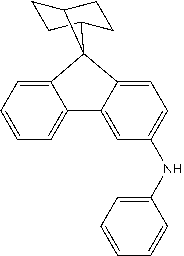 [SMILES: c1ccc(Nc2ccc3c(c2)-c2ccccc2C32C3CCC2CC3)cc1] |
| SMN-8 | 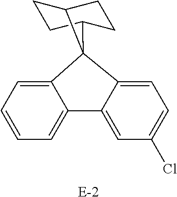 [SMILES: Clc1ccc2c(c1)-c1ccccc1C21C2CCC1CC2 ; "E-2"] | 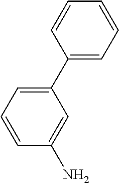 [SMILES: Nc1cccc(-c2ccccc2)c1] | 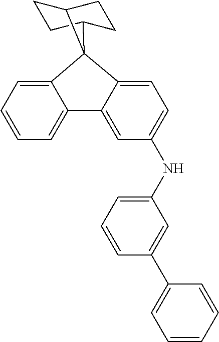 [SMILES: c1ccc(-c2cccc(Nc3ccc4c(c3)-c3ccccc3C43C4CCC3CC4)c2)cc1] |
| SMN-9 | 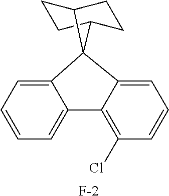 | 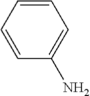 | 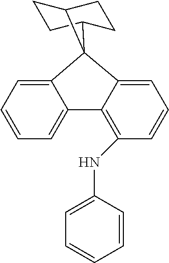 [SMILES: c1ccc(Nc2cccc3c2-c2ccccc2C32C3CCC2CC3)cc1] |
| SMN-10 | 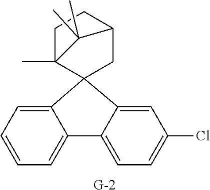 | 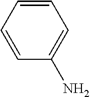 | 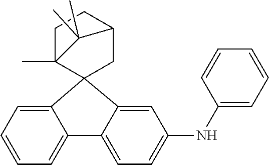 [SMILES: CC1(C)C2CCC1(C)C1(C2)c2ccccc2-c2ccc(Nc3ccccc3)cc21] |
| SMN-11 | 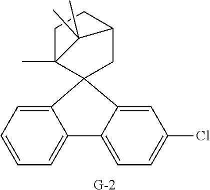 | 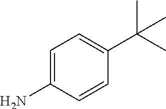 | 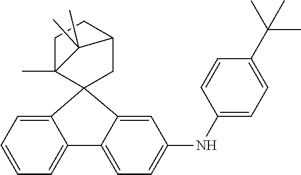 [SMILES: CC(C)(C)c1ccc(Nc2ccc3c(c2)C2(CC4CCC2(C)C4(C)C)c2ccccc2-3)cc1] |
| SMN-12 | 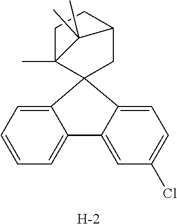 | 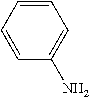 | 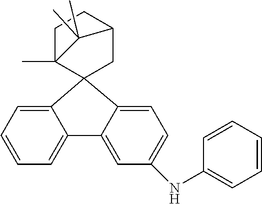 [SMILES: CC1(C)C2CCC1(C)C1(C2)c2ccccc2-c2cc(Nc3ccccc3)ccc21] |
| SMN-13 | 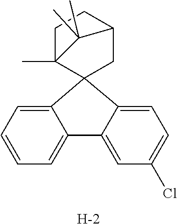 | 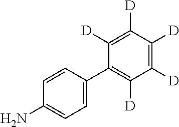 [SMILES: [2H]c1c([2H])c([2H])c(-c2ccc(N)cc2)c([2H])c1[2H]] | 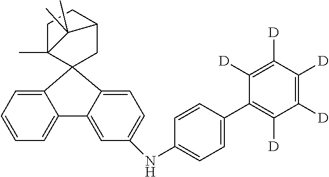 [SMILES: [2H]c1c([2H])c([2H])c(-c2ccc(Nc3ccc4c(c3)-c3ccccc3C43CC4CCC3(C)C4(C)C)cc2)c([2H])c1[2H]] |
| SMN-14 | 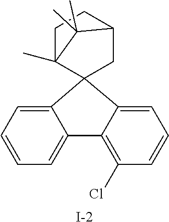 | 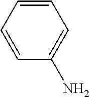 | 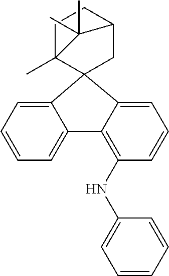 [SMILES: CC1(C)C2CCC1(C)C1(C2)c2ccccc2-c2c(Nc3ccccc3)cccc21] |
| SMN-15 | 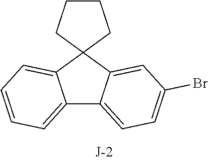 [SMILES: Brc1ccc2c(c1)C1(CCCC1)c1ccccc1-2] | 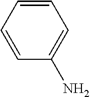 | 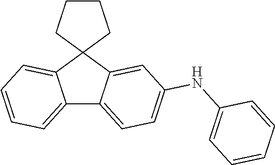 [SMILES: c1ccc(Nc2ccc3c(c2)C2(CCCC2)c2ccccc2-3)cc1] |
| SMN-16 | 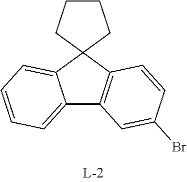 [SMILES: Brc1ccc2c(c1)-c1ccccc1C21CCCC1] | 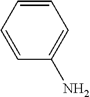 | 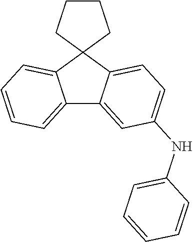 [SMILES: c1ccc(Nc2ccc3c(c2)-c2ccccc2C32CCCC2)cc1] |
| SMN-17 | 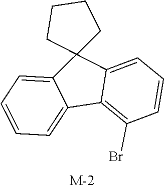 [SMILES: Brc1cccc2c1-c1ccccc1C21CCCC1 ; "M-2"] | 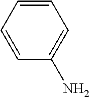 | 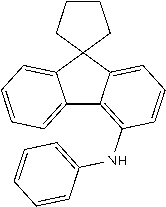 [SMILES: c1ccc(Nc2cccc3c2-c2ccccc2C32CCCC2)cc1] |
| SMN-18 | 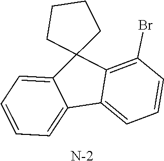 | 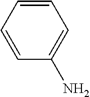 | 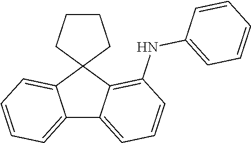 [SMILES: c1ccc(Nc2cccc3c2C2(CCCC2)c2ccccc2-3)cc1] |
| SMN-19 | 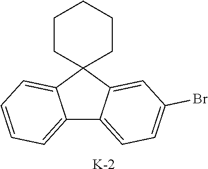 | 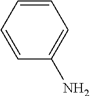 | 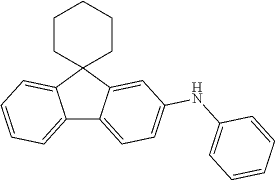 [SMILES: c1ccc(Nc2ccc3c(c2)C2(CCCCC2)c2ccccc2-3)cc1] |
| SMN-20 | 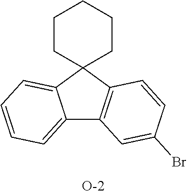 | 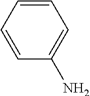 | 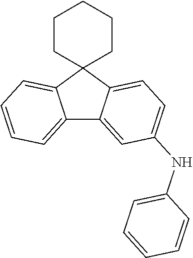 [SMILES: c1ccc(Nc2ccc3c(c2)-c2ccccc2C32CCCCC2)cc1] |
| SMN-21 | 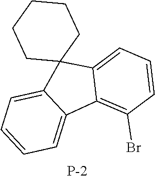 | 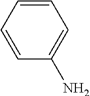 | 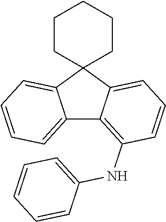 [SMILES: c1ccc(Nc2cccc3c2-c2ccccc2C32CCCCC2)cc1] |
| SMN-22 | 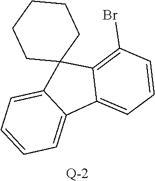 | 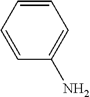 | 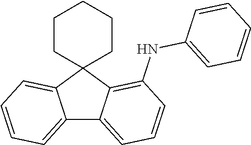 [SMILES: c1ccc(Nc2cccc3c2C2(CCCCC2)c2ccccc2-3)cc1] |
| SMN-23 | 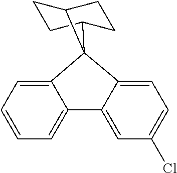 [SMILES: Clc1ccc2c(c1)-c1ccccc1C21C2CCC1CC2] | 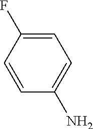 | 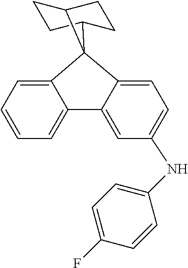 [SMILES: Fc1ccc(Nc2ccc3c(c2)-c2ccccc2C32C3CCC2CC3)cc1] |
| SMN-24 | 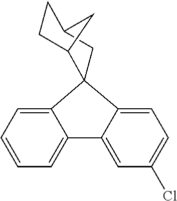 [SMILES: Clc1ccc2c(c1)-c1ccccc1C21CC2CCC1C2] | 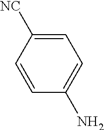 | 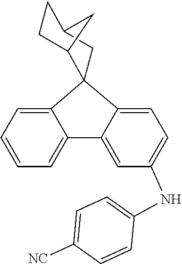 [SMILES: N#Cc1ccc(Nc2ccc3c(c2)-c2ccccc2C32CC3CCC2C3)cc1] |
| SMN-25 | 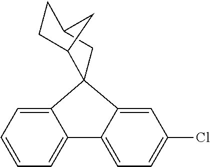 [SMILES: Clc1ccc2c(c1)C1(CC3CCC1C3)c1ccccc1-2] | 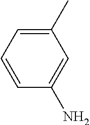 | 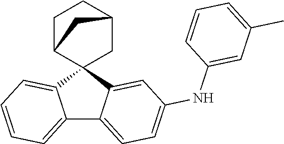 [SMILES: Cc1cccc(Nc2ccc3c(c2)[C@@]2(C[C@H]4CC[C@@H]2C4)c2ccccc2-3)c1] |

### 3. Synthesis of Intermediates SMII-Y (Y is a Variable, Specifically Shown Below)

The synthesis of the following intermediates SMH-Y was illustrated by taking an intermediate SMH-1 as an example.

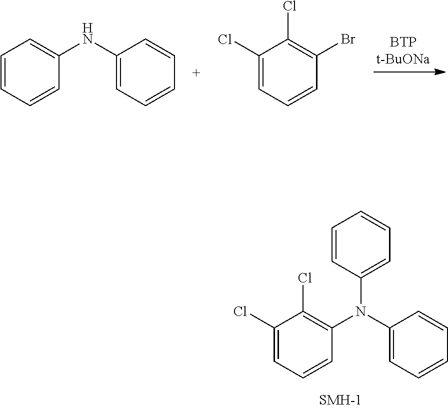 [SMILES: c1ccc(Nc2ccccc2)cc1 ; Clc1cccc(Br)c1Cl ; Clc1cccc(N(c2ccccc2)c2ccccc2)c1Cl]

Diphenylamine (5 g, 16.9 mmol) was added into a round bottom flask filled with xylene (50 mL), then sodium tert-butoxide (2.3 g, 23.8 mmol) was added, the system temperature was raised to 180° C., then 2,3-dichlorobromobenzene (17.4 g, 16.9 mmol) and tetra-n-butyl titanate (BTP, 0.13 g, 0.238 mmol) were added, after stirring the mixture for 12 h, the system was cooled to room temperature, the reaction was quenched with an aqueous ammonium chloride solution, an organic phase was extracted with ethyl acetate, dried over anhydrous magnesium sulfate, and filtered, and a solvent was removed under reduced pressure; and the obtained crude product was purified by silica gel column chromatography using dichloromethane/n-heptane (a volume ratio of 1:2) to obtain the intermediate SMH-1 (3.18 g, yield: 57%).

The following intermediates SMH-Y were prepared by using the same synthesis method as that for the synthesis of SMH-1 except that a raw material 4 in Table 3 was used instead of diphenylamine to synthesize the intermediates SMH-Y.

TABLE 3

| Intermediate | | |
|---|---|---|
| No. | Raw material 4 | Intermediate SMH-Y |
| SMH-2 | 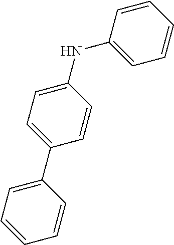 [SMILES: c1ccc(Nc2ccc(-c3ccccc3)cc2)cc1] | 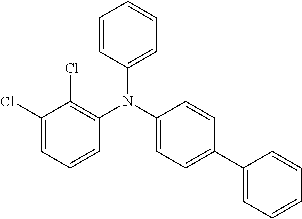 [SMILES: Clc1cccc(N(c2ccccc2)c2ccc(-c3ccccc3)cc2)c1Cl] |
| SMH-3 | 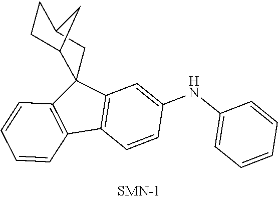 [SMILES: c1ccc(Nc2ccc3c(c2)C2(CC4CCC2C4)c2ccccc2-3)cc1] | 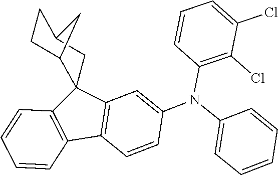 [SMILES: Clc1cccc(N(c2ccccc2)c2ccc3c(c2)C2(CC4CCC2C4)c2ccccc2-3)c1Cl] |
| SMH-4 | 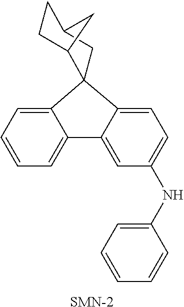 | 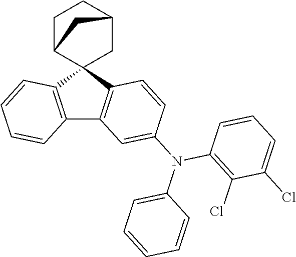 [SMILES: Clc1cccc(N(c2ccccc2)c2ccc3c(c2)-c2ccccc2[C@]32C[C@H]3CC[C@@H]2C3)c1Cl] |
| SMH-5 | 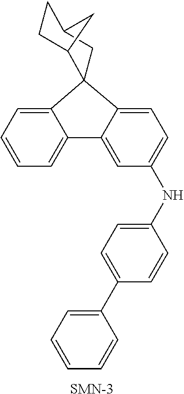 | 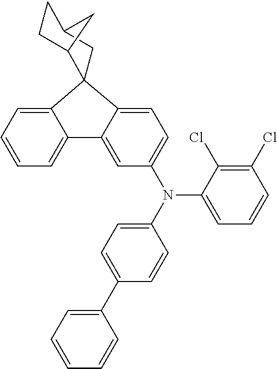 [SMILES: Clc1cccc(N(c2ccc(-c3ccccc3)cc2)c2ccc3c(c2)-c2ccccc2C32CC3CCC2C3)c1Cl] |
| SMH-6 | 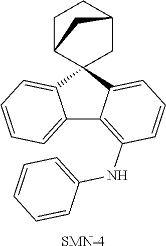 | 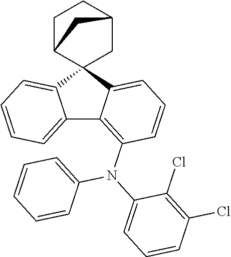 [SMILES: Clc1cccc(N(c2ccccc2)c2cccc3c2-c2ccccc2[C@]32C[C@H]3CC[C@@H]2C3)c1Cl] |
| SMH-7 | 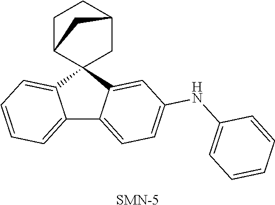 | 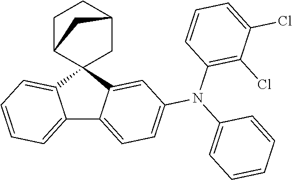 [SMILES: Clc1cccc(N(c2ccccc2)c2ccc3c(c2)[C@@]2(C[C@H]4CC[C@@H]2C4)c2ccccc2-3)c1Cl] |
| SMH-8 | 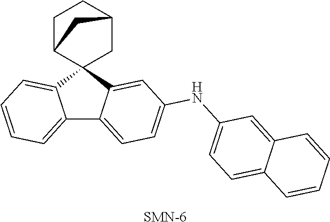 | 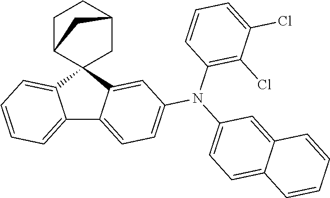 [SMILES: Clc1cccc(N(c2ccc3c(c2)[C@@]2(C[C@H]4CC[C@@H]2C4)c2ccccc2-3)c2ccc3ccccc3c2)c1Cl] |
| SMH-9 | 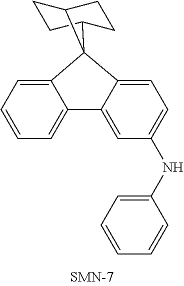 [SMILES: c1ccc(Nc2ccc3c(c2)-c2ccccc2C32C3CCC2CC3)cc1] | 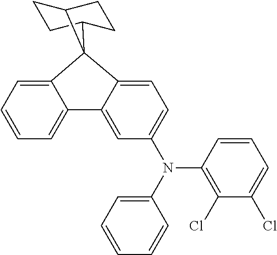 [SMILES: Clc1cccc(N(c2ccccc2)c2ccc3c(c2)-c2ccccc2C32C3CCC2CC3)c1Cl] |
| SMH-10 | 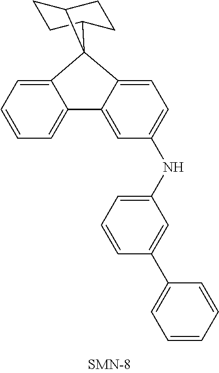 [SMILES: c1ccc(-c2cccc(Nc3ccc4c(c3)-c3ccccc3C43C4CCC3CC4)c2)cc1] | 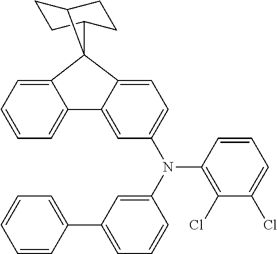 [SMILES: Clc1cccc(N(c2cccc(-c3ccccc3)c2)c2ccc3c(c2)-c2ccccc2C32C3CCC2CC3)c1Cl] |
| SMH-11 | 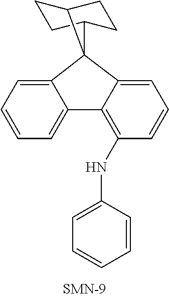 [SMILES: c1ccc(Nc2cccc3c2-c2ccccc2C32C3CCC2CC3)cc1] | 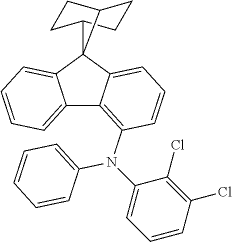 [SMILES: Clc1cccc(N(c2ccccc2)c2cccc3c2-c2ccccc2C32C3CCC2CC3)c1Cl] |
| SMH-12 | 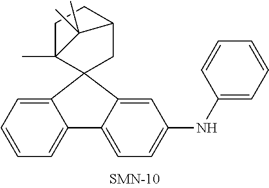 [SMILES: CC1(C)C2CCC1(C)C1(C2)c2ccccc2-c2ccc(Nc3ccccc3)cc21] | 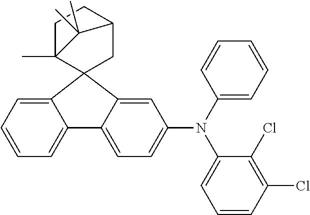 [SMILES: CC1(C)C2CCC1(C)C1(C2)c2ccccc2-c2ccc(N(c3ccccc3)c3cccc(Cl)c3Cl)cc21] |
| SMH-13 | 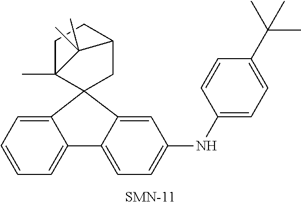 [SMILES: CC(C)(C)c1ccc(Nc2ccc3c(c2)C2(CC4CCC2(C)C4(C)C)c2ccccc2-3)cc1] | 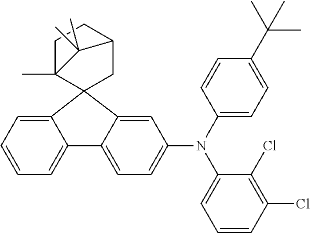 [SMILES: CC(C)(C)c1ccc(N(c2ccc3c(c2)C2(CC4CCC2(C)C4(C)C)c2ccccc2-3)c2cccc(Cl)c2Cl)cc1] |
| SMH-14 | 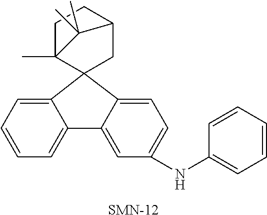 | 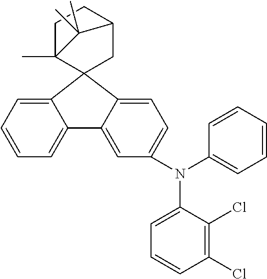 [SMILES: CC1(C)C2CCC1(C)C1(C2)c2ccccc2-c2cc(N(c3ccccc3)c3cccc(Cl)c3Cl)ccc21] |
| SMH-15 | 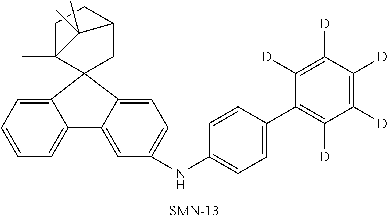 | 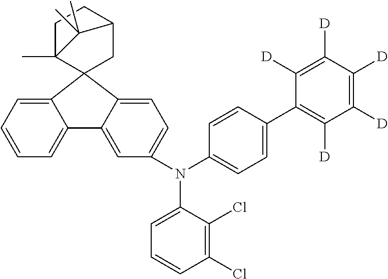 [SMILES: [2H]c1c([2H])c([2H])c(-c2ccc(N(c3ccc4c(c3)-c3ccccc3C43CC4CCC3(C)C4(C)C)c3cccc(Cl)c3Cl)cc2)c([2H])c1[2H]] |
| SMH-16 | 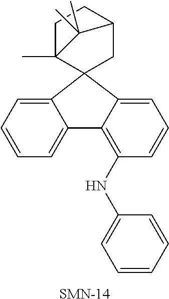 | 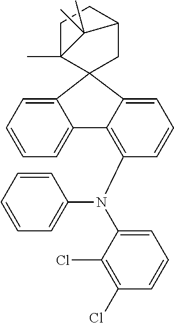 [SMILES: CC1(C)C2CCC1(C)C1(C2)c2ccccc2-c2c(N(c3ccccc3)c3cccc(Cl)c3Cl)cccc21] |
| SMH-17 | 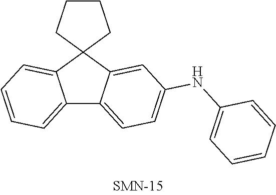 [SMILES: c1ccc(Nc2ccc3c(c2)C2(CCCC2)c2ccccc2-3)cc1] | 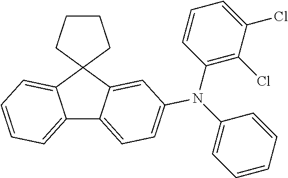 [SMILES: Clc1cccc(N(c2ccccc2)c2ccc3c(c2)C2(CCCC2)c2ccccc2-3)c1Cl] |
| SMH-18 | 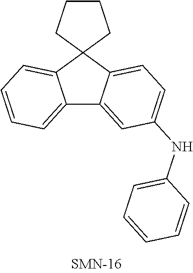 [SMILES: c1ccc(Nc2ccc3c(c2)-c2ccccc2C32CCCC2)cc1] | 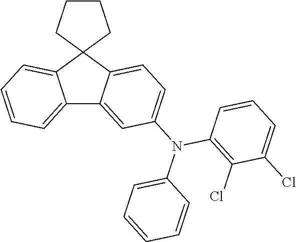 [SMILES: Clc1cccc(N(c2ccccc2)c2ccc3c(c2)-c2ccccc2C32CCCC2)c1Cl] |
| SMH-19 | 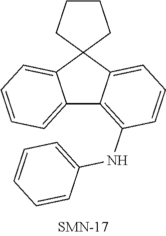 [SMILES: c1ccc(Nc2cccc3c2-c2ccccc2C32CCCC2)cc1] | 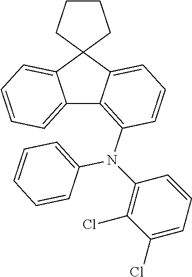 [SMILES: Clc1cccc(N(c2ccccc2)c2cccc3c2-c2ccccc2C32CCCC2)c1Cl] |
| SMH-20 | 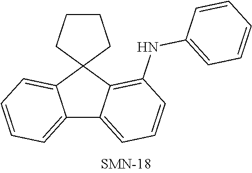 [SMILES: c1ccc(Nc2cccc3c2C2(CCCC2)c2ccccc2-3)cc1] | 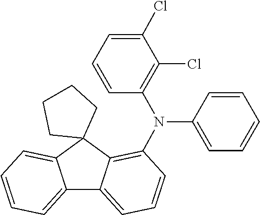 [SMILES: Clc1cccc(N(c2ccccc2)c2cccc3c2C2(CCCC2)c2ccccc2-3)c1Cl] |
| SMH-21 | 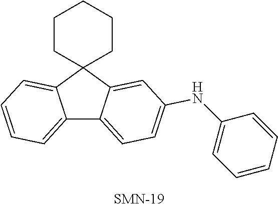 [SMILES: c1ccc(Nc2ccc3c(c2)C2(CCCCC2)c2ccccc2-3)cc1] | 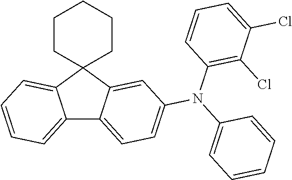 [SMILES: Clc1cccc(N(c2ccccc2)c2ccc3c(c2)C2(CCCCC2)c2ccccc2-3)c1Cl] |
| SMH-22 | 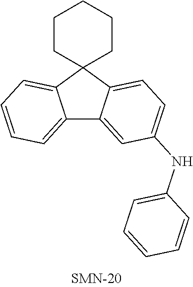 [SMILES: c1ccc(Nc2ccc3c(c2)-c2ccccc2C32CCCCC2)cc1] | 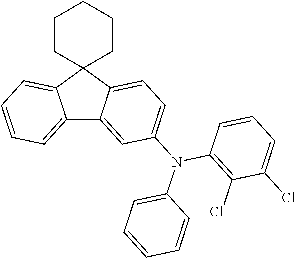 [SMILES: Clc1cccc(N(c2ccccc2)c2ccc3c(c2)-c2ccccc2C32CCCCC2)c1Cl] |
| SMH-23 | 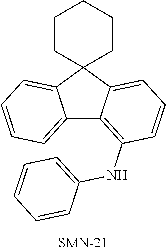 [SMILES: c1ccc(Nc2cccc3c2-c2ccccc2C32CCCCC2)cc1] | 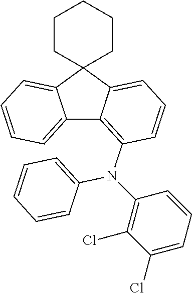 [SMILES: Clc1cccc(N(c2ccccc2)c2cccc3c2-c2ccccc2C32CCCCC2)c1Cl] |
| SMH-24 | 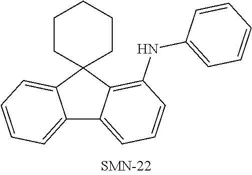 [SMILES: c1ccc(Nc2cccc3c2C2(CCCCC2)c2ccccc2-3)cc1] | 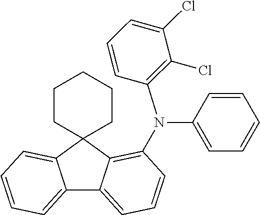 [SMILES: Clc1cccc(N(c2ccccc2)c2cccc3c2C2(CCCCC2)c2ccccc2-3)c1Cl] |

### 4. Synthesis of Intermediates SM-S (S is a Variable, Specifically Shown Below)

The synthesis of the following intermediates SM-S was illustrated by taking an intermediate SM-1 as an example.

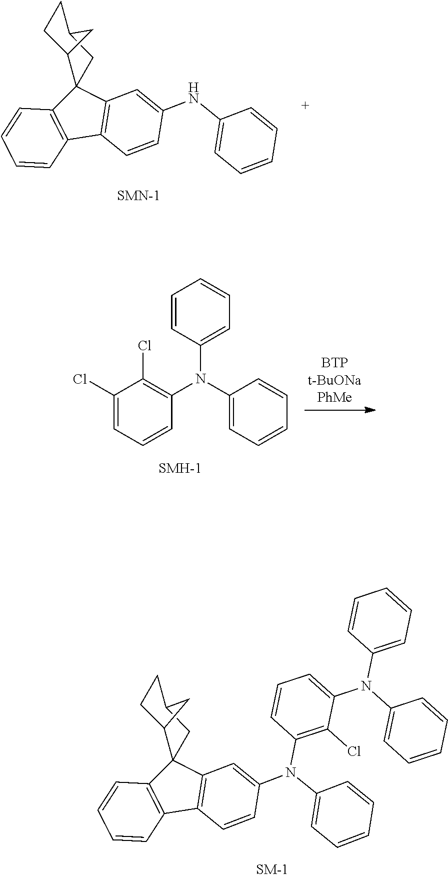 [SMILES: c1ccc(Nc2ccc3c(c2)C2(CC4CCC2C4)c2ccccc2-3)cc1 ; Clc1cccc(N(c2ccccc2)c2ccccc2)c1Cl ; Clc1c(N(c2ccccc2)c2ccccc2)cccc1N(c1ccccc1)c1ccc2c(c1)C1(CC3CCC1C3)c1ccccc1-2]

The intermediate SMN-1 (3.25 g, 9.63 mmol) was dissolved in 50 mL of toluene into a round bottom flask under nitrogen protection, sodium tert-butoxide (1.39, 14.45 mmol) was added, stirring was started, the system temperature was raised to 110° C., then the intermediate SMH-1 (3.18 g, 10.11 mmol) and tetra-n-butyl titanate BTP (0.16 g, 0.48 mmol) were added sequentially, and after stirring the mixture for 12 hours, the system was cooled to room temperature. The reaction was quenched by the addition of an aqueous ammonium chloride solution, an organic phase was extracted with ethyl acetate, dried over anhydrous magnesium sulfate, and filtered, and a solvent was removed under reduced pressure. Silica gel column chromatography was performed by using dichloromethane/n-heptane (a volume ratio of 1:2) to obtain the intermediate SM-1 (3.56 g, yield: 60.1%) as a white solid.

Referring to the synthesis method of the intermediate SM-1, intermediates SM-S (S=2 to 22) were prepared by the same synthesis method as that of the intermediate SM-1 by using intermediates SMN-Y (Y=2, 4 to 8, 11 to 13, 15, 16, 18 to 20, and 23 to 25) shown in Table 4 below instead of the intermediate SMN-1 and intermediates SMH-Y (Y=1 to 4, 18, 21, and 22) shown in Table 4 below instead of the intermediate SMH-1.

TABLE 4

| Intermediate | | | |
|---|---|---|---|
| No. | Intermediate SMN-Y | Intermediate SMH-Y | Intermediate SM-S |
| SM-2 | 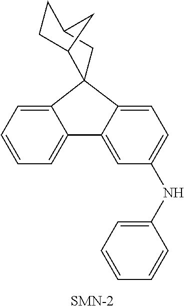 | 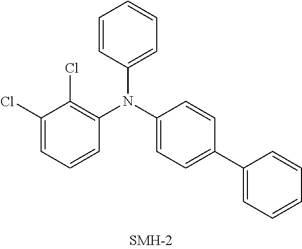 [SMILES: Clc1cccc(N(c2ccccc2)c2ccc(-c3ccccc3)cc2)c1Cl] | 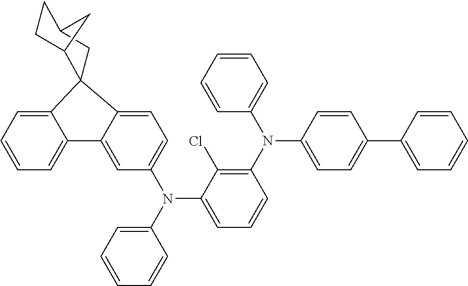 [SMILES: Clc1c(N(c2ccccc2)c2ccc(-c3ccccc3)cc2)cccc1N(c1ccccc1)c1ccc2c(c1)-c1ccccc1C21CC2CCC1C2] |
| SM-3 | 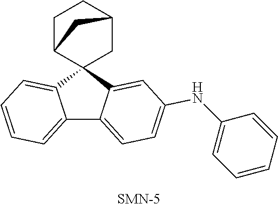 [SMILES: c1ccc(Nc2ccc3c(c2)[C@@]2(C[C@H]4CC[C@@H]2C4)c2ccccc2-3)cc1] | 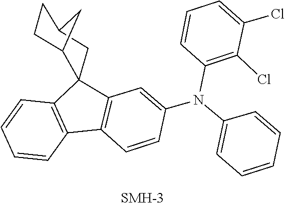 [SMILES: Clc1cccc(N(c2ccccc2)c2ccc3c(c2)C2(CC4CCC2C4)c2ccccc2-3)c1Cl] | 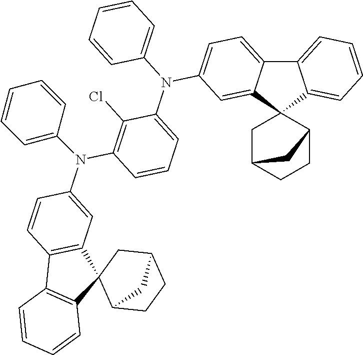 [SMILES: Clc1c(N(c2ccccc2)c2ccc3c(c2)[C@@]2(C[C@H]4CC[C@@H]2C4)c2ccccc2-3)cccc1N(c1ccccc1)c1ccc2c(c1)[C@@]1(C[C@H]3CC[C@@H]1C3)c1ccccc1-2] |
| SM-4 | 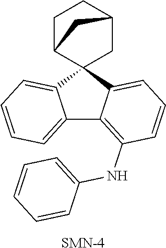 | 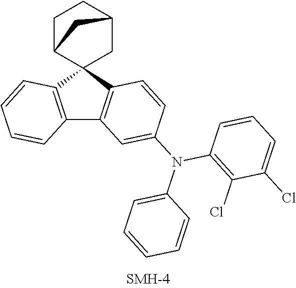 [SMILES: Clc1cccc(N(c2ccccc2)c2ccc3c(c2)-c2ccccc2[C@]32C[C@H]3CC[C@@H]2C3)c1Cl] | 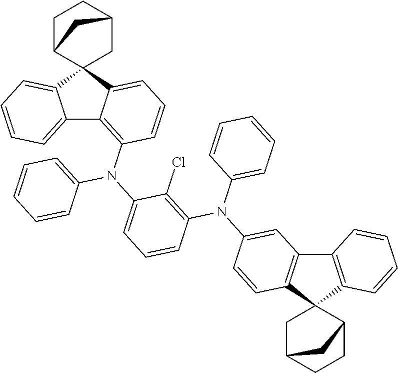 [SMILES: Clc1c(N(c2ccccc2)c2ccc3c(c2)-c2ccccc2[C@]32C[C@H]3CC[C@@H]2C3)cccc1N(c1ccccc1)c1cccc2c1-c1ccccc1[C@]21C[C@H]2CC[C@@H]1C2] |
| SM-5 | 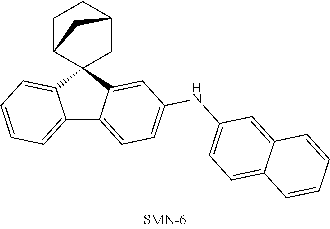 [SMILES: c1ccc2c(c1)-c1ccc(Nc3ccc4ccccc4c3)cc1[C@@]21C[C@H]2CC[C@@H]1C2] | 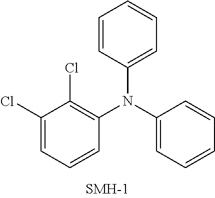 [SMILES: Clc1cccc(N(c2ccccc2)c2ccccc2)c1Cl] | 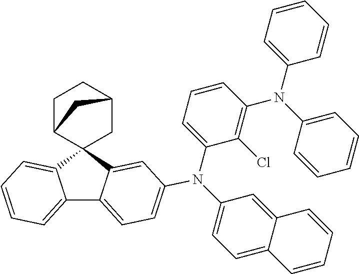 [SMILES: Clc1c(N(c2ccccc2)c2ccccc2)cccc1N(c1ccc2c(c1)[C@@]1(C[C@H]3CC[C@@H]1C3)c1ccccc1-2)c1ccc2ccccc2c1] |
| SM-7 | 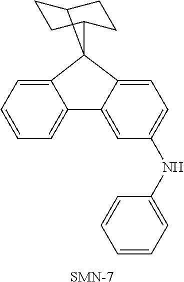 | 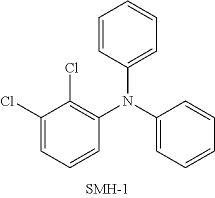 [SMILES: Clc1cccc(N(c2ccccc2)c2ccccc2)c1Cl] | 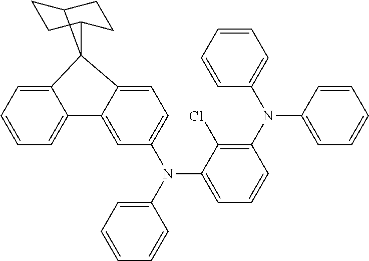 [SMILES: Clc1c(N(c2ccccc2)c2ccccc2)cccc1N(c1ccccc1)c1ccc2c(c1)-c1ccccc1C21C2CCC1CC2] |
| SM-8 | 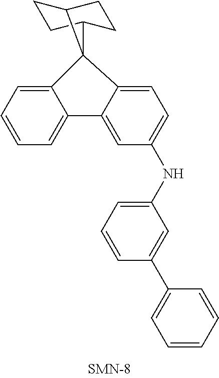 [SMILES: c1ccc(-c2cccc(Nc3ccc4c(c3)-c3ccccc3C43C4CCC3CC4)c2)cc1] | 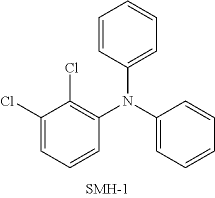 [SMILES: Clc1cccc(N(c2ccccc2)c2ccccc2)c1Cl] | 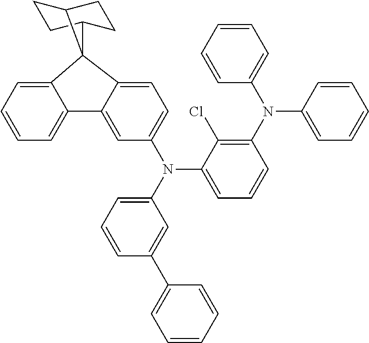 [SMILES: Clc1c(N(c2ccccc2)c2ccccc2)cccc1N(c1cccc(-c2ccccc2)c1)c1ccc2c(c1)-c1ccccc1C21C2CCC1CC2] |
| SM-10 | 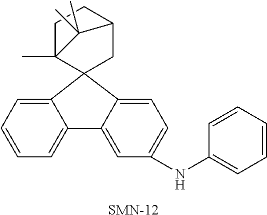 | 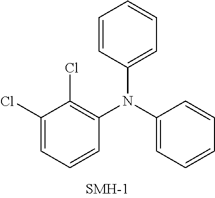 [SMILES: Clc1cccc(N(c2ccccc2)c2ccccc2)c1Cl] | 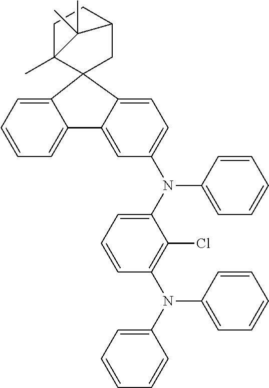 [SMILES: CC1(C)C2CCC1(C)C1(C2)c2ccccc2-c2cc(N(c3ccccc3)c3cccc(N(c4ccccc4)c4ccccc4)c3Cl)ccc21] |
| SM-13 | 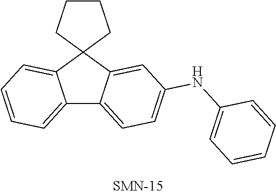 [SMILES: c1ccc(Nc2ccc3c(c2)C2(CCCC2)c2ccccc2-3)cc1] | 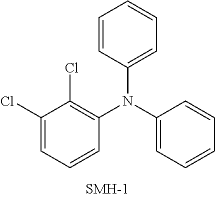 [SMILES: Clc1cccc(N(c2ccccc2)c2ccccc2)c1Cl] | 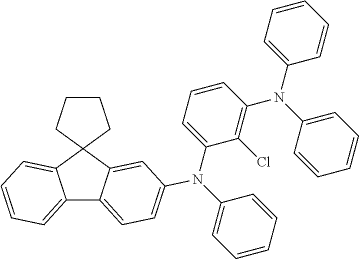 [SMILES: Clc1c(N(c2ccccc2)c2ccccc2)cccc1N(c1ccccc1)c1ccc2c(c1)C1(CCCC1)c1ccccc1-2] |
| SM-14 | 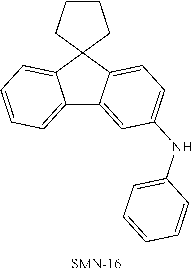 [SMILES: c1ccc(Nc2ccc3c(c2)-c2ccccc2C32CCCC2)cc1] | 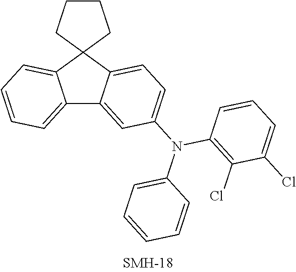 [SMILES: Clc1cccc(N(c2ccccc2)c2ccc3c(c2)-c2ccccc2C32CCCC2)c1Cl] | 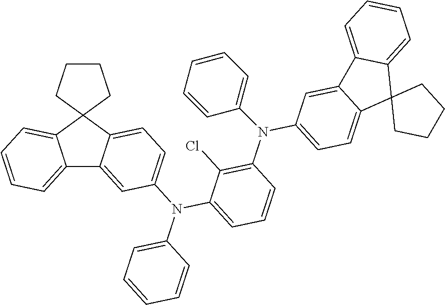 [SMILES: Clc1c(N(c2ccccc2)c2ccc3c(c2)-c2ccccc2C32CCCC2)cccc1N(c1ccccc1)c1ccc2c(c1)-c1ccccc1C21CCCC1] |
| SM-15 | 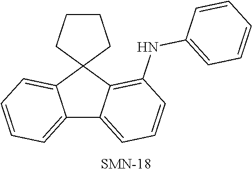 [SMILES: c1ccc(Nc2cccc3c2C2(CCCC2)c2ccccc2-3)cc1] | 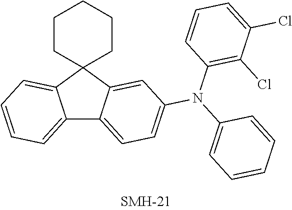 [SMILES: Clc1cccc(N(c2ccccc2)c2ccc3c(c2)C2(CCCCC2)c2ccccc2-3)c1Cl] | 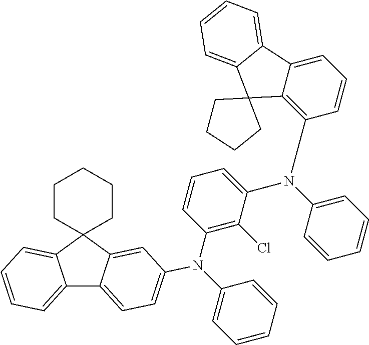 [SMILES: Clc1c(N(c2ccccc2)c2ccc3c(c2)C2(CCCCC2)c2ccccc2-3)cccc1N(c1ccccc1)c1cccc2c1C1(CCCC1)c1ccccc1-2] |
| SM-16 | 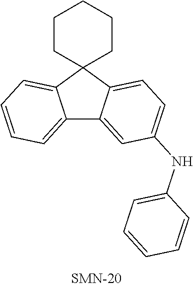 [SMILES: c1ccc(Nc2ccc3c(c2)-c2ccccc2C32CCCCC2)cc1] | 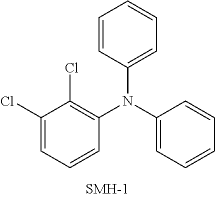 [SMILES: Clc1cccc(N(c2ccccc2)c2ccccc2)c1Cl] | 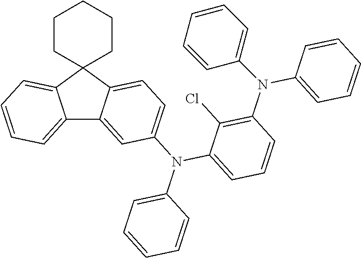 [SMILES: Clc1c(N(c2ccccc2)c2ccccc2)cccc1N(c1ccccc1)c1ccc2c(c1)-c1ccccc1C21CCCCC1] |
| SM-17 | 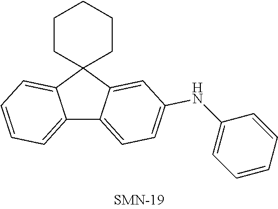 [SMILES: c1ccc(Nc2ccc3c(c2)C2(CCCCC2)c2ccccc2-3)cc1] | 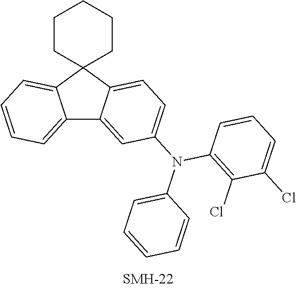 [SMILES: Clc1cccc(N(c2ccccc2)c2ccc3c(c2)-c2ccccc2C32CCCCC2)c1Cl] | 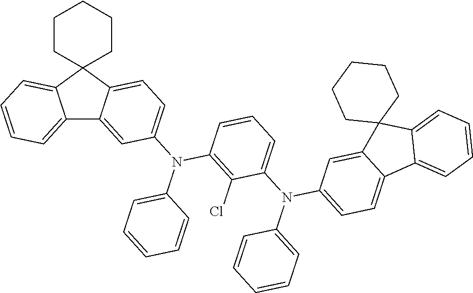 [SMILES: Clc1c(N(c2ccccc2)c2ccc3c(c2)-c2ccccc2C32CCCCC2)cccc1N(c1ccccc1)c1ccc2c(c1)C1(CCCCC1)c1ccccc1-2] |
| SM-18 | 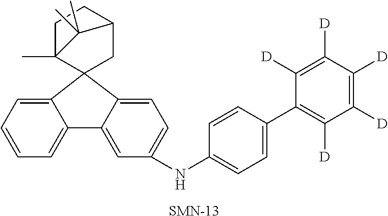 | 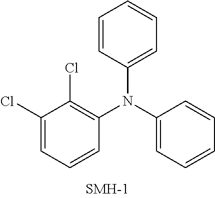 [SMILES: Clc1cccc(N(c2ccccc2)c2ccccc2)c1Cl] | 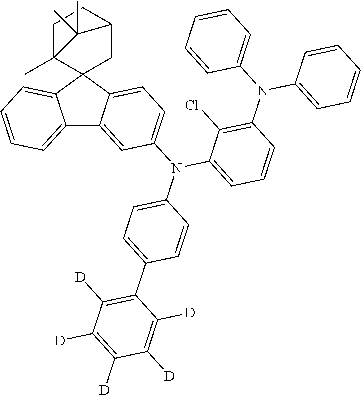 [SMILES: [2H]c1c([2H])c([2H])c(-c2ccc(N(c3ccc4c(c3)-c3ccccc3C43CC4CCC3(C)C4(C)C)c3cccc(N(c4ccccc4)c4ccccc4)c3Cl)cc2)c([2H])c1[2H]] |
| SM-19 | 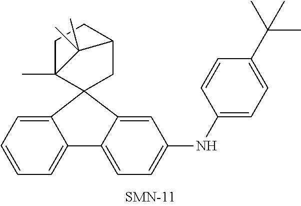 [SMILES: CC(C)(C)c1ccc(Nc2ccc3c(c2)C2(CC4CCC2(C)C4(C)C)c2ccccc2-3)cc1] | 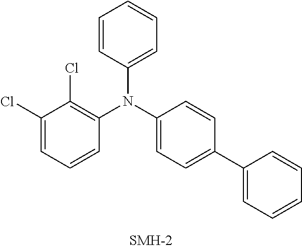 [SMILES: Clc1cccc(N(c2ccccc2)c2ccc(-c3ccccc3)cc2)c1Cl] | 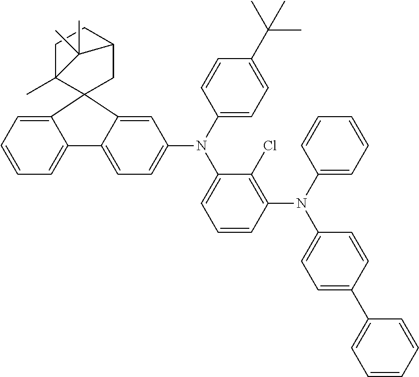 [SMILES: CC(C)(C)c1ccc(N(c2ccc3c(c2)C2(CC4CCC2(C)C4(C)C)c2ccccc2-3)c2cccc(N(c3ccccc3)c3ccc(-c4ccccc4)cc3)c2Cl)cc1] |
| SM-20 | 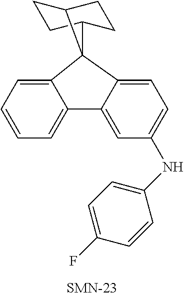 [SMILES: Fc1ccc(Nc2ccc3c(c2)-c2ccccc2C32C3CCC2CC3)cc1] | 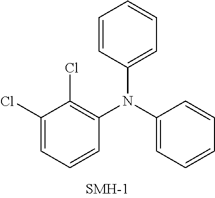 [SMILES: Clc1cccc(N(c2ccccc2)c2ccccc2)c1Cl] | 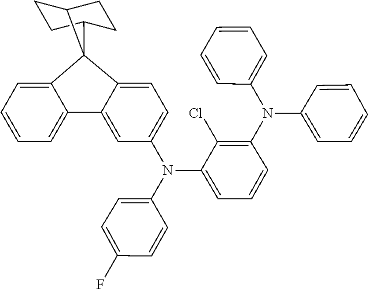 [SMILES: Fc1ccc(N(c2ccc3c(c2)-c2ccccc2C32C3CCC2CC3)c2cccc(N(c3ccccc3)c3ccccc3)c2Cl)cc1] |
| SM-21 | 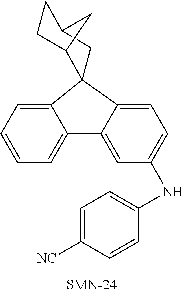 [SMILES: N#Cc1ccc(Nc2ccc3c(c2)-c2ccccc2C32CC3CCC2C3)cc1] | 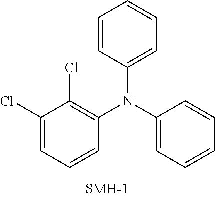 [SMILES: Clc1cccc(N(c2ccccc2)c2ccccc2)c1Cl] | 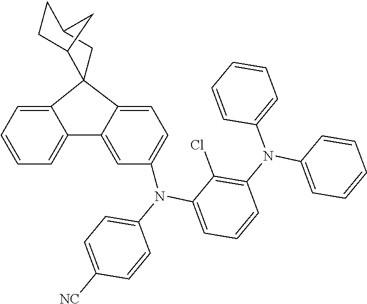 [SMILES: N#Cc1ccc(N(c2ccc3c(c2)-c2ccccc2C32CC3CCC2C3)c2cccc(N(c3ccccc3)c3ccccc3)c2Cl)cc1] |
| SM-22 | 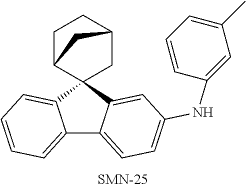 [SMILES: Cc1cccc(Nc2ccc3c(c2)[C@@]2(C[C@H]4CC[C@@H]2C4)c2ccccc2-3)c1] | 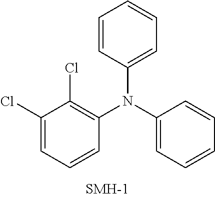 [SMILES: Clc1cccc(N(c2ccccc2)c2ccccc2)c1Cl] | 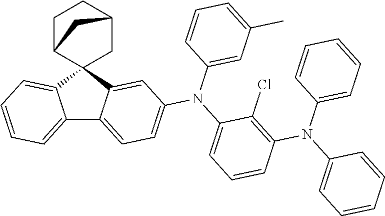 [SMILES: Cc1cccc(N(c2ccc3c(c2)[C@@]2(C[C@H]4CC[C@@H]2C4)c2ccccc2-3)c2cccc(N(c3ccccc3)c3ccccc3)c2Cl)c1] |

### 5. Preparation in Synthesis Examples

A preparation process of the following compounds was illustrated by taking Synthesis example 1-Compounds A-6 and A-10 as an example.

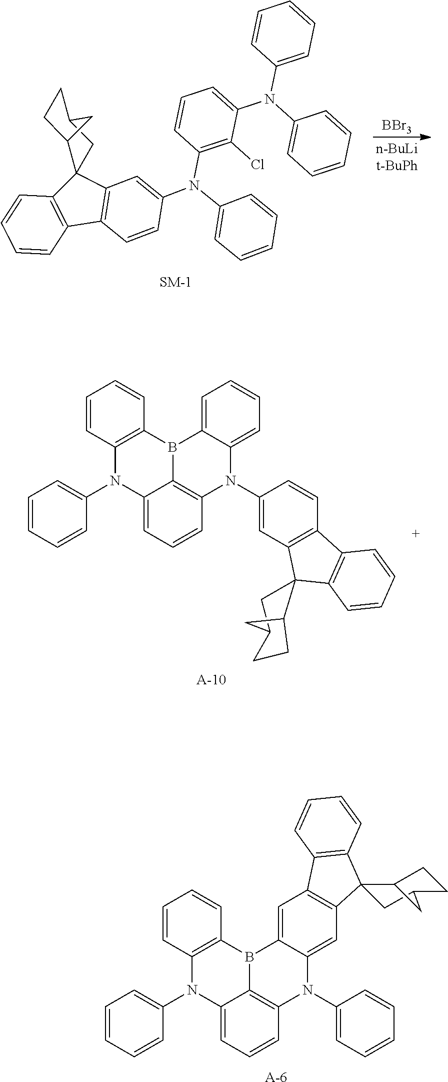

Under nitrogen protection, the intermediate SM-1 (3.56 g, 5.79 mmol) was dissolved in tert-butylbenzene (20 mL) into a round bottom flask, after dropwise addition of n-butyllithium (2.5 M, 1.83 mL), the mixture was heated to 200° C. for 6 h, the system was cooled to room temperature, the temperature was cooled to −78° C. with liquid nitrogen, boron tribromide (1 M, 2.2 mL) was slowly added dropwise, after the adding dropwise was completed, the reaction was reheated to 180° C., after 2 h, the reaction mixture was quenched with an aqueous sodium thiosulfate solution, an organic phase was extracted with toluene, dried over anhydrous magnesium sulfate, and filtered, and a solvent was removed under reduced pressure. Purification was performed by column chromatography using n-heptane to obtain an organic compound A-10 (1.58 g, yield: 46.3%), mass spectrum: m/z=589.5 [M+H] +and an organic compound A-6 (1.34 g, yield: 39.3%), mass spectrum: m/z=589.6 [M+H]⁺.

The structure of the organic compound A-10 was determined according to ¹HNMR:

¹H NMR (400 MHz, CD₂Cl₂): 8.15 (m, 3H), 7.91 (dd, 1H), 7.82-7.66 (m, 7H), 7.50 (s, 1H), 7.36-7.19 (m, 5H), 7.04-6.87 (m, 3H), 6.74 (dd, 1H), 6.72-6.65 (m, 2H), 2.94 (s, 1H), 2.73 (s, 1H), 2.45-2.17 (m, 8H).

The structure of the organic compound A-6 was determined according to ¹HNMR:

¹H NMR (400 MHz, CD₂Cl₂): 8.18 (s, 1H), 8.03 (d, 1H), 7.93 (d, 1H), 7.77-7.53 (m, 8H), 7.32-7.01 (m, 4H), 6.87 (m, 6H), 6.77-6.70 (m, 2H), 2.73 (s, 1H), 2.62 (s, 1H), 2.57-2.49 (m, 2H), 2.31-1.97 (m, 6H).

The following compounds were prepared by the same synthesis method as that in Synthesis example 1 except that an intermediate SM-S in Table 5 was used instead of the intermediate SM-1 to synthesize compounds in Table 5, and specific compound numbers, structures, the synthesis yield in a last step, characterization data and the like are shown in Table 5.

TABLE 5

| | | | | Mass spectrum |
|---|---|---|---|---|
| Compound No. | Intermediate SM-S | Compound structure | Yield (%) | (m/z) [M + H]⁺ |
| G-9 | 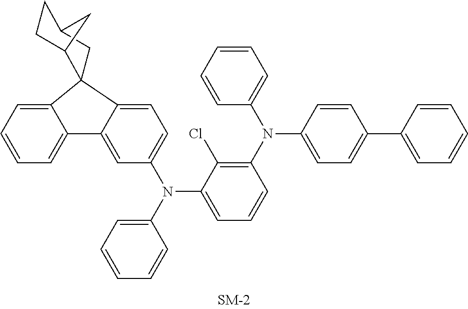 [SMILES: Clc1c(N(c2ccccc2)c2ccc(-c3ccccc3)cc2)cccc1N(c1ccccc1)c1ccc2c(c1)-c1ccccc1C21CC2CCC1C2] | 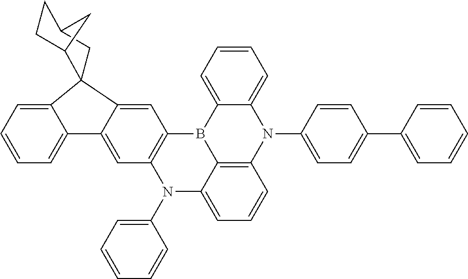 [SMILES: c1ccc(-c2ccc(N3c4ccccc4B4c5cc6c(cc5N(c5ccccc5)c5cccc3c54)-c3ccccc3C63CC4CCC3C4)cc2)cc1] | 29 | 665.3 |
| G-10 | | 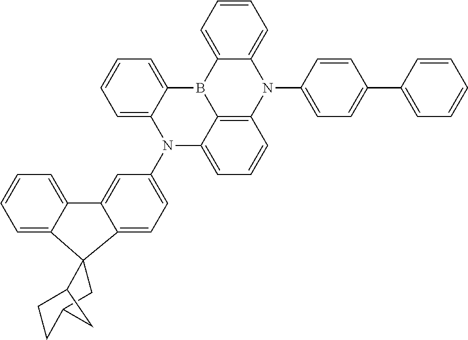 [SMILES: c1ccc(-c2ccc(N3c4ccccc4B4c5ccccc5N(c5ccc6c(c5)-c5ccccc5C65CC6CCC5C6)c5cccc3c54)cc2)cc1] | 26 | 665.3 |
| G-11 | 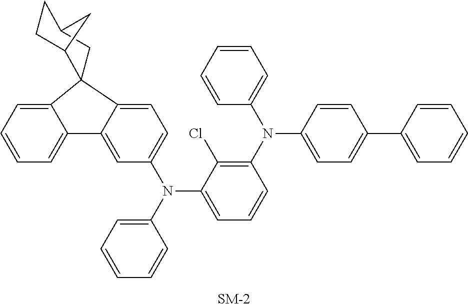 [SMILES: Clc1c(N(c2ccccc2)c2ccc(-c3ccccc3)cc2)cccc1N(c1ccccc1)c1ccc2c(c1)-c1ccccc1C21CC2CCC1C2] | 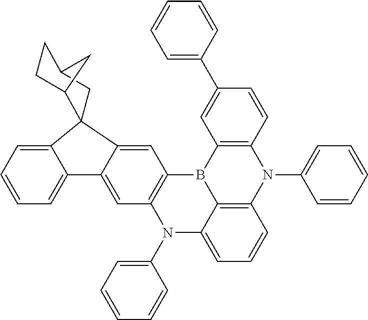 [SMILES: c1ccc(-c2ccc3c(c2)B2c4cc5c(cc4N(c4ccccc4)c4cccc(c42)N3c2ccccc2)-c2ccccc2C52CC3CCC2C3)cc1] | 20 | 665.5 |
| G-12 | | 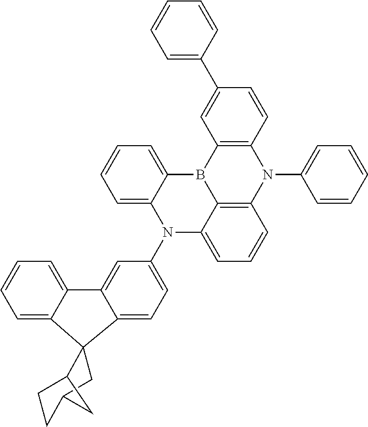 [SMILES: c1ccc(-c2ccc3c(c2)B2c4ccccc4N(c4ccc5c(c4)-c4ccccc4C54CC5CCC4C5)c4cccc(c42)N3c2ccccc2)cc1] | 21 | 665.5 |
| B-62 | 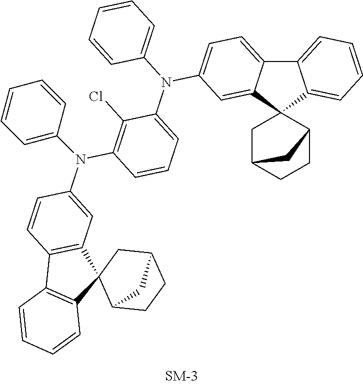 [SMILES: Clc1c(N(c2ccccc2)c2ccc3c(c2)[C@@]2(C[C@H]4CC[C@@H]2C4)c2ccccc2-3)cccc1N(c1ccccc1)c1ccc2c(c1)[C@@]1(C[C@H]3CC[C@@H]1C3)c1ccccc1-2] | 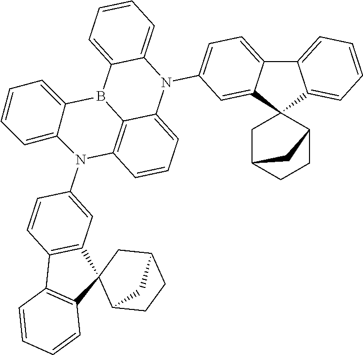 [SMILES: c1ccc2c(c1)B1c3ccccc3N(c3ccc4c(c3)[C@@]3(C[C@H]5CC[C@@H]3C5)c3ccccc3-4)c3cccc(c31)N2c1ccc2c(c1)[C@@]1(C[C@H]3CC[C@@H]1C3)c1ccccc1-2] | 44 | 757.4 |
| B-65 | | 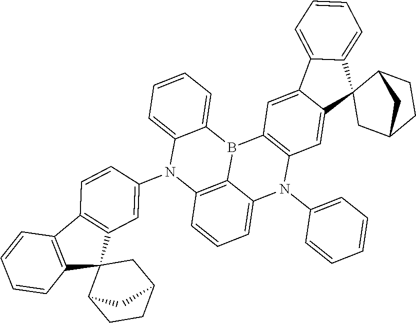 [SMILES: c1ccc(N2c3cc4c(cc3B3c5ccccc5N(c5ccc6c(c5)[C@@]5(C[C@H]7CC[C@@H]5C7)c5ccccc5-6)c5cccc2c53)-c2ccccc2[C@]42C[C@H]3CC[C@@H]2C3)cc1] | 32 | 757.3 |
| B-72 | 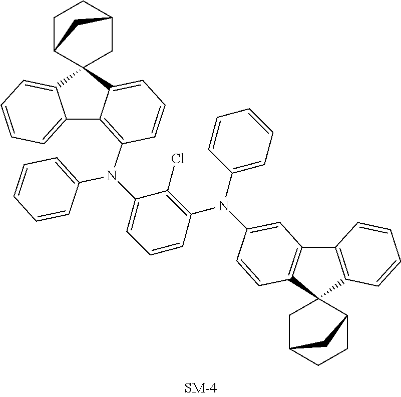 [SMILES: Clc1c(N(c2ccccc2)c2ccc3c(c2)-c2ccccc2[C@]32C[C@H]3CC[C@@H]2C3)cccc1N(c1ccccc1)c1cccc2c1-c1ccccc1[C@]21C[C@H]2CC[C@@H]1C2] | 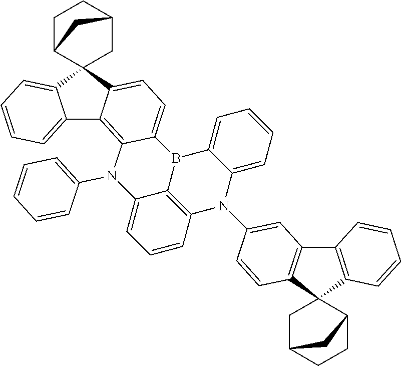 [SMILES: c1ccc(N2c3cccc4c3B(c3ccccc3N4c3ccc4c(c3)-c3ccccc3[C@]43C[C@H]4CC[C@@H]3C4)c3ccc4c(c32)-c2ccccc2[C@]42C[C@H]3CC[C@@H]2C3)cc1] | 19 | 757.3 |
| B-69 | | 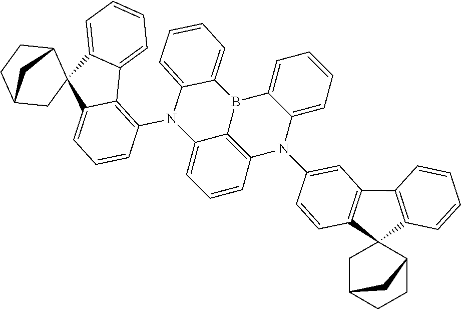 [SMILES: c1ccc2c(c1)B1c3ccccc3N(c3cccc4c3-c3ccccc3[C@@]43C[C@@H]4CC[C@H]3C4)c3cccc(c31)N2c1ccc2c(c1)-c1ccccc1[C@]21C[C@H]2CC[C@@H]1C2] | 17 | 757.4 |
| B-21 | 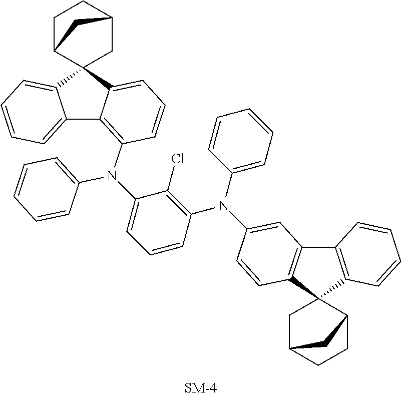 [SMILES: Clc1c(N(c2ccccc2)c2ccc3c(c2)-c2ccccc2[C@]32C[C@H]3CC[C@@H]2C3)cccc1N(c1ccccc1)c1cccc2c1-c1ccccc1[C@]21C[C@H]2CC[C@@H]1C2] | 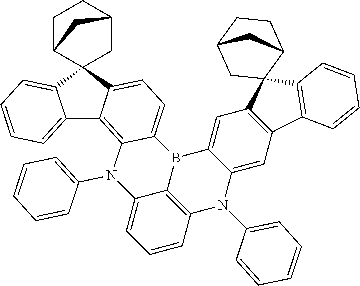 [SMILES: c1ccc(N2c3cc4c(cc3B3c5ccc6c(c5N(c5ccccc5)c5cccc2c53)-c2ccccc2[C@]62C[C@H]3CC[C@@H]2C3)[C@]2(C[C@@H]3CC[C@H]2C3)c2ccccc2-4)cc1] | 14 | 757.4 |
| B-18 | | 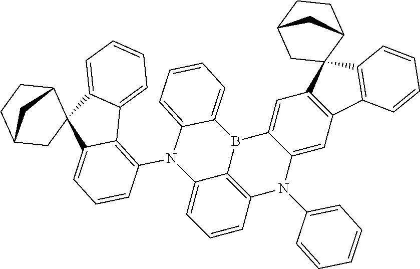 [SMILES: c1ccc(N2c3cc4c(cc3B3c5ccccc5N(c5cccc6c5-c5ccccc5[C@@]65C[C@@H]6CC[C@H]5C6)c5cccc2c53)[C@]2(C[C@@H]3CC[C@H]2C3)c2ccccc2-4)cc1] | 23 | 757.4 |
| G-13 | 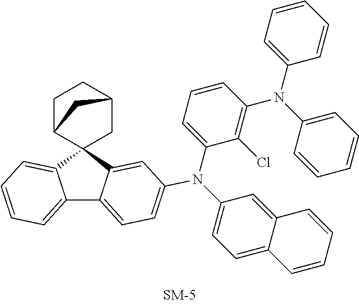 [SMILES: Clc1c(N(c2ccccc2)c2ccccc2)cccc1N(c1ccc2c(c1)[C@@]1(C[C@H]3CC[C@@H]1C3)c1ccccc1-2)c1ccc2ccccc2c1] | 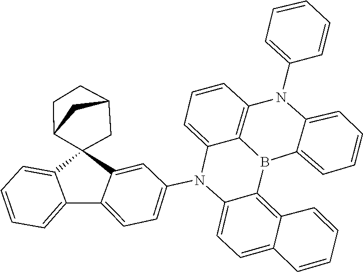 [SMILES: c1ccc(N2c3ccccc3B3c4c2cccc4N(c2ccc4c(c2)[C@@]2(C[C@H]5CC[C@@H]2C5)c2ccccc2-4)c2ccc4ccccc4c23)cc1] | 51 | 639.3 |
| G-14 | | 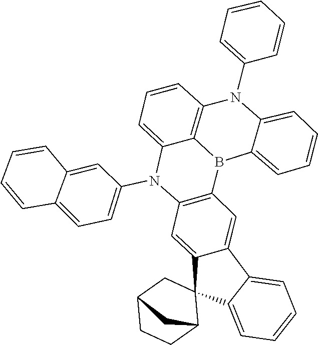 [SMILES: c1ccc(N2c3ccccc3B3c4cc5c(cc4N(c4ccc6ccccc6c4)c4cccc2c43)[C@@]2(C[C@H]3CC[C@@H]2C3)c2ccccc2-5)cc1] | 40 | 639.3 |
| A-42 | | 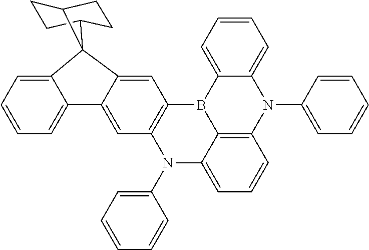 [SMILES: c1ccc(N2c3ccccc3B3c4cc5c(cc4N(c4ccccc4)c4cccc2c43)-c2ccccc2C52C3CCC2CC3)cc1] | 43 | 589.3 |
| A-49 | 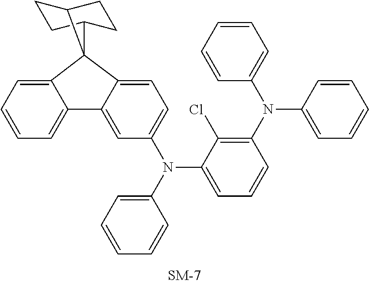 [SMILES: Clc1c(N(c2ccccc2)c2ccccc2)cccc1N(c1ccccc1)c1ccc2c(c1)-c1ccccc1C21C2CCC1CC2] | 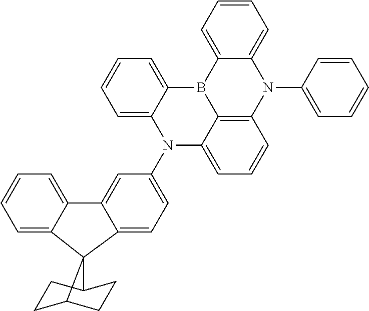 [SMILES: c1ccc(N2c3ccccc3B3c4ccccc4N(c4ccc5c(c4)-c4ccccc4C54C5CCC4CC5)c4cccc2c43)cc1] | 50 | 589.3 |
| G-15 | 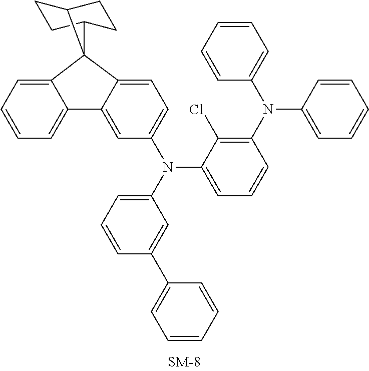 [SMILES: Clc1c(N(c2ccccc2)c2ccccc2)cccc1N(c1cccc(-c2ccccc2)c1)c1ccc2c(c1)-c1ccccc1C21C2CCC1CC2] | 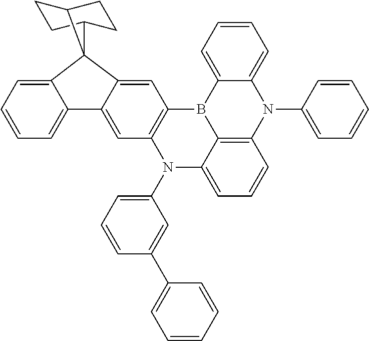 [SMILES: c1ccc(-c2cccc(N3c4cc5c(cc4B4c6ccccc6N(c6ccccc6)c6cccc3c64)C3(c4ccccc4-5)C4CCC3CC4)c2)cc1] | 38 | 665.3 |
| G-16 | | 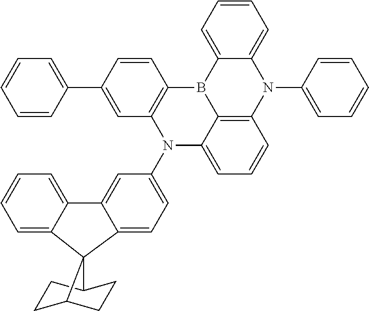 [SMILES: c1ccc(-c2ccc3c(c2)N(c2ccc4c(c2)-c2ccccc2C42C4CCC2CC4)c2cccc4c2B3c2ccccc2N4c2ccccc2)cc1] | 46 | 665.3 |
| A-39 | 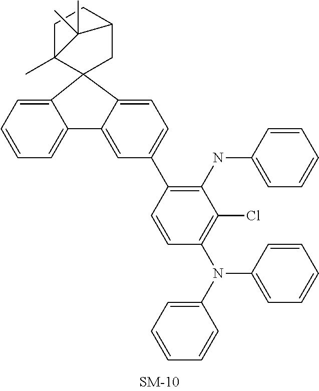 [SMILES: CC1(C)C2CCC1(C)C1(C2)c2ccccc2-c2cc(-c3ccc(N(c4ccccc4)c4ccccc4)c(Cl)c3Nc3ccccc3)ccc21] | 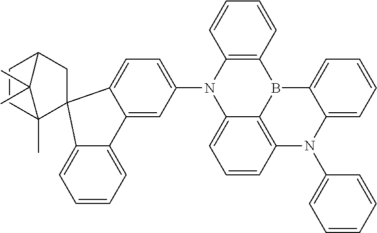 [SMILES: CC1(C)C2CCC1(C)C1(C2)c2ccccc2-c2cc(N3c4ccccc4B4c5ccccc5N(c5ccccc5)c5cccc3c54)ccc21] | 55 | 631.4 |
| A-34 | | 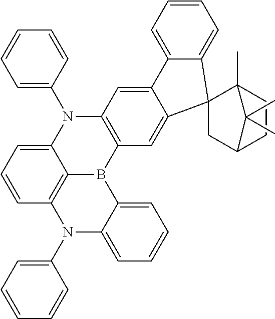 [SMILES: CC1(C)C2CCC1(C)C1(C2)c2ccccc2-c2cc3c(cc21)B1c2ccccc2N(c2ccccc2)c2cccc(c21)N3c1ccccc1] | 35 | 631.3 |
| A-19 | 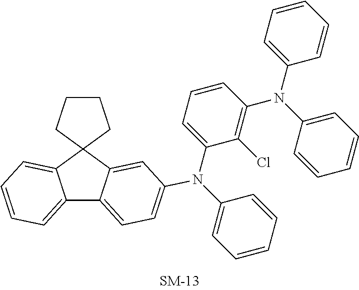 [SMILES: Clc1c(N(c2ccccc2)c2ccccc2)cccc1N(c1ccccc1)c1ccc2c(c1)C1(CCCC1)c1ccccc1-2] | 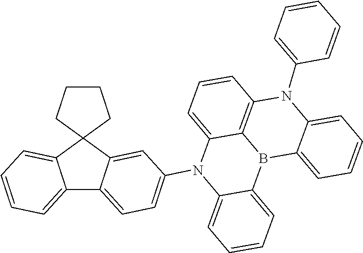 [SMILES: c1ccc(N2c3ccccc3B3c4ccccc4N(c4ccc5c(c4)C4(CCCC4)c4ccccc4-5)c4cccc2c43)cc1] | 46 | 563.2 |
| A-15 | | 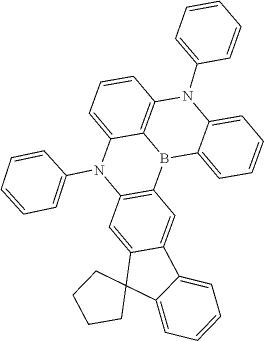 [SMILES: c1ccc(N2c3ccccc3B3c4cc5c(cc4N(c4ccccc4)c4cccc2c43)C2(CCCC2)c2ccccc2-5)cc1] | 51 | 563.3 |
| C-19 | 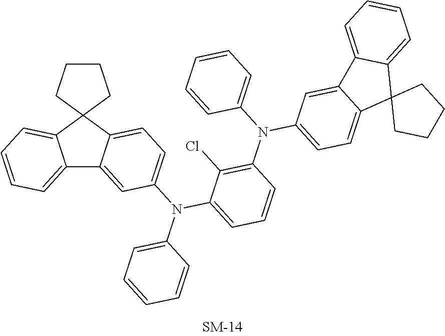 [SMILES: Clc1c(N(c2ccccc2)c2ccc3c(c2)-c2ccccc2C32CCCC2)cccc1N(c1ccccc1)c1ccc2c(c1)-c1ccccc1C21CCCC1] | 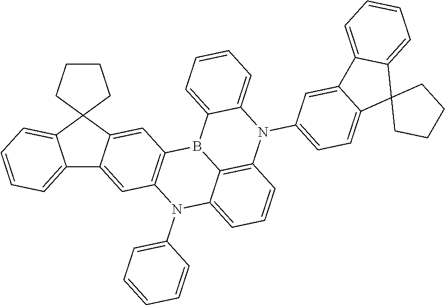 [SMILES: c1ccc(N2c3cc4c(cc3B3c5ccccc5N(c5ccc6c(c5)-c5ccccc5C65CCCC5)c5cccc2c53)C2(CCCC2)c2ccccc2-4)cc1] | 37 | 705.3 |
| C-61 | | 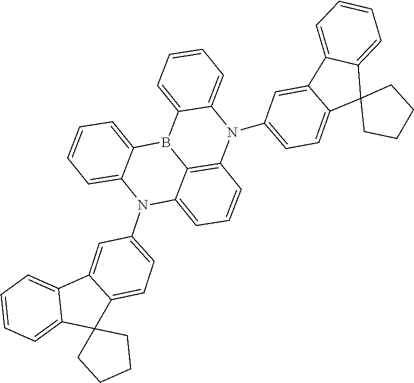 [SMILES: c1ccc2c(c1)B1c3ccccc3N(c3ccc4c(c3)-c3ccccc3C43CCCC3)c3cccc(c31)N2c1ccc2c(c1)-c1ccccc1C21CCCC1] | 25 | 705.3 |
| C-68 | 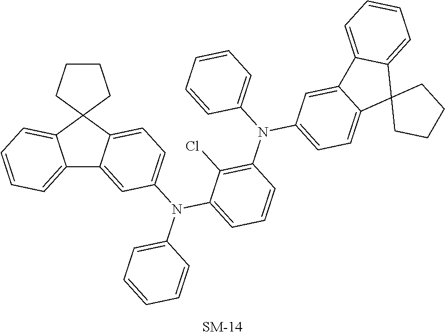 [SMILES: Clc1c(N(c2ccccc2)c2ccc3c(c2)-c2ccccc2C32CCCC2)cccc1N(c1ccccc1)c1ccc2c(c1)-c1ccccc1C21CCCC1] | 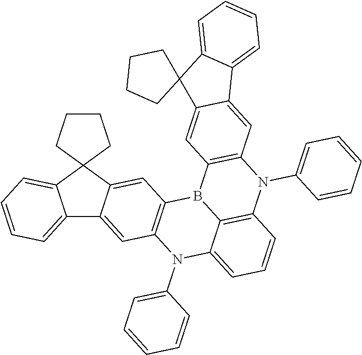 [SMILES: c1ccc(N2c3cc4c(cc3B3c5cc6c(cc5N(c5ccccc5)c5cccc2c53)-c2ccccc2C62CCCC2)C2(CCCC2)c2ccccc2-4)cc1] | 31 | 705.4 |
| G-17 | 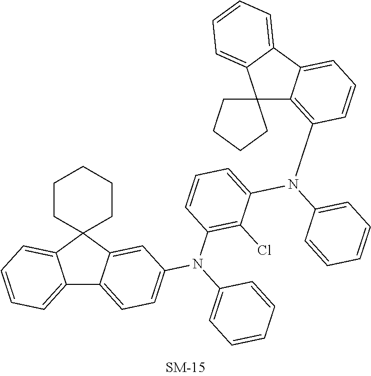 [SMILES: Clc1c(N(c2ccccc2)c2ccc3c(c2)C2(CCCCC2)c2ccccc2-3)cccc1N(c1ccccc1)c1cccc2c1C1(CCCC1)c1ccccc1-2] | 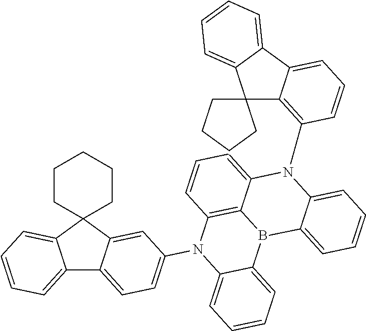 [SMILES: c1ccc2c(c1)B1c3ccccc3N(c3cccc4c3C3(CCCC3)c3ccccc3-4)c3cccc(c31)N2c1ccc2c(c1)C1(CCCCC1)c1ccccc1-2] | 29 | 719.4 |
| G-18 | | 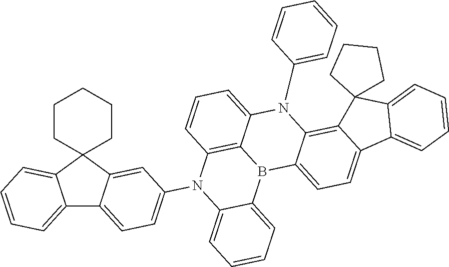 [SMILES: c1ccc(N2c3cccc4c3B(c3ccccc3N4c3ccc4c(c3)C3(CCCCC3)c3ccccc3-4)c3ccc4c(c32)C2(CCCC2)c2ccccc2-4)cc1] | 26 | 719.4 |
| G-19 | 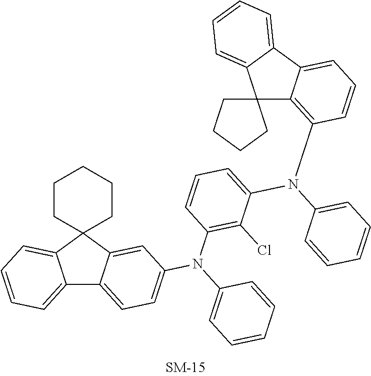 [SMILES: Clc1c(N(c2ccccc2)c2ccc3c(c2)C2(CCCCC2)c2ccccc2-3)cccc1N(c1ccccc1)c1cccc2c1C1(CCCC1)c1ccccc1-2] | 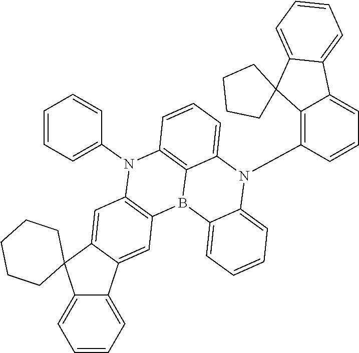 [SMILES: c1ccc(N2c3cc4c(cc3B3c5ccccc5N(c5cccc6c5C5(CCCC5)c5ccccc5-6)c5cccc2c53)-c2ccccc2C42CCCCC2)cc1] | 33 | 719.5 |
| A-24 | 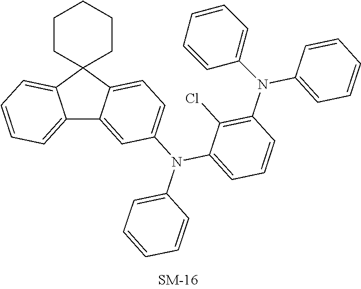 [SMILES: Clc1c(N(c2ccccc2)c2ccccc2)cccc1N(c1ccccc1)c1ccc2c(c1)-c1ccccc1C21CCCCC1] | 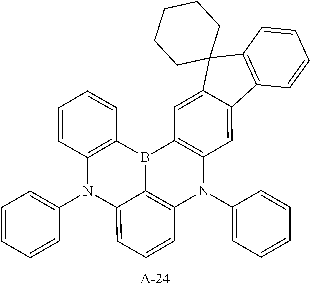 | 53 | 577.2 |
| A-29 | | 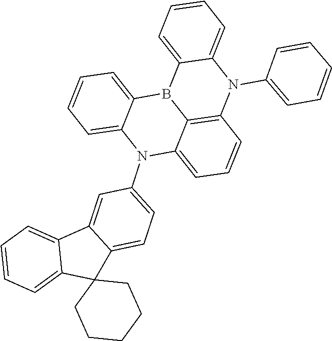 [SMILES: c1ccc(N2c3ccccc3B3c4ccccc4N(c4ccc5c(c4)-c4ccccc4C54CCCCC4)c4cccc2c43)cc1] | 43 | 577.3 |
| D-49 | 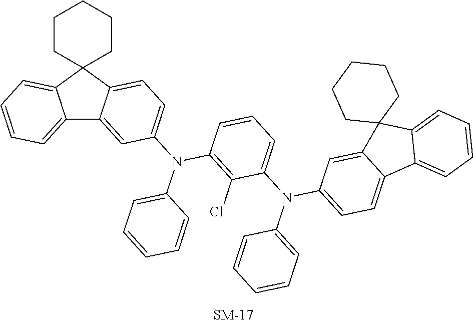 [SMILES: Clc1c(N(c2ccccc2)c2ccc3c(c2)-c2ccccc2C32CCCCC2)cccc1N(c1ccccc1)c1ccc2c(c1)C1(CCCCC1)c1ccccc1-2] | 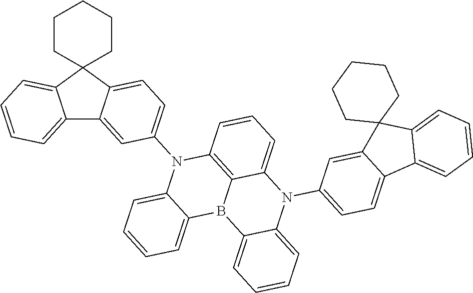 [SMILES: c1ccc2c(c1)B1c3ccccc3N(c3ccc4c(c3)C3(CCCCC3)c3ccccc3-4)c3cccc(c31)N2c1ccc2c(c1)-c1ccccc1C21CCCCC1] | 20 | 733.4 |
| D-52 | | 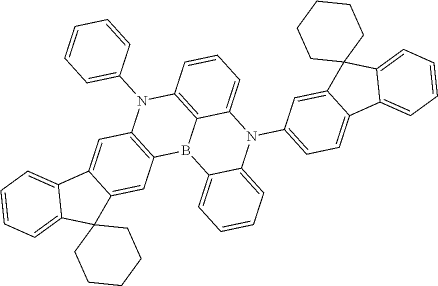 [SMILES: c1ccc(N2c3cc4c(cc3B3c5ccccc5N(c5ccc6c(c5)C5(CCCCC5)c5ccccc5-6)c5cccc2c53)C2(CCCCC2)c2ccccc2-4)cc1] | 26 | 733.4 |
| D-27 | 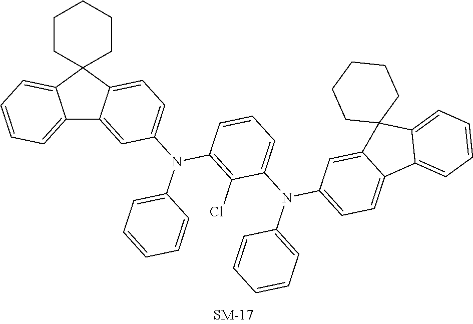 [SMILES: Clc1c(N(c2ccccc2)c2ccc3c(c2)-c2ccccc2C32CCCCC2)cccc1N(c1ccccc1)c1ccc2c(c1)C1(CCCCC1)c1ccccc1-2] | 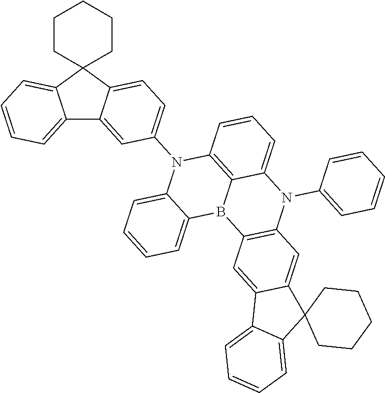 [SMILES: c1ccc(N2c3cc4c(cc3B3c5ccccc5N(c5ccc6c(c5)-c5ccccc5C65CCCCC5)c5cccc2c53)-c2ccccc2C42CCCCC2)cc1] | 18 | 733.5 |
| D-30 | | 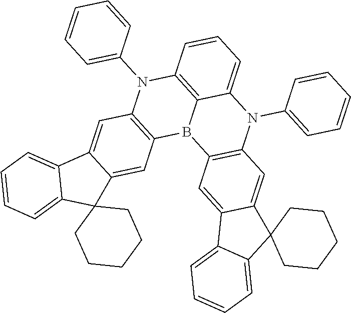 [SMILES: c1ccc(N2c3cc4c(cc3B3c5cc6c(cc5N(c5ccccc5)c5cccc2c53)C2(CCCCC2)c2ccccc2-6)C2(CCCCC2)c2ccccc2-4)cc1] | 23 | 733.3 |
| G-20 | 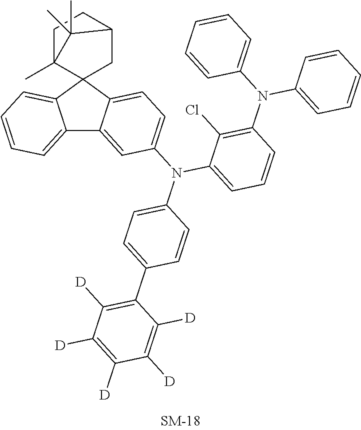 [SMILES: [2H]c1c([2H])c([2H])c(-c2ccc(N(c3ccc4c(c3)-c3ccccc3C43CC4CCC3(C)C4(C)C)c3cccc(N(c4ccccc4)c4ccccc4)c3Cl)cc2)c([2H])c1[2H]] | 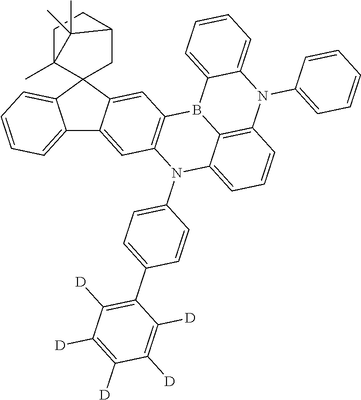 [SMILES: [2H]c1c([2H])c([2H])c(-c2ccc(N3c4cc5c(cc4B4c6ccccc6N(c6ccccc6)c6cccc3c64)C3(CC4CCC3(C)C4(C)C)c3ccccc3-5)cc2)c([2H])c1[2H]] | 46 | 712.4 |
| G-21 | | 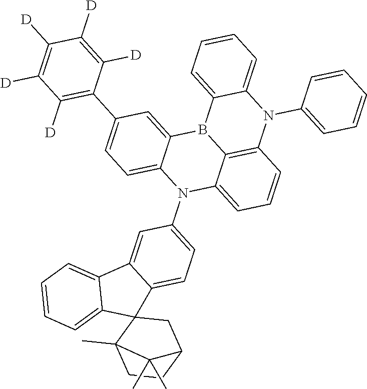 [SMILES: [2H]c1c([2H])c([2H])c(-c2ccc3c(c2)B2c4ccccc4N(c4ccccc4)c4cccc(c42)N3c2ccc3c(c2)-c2ccccc2C32CC3CCC2(C)C3(C)C)c([2H])c1[2H]] | 37 | 712.6 |
| G-33 | 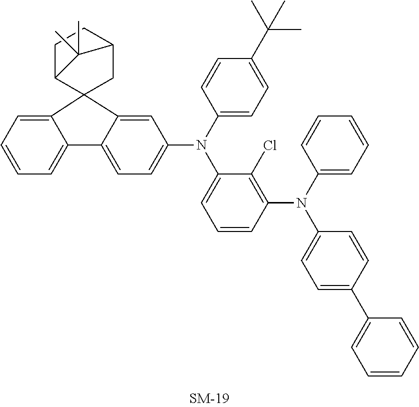 [SMILES: CC(C)(C)c1ccc(N(c2ccc3c(c2)C2(CC4CCC2C4(C)C)c2ccccc2-3)c2cccc(N(c3ccccc3)c3ccc(-c4ccccc4)cc3)c2Cl)cc1] | 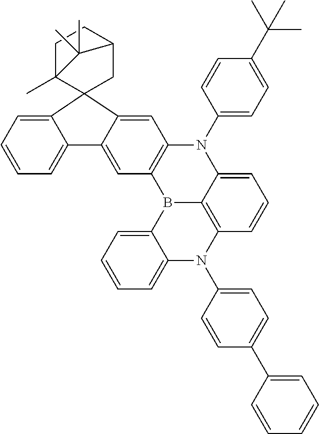 [SMILES: CC(C)(C)c1ccc(N2c3cc4c(cc3B3c5ccccc5N(c5ccc(-c6ccccc6)cc5)c5cccc2c53)-c2ccccc2C42CC3CCC2(C)C3(C)C)cc1] | 40 | 763.3 |
| G-34 | 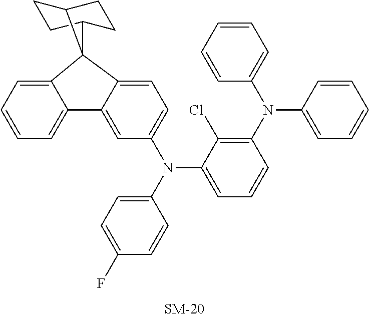 [SMILES: Fc1ccc(N(c2ccc3c(c2)-c2ccccc2C32C3CCC2CC3)c2cccc(N(c3ccccc3)c3ccccc3)c2Cl)cc1] | 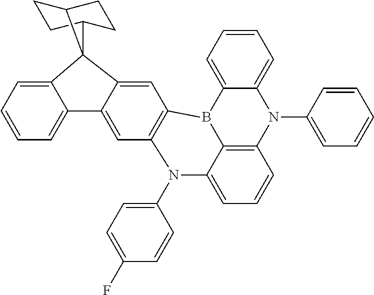 [SMILES: Fc1ccc(N2c3cc4c(cc3B3c5ccccc5N(c5ccccc5)c5cccc2c53)C2(c3ccccc3-4)C3CCC2CC3)cc1] | 31 | 607.4 |
| G-35 | 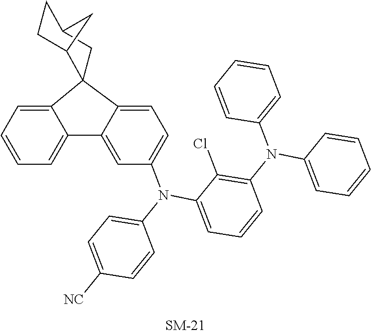 [SMILES: N#Cc1ccc(N(c2ccc3c(c2)-c2ccccc2C32CC3CCC2C3)c2cccc(N(c3ccccc3)c3ccccc3)c2Cl)cc1] | 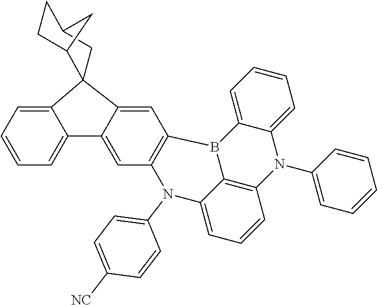 [SMILES: N#Cc1ccc(N2c3cc4c(cc3B3c5ccccc5N(c5ccccc5)c5cccc2c53)C2(CC3CCC2C3)c2ccccc2-4)cc1] | 39 | 614.3 |
| G-36 | 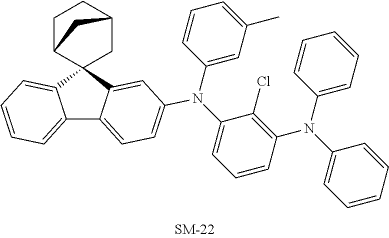 [SMILES: Cc1cccc(N(c2ccc3c(c2)[C@@]2(C[C@H]4CC[C@@H]2C4)c2ccccc2-3)c2cccc(N(c3ccccc3)c3ccccc3)c2Cl)c1] | 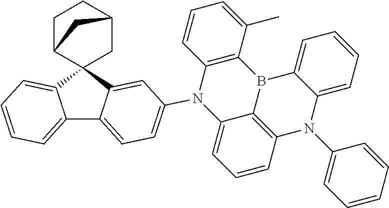 [SMILES: Cc1cccc2c1B1c3ccccc3N(c3ccccc3)c3cccc(c31)N2c1ccc2c(c1)[C@@]1(C[C@H]3CC[C@@H]1C3)c1ccccc1-2] | 42 | 603.3 |

The embodiment of the present disclosure further provides an organic electroluminescent device, including an anode, a cathode, and an organic layer between the anode and the cathode, wherein the organic layer includes the above organic compound of the present disclosure. In the following, the organic electroluminescent device of the present disclosure was described in detail by way of examples. However, the following examples are only examples of the present disclosure, and are not intended to limit the present disclosure.

### MANUFACTURE AND EVALUATIOON EXAMPLES OF ORGANIC ELECTROLUMINESCENT DEVICE

### Example 1: Blue Organic Electroluminescent Device

An anode was prepared by the following process: an ITO substrate with an ITO thickness of 1300 Å was cut into a size of 40 mm (length)×40 mm (width)×0.7 mm (thickness) to be prepared into an experimental substrate with cathode, anode and insulating layer patterns by adopting a photoetching process, and surface treatment was performed by utilizing ultraviolet ozone and O₂:N₂ plasma to increase the work function of the anode, and the surface of the ITO substrate may be cleaned with an organic solvent to remove impurities and oil on the surface of the ITO substrate. It should be noted that the ITO substrate can also be cut into other sizes according to actual needs, and the size of the ITO substrate in the present disclosure is not specifically limited here.

HAT-CN (cas: 105598-27-4) was vacuum evaporated on the experimental substrate (the anode) to form a hole injection layer (HIL) having a thickness of 100 Å, and then NPB (cas: 123847-85-8) was vacuum evaporated on the hole injection layer to form a first hole transport layer having a thickness of 1040 Å.

TcTa (cas: 139092-78-7) was vacuum evaporated on the first hole transport layer to form a second hole transport layer having a thickness of 50 Å.

Next, a compound BH-1 (a host material) and a compound A-10 (a guest material) were co-evaporated on the second hole transport layer in a weight ratio of 97%:3% to form an organic light-emitting layer (EML) having a thickness of 240 Å.

Then, a compound ET-1 and LiQ were mixed in a weight ratio of 1:1 and evaporated to form an electron transport layer (ETL) having a thickness of 350 Å, Yb was evaporated on the electron transport layer to form an electron injection layer (EIL) having a thickness of 15 Å, and then magnesium (Mg) and silver (Ag) were mixed at an evaporation rate of 1:9 and vacuum evaporated on the electron injection layer to form a cathode having a thickness of 140 Å.

In addition, CP-1 having a thickness of 630 Å was vacuum evaporated on the above cathode, thus completing the manufacture of the blue organic electroluminescent device.

### Examples 2 to 40

An organic electroluminescent device was manufactured by the same method as that in Example 1 except that compounds in Table 7 were used instead of the compound A-10 in Example 1 when the organic light-emitting layer was manufactured.

### Comparative Examples 1 to 3

An organic electroluminescent device was manufactured by the same method as that in Example 1 except that compounds 1 to 3 shown in Table 6 below were used instead of the compound A-10 in Example 1 when the organic light-emitting layer was manufactured.

When the organic electroluminescent device was manufactured, the structures of materials used in the comparative examples and the examples are as follows:

TABLE 6

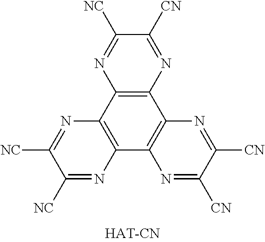 [SMILES: N#Cc1nc2c3nc(C#N)c(C#N)nc3c3nc(C#N)c(C#N)nc3c2nc1C#N]

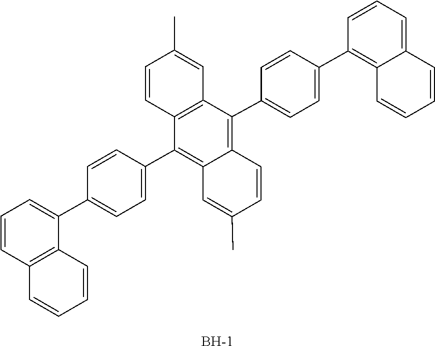

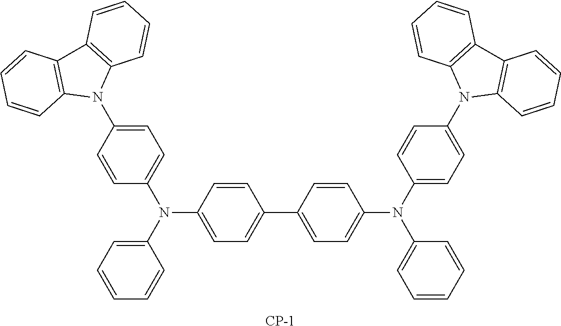 [SMILES: c1ccc(N(c2ccc(-c3ccc(N(c4ccccc4)c4ccc(-n5c6ccccc6c6ccccc65)cc4)cc3)cc2)c2ccc(-n3c4ccccc4c4ccccc43)cc2)cc1 ; "CP-1"]

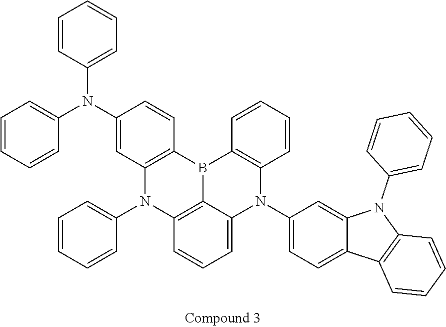 [SMILES: c1ccc(N(c2ccccc2)c2ccc3c(c2)N(c2ccccc2)c2cccc4c2B3c2ccccc2N4c2ccc3c4ccccc4n(-c4ccccc4)c3c2)cc1]

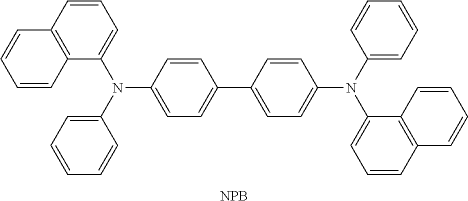 [SMILES: c1ccc(N(c2ccc(-c3ccc(N(c4ccccc4)c4cccc5ccccc45)cc3)cc2)c2cccc3ccccc23)cc1 ; "NPB"]

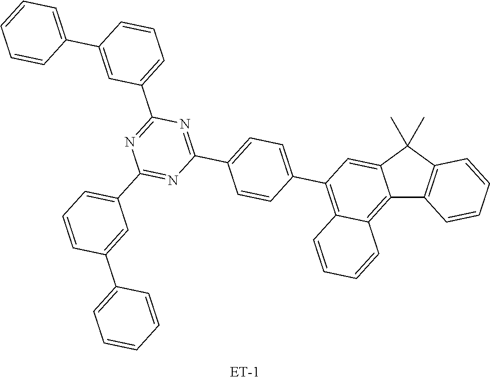 [SMILES: CC1(C)c2ccccc2-c2c1cc(-c1ccc(-c3nc(-c4cccc(-c5ccccc5)c4)nc(-c4cccc(-c5ccccc5)c4)n3)cc1)c1ccccc21]

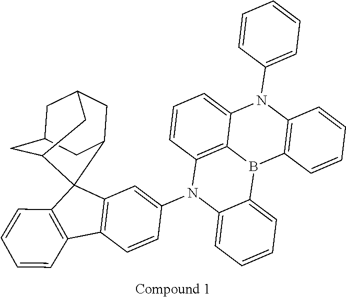 [SMILES: c1ccc(N2c3ccccc3B3c4ccccc4N(c4ccc5c(c4)C4(c6ccccc6-5)C5CC6CC(C5)CC4C6)c4cccc2c43)cc1]

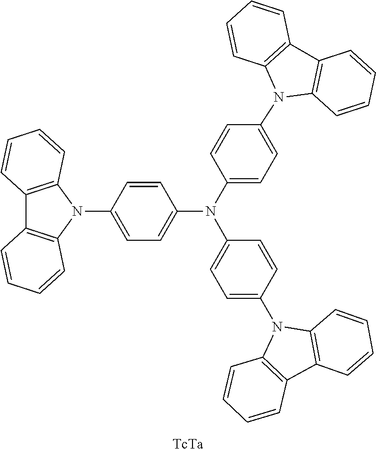 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; "TcTa"]

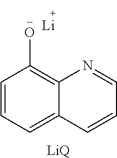

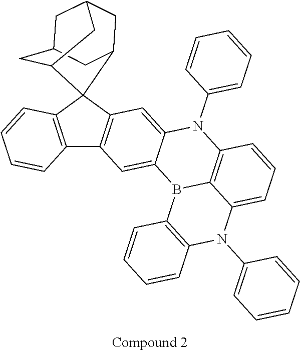 [SMILES: c1ccc(N2c3ccccc3B3c4cc5c(cc4N(c4ccccc4)c4cccc2c43)C2(c3ccccc3-5)C3CC4CC(C3)CC2C4)cc1]

The blue organic electroluminescent devices manufactured in Examples 1 to 40 and Comparative examples 1 to 3 were subjected to performance test, specifically the current-voltage-brightness (IVL) performance of the devices was tested under the condition of 10 mA/cm², the T95 device service life was tested under the condition of 15 mA/cm², and the test results are shown in Table 7.

TABLE 7

| | Organic light- | Operating | Luminous | Chromaticity | T95 |
|---|---|---|---|---|---|
| Example/Comparative | emitting layer | voltage | efficiency | coordinate | service life |
| example | doped guest | (V) | (Cd/A) | CIEx, CIEy | (h) |
| Example 1 | Compound A-10 | 4.13 | 5.51 | 0.136, 0.048 | 176 |
| Example 2 | Compound A-6 | 4.16 | 5.72 | 0.136, 0.047 | 192 |
| Example 3 | Compound G-9 | 4.12 | 5.63 | 0.136, 0.047 | 190 |
| Example 4 | Compound G-10 | 4.13 | 5.84 | 0.135, 0.047 | 196 |
| Example 5 | Compound G-11 | 4.13 | 5.73 | 0.135, 0.049 | 191 |
| Example 6 | Compound G-12 | 4.15 | 5.86 | 0.136, 0.049 | 195 |
| Example 7 | Compound B-62 | 4.15 | 5.70 | 0.137, 0.047 | 193 |
| Example 8 | Compound B-65 | 4.12 | 5.88 | 0.135, 0.049 | 176 |
| Example 9 | Compound B-72 | 4.12 | 5.76 | 0.137, 0.047 | 182 |
| Example 10 | Compound B-69 | 4.19 | 5.20 | 0.137, 0.047 | 194 |
| Example 11 | Compound B-21 | 4.18 | 5.65 | 0.137, 0.047 | 180 |
| Example 12 | Compound B-18 | 4.16 | 5.41 | 0.137, 0.049 | 190 |
| Example 13 | Compound G-13 | 4.16 | 5.60 | 0.136, 0.048 | 174 |
| Example 14 | Compound G-14 | 4.18 | 5.56 | 0.137, 0.048 | 184 |
| Example 15 | Compound A-42 | 4.16 | 5.50 | 0.135, 0.049 | 182 |
| Example 16 | Compound A-49 | 4.17 | 5.58 | 0.137, 0.049 | 173 |
| Example 17 | Compound G-15 | 4.17 | 5.45 | 0.136, 0.048 | 175 |
| Example 18 | Compound G-16 | 4.18 | 5.48 | 0.135, 0.049 | 200 |
| Example 19 | Compound A-39 | 4.18 | 5.39 | 0.136, 0.048 | 187 |
| Example 20 | Compound A-34 | 4.16 | 5.67 | 0.137, 0.049 | 177 |
| Example 21 | Compound A-19 | 4.21 | 5.12 | 0.136, 0.047 | 143 |
| Example 22 | Compound A-15 | 4.20 | 5.27 | 0.137, 0.048 | 144 |
| Example 23 | Compound C-19 | 4.18 | 5.33 | 0.135, 0.048 | 148 |
| Example 24 | Compound C-61 | 4.19 | 5.19 | 0.136, 0.047 | 149 |
| Example 25 | Compound C-68 | 4.20 | 5.47 | 0.137, 0.049 | 142 |
| Example 26 | Compound G-17 | 4.18 | 5.44 | 0.136, 0.048 | 146 |
| Example 27 | Compound G-18 | 4.20 | 5.39 | 0.137, 0.047 | 148 |
| Example 28 | Compound G-19 | 4.21 | 5.35 | 0.136, 0.048 | 140 |
| Example 29 | Compound A-24 | 4.18 | 5.21 | 0.135, 0.049 | 141 |
| Example 30 | Compound A-29 | 4.20 | 5.30 | 0.137, 0.048 | 147 |
| Example 31 | Compound D-49 | 4.21 | 5.45 | 0.136, 0.049 | 150 |
| Example 32 | Compound D-52 | 4.18 | 5.15 | 0.136, 0.049 | 151 |
| Example 33 | Compound D-27 | 4.18 | 5.31 | 0.136, 0.047 | 149 |
| Example 34 | Compound D-30 | 4.18 | 5.36 | 0.137, 0.049 | 145 |
| Example 35 | Compound G-20 | 4.22 | 5.22 | 0.137, 0.047 | 192 |
| Example 36 | Compound G-21 | 4.19 | 5.49 | 0.135, 0.049 | 200 |
| Example 37 | Compound G-33 | 4.22 | 5.64 | 0.137, 0.047 | 179 |
| Example 38 | Compound G-34 | 4.17 | 5.52 | 0.137, 0.048 | 181 |
| Example 39 | Compound G-35 | 4.20 | 5.87 | 0.136, 0.049 | 185 |
| Example 40 | Compound G-36 | 4.19 | 5.66 | 0.137, 0.048 | 197 |
| Comparative example 1 | Compound 1 | 4.33 | 4.50 | 0.137, 0.048 | 125 |
| Comparative example 2 | Compound 2 | 4.47 | 4.11 | 0.136, 0.048 | 113 |
| Comparative example 3 | Compound 3 | 4.62 | 3.72 | 0.137, 0.047 | 86 |

As can be seen from Table 7 above, compared with the organic electroluminescent devices in Comparative examples 1 to 3, the performance of the organic electroluminescent devices in Examples 1 to 40 is greatly improved, the luminous efficiency is improved by at least 13.8%, and the T95 service life is improved by at least 12%.

When the organic compound of the present disclosure is used in the manufacture of the organic electroluminescent device, the device performance is significantly improved. This is because the organic compound of the present disclosure has a norborneol-fluorene structure, or a cyclohexane-fluorene structure, or a cyclopentane-fluorene structure, so that the organic compound provided by the present disclosure can improve the carrier transport efficiency and the service life of the organic electroluminescent device by improving the electron density of a conjugated system of a fluorene ring and the entire nitrogen-containing compound, and increasing the hole transport efficiency of the nitrogen-containing compound. And the organic compound provided by the present disclosure combines the norborneol-fluorene structure, or the cyclohexane-fluorene structure, or the cyclopentane-fluorene structure with a solid ring centered on the boron element, so that the carrier stability can be effectively increased, and the luminescent performance of the organic electroluminescent device can be improved.

1. An organic compound, having a structure obtained by fusing a formula (1) with one or two Ar groups: 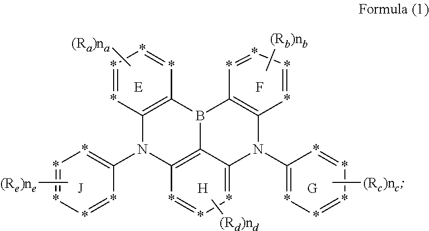
“*” indicates a site wherein the structure shown in formula (1) is fused with the Ar group;
the Ar group is selected from the group consisting of groups shown in formulae (2-1) to (2-5): 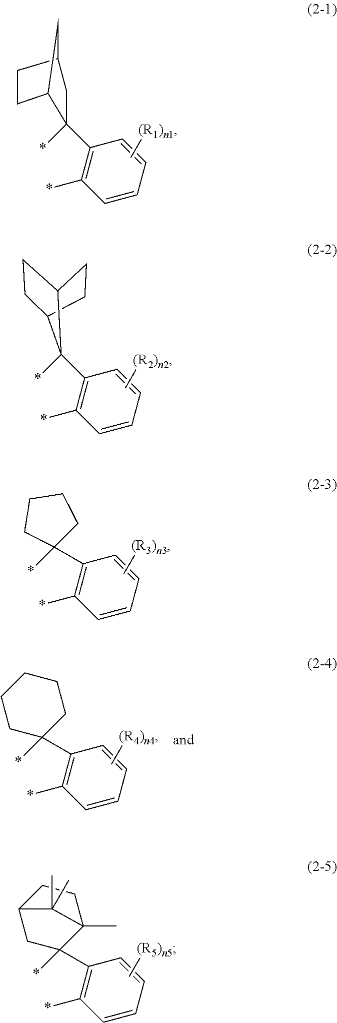
the Ar group is fused to any two adjacent * positions in a ring E, a ring F, a ring G, a ring H or a ring J in the formula (1);
when the number of the Ar group is two, the two Ar groups are the same or different;
each Rₐ, each R_{b}, each R_{c}, each R_{d} and each Rₑ are the same or different from each other, and are each independently selected from deuterium, a halogen group, cyano, substituted or unsubstituted alkyl with 1 to 20 carbon atoms, substituted or unsubstituted cycloalkyl with 3 to 20 carbon atoms, substituted or unsubstituted aryl with 6 to 20 carbon atoms, substituted or unsubstituted heteroaryl with 3 to 20 carbon atoms, substituted or unsubstituted trialkylsilyl with 3 to 20 carbon atoms, substituted or unsubstituted haloalkyl with 1 to 20 carbon atoms, substituted or unsubstituted triarylsilyl with 18 to 24 carbon atoms, substituted or unsubstituted alkoxy with 1 to 20 carbon atoms, and substituted or unsubstituted alkylthio with 1 to 20 carbon atoms;
nₐ represents the number of Rₐ, and is selected from 0, 1, 2, 3 or 4, and when nₐ is greater than 1, any two Rₐ are the same or different;
n_{b} represents the number of R_{b}, and is selected from 0, 1, 2, 3 or 4, and when n_{b} is greater than 1, any two R_{b} are the same or different;
n_{c} represents the number of R_{c}, and is selected from 0, 1, 2, 3, 4 or 5, and when n_{c} is greater than 1, any two R_{c} are the same or different;
n_{d} represents the number of R_{d}, and is selected from 0, 1, 2 or 3, and when n_{d} is greater than 1, any two R_{d} are the same or different;
nₑ represents the number of Rₑ, and is selected from 0, 1, 2, 3, 4 or 5, and when nₑ is greater than 1, any two Rₑ are the same or different;
each R₁, each R₂, each R₃, each R₄ and each Rs are the same or different from each other, and are each independently selected from deuterium, a halogen group, cyano, trialkylsilyl with 3 to 12 carbon atoms, triarylsilyl with 18 to 24 carbon atoms, alkyl with 1 to 10 carbon atoms, cycloalkyl with 3 to 10 carbon atoms, alkoxy with 1 to 10 carbon atoms, aryl with 6 to 20 carbon atoms or heteroaryl with 3 to 20 carbon atoms;
n₁ represents the number of R₁, n₂ represents the number of R₂, n₃ represents the number of R3, n4 represents the number of R4, ns represents the number of Rs, and the ni, the na, the n3, the n₄ and the n₅ are each independently selected from 0, 1, 2, 3 or 4; and
substituents in the Rₐ, the R_{b}, the R_{c}, the R_{d} and the Rₑ are the same or different from each other, and are each independently selected from: deuterium, a halogen group, cyano, heteroaryl with 3 to 12 carbon atoms, aryl with 6 to 12 carbon atoms, trialkylsilyl with 3 to 12 carbon atoms, alkyl with 1 to 10 carbon atoms, haloalkyl with 1 to 10 carbon atoms, cycloalkyl with 3 to 10 carbon atoms, heterocycloalkyl with 2 to 10 carbon atoms, alkoxy with 1 to 10 carbon atoms, alkylthio with 1 to 10 carbon atoms, aryloxy with 6 to 12 carbon atoms, arylthio with 6 to 12 carbon atoms, alkylsulfonyl with 6 to 12 carbon atoms, trialkylphosphino with 3 to 12 carbon atoms, or trialkylboryl with 3 to 12 carbon atoms.

2. The organic compound according to claim 1, wherein the organic compound is selected from the group consisting of structures represented by formulae K to Q below:
the formula K is obtained by fusing any one of a ring F, a ring G or a ring H in a formula (1-1) below with one of the Ar groups;
the formula L is obtained by separately fusing a ring E and a ring F in a formula (1-2) below with one of the Ar groups, and the two Ar groups are the same or different;
the formula M is obtained by separately fusing a ring F and a ring G in a formula (1-3) below with one of the Ar groups, and the two Ar groups are the same or different;
the formula N is obtained by separately fusing a ring F and a ring H in a formula (1-4) below with one of the Ar groups, and the two Ar groups are the same or different;
the formula O is obtained by separately fusing a ring G and a ring H in a formula (1-5) below with one of the Ar groups, and the two Ar groups are the same or different;
the formula P is obtained by separately fusing a ring E and a ring G in a formula (1-6) below with one of the Ar groups, and the two Ar groups are the same or different;
the formula Q is obtained by separately fusing a ring G and a ring J in a formula (1-7) below with one of the Ar groups, and the two Ar groups are the same or different; and
the structure represented by the formula (1-1), the formula (1-2), the formula (1-3), the formula (1-4), the formula (1-5), the formula (1-6), or the formula (1-7) is shown below:

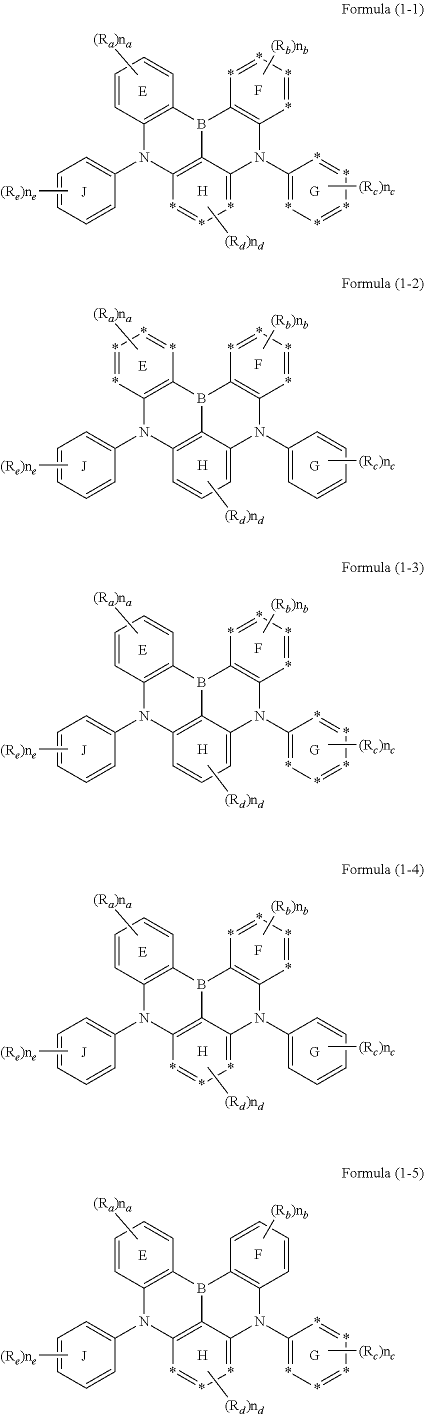

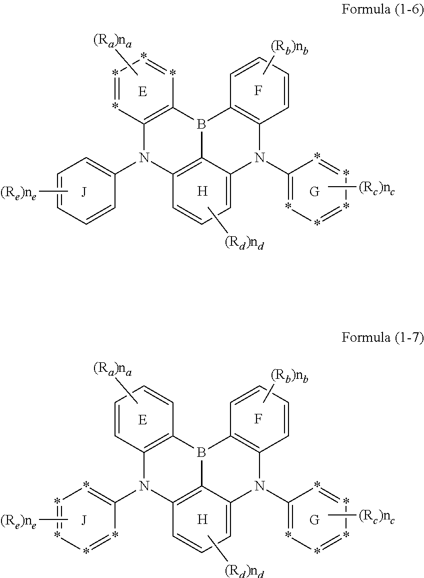

3. The organic compound according to claim 2, wherein in the formula K, the Ar group fused with the ring F is selected from 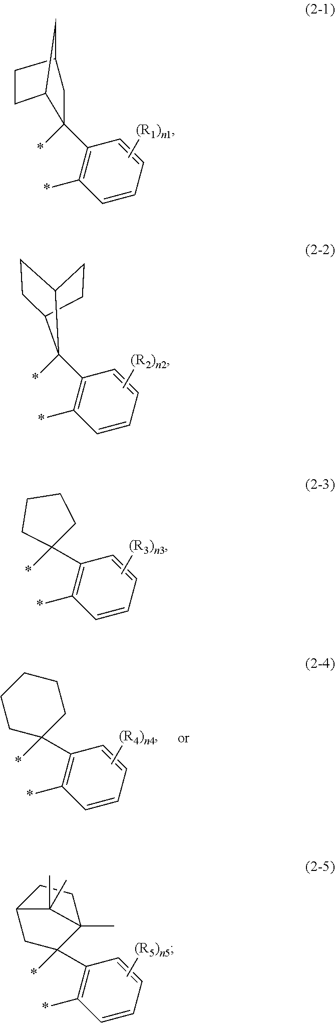
in the formula K, the Ar group fused with the ring G is selected from 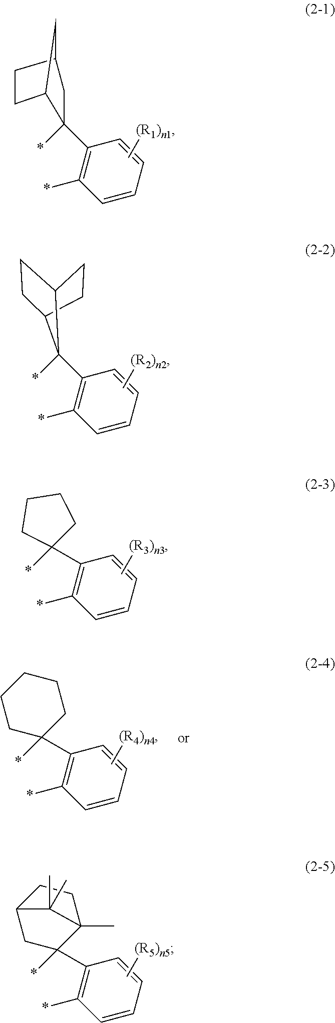
in the formula L, the Ar group fused with the ring E is selected from 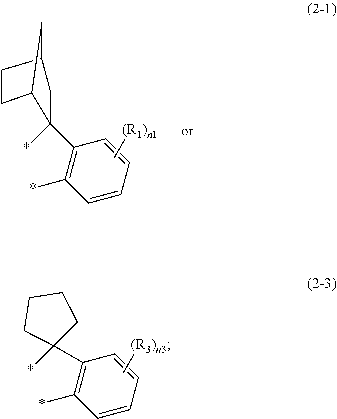
in the formula L, the Ar group fused with the ring F is selected from 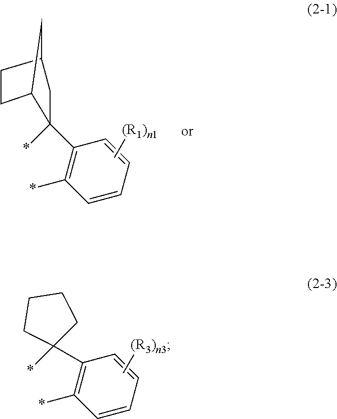
in the formula P, the Ar group fused with the ring E is selected from 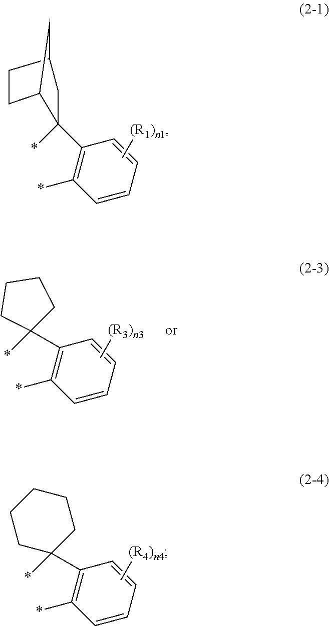
in the formula P, the Ar group fused with the ring G is selected from 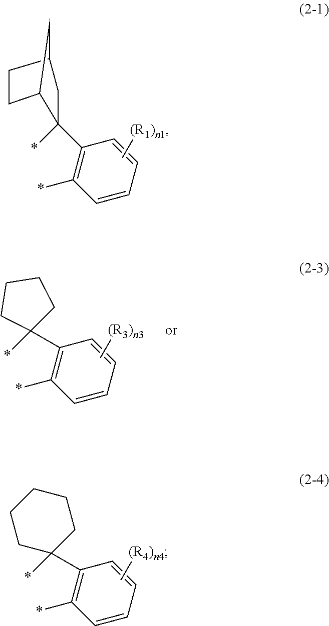
in the formula Q, the Ar group fused with the ring G is selected from 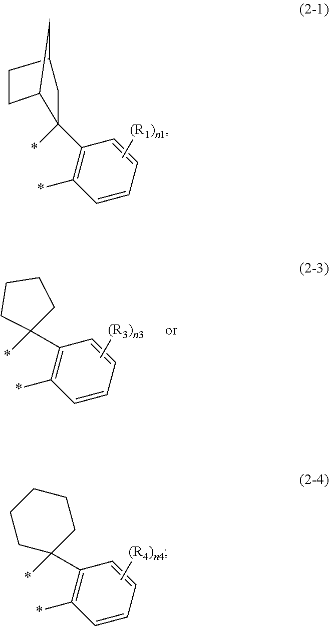
and
in the formula Q, the Ar uoun fused with the ring J is selected from

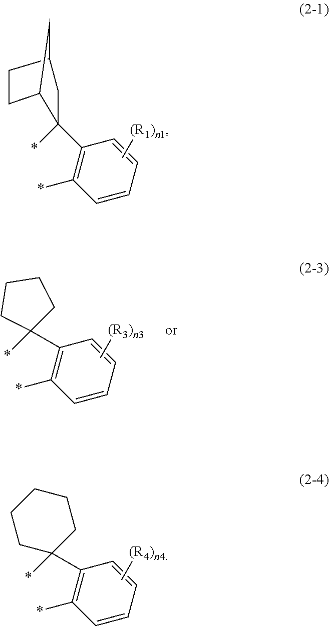

4. The organic compound according to claim 1, wherein the Rₐ, the R_{b}, the R_{c}, the R_{d}, and the Rₑ are the same or different from each other, and are each independently selected from deuterium, a halogen group, cyano, alkyl with 1 to 5 carbon atoms, substituted or unsubstituted aryl with 6 to 15 carbon atoms, substituted or unsubstituted heteroaryl with 5 to 12 carbon atoms, trialkylsilyl with 3 to 6 carbon atoms, and haloalkyl with 1 to 5 carbon atoms;
preferably, sub stituents in the Rₐ, the R_{b}, the R_{c}, the R_{d}, and the Rₑ are the same or different from each other, and are each independently selected from deuterium, a halogen group, cyano, alkyl with 1 to 5 carbon atoms, trialkylsilyl with 3 to 6 carbon atoms or haloalkyl with 1 to 5 carbon atoms; and
preferably, the substituents in the Rₐ, the R_{b}, the R_{c}, the R_{d}, and the Rₑ are the same or different from each other, and are each independently selected from deuterium, a halogen group, cyano or alkyl with 1 to 5 carbon atoms.

5. The organic compound according to claim 1, wherein the Rₐ, the R_{b}, the R_{c}, the R_{d}, and the Rₑ are the same or different from each other, and are each independently selected from deuterium, fluorine, cyano, methyl, ethyl, n-propyl, isopropyl, tert-butyl, trimethylsilyl, trifluoromethyl, substituted or unsubstituted phenyl, substituted or unsubstituted naphthyl, substituted or unsubstituted phenanthryl, and substituted or unsubstituted biphenyl;
preferably, sub stituents in the Rₐ, the R_{b}, the R_{c}, the R_{d}, and the Rₑ are the same or different from each other, and are each independently selected from deuterium, fluorine, cyano, methyl, ethyl, n-propyl, isopropyl, tert-butyl, trimethylsilyl, and trifluoromethyl; and
preferably, the sub stituents in the Rₐ, the R_{b}, the R_{c}, the R_{d}, and the Rₑ are the same or different from each other, and are each independently selected from deuterium, fluorine, cyano, methyl, ethyl, n-propyl, isopropyl, and tert-butyl.

6. The organic compound according to claim 1, wherein the Rₐ, the R_{b}, the R_{c}, the R_{d}, and the Rₑ are the same or different from each other, and are each independently selected from deuterium, cyano, fluorine, alkyl with 1 to 5 carbon atoms, trialkylsilyl with 3 to 6 carbon atoms, haloalkyl with 1 to 5 carbon atoms, and a substituted or unsubstituted group W, wherein the unsubstituted group W is selected from the group consisting of the following groups: 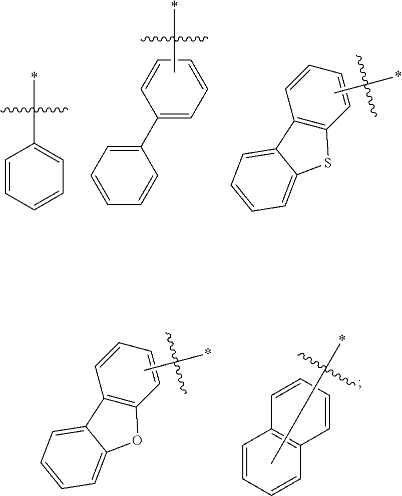
wherein the substituted group W has one or two or more sub stituents each independently selected from deuterium, fluorine, cyano, methyl, ethyl, n-propyl, isopropyl, tert-butyl, trimethylsilyl or trifluoromethyl; and when the number of the substituents of the group W is greater than 1, the substituents are the same or different.

7. The organic compound according to claim 1, wherein the Rₐ, the R_{b}, the R_{c}, the R_{d}, and the Rₑ are the same or different from each other, and are each independently selected from deuterium, cyano, fluorine, methyl, ethyl, n-propyl, isopropyl, tert-butyl, trimethylsilyl, trifluoromethyl or the group consisting of the following groups:

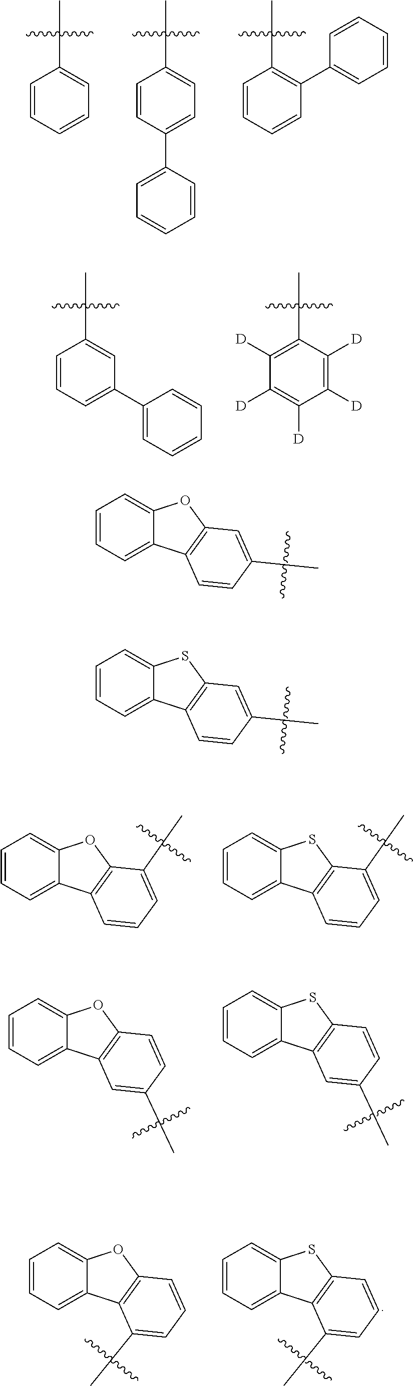

8. The organic compound according to claim 1, wherein the n₁, the n₂, the n₃, the n₄, and the n₅ are all 0.

9. The organic compound according to claim 1, wherein the organic compound is selected from the following compounds:

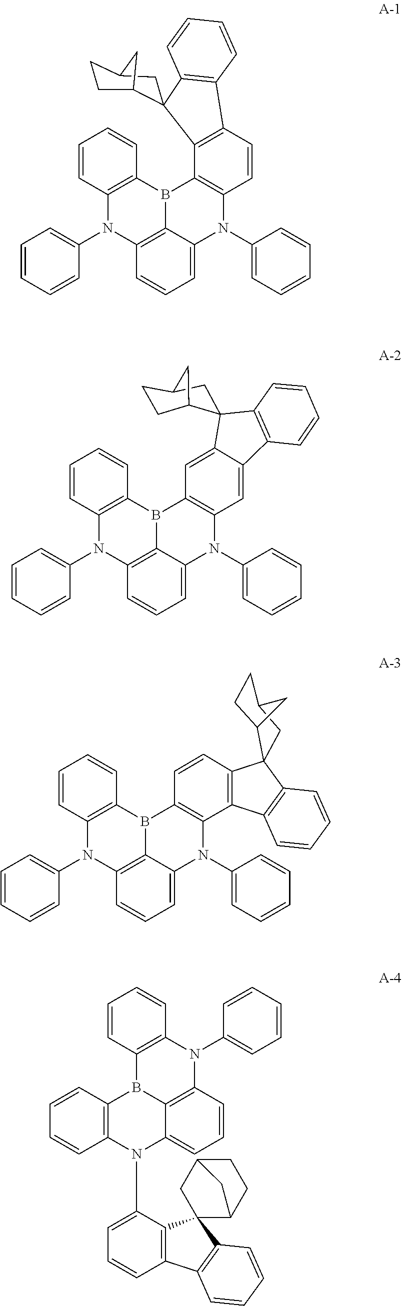 [SMILES: c1ccc(N2c3ccccc3B3c4c2cccc4N(c2ccccc2)c2ccc4c(c23)C2(CC3CCC2C3)c2ccccc2-4)cc1 ; c1ccc(N2c3ccccc3B3c4cc5c(cc4N(c4ccccc4)c4cccc2c43)-c2ccccc2C52CC3CCC2C3)cc1 ; c1ccc(N2c3ccccc3B3c4ccc5c(c4N(c4ccccc4)c4cccc2c43)-c2ccccc2C52CC3CCC2C3)cc1 ; c1ccc(N2c3ccccc3B3c4ccccc4N(c4cccc5c4[C@@]4(CC6CCC4C6)c4ccccc4-5)c4cccc2c43)cc1]

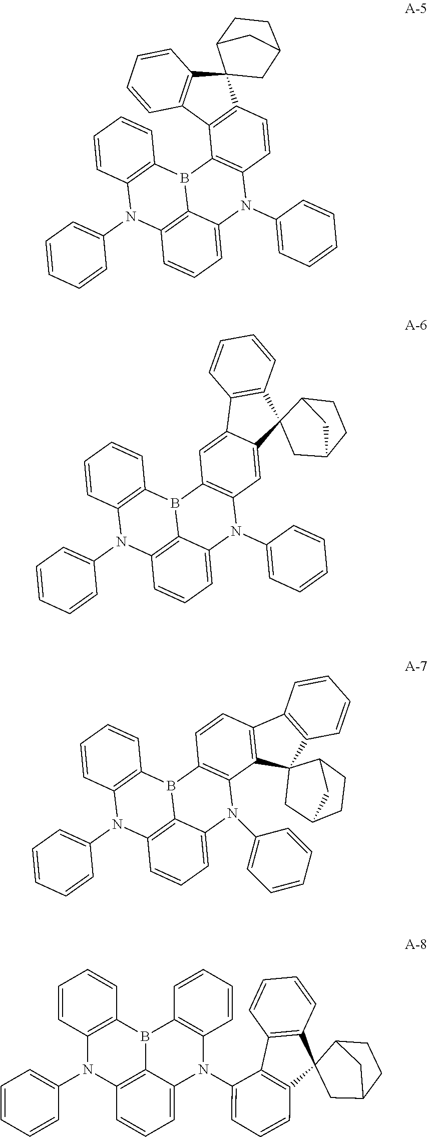 [SMILES: c1ccc(N2c3ccccc3B3c4c2cccc4N(c2ccccc2)c2ccc4c(c23)-c2ccccc2[C@@]42CC3CCC2C3)cc1 ; c1ccc(N2c3ccccc3B3c4cc5c(cc4N(c4ccccc4)c4cccc2c43)[C@@]2(C[C@@H]3CCC2C3)c2ccccc2-5)cc1 ; c1ccc(N2c3ccccc3B3c4ccc5c(c4N(c4ccccc4)c4cccc2c43)[C@@]2(C[C@@H]3CCC2C3)c2ccccc2-5)cc1 ; c1ccc(N2c3ccccc3B3c4ccccc4N(c4cccc5c4-c4ccccc4[C@@]54CC5CCC4C5)c4cccc2c43)cc1]

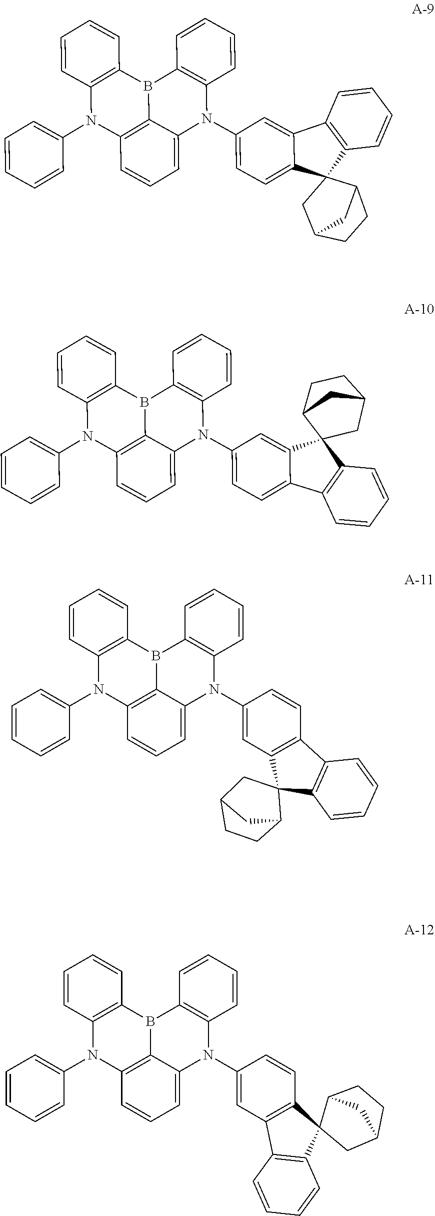 [SMILES: c1ccc(N2c3ccccc3B3c4ccccc4N(c4ccc5c(c4)-c4ccccc4[C@]54C[C@@H]5CCC4C5)c4cccc2c43)cc1 ; c1ccc(N2c3ccccc3B3c4ccccc4N(c4ccc5c(c4)[C@]4(C[C@H]6CC[C@@H]4C6)c4ccccc4-5)c4cccc2c43)cc1 ; c1ccc(N2c3ccccc3B3c4ccccc4N(c4ccc5c(c4)[C@]4(CC6CC[C@H]4C6)c4ccccc4-5)c4cccc2c43)cc1 ; c1ccc(N2c3ccccc3B3c4ccccc4N(c4ccc5c(c4)-c4ccccc4[C@]54C[C@@H]5CC[C@H]4C5)c4cccc2c43)cc1]

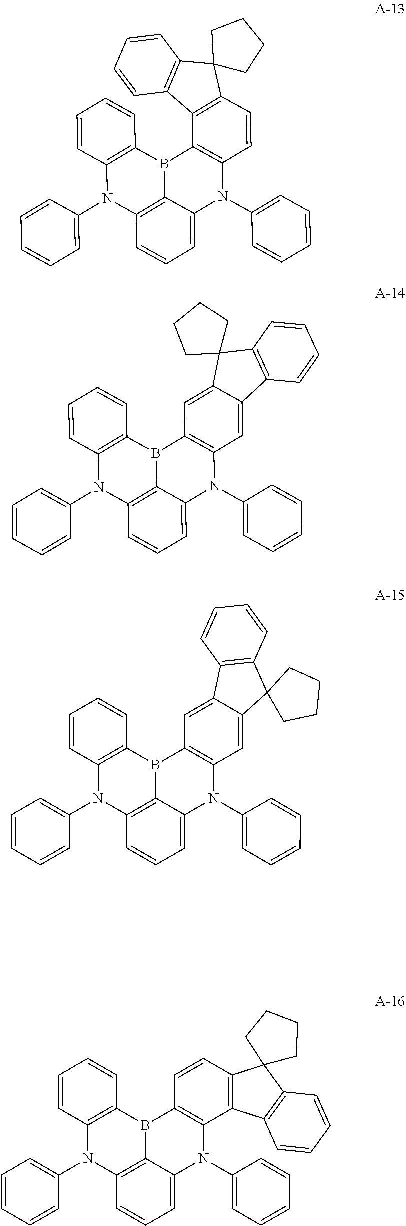 [SMILES: c1ccc(N2c3ccccc3B3c4c2cccc4N(c2ccccc2)c2ccc4c(c23)-c2ccccc2C42CCCC2)cc1 ; c1ccc(N2c3ccccc3B3c4cc5c(cc4N(c4ccccc4)c4cccc2c43)-c2ccccc2C52CCCC2)cc1 ; c1ccc(N2c3ccccc3B3c4cc5c(cc4N(c4ccccc4)c4cccc2c43)C2(CCCC2)c2ccccc2-5)cc1 ; c1ccc(N2c3ccccc3B3c4ccc5c(c4N(c4ccccc4)c4cccc2c43)-c2ccccc2C52CCCC2)cc1]

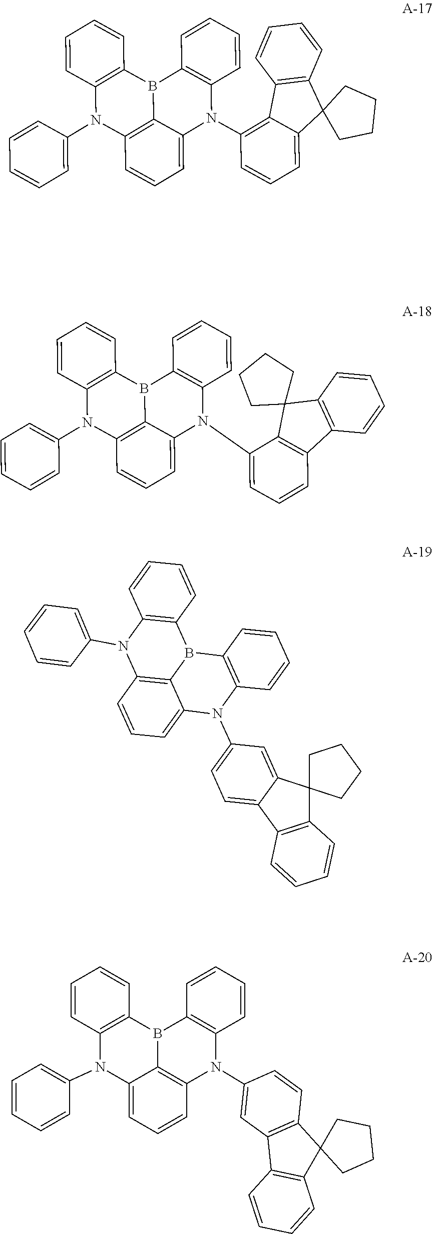 [SMILES: c1ccc(N2c3ccccc3B3c4ccccc4N(c4cccc5c4-c4ccccc4C54CCCC4)c4cccc2c43)cc1 ; c1ccc(N2c3ccccc3B3c4ccccc4N(c4cccc5c4C4(CCCC4)c4ccccc4-5)c4cccc2c43)cc1 ; c1ccc(N2c3ccccc3B3c4ccccc4N(c4ccc5c(c4)C4(CCCC4)c4ccccc4-5)c4cccc2c43)cc1 ; c1ccc(N2c3ccccc3B3c4ccccc4N(c4ccc5c(c4)-c4ccccc4C54CCCC4)c4cccc2c43)cc1]

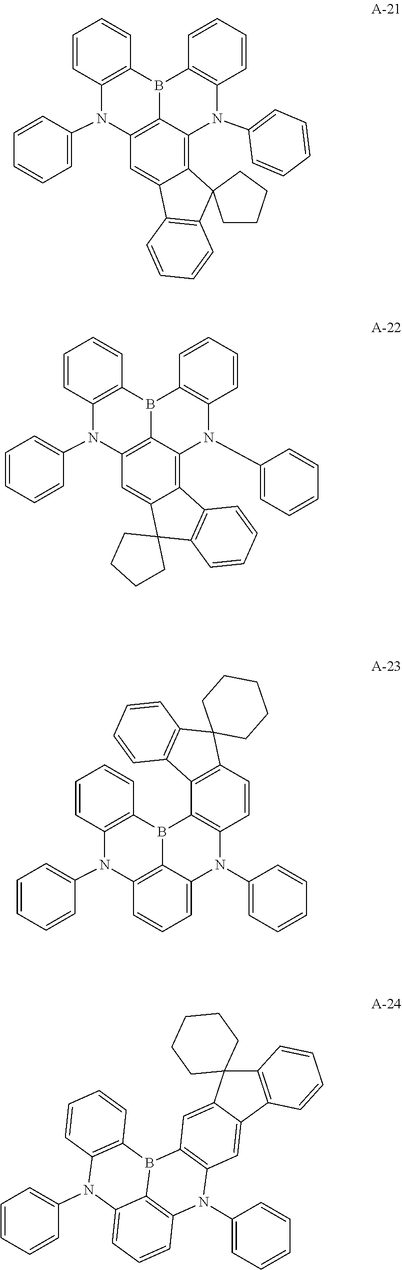 [SMILES: c1ccc(N2c3ccccc3B3c4ccccc4N(c4ccccc4)c4c3c2cc2c4C3(CCCC3)c3ccccc3-2)cc1 ; c1ccc(N2c3ccccc3B3c4ccccc4N(c4ccccc4)c4c3c2cc2c4-c3ccccc3C23CCCC3)cc1 ; c1ccc(N2c3ccccc3B3c4c2cccc4N(c2ccccc2)c2ccc4c(c23)-c2ccccc2C42CCCCC2)cc1 ; c1ccc(N2c3ccccc3B3c4cc5c(cc4N(c4ccccc4)c4cccc2c43)-c2ccccc2C52CCCCC2)cc1]

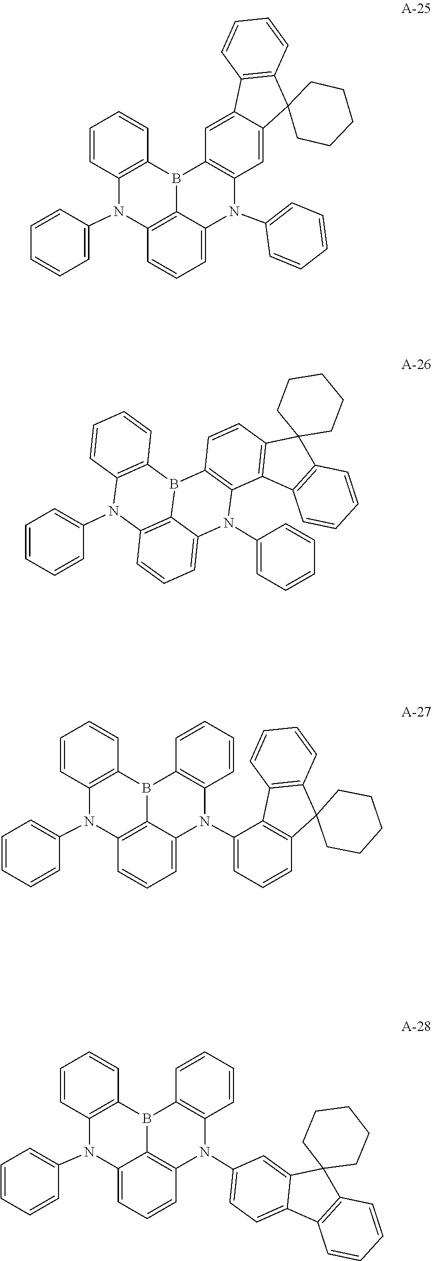 [SMILES: c1ccc(N2c3ccccc3B3c4cc5c(cc4N(c4ccccc4)c4cccc2c43)C2(CCCCC2)c2ccccc2-5)cc1 ; c1ccc(N2c3ccccc3B3c4ccc5c(c4N(c4ccccc4)c4cccc2c43)-c2ccccc2C52CCCCC2)cc1 ; c1ccc(N2c3ccccc3B3c4ccccc4N(c4cccc5c4-c4ccccc4C54CCCCC4)c4cccc2c43)cc1 ; c1ccc(N2c3ccccc3B3c4ccccc4N(c4ccc5c(c4)C4(CCCCC4)c4ccccc4-5)c4cccc2c43)cc1]

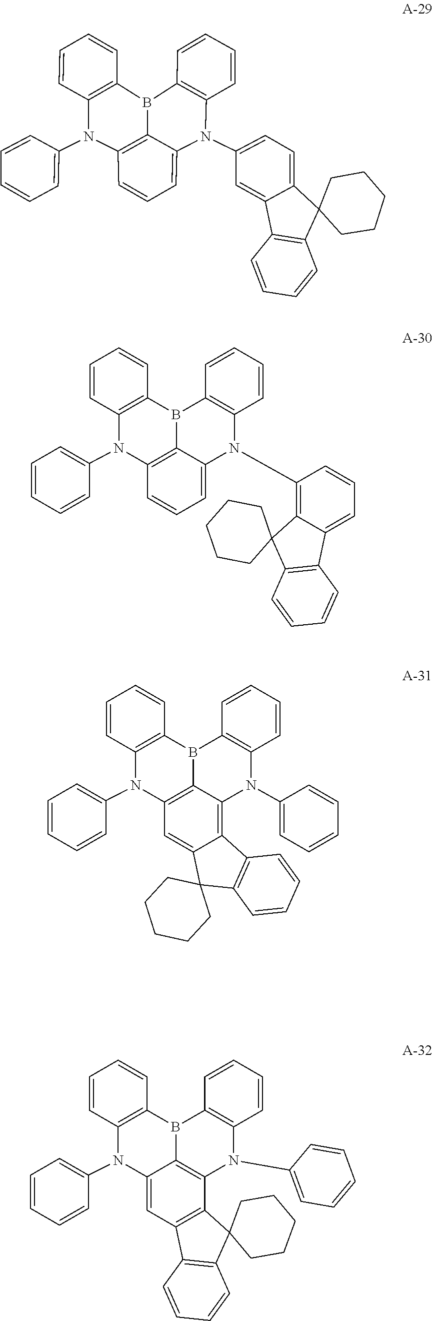 [SMILES: c1ccc(N2c3ccccc3B3c4ccccc4N(c4ccc5c(c4)-c4ccccc4C54CCCCC4)c4cccc2c43)cc1 ; c1ccc(N2c3ccccc3B3c4ccccc4N(c4cccc5c4C4(CCCCC4)c4ccccc4-5)c4cccc2c43)cc1 ; c1ccc(N2c3ccccc3B3c4ccccc4N(c4ccccc4)c4c3c2cc2c4-c3ccccc3C23CCCCC3)cc1 ; c1ccc(N2c3ccccc3B3c4ccccc4N(c4ccccc4)c4c3c2cc2c4C3(CCCCC3)c3ccccc3-2)cc1]

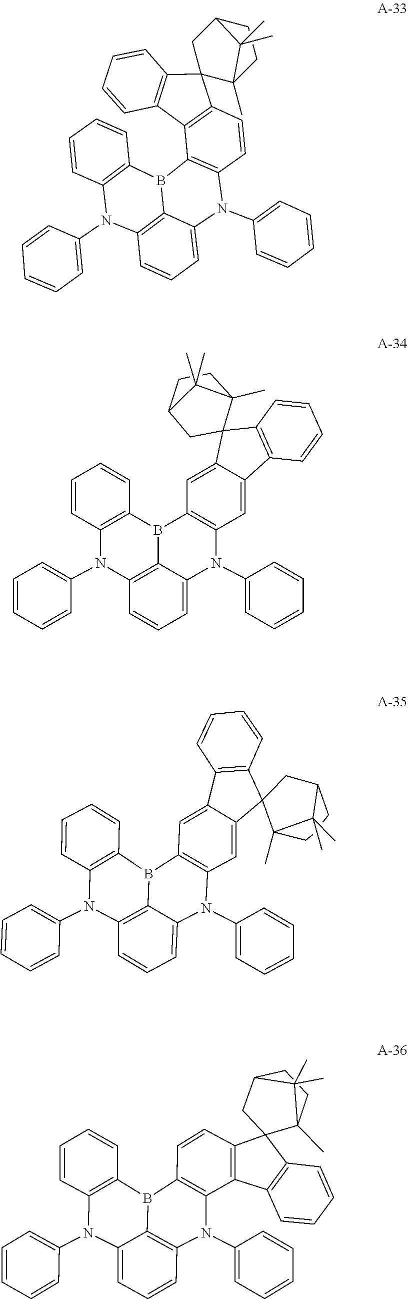 [SMILES: CC1(C)C2CCC1(C)C1(C2)c2ccccc2-c2c1ccc1c2B2c3ccccc3N(c3ccccc3)c3cccc(c32)N1c1ccccc1 ; CCC1CC2(c3ccccc3-c3cc4c(cc32)B2c3ccccc3N(c3ccccc3)c3cccc(c32)N4c2ccccc2)C(C)(CC)C1(C)C ; CCC1CC2(c3ccccc3-c3cc4c(cc32)N(c2ccccc2)c2cccc3c2B4c2ccccc2N3c2ccccc2)C(C)(CC)C1(C)C ; CC1(C)C2CCC1(C)C1(C2)c2ccccc2-c2c1ccc1c2N(c2ccccc2)c2cccc3c2B1c1ccccc1N3c1ccccc1]

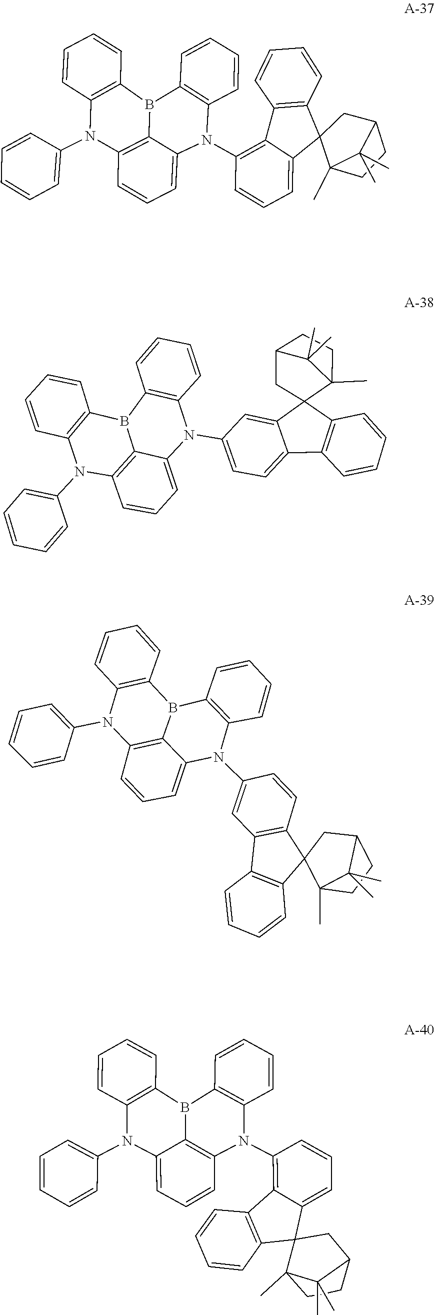 [SMILES: CC1(C)C2CCC1(C)C1(C2)c2ccccc2-c2c(N3c4ccccc4B4c5ccccc5N(c5ccccc5)c5cccc3c54)cccc21 ; CC1(C)C2CCC1(C)C1(C2)c2ccccc2-c2ccc(N3c4ccccc4B4c5ccccc5N(c5ccccc5)c5cccc3c54)cc21 ; CC1(C)C2CCC1(C)C1(C2)c2ccccc2-c2cc(N3c4ccccc4B4c5ccccc5N(c5ccccc5)c5cccc3c54)ccc21 ; CC1(C)C2CCCC1(C)C1(C2)c2ccccc2-c2c(N3c4ccccc4B4c5ccccc5N(c5ccccc5)c5cccc3c54)cccc21]

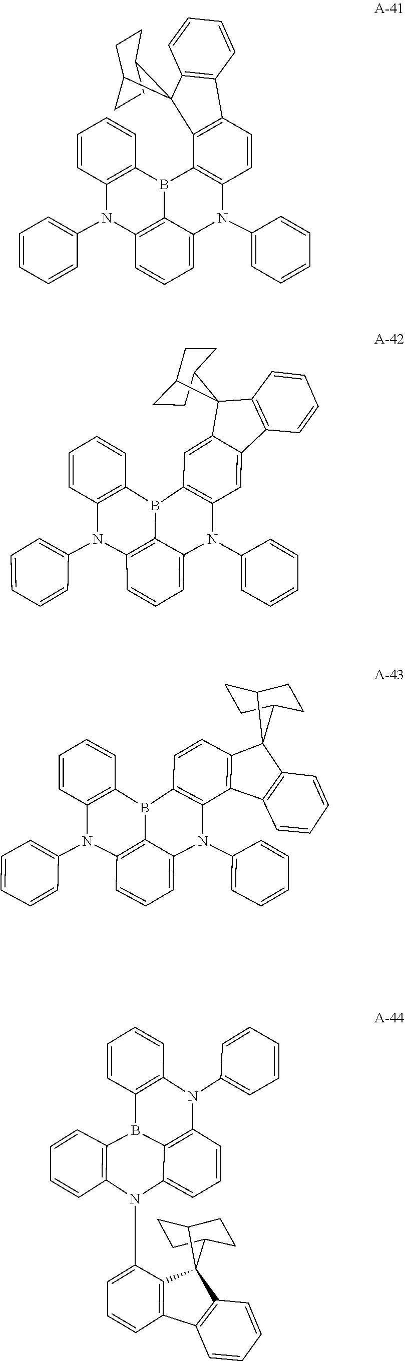

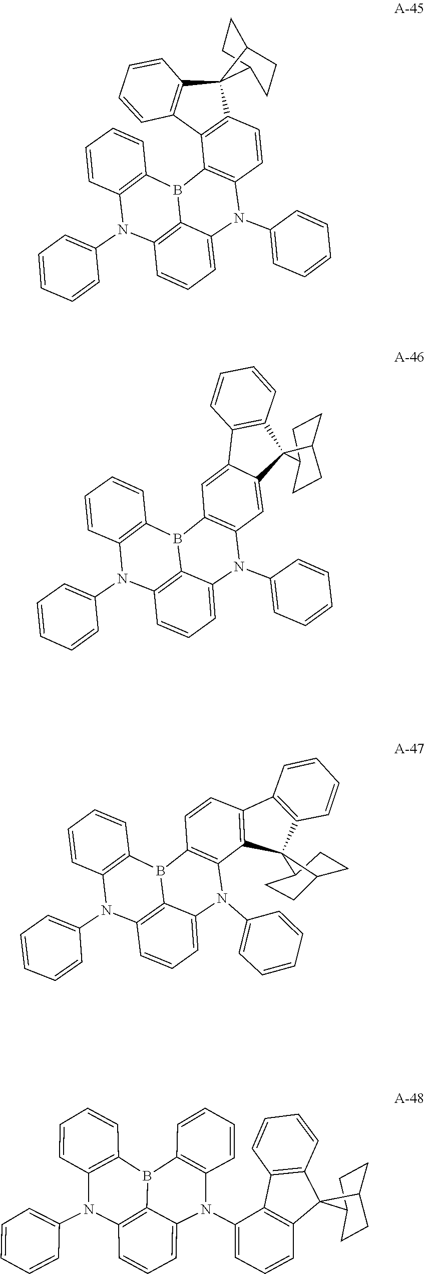

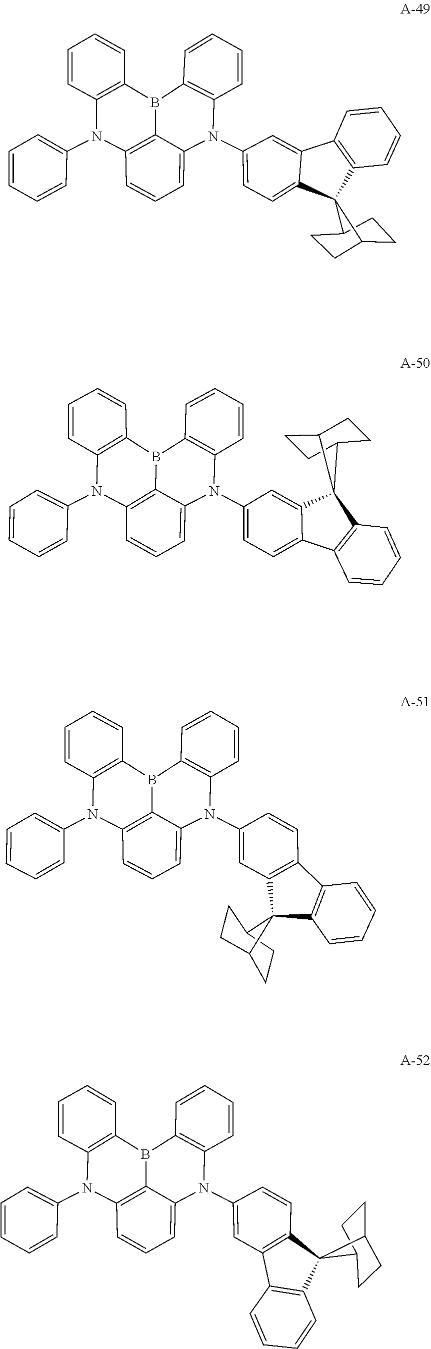

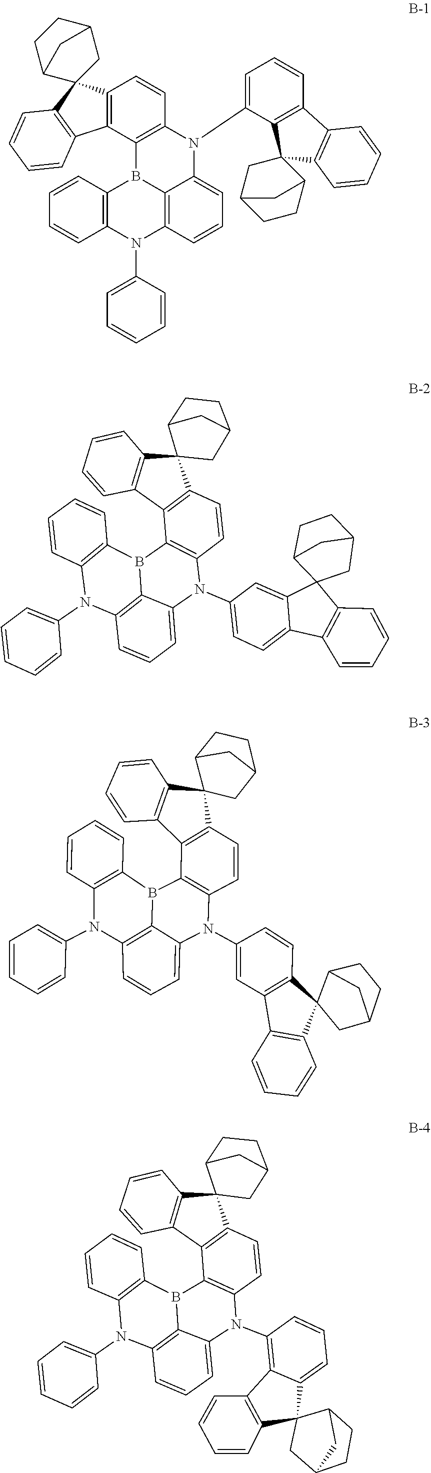 [SMILES: c1ccc(N2c3ccccc3B3c4c2cccc4N(c2cccc4c2[C@@]2(CC5CCC2C5)c2ccccc2-4)c2ccc4c(c23)-c2ccccc2[C@@]42CC3CCC2C3)cc1 ; c1ccc(N2c3ccccc3B3c4c2cccc4N(c2ccc4c(c2)C2(CC5CCC2C5)c2ccccc2-4)c2ccc4c(c23)-c2ccccc2[C@@]42CC3CCC2C3)cc1 ; c1ccc(N2c3ccccc3B3c4c2cccc4N(c2ccc4c(c2)-c2ccccc2[C@]42CC4CCC2C4)c2ccc4c(c23)-c2ccccc2[C@@]42CC3CCC2C3)cc1 ; c1ccc(N2c3ccccc3B3c4c2cccc4N(c2cccc4c2-c2ccccc2[C@@]42C[C@@H]4CCC2C4)c2ccc4c(c23)-c2ccccc2[C@@]42CC3CCC2C3)cc1]

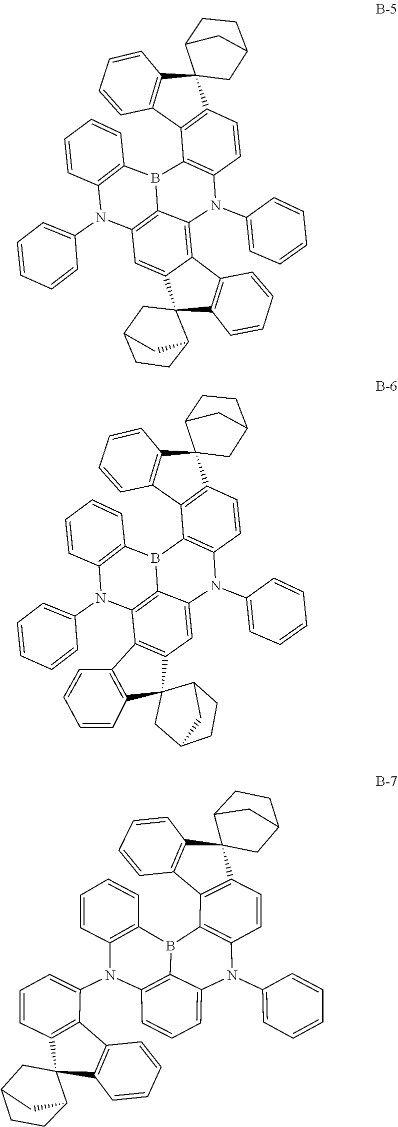

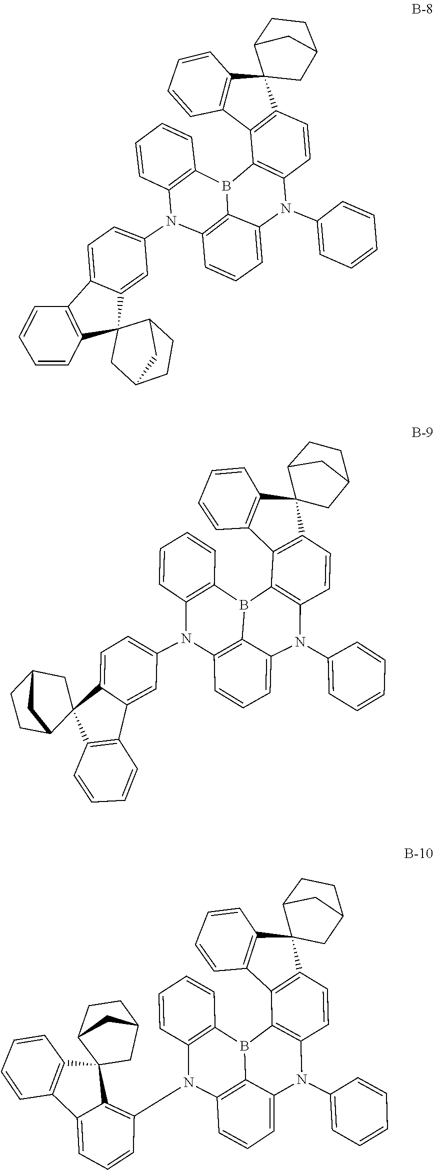 [SMILES: c1ccc(N2c3cccc4c3B(c3ccccc3N4c3ccc4c(c3)[C@]3(C[C@@H]5CCC3C5)c3ccccc3-4)c3c2ccc2c3-c3ccccc3[C@@]23CC2CCC3C2)cc1 ; c1ccc(N2c3cccc4c3B(c3ccccc3N4c3ccc4c(c3)-c3ccccc3[C@]43C[C@H]4CC[C@@H]3C4)c3c2ccc2c3-c3ccccc3[C@@]23CC2CCC3C2)cc1 ; c1ccc(N2c3cccc4c3B(c3ccccc3N4c3cccc4c3[C@@]3(C[C@H]5CC[C@@H]3C5)c3ccccc3-4)c3c2ccc2c3-c3ccccc3[C@@]23CC2CCC3C2)cc1]

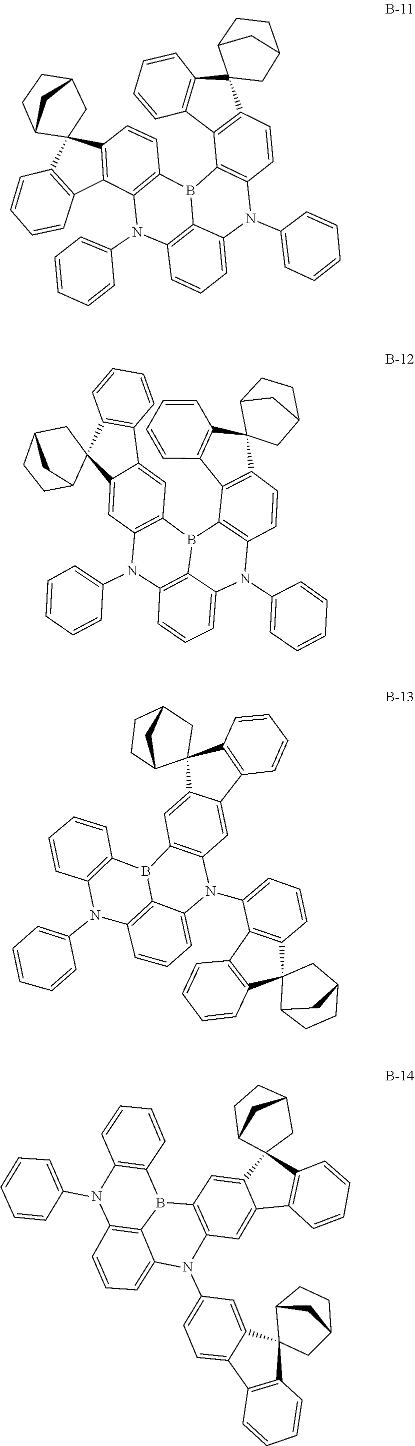

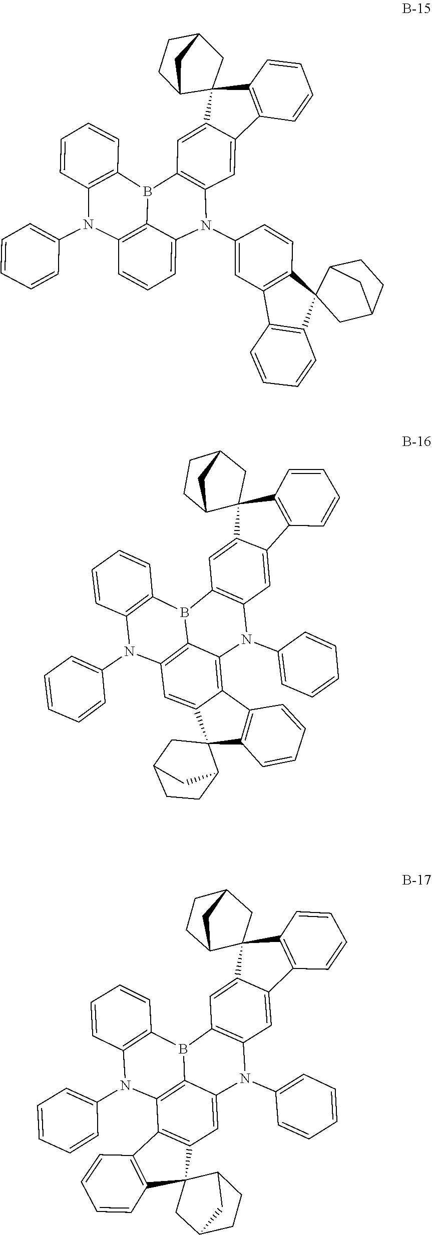 [SMILES: c1ccc(N2c3ccccc3B3c4cc5c(cc4N(c4ccc6c(c4)-c4ccccc4[C@]64CC6CCC4C6)c4cccc2c43)-c2ccccc2[C@@]52C[C@H]3CC[C@@H]2C3)cc1 ; c1ccc(N2c3ccccc3B3c4cc5c(cc4N(c4ccccc4)c4c3c2cc2c4-c3ccccc3[C@@]23CC2CC[C@H]3C2)-c2ccccc2[C@@]52C[C@H]3CC[C@@H]2C3)cc1 ; c1ccc(N2c3cc4c(cc3B3c5ccccc5N(c5ccccc5)c5c3c2cc2c5-c3ccccc3[C@@]23C[C@@H]2CCC3C2)[C@]2(C[C@H]3CC[C@@H]2C3)c2ccccc2-4)cc1]

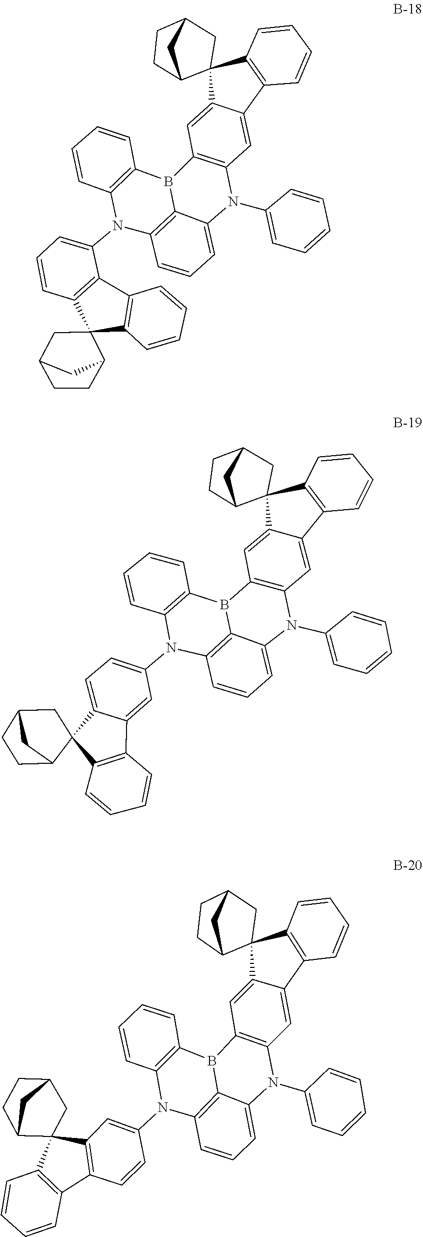 [SMILES: c1ccc(N2c3cc4c(cc3B3c5ccccc5N(c5cccc6c5-c5ccccc5[C@@]65CC6CC[C@H]5C6)c5cccc2c53)[C@]2(C[C@H]3CC[C@@H]2C3)c2ccccc2-4)cc1 ; c1ccc(N2c3cc4c(cc3B3c5ccccc5N(c5ccc6c(c5)-c5ccccc5[C@@]65C[C@H]6CCC5C6)c5cccc2c53)[C@]2(C[C@H]3CC[C@@H]2C3)c2ccccc2-4)cc1 ; c1ccc(N2c3cc4c(cc3B3c5ccccc5N(c5ccc6c(c5)[C@@]5(C[C@H]7CC[C@@H]5C7)c5ccccc5-6)c5cccc2c53)[C@]2(C[C@H]3CC[C@@H]2C3)c2ccccc2-4)cc1]

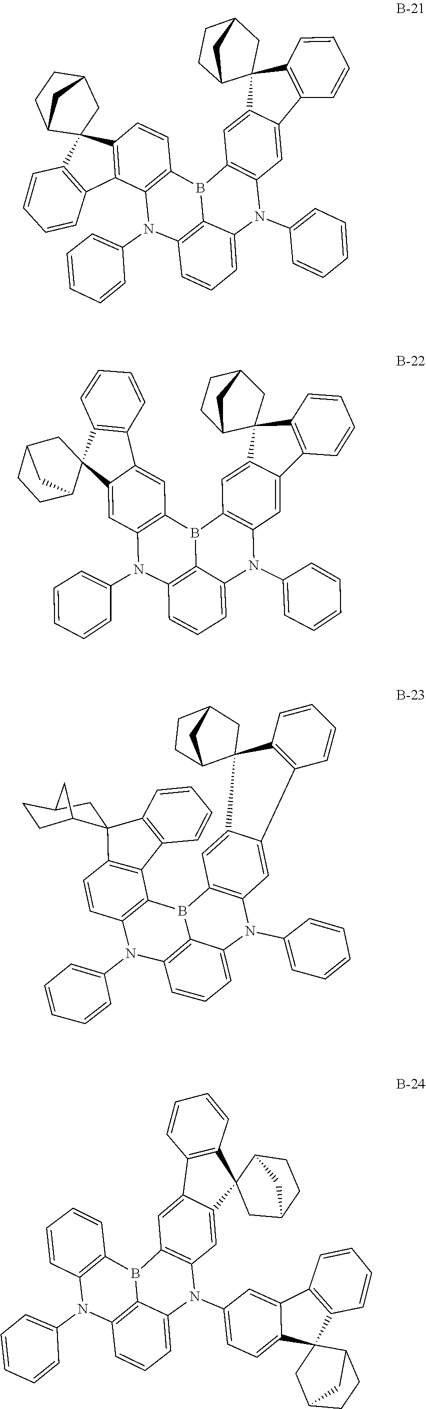 [SMILES: c1ccc(N2c3cc4c(cc3B3c5ccc6c(c5N(c5ccccc5)c5cccc2c53)-c2ccccc2[C@]62C[C@H]3CC[C@@H]2C3)[C@]2(C[C@H]3CC[C@@H]2C3)c2ccccc2-4)cc1 ; c1ccc(N2c3cc4c(cc3B3c5cc6c(cc5N(c5ccccc5)c5cccc2c53)[C@@]2(CC3CC[C@H]2C3)c2ccccc2-6)[C@]2(C[C@H]3CC[C@@H]2C3)c2ccccc2-4)cc1 ; c1ccc(N2c3cc4c(cc3B3c5c2cccc5N(c2ccccc2)c2ccc5c(c23)-c2ccccc2C52CC3CCC2C3)[C@]2(C[C@H]3CC[C@@H]2C3)c2ccccc2-4)cc1 ; c1ccc(N2c3ccccc3B3c4cc5c(cc4N(c4ccc6c(c4)-c4ccccc4[C@]64C[C@@H]6CCC4C6)c4cccc2c43)[C@]2(C[C@@H]3CC[C@H]2C3)c2ccccc2-5)cc1]

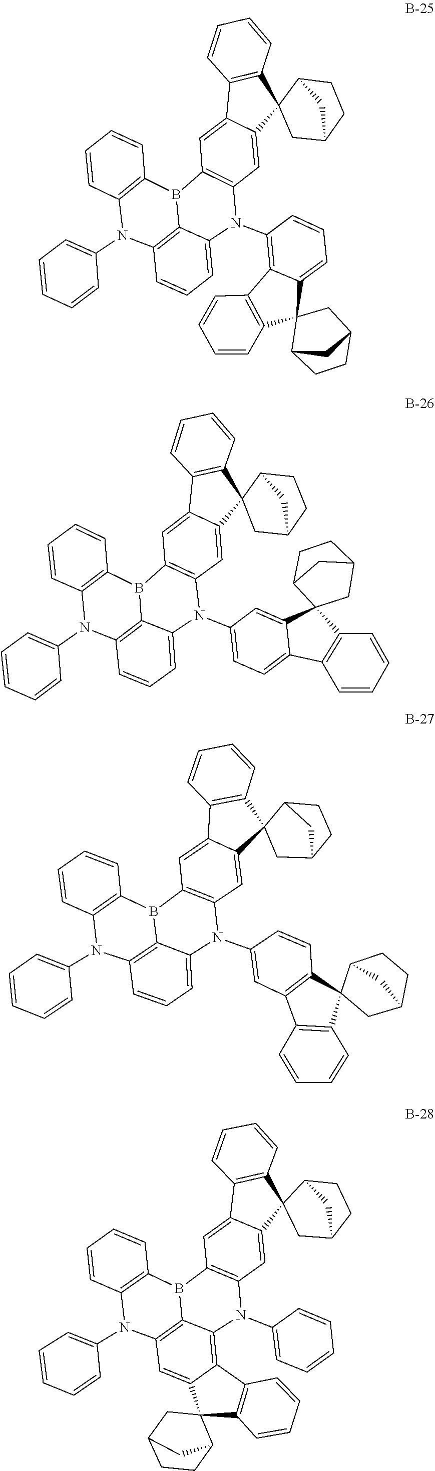 [SMILES: c1ccc(N2c3ccccc3B3c4cc5c(cc4N(c4cccc6c4-c4ccccc4[C@@]64C[C@@H]6CC[C@H]4C6)c4cccc2c43)[C@]2(C[C@@H]3CC[C@H]2C3)c2ccccc2-5)cc1 ; c1ccc(N2c3ccccc3B3c4cc5c(cc4N(c4ccc6c(c4)[C@@]4(CC7CCC4C7)c4ccccc4-6)c4cccc2c43)[C@]2(C[C@@H]3CC[C@H]2C3)c2ccccc2-5)cc1 ; c1ccc(N2c3ccccc3B3c4cc5c(cc4N(c4ccc6c(c4)-c4ccccc4[C@]64C[C@@H]6CC[C@H]4C6)c4cccc2c43)[C@@]2(C[C@@H]3CCC2C3)c2ccccc2-5)cc1 ; c1ccc(N2c3ccccc3B3c4cc5c(cc4N(c4ccccc4)c4c3c2cc2c4-c3ccccc3[C@@]23CC2CC[C@H]3C2)[C@]2(C[C@@H]3CC[C@H]2C3)c2ccccc2-5)cc1]

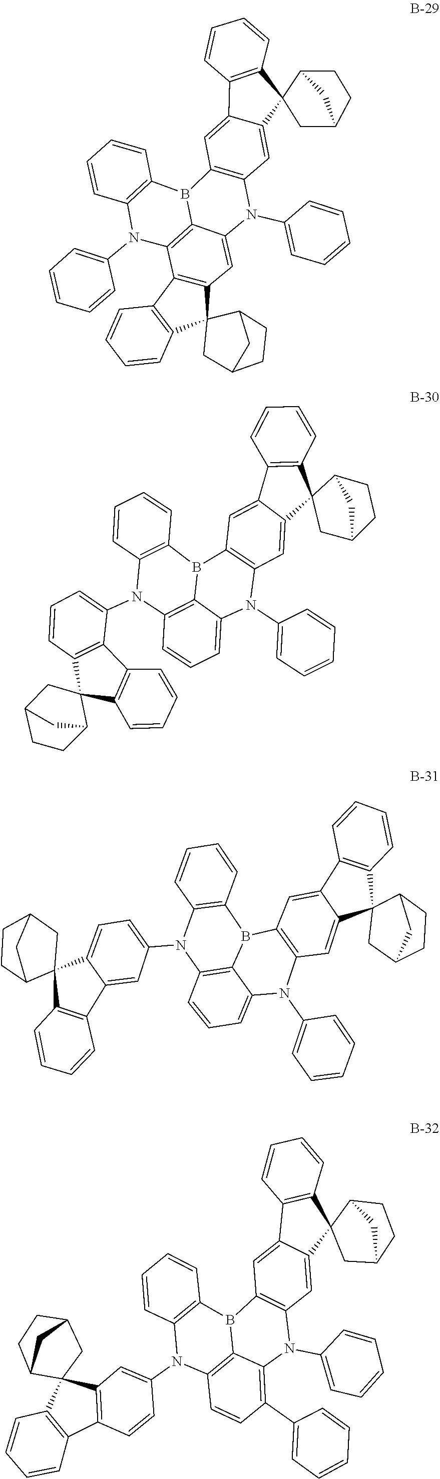

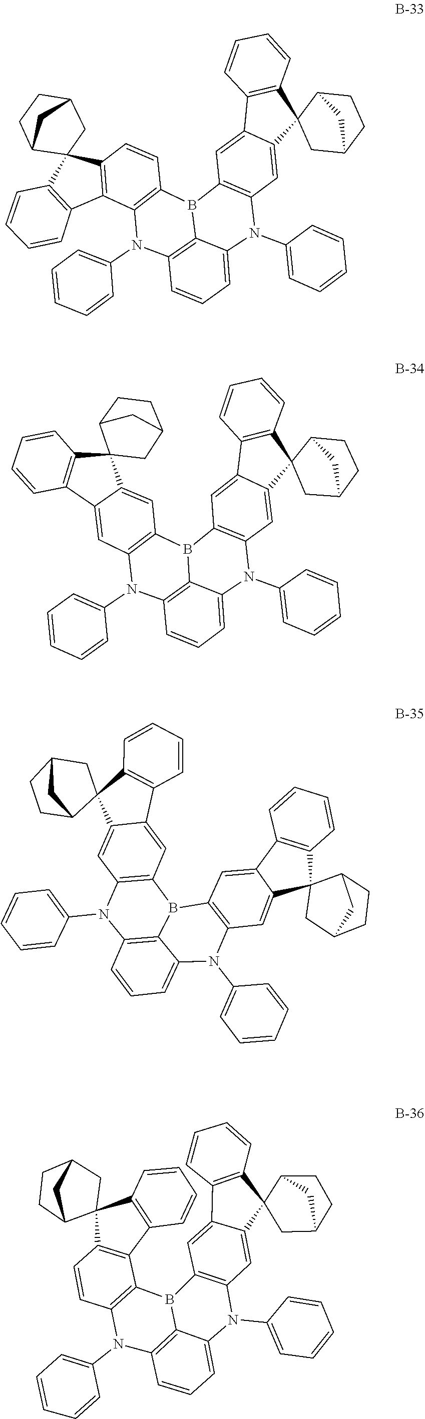 [SMILES: c1ccc(N2c3cc4c(cc3B3c5ccc6c(c5N(c5ccccc5)c5cccc2c53)-c2ccccc2[C@]62C[C@H]3CC[C@@H]2C3)-c2ccccc2[C@@]42C[C@@H]3CC[C@H]2C3)cc1 ; c1ccc(N2c3cc4c(cc3B3c5cc6c(cc5N(c5ccccc5)c5cccc2c53)[C@]2(C[C@@H]3CC[C@H]2C3)c2ccccc2-6)[C@]2(CC3CCC2C3)c2ccccc2-4)cc1 ; c1ccc(N2c3cc4c(cc3B3c5cc6c(cc5N(c5ccccc5)c5cccc2c53)[C@]2(C[C@H]3CC[C@@H]2C3)c2ccccc2-6)-c2ccccc2[C@]42C[C@@H]3CCC2C3)cc1 ; c1ccc(N2c3cc4c(cc3B3c5c2cccc5N(c2ccccc2)c2ccc5c(c23)-c2ccccc2[C@@]52C[C@H]3CC[C@@H]2C3)-c2ccccc2[C@@]42C[C@@H]3CC[C@H]2C3)cc1]

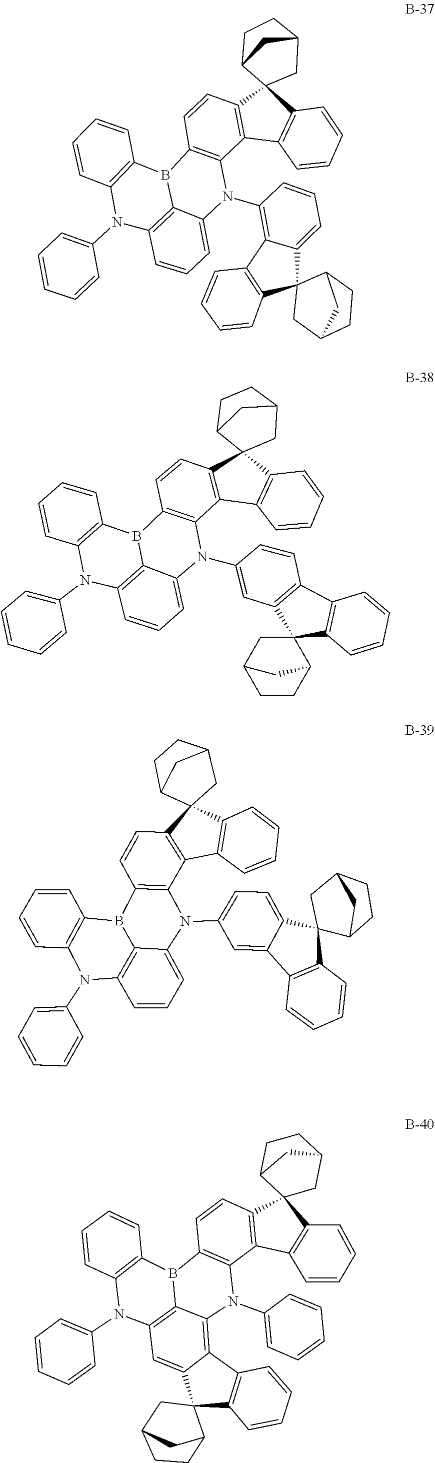 [SMILES: c1ccc(N2c3ccccc3B3c4ccc5c(c4N(c4cccc6c4-c4ccccc4[C@@]64C[C@@H]6CCC4C6)c4cccc2c43)-c2ccccc2[C@@]52C[C@H]3CC[C@@H]2C3)cc1 ; c1ccc(N2c3ccccc3B3c4ccc5c(c4N(c4ccc6c(c4)[C@]4(CC7CC[C@H]4C7)c4ccccc4-6)c4cccc2c43)-c2ccccc2[C@]52CC3CCC2C3)cc1 ; c1ccc(N2c3ccccc3B3c4ccc5c(c4N(c4ccc6c(c4)-c4ccccc4[C@]64C[C@@H]6CCC4C6)c4cccc2c43)-c2ccccc2[C@]52CC3CCC2C3)cc1 ; c1ccc(N2c3ccccc3B3c4ccc5c(c4N(c4ccccc4)c4c3c2cc2c4-c3ccccc3[C@@]23C[C@H]2CCC3C2)-c2ccccc2[C@@]52C[C@@H]3CCC2C3)cc1]

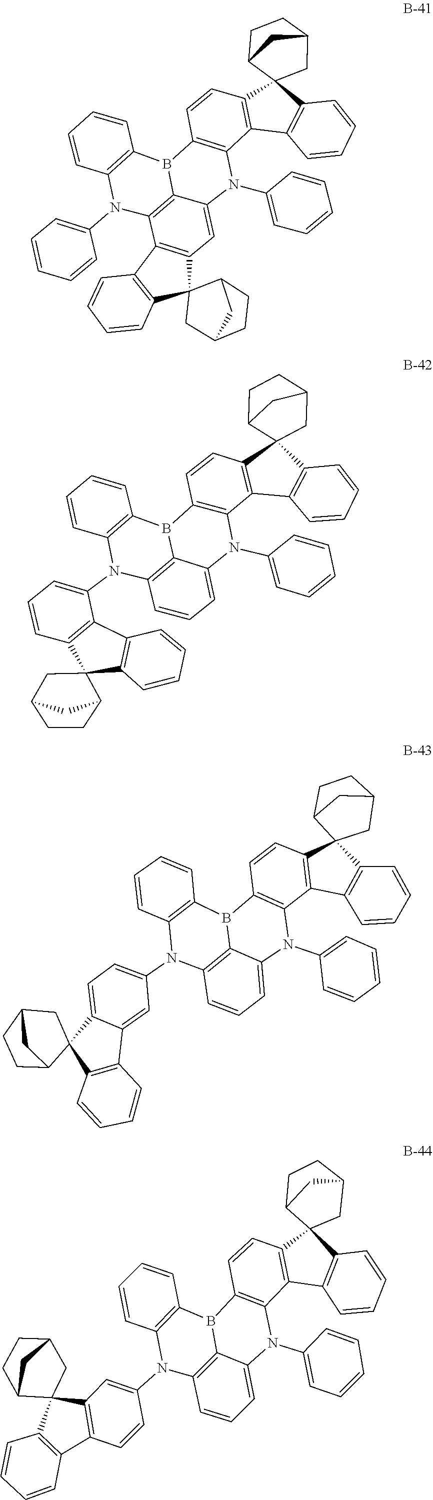

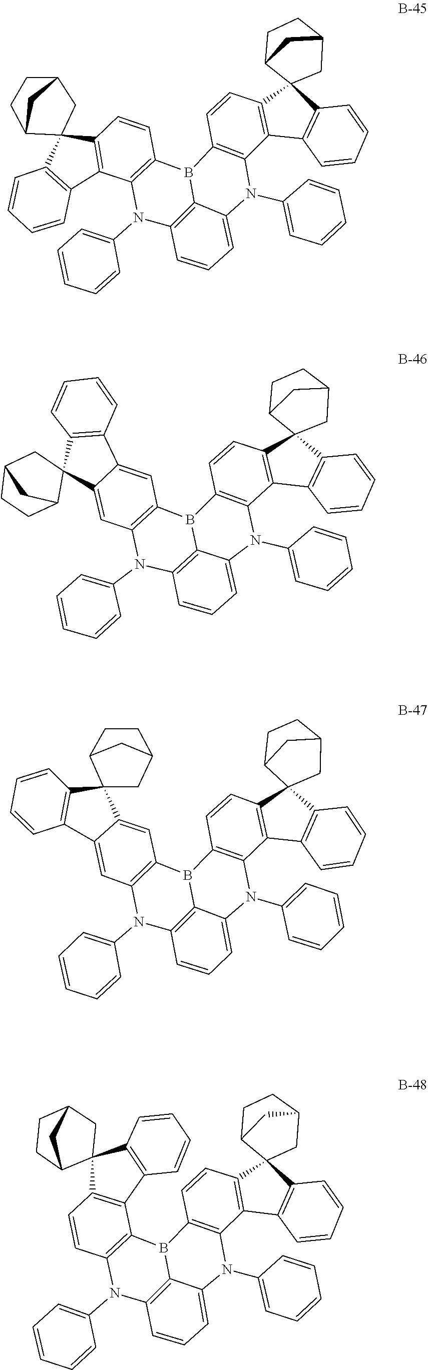 [SMILES: c1ccc(N2c3cccc4c3B(c3ccc5c(c32)-c2ccccc2[C@@]52C[C@H]3CC[C@@H]2C3)c2ccc3c(c2N4c2ccccc2)-c2ccccc2[C@]32C[C@H]3CC[C@@H]2C3)cc1 ; c1ccc(N2c3cc4c(cc3B3c5ccc6c(c5N(c5ccccc5)c5cccc2c53)-c2ccccc2[C@]62CC3CCC2C3)-c2ccccc2[C@]42C[C@H]3CCC2C3)cc1 ; c1ccc(N2c3cc4c(cc3B3c5ccc6c(c5N(c5ccccc5)c5cccc2c53)-c2ccccc2[C@]62CC3CCC2C3)[C@]2(CC3CCC2C3)c2ccccc2-4)cc1 ; c1ccc(N2c3cccc4c3B(c3ccc5c(c3N4c3ccccc3)-c3ccccc3[C@@]53C[C@@H]4CCC3C4)c3c2ccc2c3-c3ccccc3[C@@]23C[C@H]2CC[C@@H]3C2)cc1]

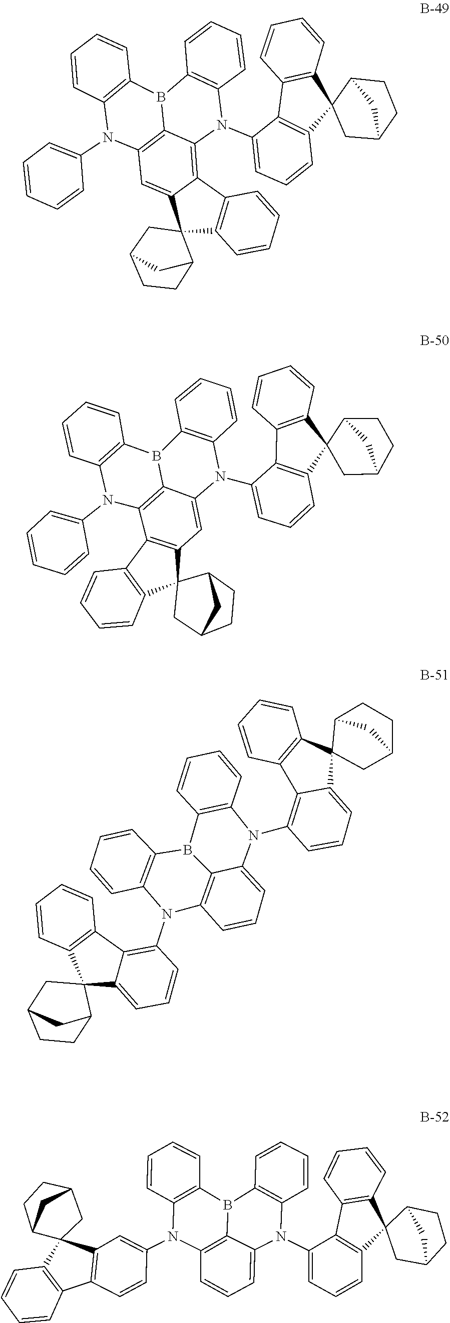

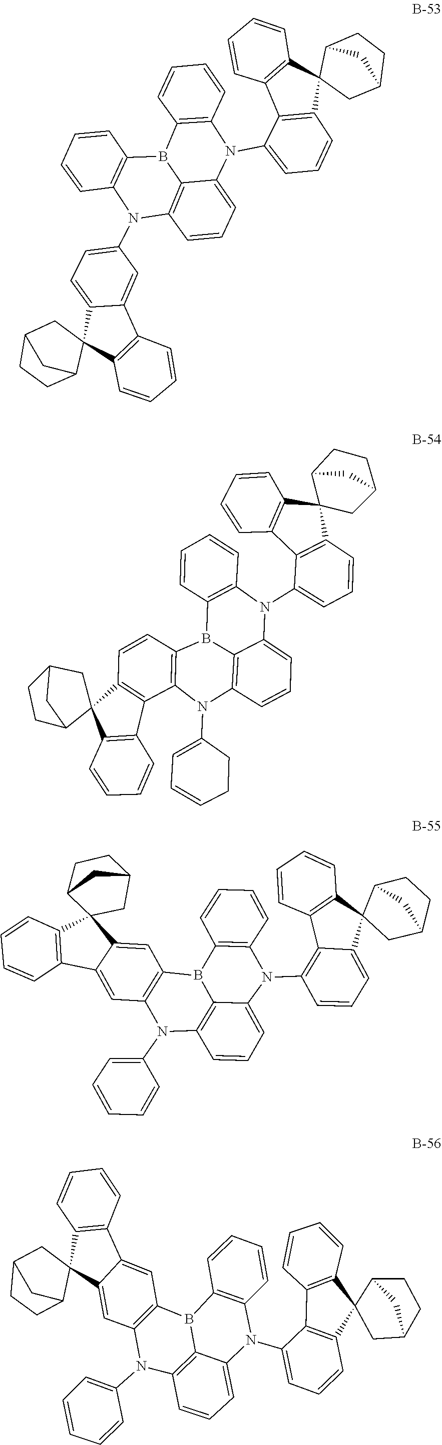 [SMILES: c1ccc2c(c1)B1c3ccccc3N(c3cccc4c3-c3ccccc3[C@@]43C[C@@H]4CC[C@H]3C4)c3cccc(c31)N2c1ccc2c(c1)-c1ccccc1[C@@]21CC2CCC1C2 ; C1=CCCC(N2c3cccc4c3B(c3ccccc3N4c3cccc4c3-c3ccccc3[C@@]43C[C@@H]4CC[C@H]3C4)c3ccc4c(c32)-c2ccccc2[C@@]42CC3CCC2C3)=C1 ; c1ccc(N2c3cc4c(cc3B3c5ccccc5N(c5cccc6c5-c5ccccc5[C@@]65C[C@@H]6CC[C@H]5C6)c5cccc2c53)[C@@]2(C[C@H]3CC[C@@H]2C3)c2ccccc2-4)cc1 ; c1ccc(N2c3cc4c(cc3B3c5ccccc5N(c5cccc6c5-c5ccccc5[C@@]65C[C@@H]6CC[C@H]5C6)c5cccc2c53)-c2ccccc2[C@]42CC3CCC2C3)cc1]

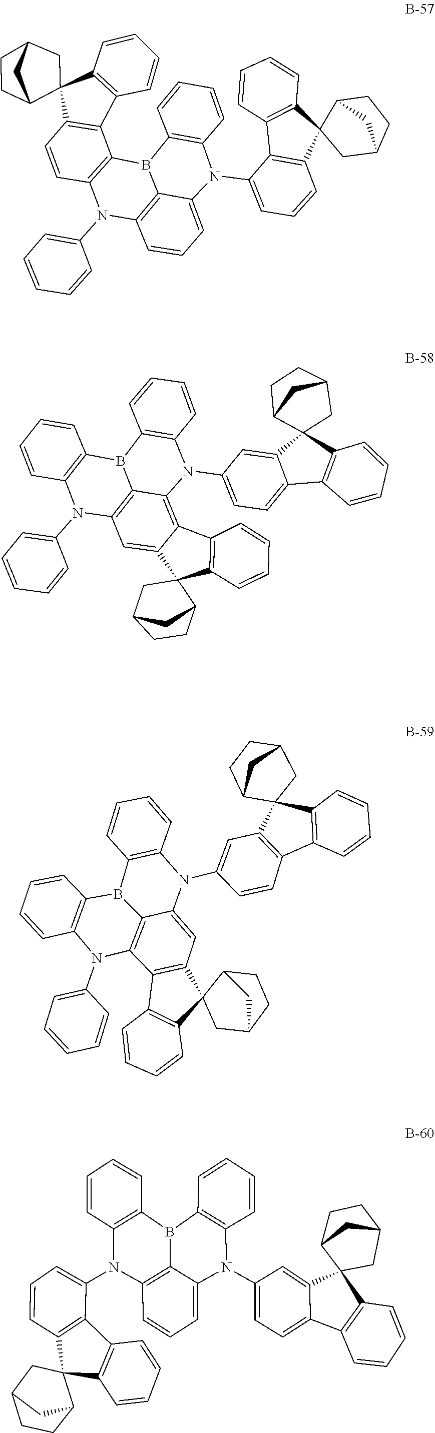 [SMILES: c1ccc(N2c3cccc4c3B(c3ccccc3N4c3cccc4c3-c3ccccc3[C@@]43C[C@@H]4CC[C@H]3C4)c3c2ccc2c3-c3ccccc3[C@@]23C[C@H]2CC[C@@H]3C2)cc1 ; c1ccc(N2c3ccccc3B3c4ccccc4N(c4ccc5c(c4)[C@]4(C[C@H]6CC[C@@H]4C6)c4ccccc4-5)c4c3c2cc2c4-c3ccccc3[C@@]23C[C@H]2CC[C@@H]3C2)cc1 ; c1ccc(N2c3ccccc3B3c4ccccc4N(c4ccc5c(c4)[C@]4(C[C@H]6CC[C@@H]4C6)c4ccccc4-5)c4cc5c(c2c43)-c2ccccc2[C@@]52C[C@@H]3CCC2C3)cc1 ; c1ccc2c(c1)B1c3ccccc3N(c3cccc4c3-c3ccccc3[C@@]43CC4CC[C@H]3C4)c3cccc(c31)N2c1ccc2c(c1)[C@]1(C[C@H]3CC[C@@H]1C3)c1ccccc1-2]

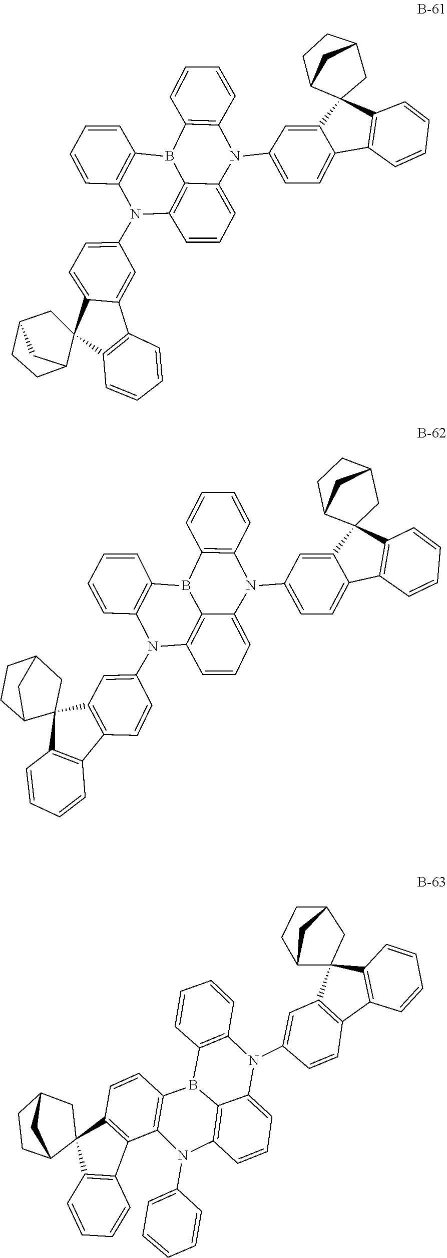 [SMILES: c1ccc2c(c1)B1c3ccccc3N(c3ccc4c(c3)[C@]3(C[C@H]5CC[C@@H]3C5)c3ccccc3-4)c3cccc(c31)N2c1ccc2c(c1)-c1ccccc1[C@]21C[C@@H]2CCC1C2 ; c1ccc2c(c1)B1c3ccccc3N(c3ccc4c(c3)[C@]3(C[C@H]5CC[C@@H]3C5)c3ccccc3-4)c3cccc(c31)N2c1ccc2c(c1)[C@]1(CC3CCC1C3)c1ccccc1-2 ; c1ccc(N2c3cccc4c3B(c3ccccc3N4c3ccc4c(c3)[C@]3(C[C@H]5CC[C@@H]3C5)c3ccccc3-4)c3ccc4c(c32)-c2ccccc2[C@]42C[C@H]3CC[C@@H]2C3)cc1]

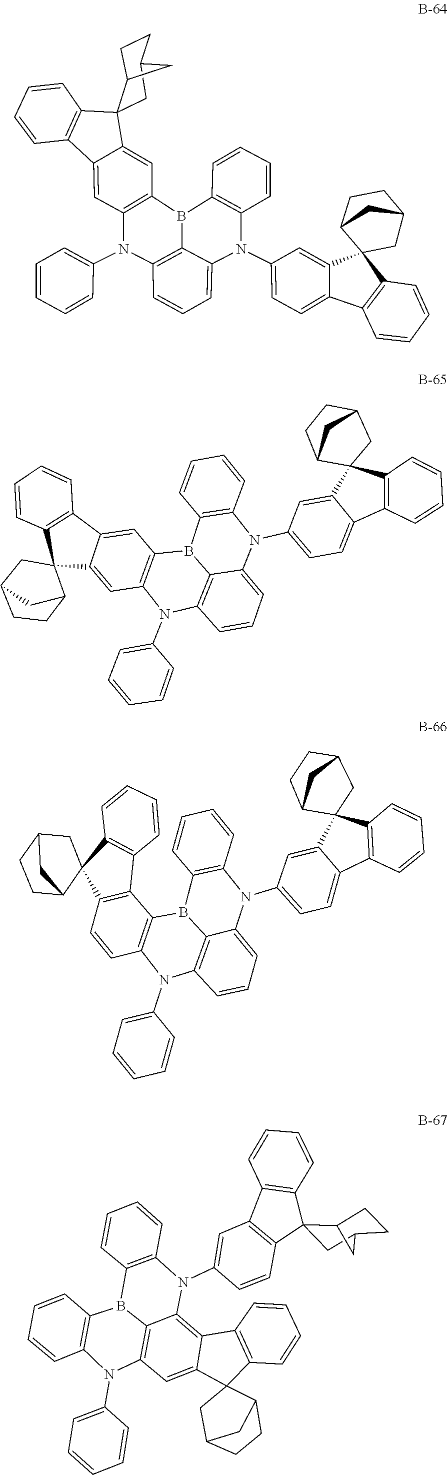 [SMILES: c1ccc(N2c3cc4c(cc3B3c5ccccc5N(c5ccc6c(c5)[C@]5(C[C@H]7CC[C@@H]5C7)c5ccccc5-6)c5cccc2c53)C2(CC3CCC2C3)c2ccccc2-4)cc1 ; c1ccc(N2c3cc4c(cc3B3c5ccccc5N(c5ccc6c(c5)[C@]5(C[C@H]7CC[C@@H]5C7)c5ccccc5-6)c5cccc2c53)-c2ccccc2[C@@]42C[C@@H]3CCC2C3)cc1 ; c1ccc(N2c3cccc4c3B(c3ccccc3N4c3ccc4c(c3)[C@]3(C[C@H]5CC[C@@H]3C5)c3ccccc3-4)c3c2ccc2c3-c3ccccc3[C@@]23CC2CC[C@@H]3C2)cc1 ; c1ccc(N2c3ccccc3B3c4ccccc4N(c4ccc5c(c4)-c4ccccc4C54CC5CCC4C5)c4c3c2cc2c4-c3ccccc3C23CC2CCC3C2)cc1]

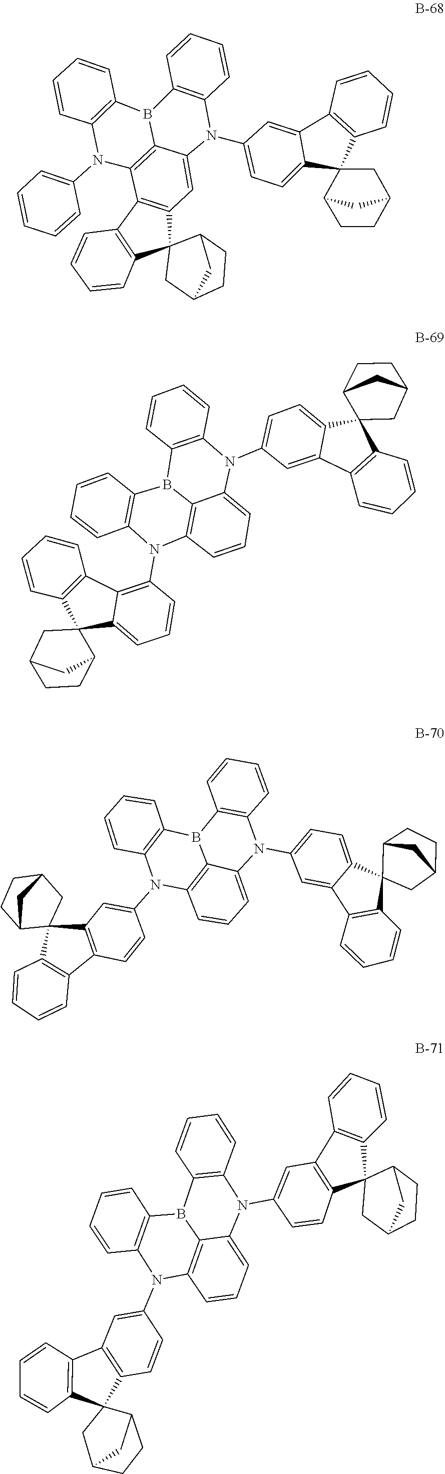 [SMILES: c1ccc(N2c3ccccc3B3c4ccccc4N(c4ccc5c(c4)-c4ccccc4[C@@]54C[C@H]5CC[C@@H]4C5)c4cc5c(c2c43)-c2ccccc2[C@@]52C[C@@H]3CCC2C3)cc1 ; c1ccc2c(c1)B1c3ccccc3N(c3cccc4c3-c3ccccc3[C@]43CC4CC[C@H]3C4)c3cccc(c31)N2c1ccc2c(c1)-c1ccccc1[C@@]21C[C@H]2CC[C@@H]1C2 ; c1ccc2c(c1)B1c3ccccc3N(c3ccc4c(c3)[C@@]3(C[C@H]5CC[C@@H]3C5)c3ccccc3-4)c3cccc(c31)N2c1ccc2c(c1)-c1ccccc1[C@@]21C[C@H]2CC[C@@H]1C2 ; c1ccc2c(c1)B1c3ccccc3N(c3ccc4c(c3)-c3ccccc3[C@]43C[C@@H]4CCC3C4)c3cccc(c31)N2c1ccc2c(c1)-c1ccccc1[C@@]21C[C@@H]2CCC1C2]

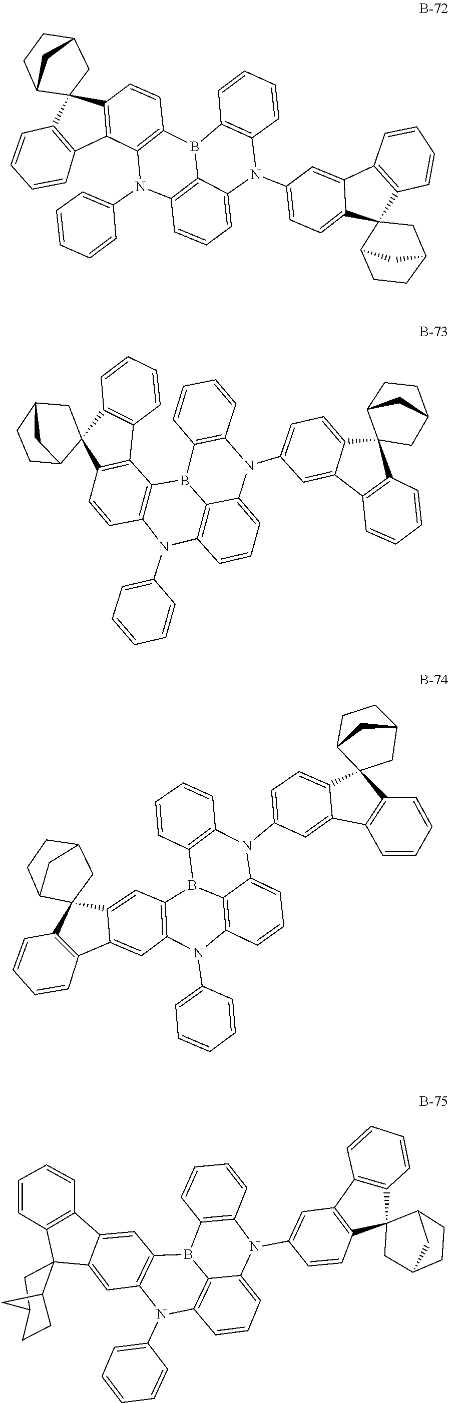 [SMILES: c1ccc(N2c3cccc4c3B(c3ccccc3N4c3ccc4c(c3)-c3ccccc3[C@@]43C[C@H]4CC[C@@H]3C4)c3ccc4c(c32)-c2ccccc2[C@]42C[C@H]3CC[C@@H]2C3)cc1 ; c1ccc(N2c3cccc4c3B(c3ccccc3N4c3ccc4c(c3)-c3ccccc3[C@@]43C[C@H]4CC[C@@H]3C4)c3c2ccc2c3-c3ccccc3[C@]23C[C@H]2CCC3C2)cc1 ; c1ccc(N2c3cc4c(cc3B3c5ccccc5N(c5ccc6c(c5)-c5ccccc5[C@@]65C[C@H]6CC[C@@H]5C6)c5cccc2c53)[C@]2(CC3CCC2C3)c2ccccc2-4)cc1 ; c1ccc(N2c3cc4c(cc3B3c5ccccc5N(c5ccc6c(c5)-c5ccccc5[C@]65C[C@@H]6CCC5C6)c5cccc2c53)-c2ccccc2C42CC3CCC2C3)cc1]

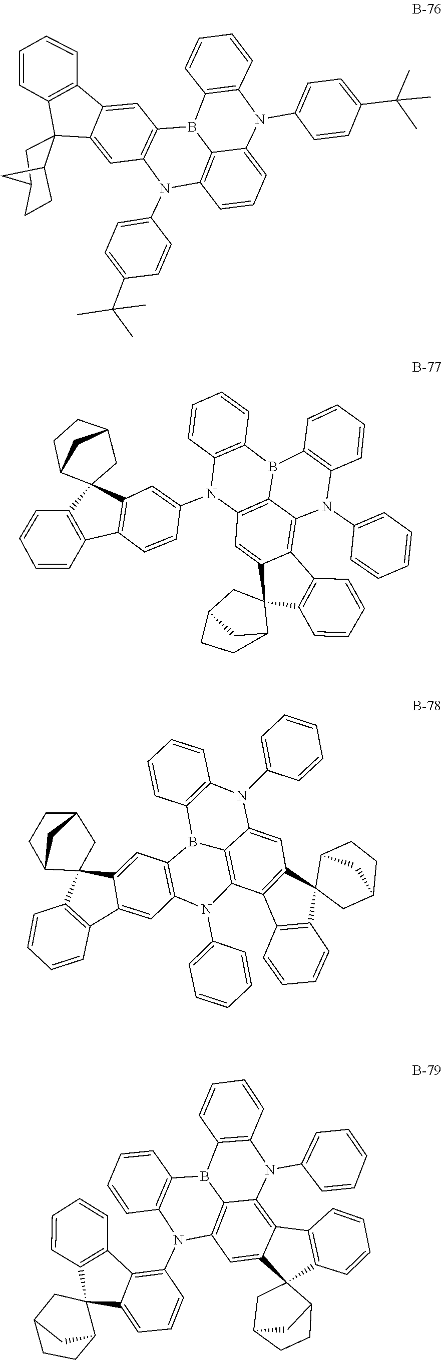 [SMILES: CC(C)(C)c1ccc(N2c3ccccc3B3c4cc5c(cc4N(c4ccc(C(C)(C)C)cc4)c4cccc2c43)C2(CC3CCC2C3)c2ccccc2-5)cc1 ; c1ccc(N2c3ccccc3B3c4ccccc4N(c4ccc5c(c4)[C@@]4(C[C@H]6CC[C@@H]4C6)c4ccccc4-5)c4cc5c(c2c43)-c2ccccc2[C@]52C[C@@H]3CCC2C3)cc1 ; c1ccc(N2c3ccccc3B3c4cc5c(cc4N(c4ccccc4)c4c3c2cc2c4-c3ccccc3[C@]23C[C@@H]2CC[C@H]3C2)-c2ccccc2[C@]52C[C@H]3CC[C@@H]2C3)cc1 ; c1ccc(N2c3ccccc3B3c4ccccc4N(c4cccc5c4-c4ccccc4[C@]54CC5CC[C@H]4C5)c4cc5c(c2c43)-c2ccccc2[C@]52C[C@@H]3CCC2C3)cc1]

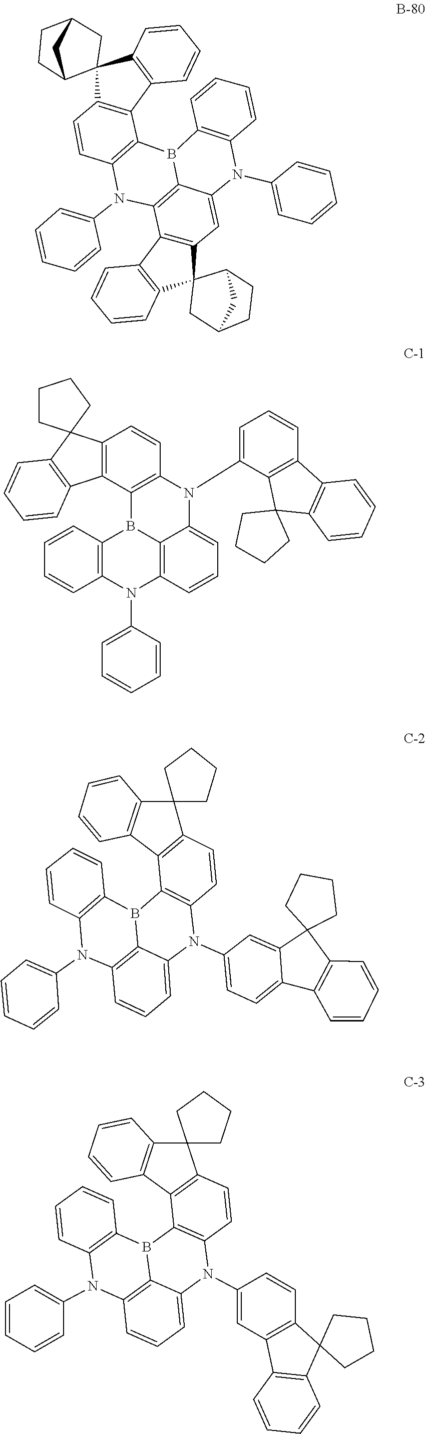 [SMILES: c1ccc(N2c3ccccc3B3c4c(ccc5c4-c4ccccc4[C@@]54C[C@H]5CC[C@@H]4C5)N(c4ccccc4)c4c3c2cc2c4-c3ccccc3[C@]23C[C@@H]2CC[C@H]3C2)cc1 ; c1ccc(N2c3ccccc3B3c4c2cccc4N(c2cccc4c2C2(CCCC2)c2ccccc2-4)c2ccc4c(c23)-c2ccccc2C42CCCC2)cc1 ; c1ccc(N2c3ccccc3B3c4c2cccc4N(c2ccc4c(c2)C2(CCCC2)c2ccccc2-4)c2ccc4c(c23)-c2ccccc2C42CCCC2)cc1 ; c1ccc(N2c3ccccc3B3c4c2cccc4N(c2ccc4c(c2)-c2ccccc2C42CCCC2)c2ccc4c(c23)-c2ccccc2C42CCCC2)cc1]

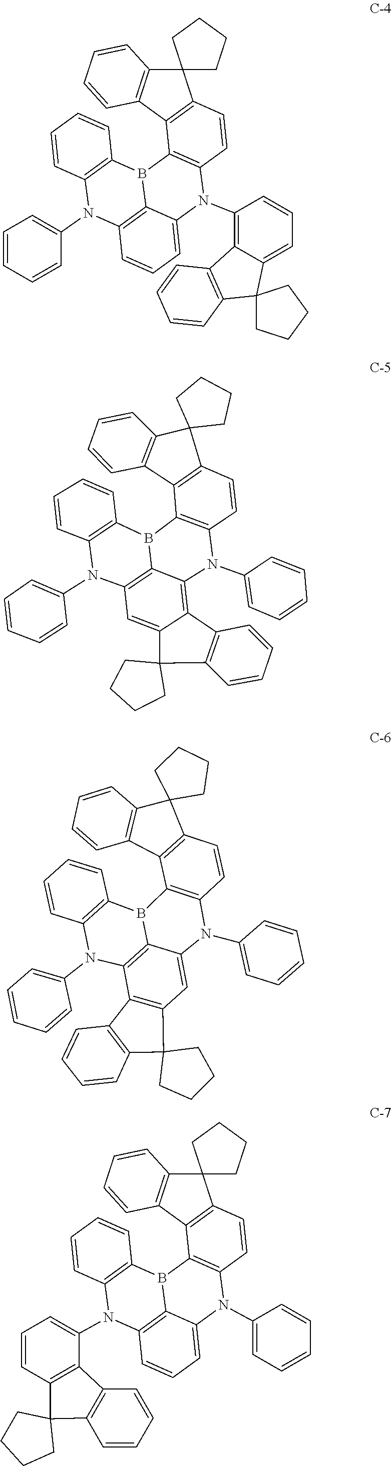

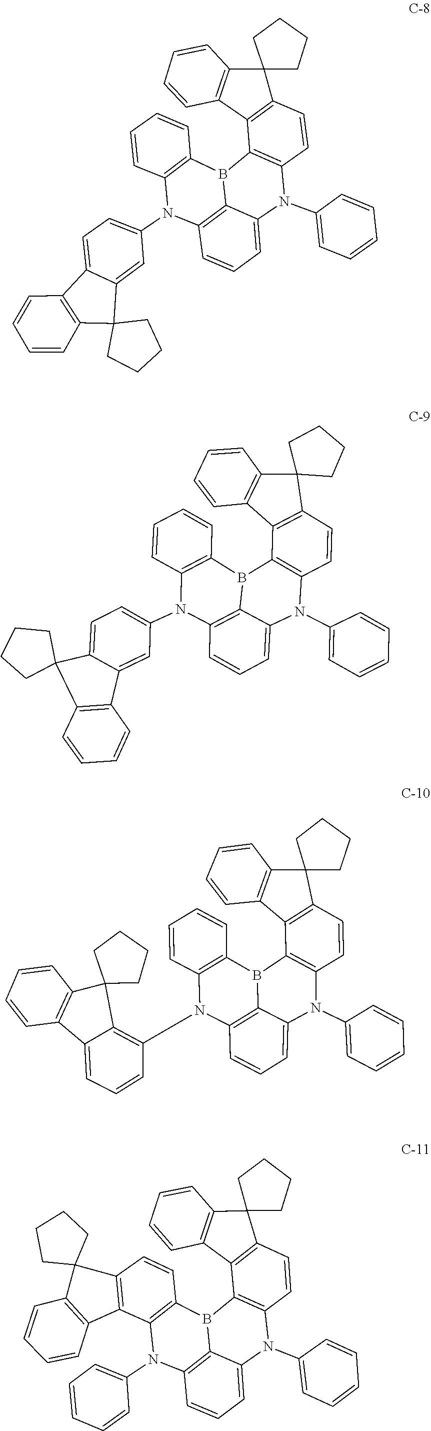 [SMILES: c1ccc(N2c3cccc4c3B(c3ccccc3N4c3ccc4c(c3)C3(CCCC3)c3ccccc3-4)c3c2ccc2c3-c3ccccc3C23CCCC3)cc1 ; c1ccc(N2c3cccc4c3B(c3ccccc3N4c3ccc4c(c3)-c3ccccc3C43CCCC3)c3c2ccc2c3-c3ccccc3C23CCCC3)cc1 ; c1ccc(N2c3cccc4c3B(c3ccccc3N4c3cccc4c3C3(CCCC3)c3ccccc3-4)c3c2ccc2c3-c3ccccc3C23CCCC3)cc1 ; c1ccc(N2c3cccc4c3B(c3ccc5c(c3N4c3ccccc3)-c3ccccc3C53CCCC3)c3c2ccc2c3-c3ccccc3C23CCCC3)cc1]

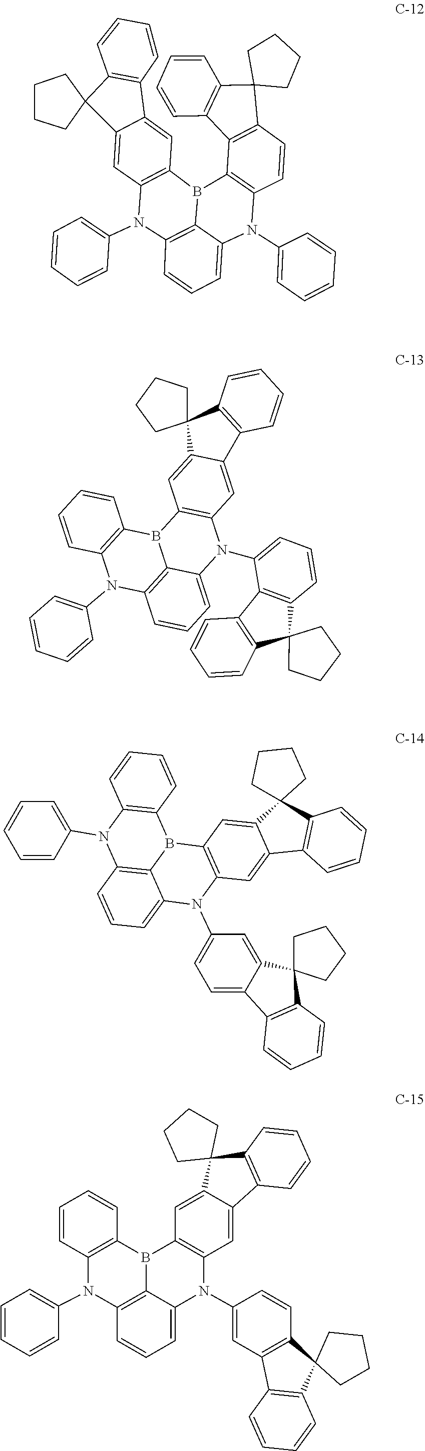

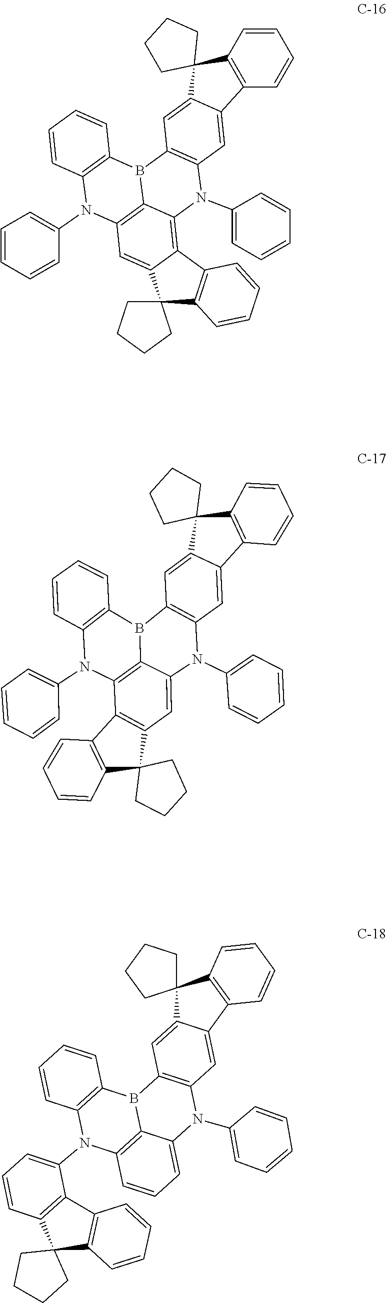

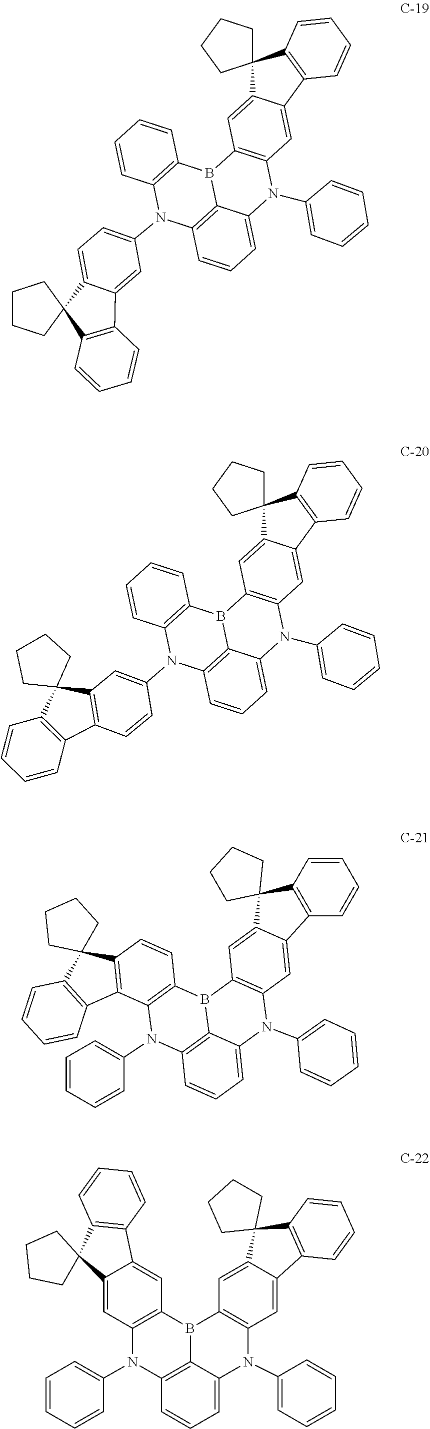

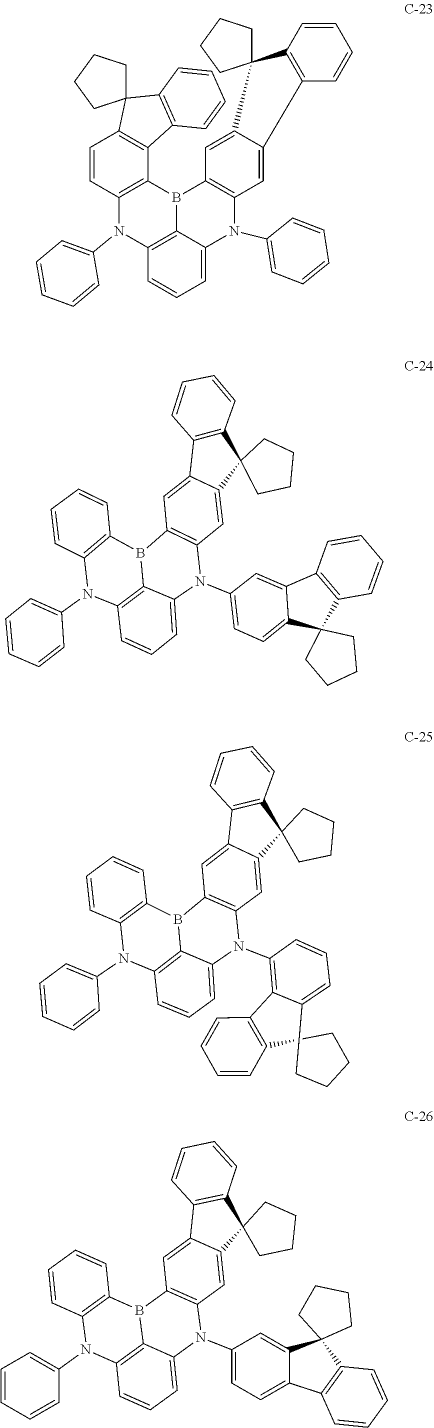

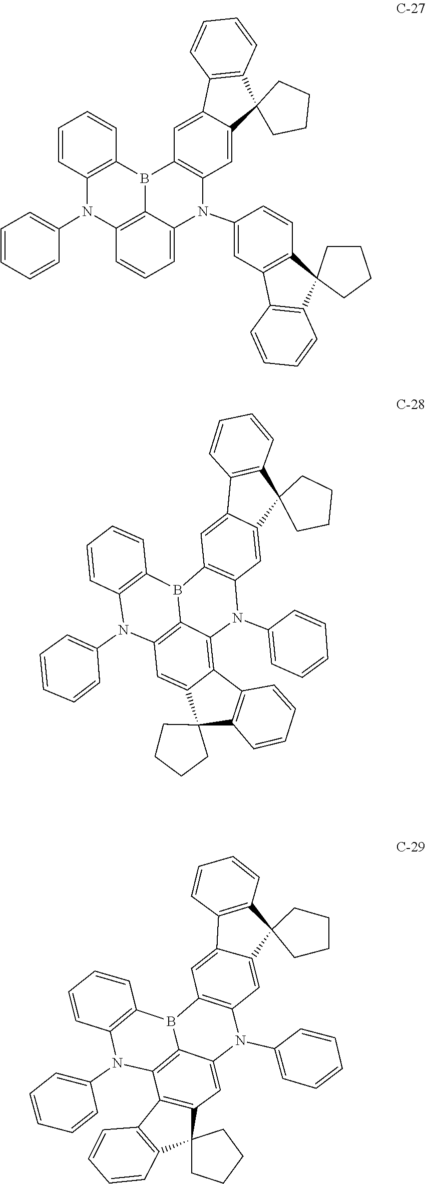

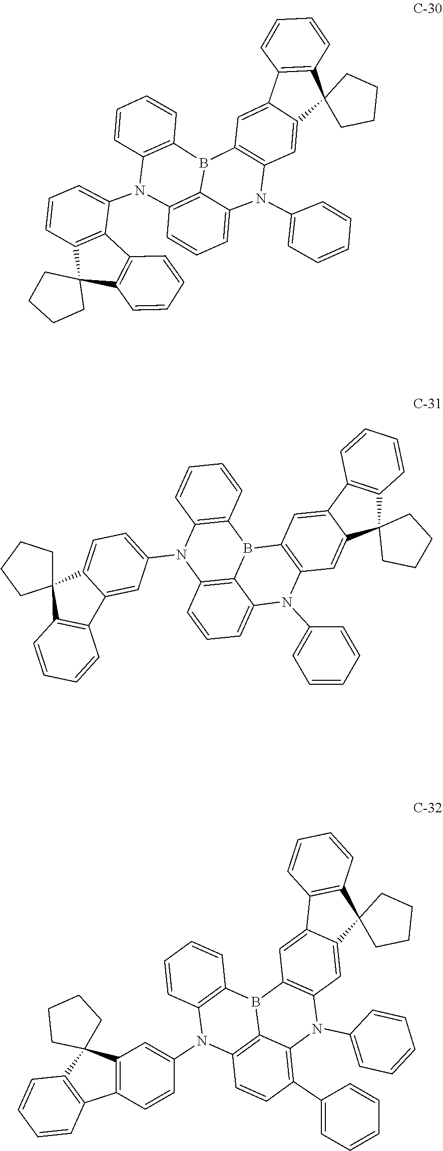

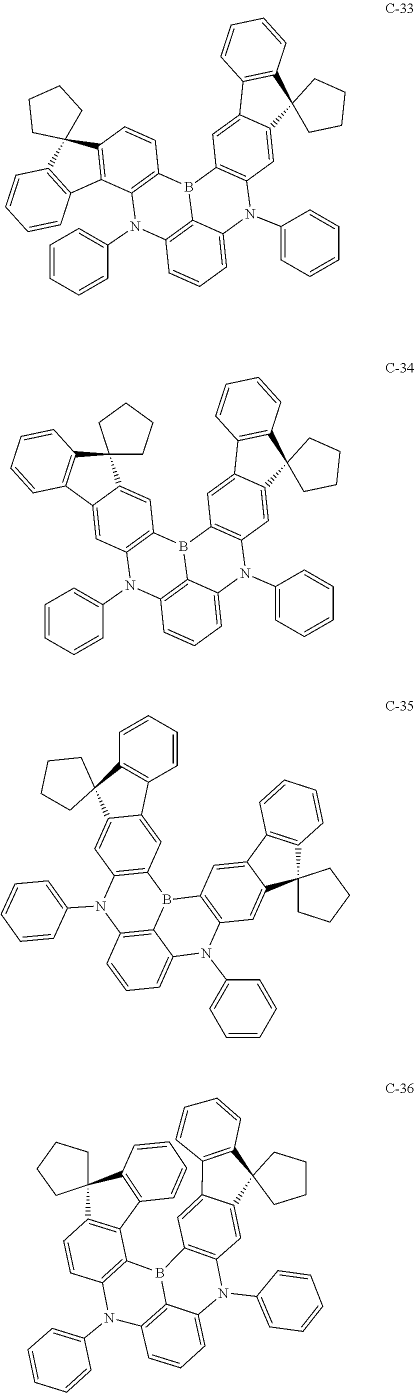 [SMILES: c1ccc(N2c3cc4c(cc3B3c5ccc6c(c5N(c5ccccc5)c5cccc2c53)-c2ccccc2[C@]62CCCC2)-c2ccccc2[C@@]42CCCC2)cc1 ; c1ccc(N2c3cc4c(cc3B3c5cc6c(cc5N(c5ccccc5)c5cccc2c53)[C@]2(CCCC2)c2ccccc2-6)[C@]2(CCCC2)c2ccccc2-4)cc1 ; c1ccc(N2c3cc4c(cc3B3c5cc6c(cc5N(c5ccccc5)c5cccc2c53)[C@]2(CCCC2)c2ccccc2-6)-c2ccccc2[C@@]42CCCC2)cc1 ; c1ccc(N2c3cc4c(cc3B3c5c2cccc5N(c2ccccc2)c2ccc5c(c23)-c2ccccc2[C@]52CCCC2)-c2ccccc2[C@@]42CCCC2)cc1]

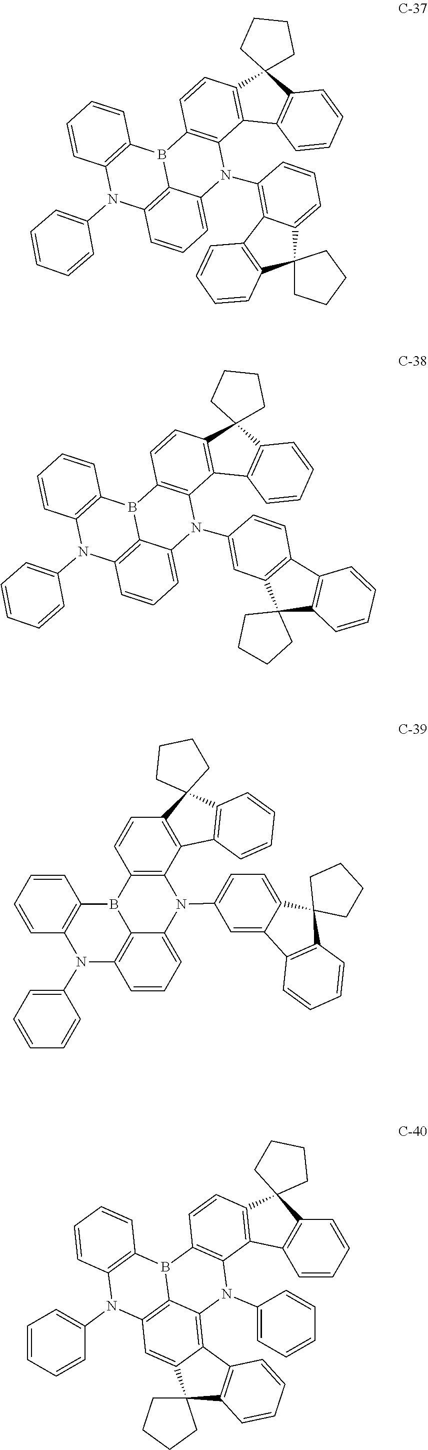

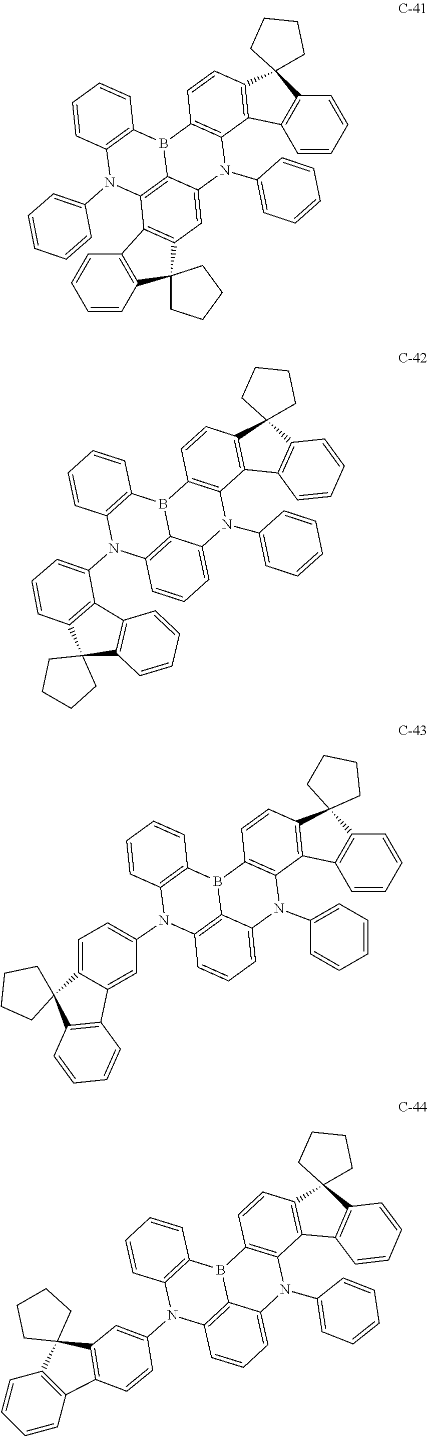

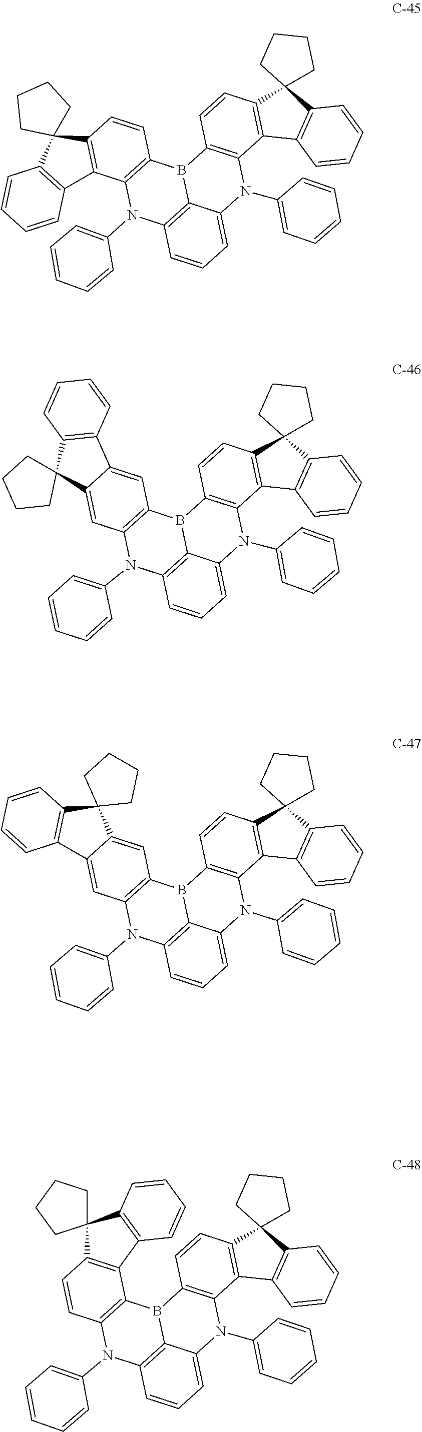 [SMILES: c1ccc(N2c3cccc4c3B(c3ccc5c(c32)-c2ccccc2[C@]52CCCC2)c2ccc3c(c2N4c2ccccc2)-c2ccccc2[C@]32CCCC2)cc1 ; c1ccc(N2c3cc4c(cc3B3c5ccc6c(c5N(c5ccccc5)c5cccc2c53)-c2ccccc2[C@]62CCCC2)-c2ccccc2[C@@]42CCCC2)cc1 ; c1ccc(N2c3cc4c(cc3B3c5ccc6c(c5N(c5ccccc5)c5cccc2c53)-c2ccccc2[C@]62CCCC2)[C@]2(CCCC2)c2ccccc2-4)cc1 ; c1ccc(N2c3cccc4c3B(c3ccc5c(c3N4c3ccccc3)-c3ccccc3[C@]53CCCC3)c3c2ccc2c3-c3ccccc3[C@]23CCCC3)cc1]

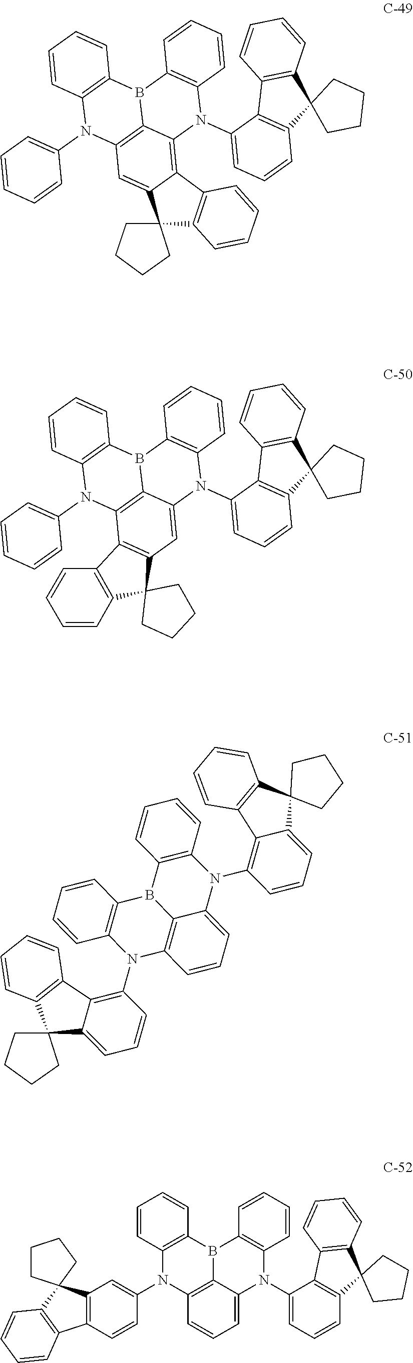

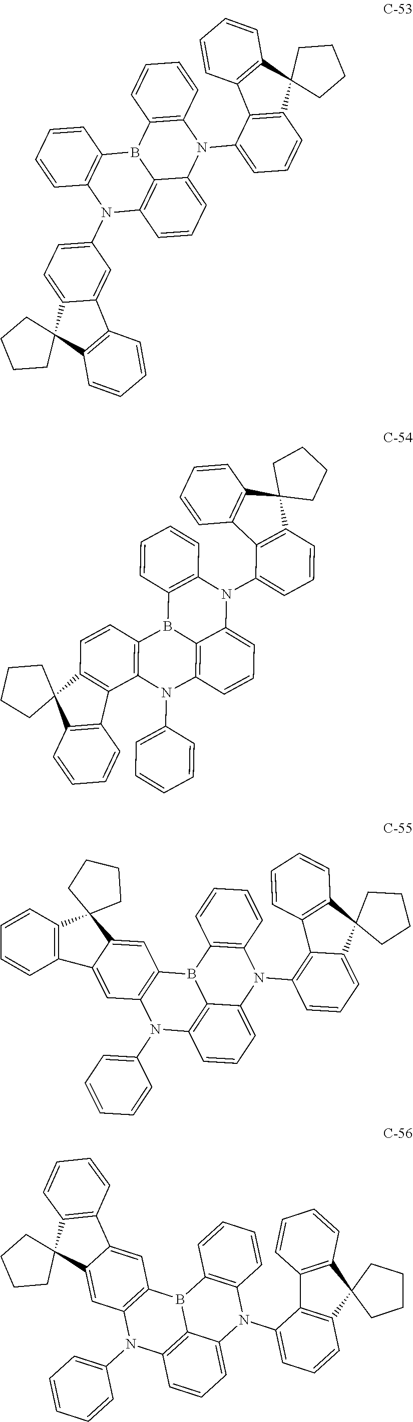

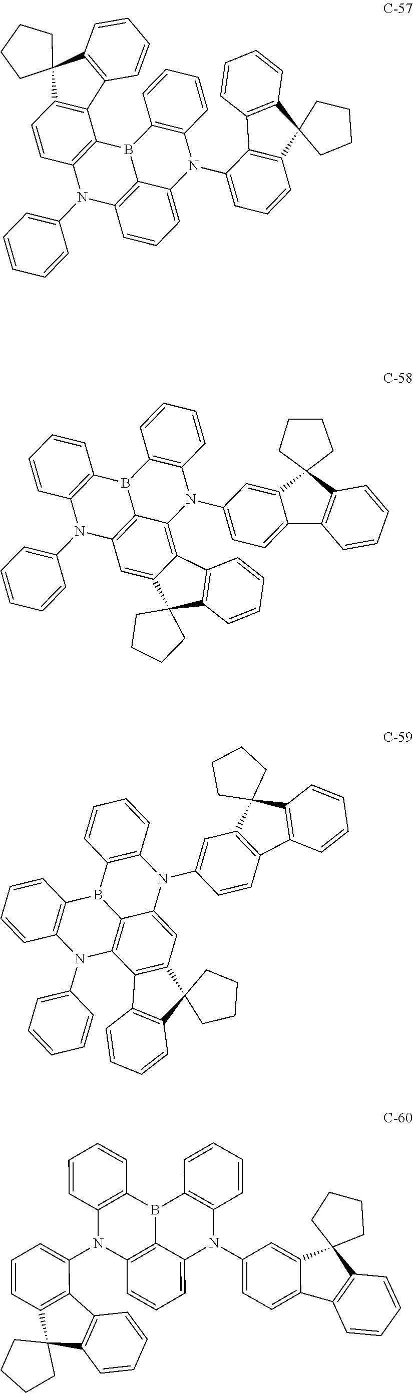

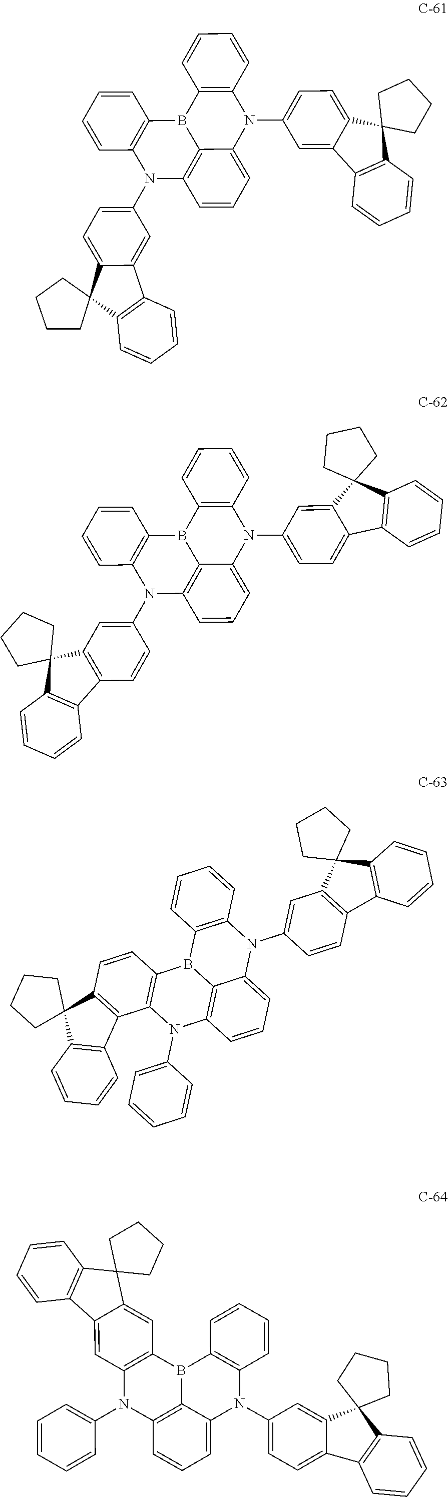

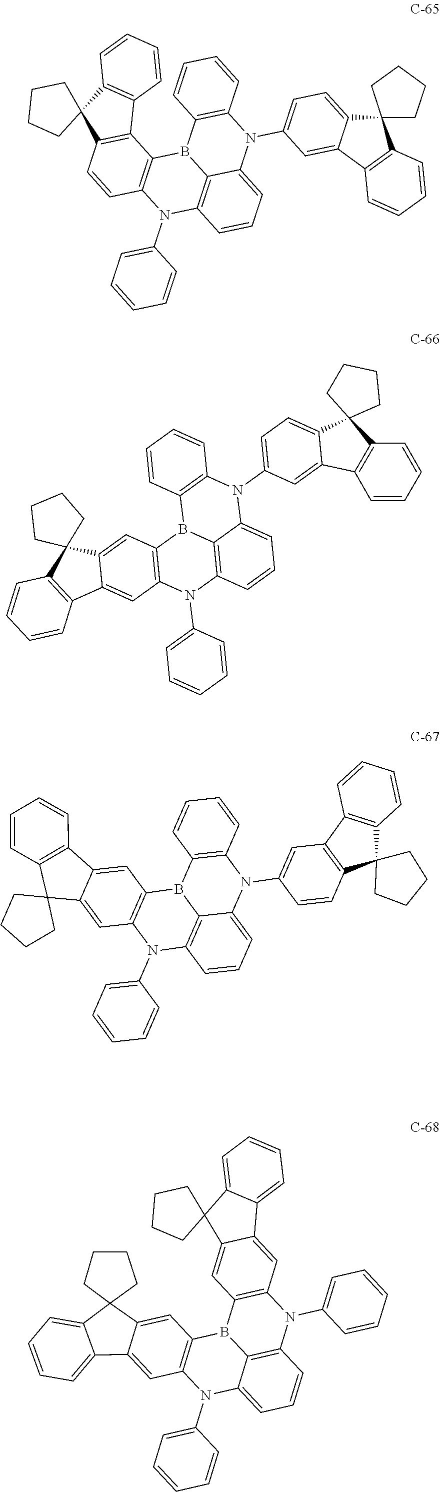

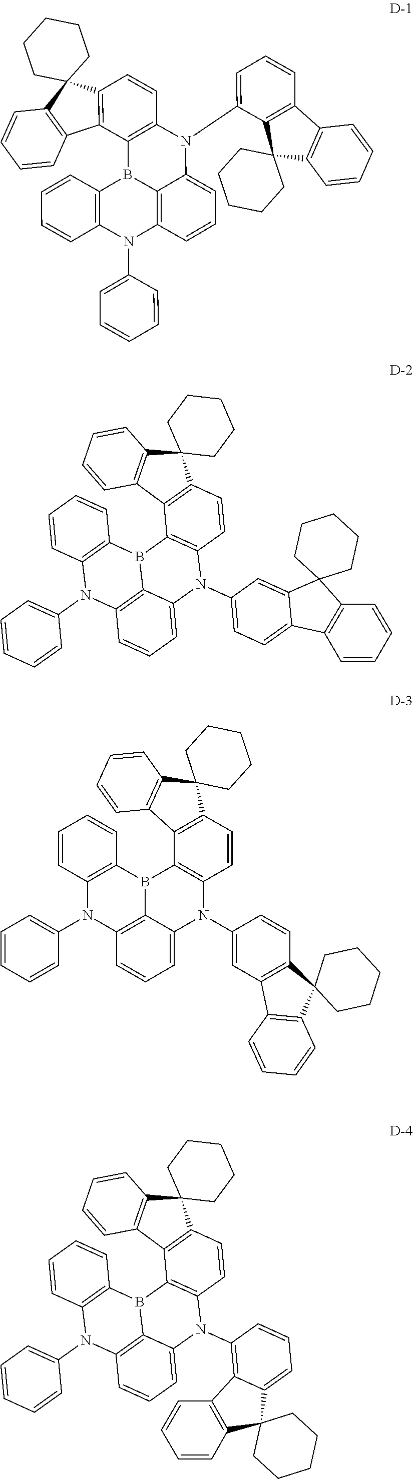

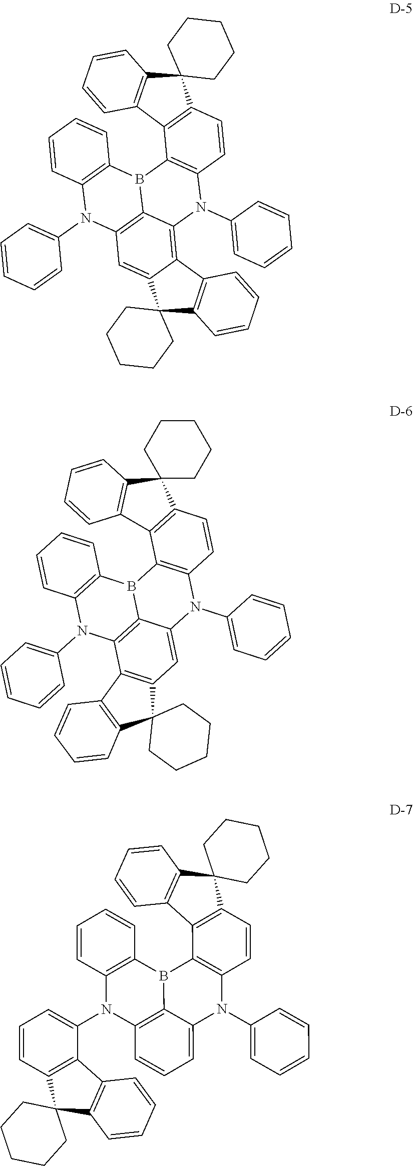

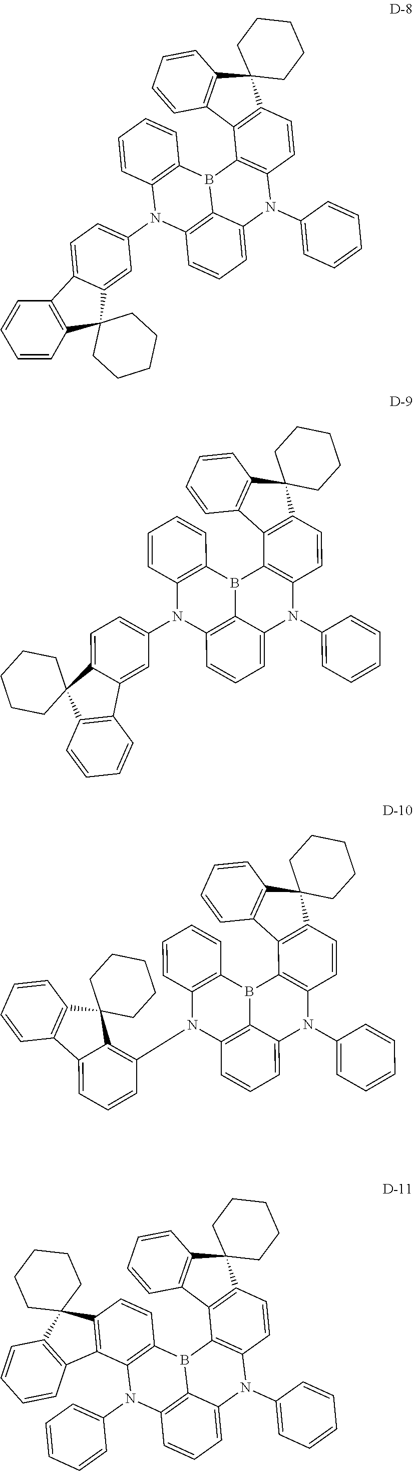

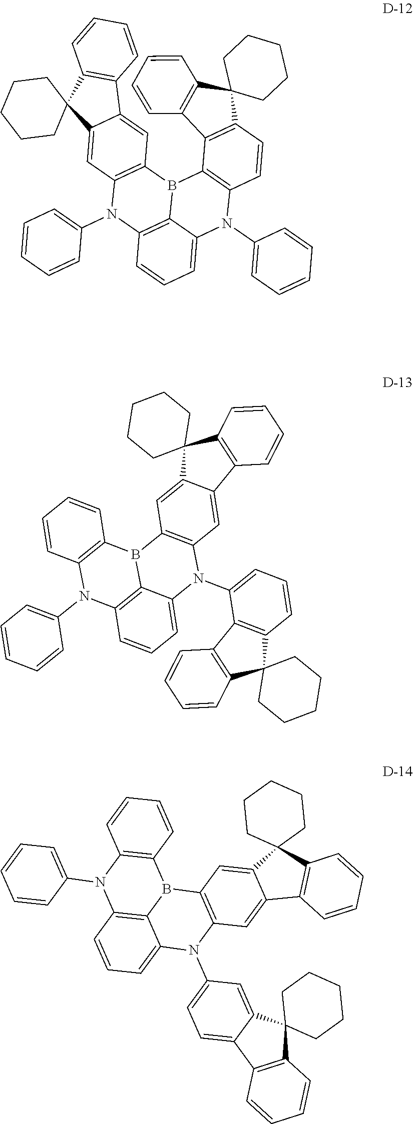

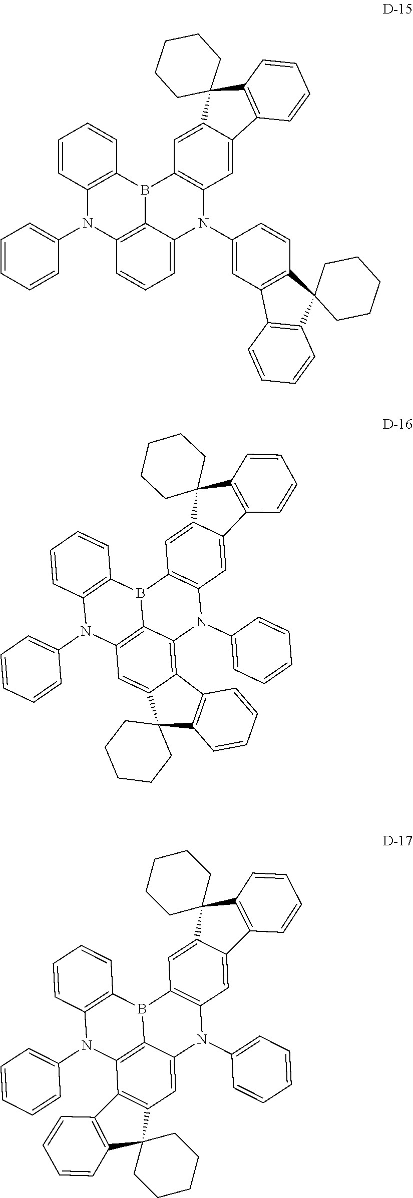

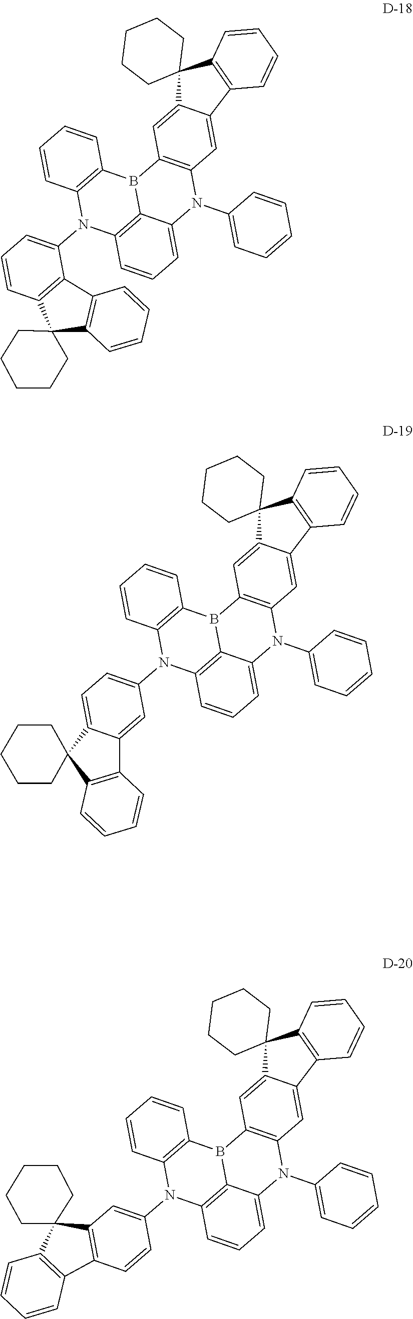

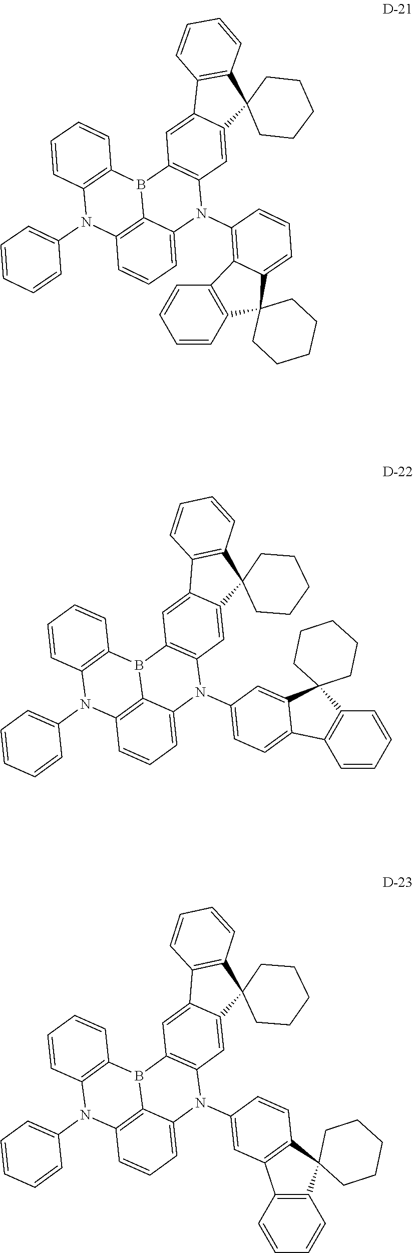

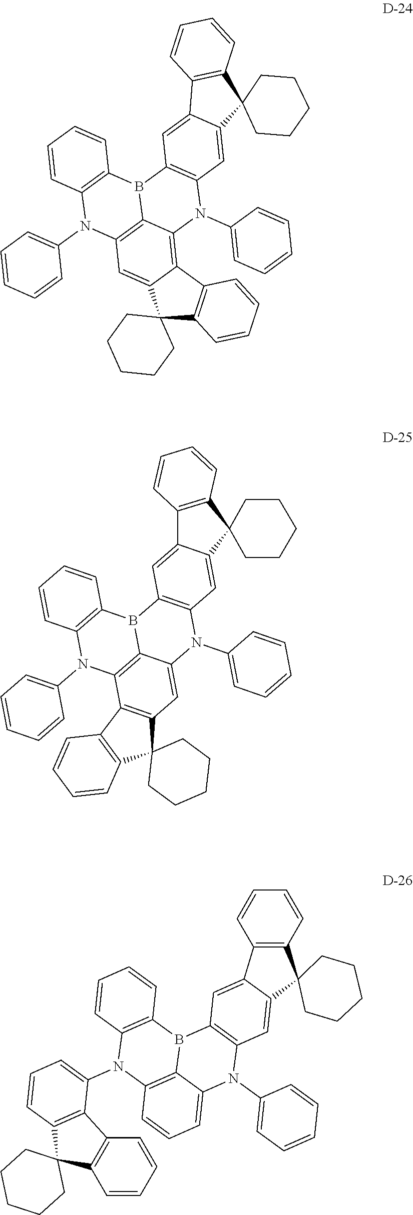

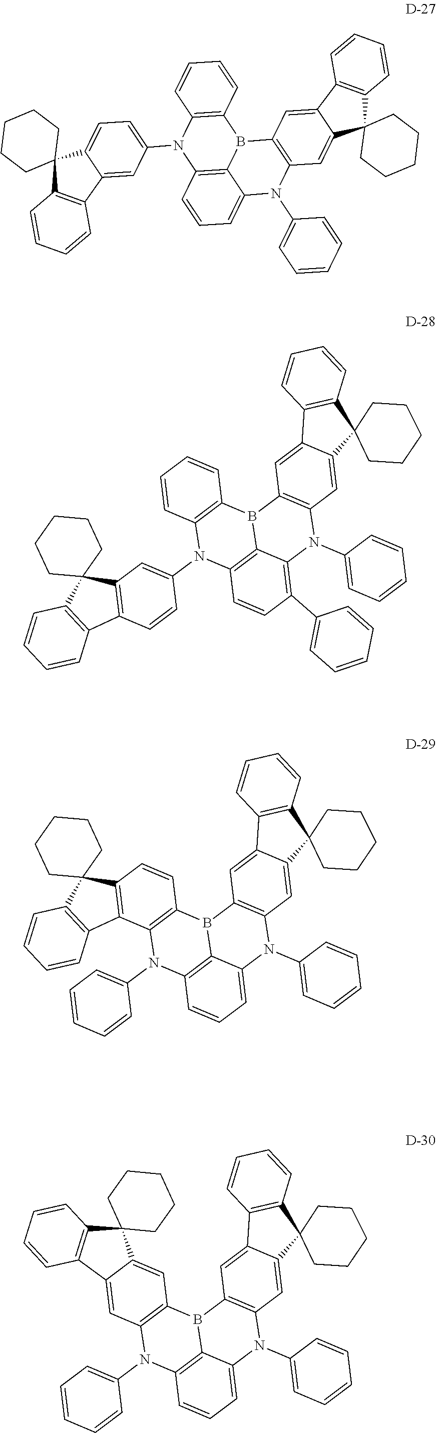

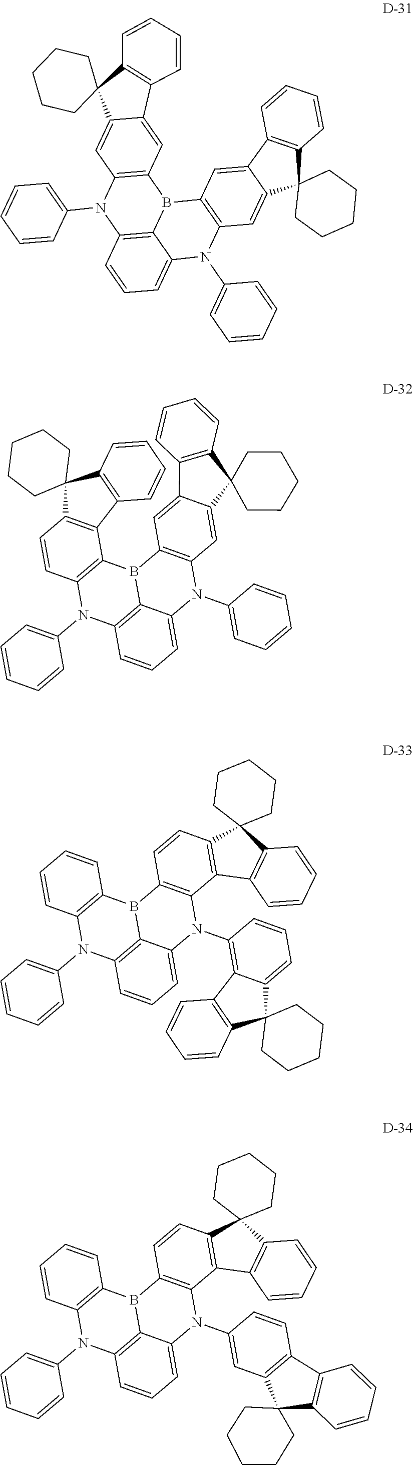

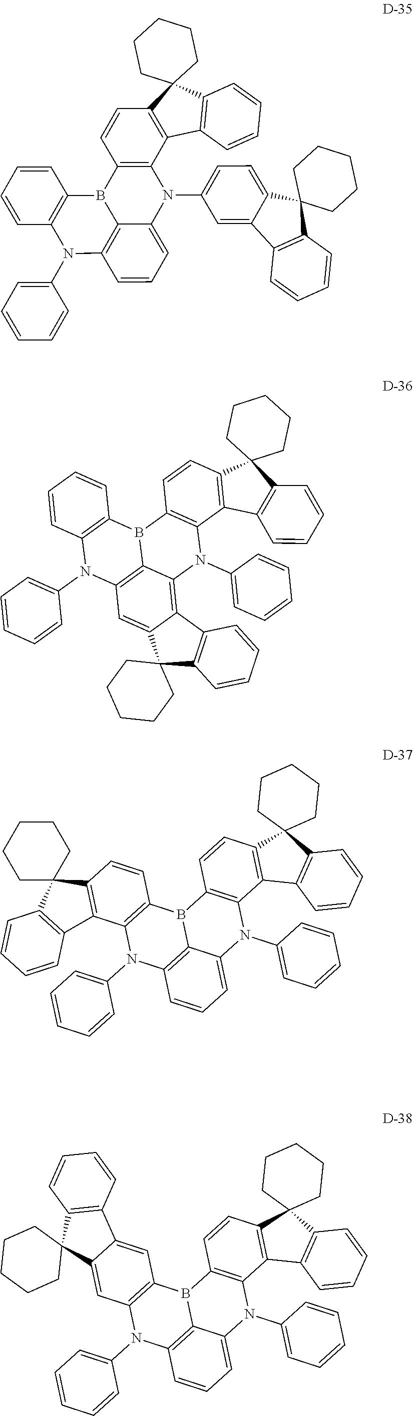

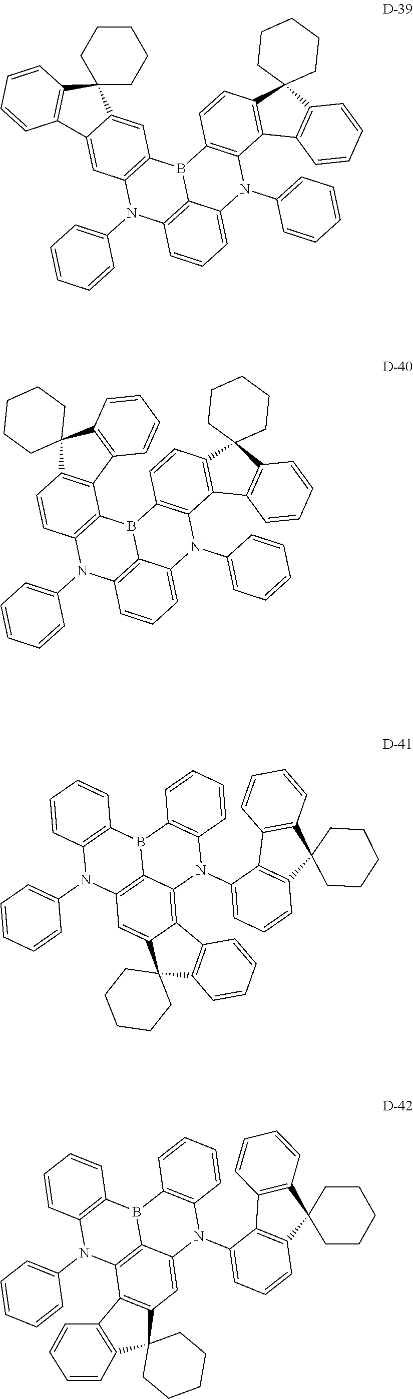

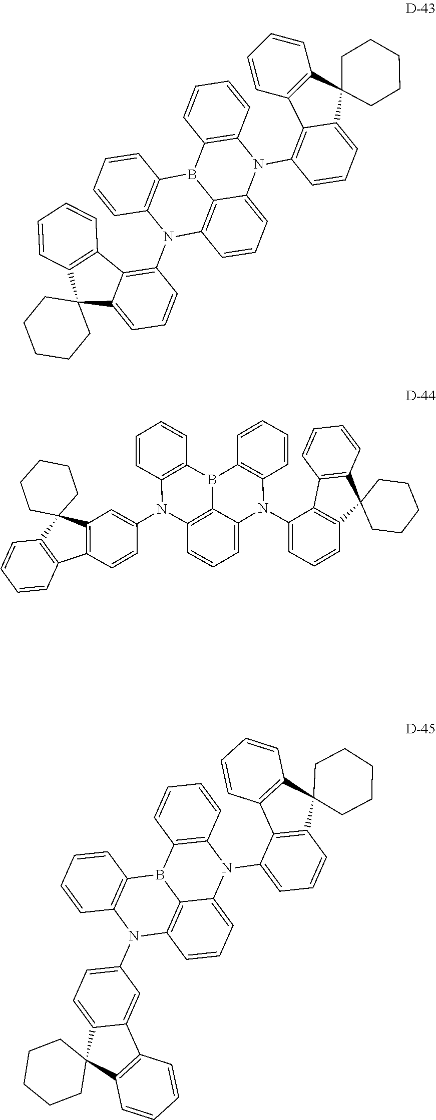

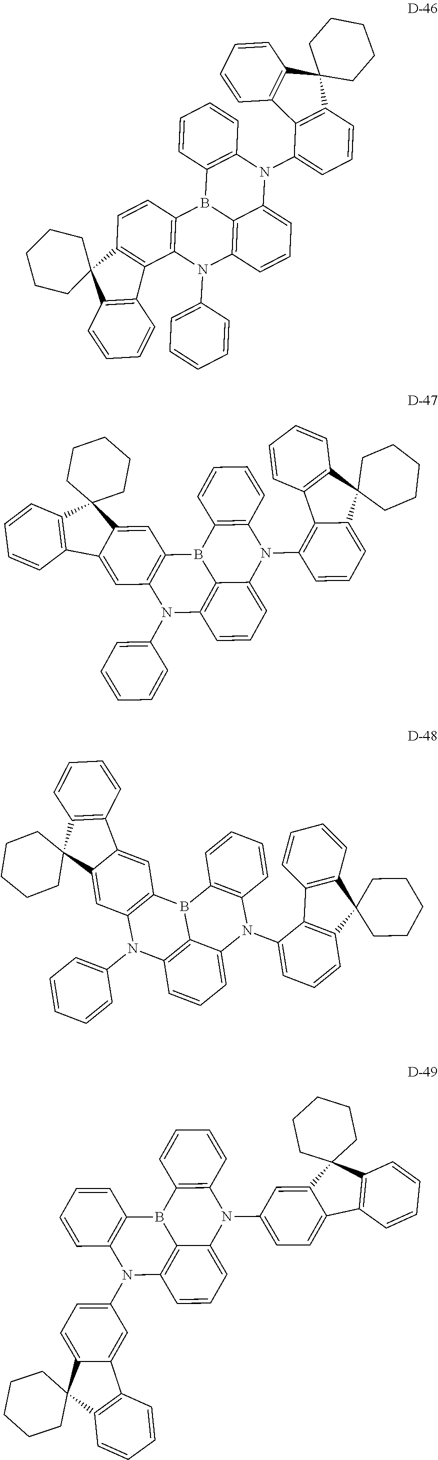

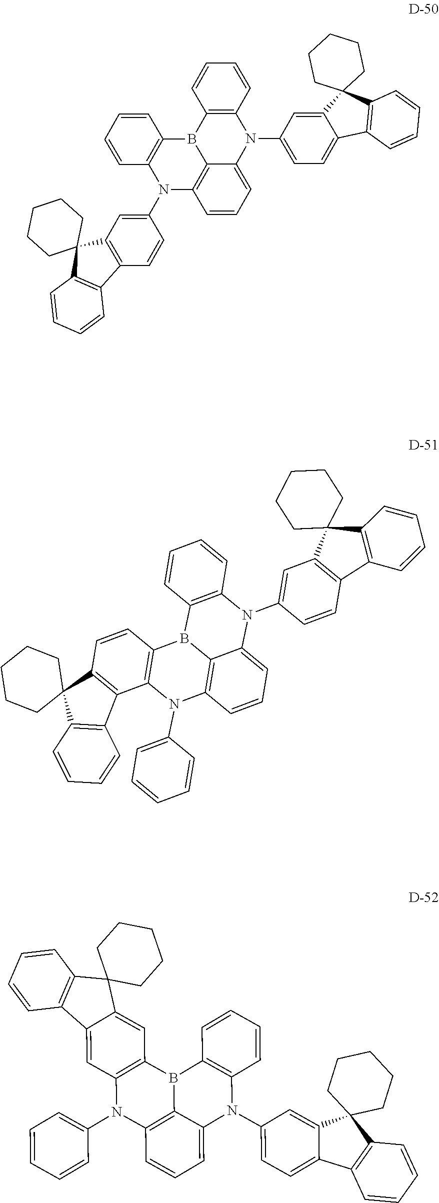

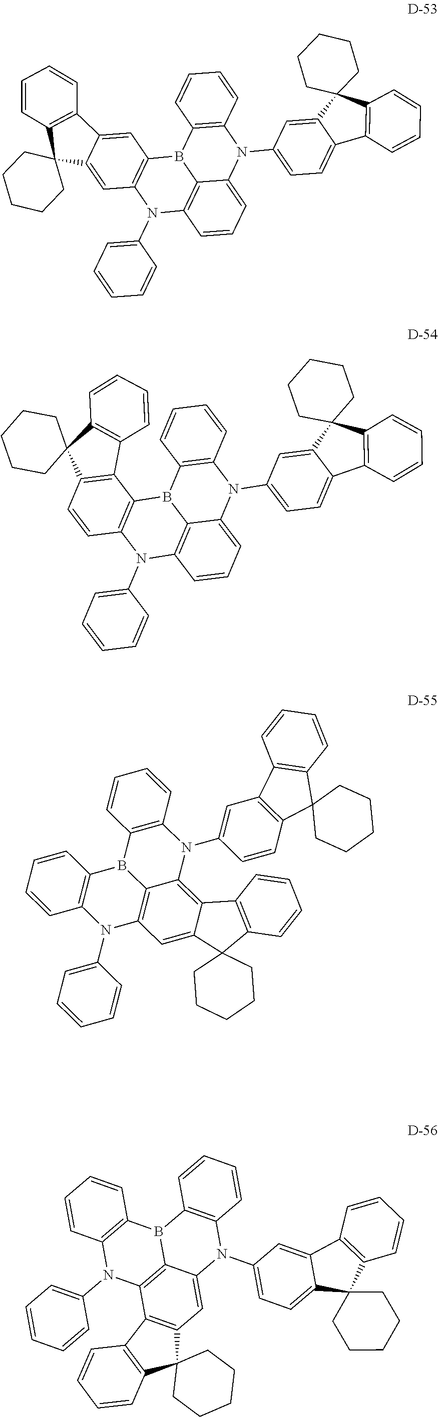

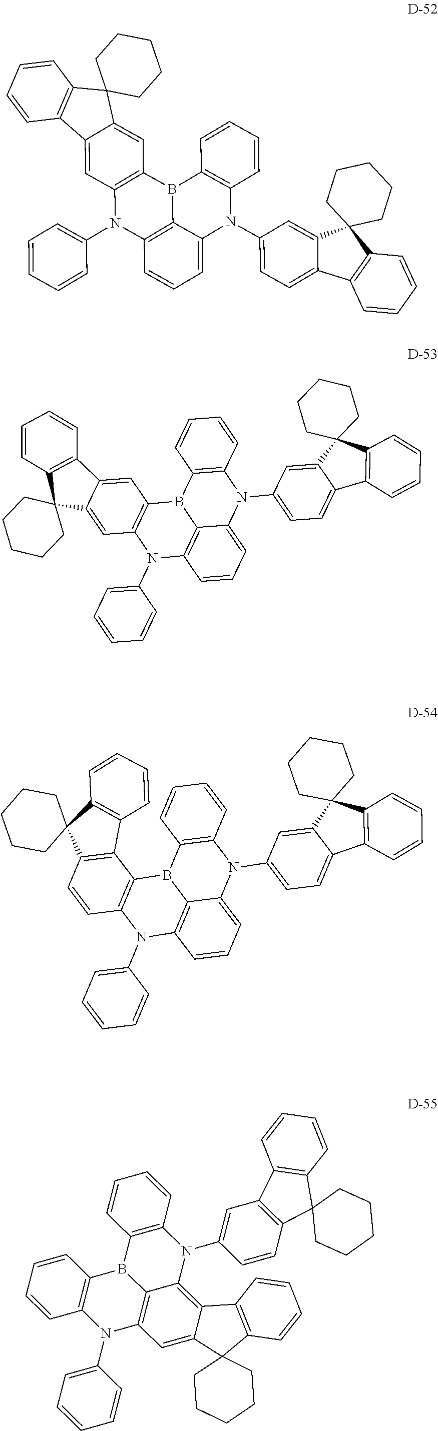

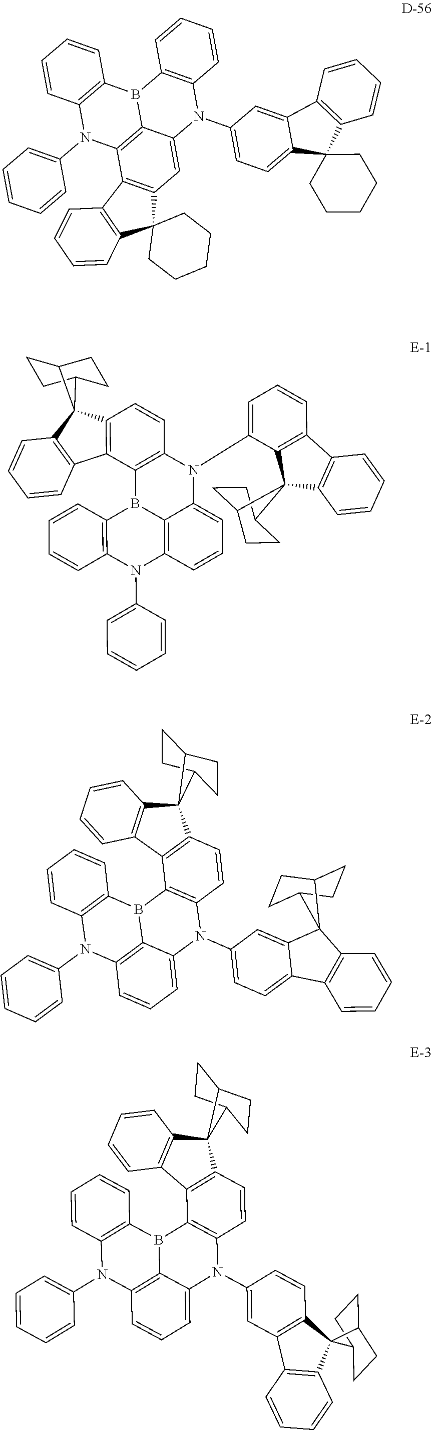

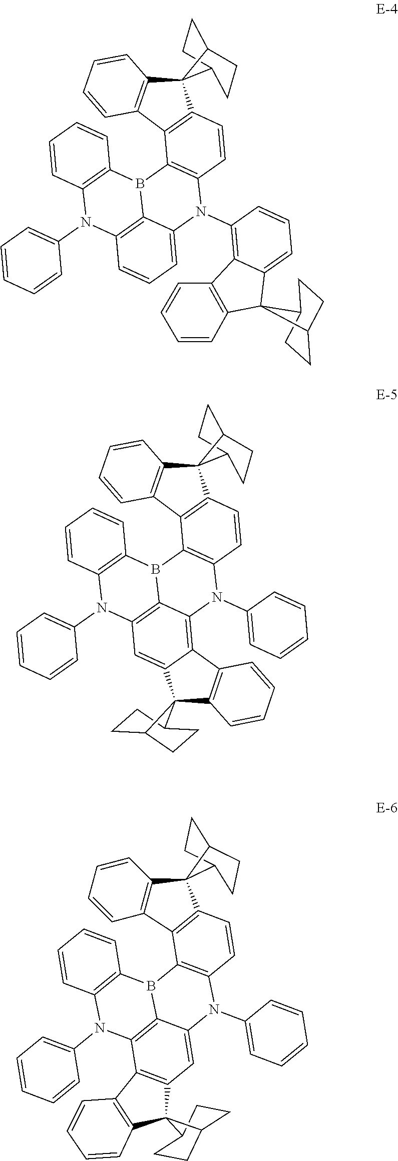

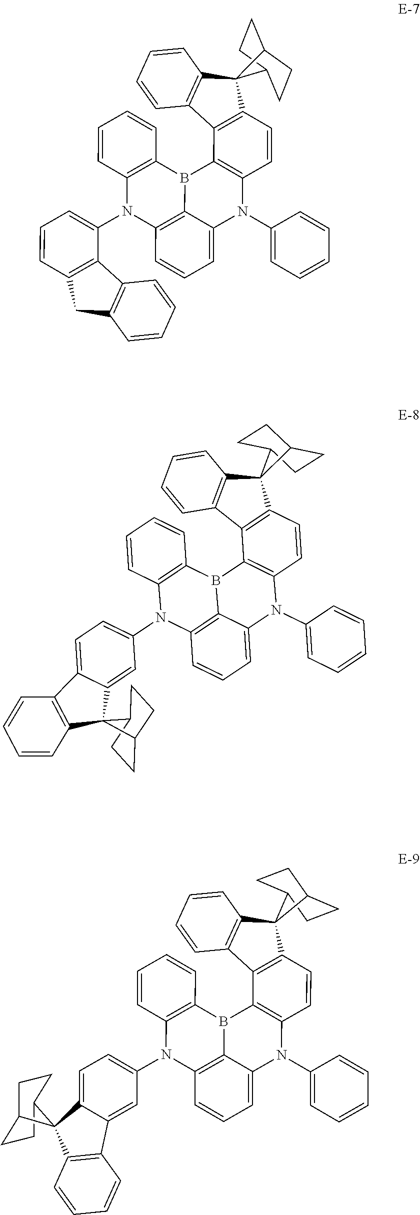

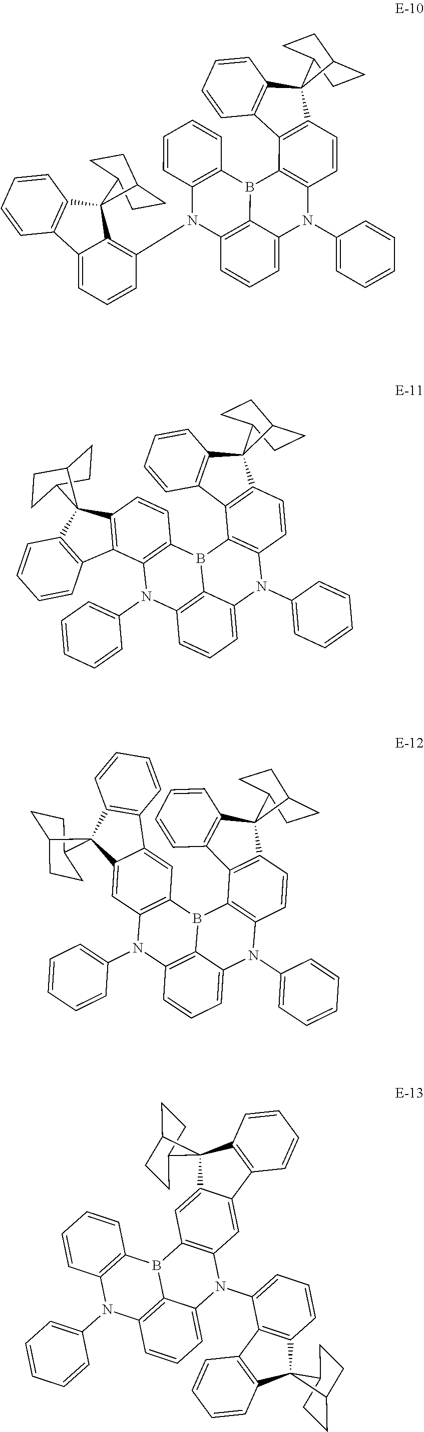

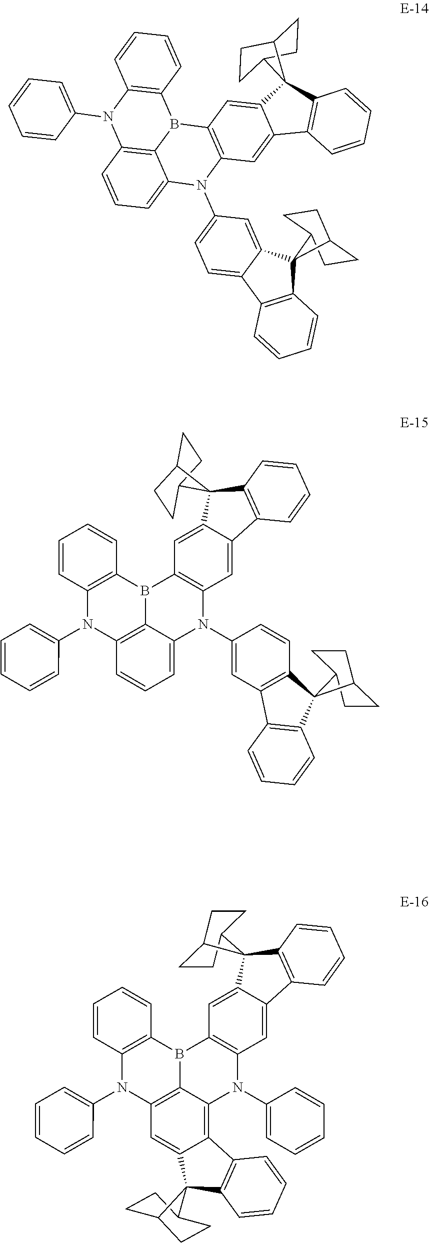

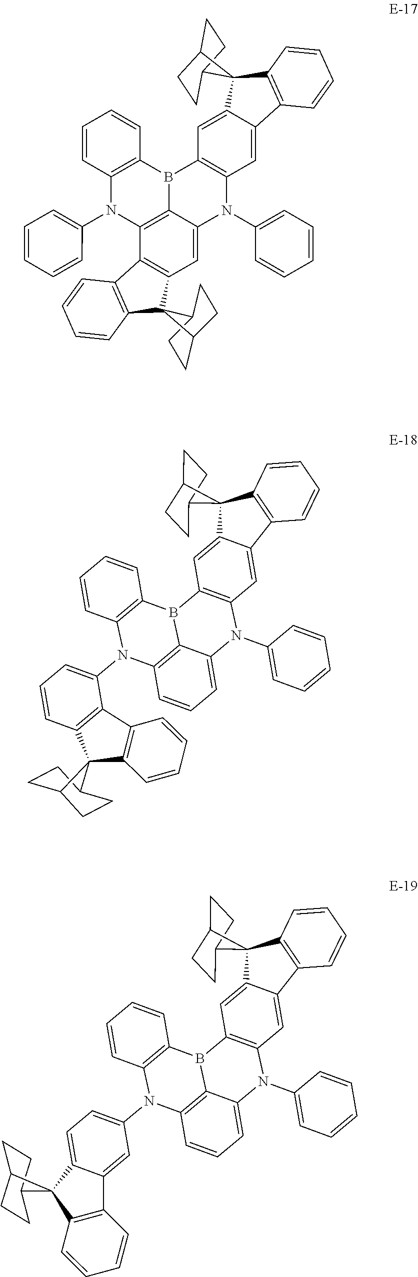

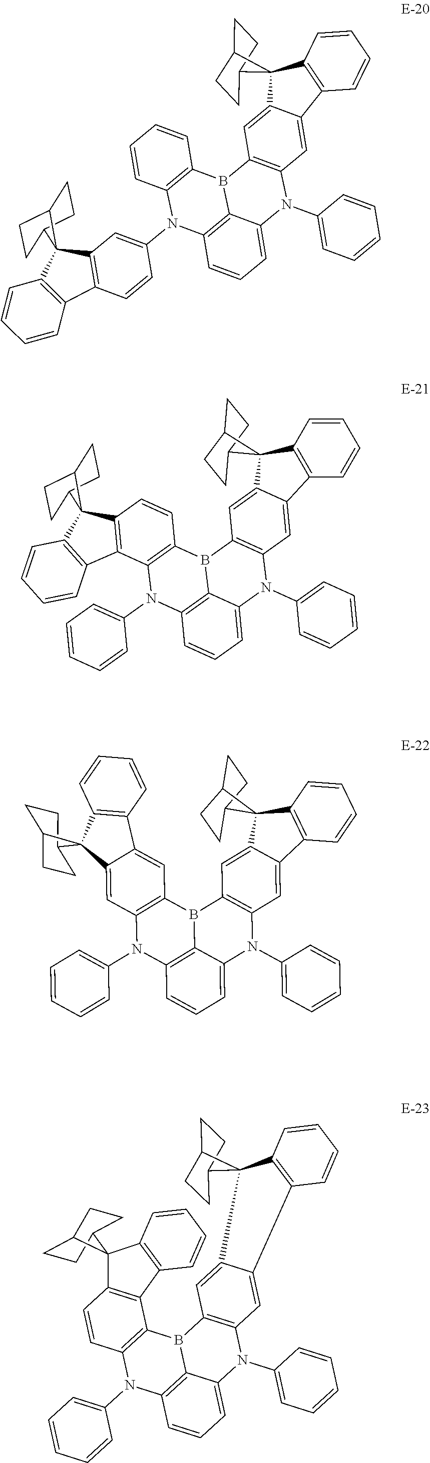

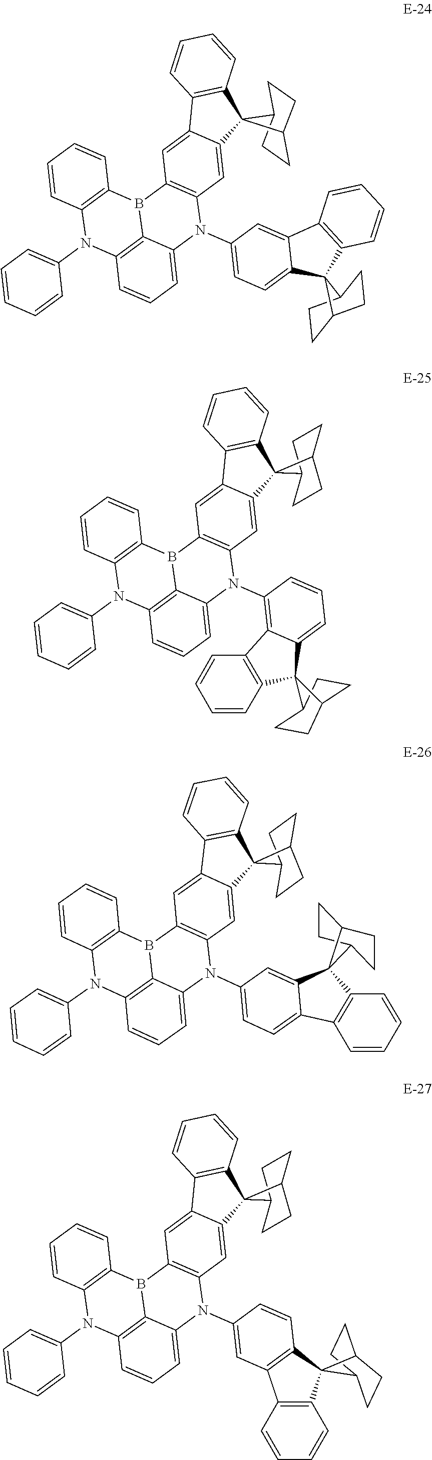

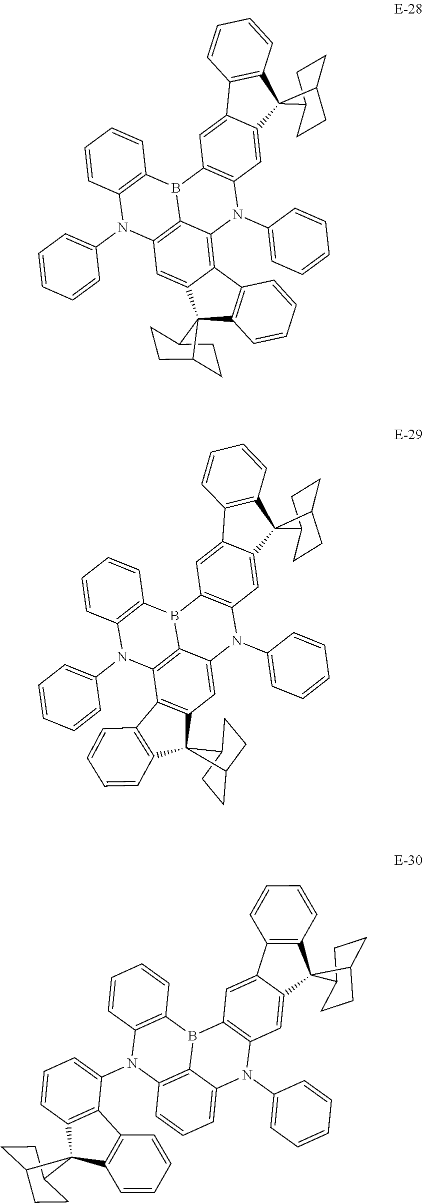

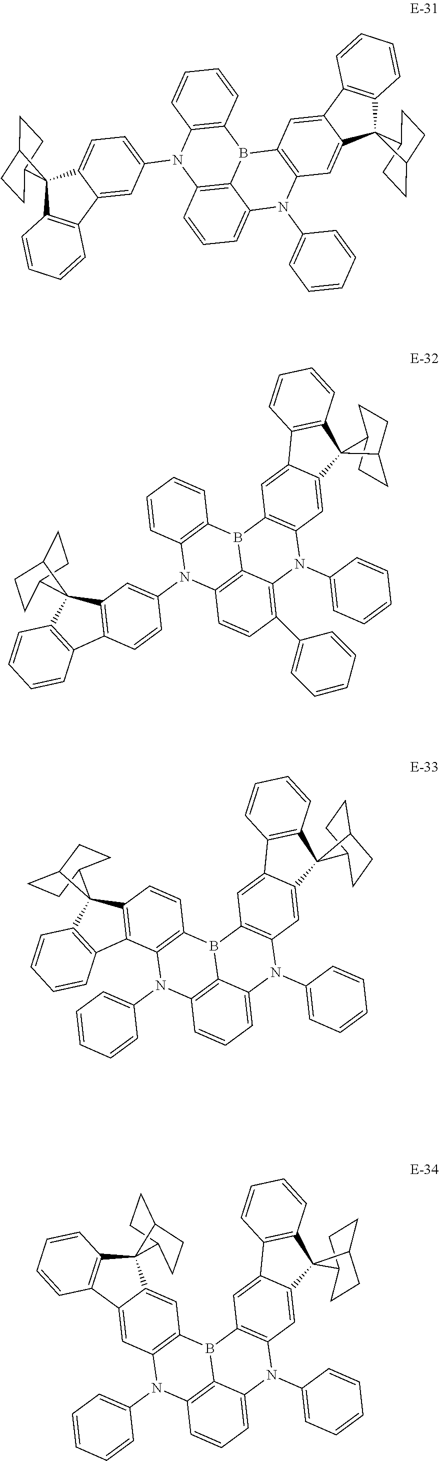

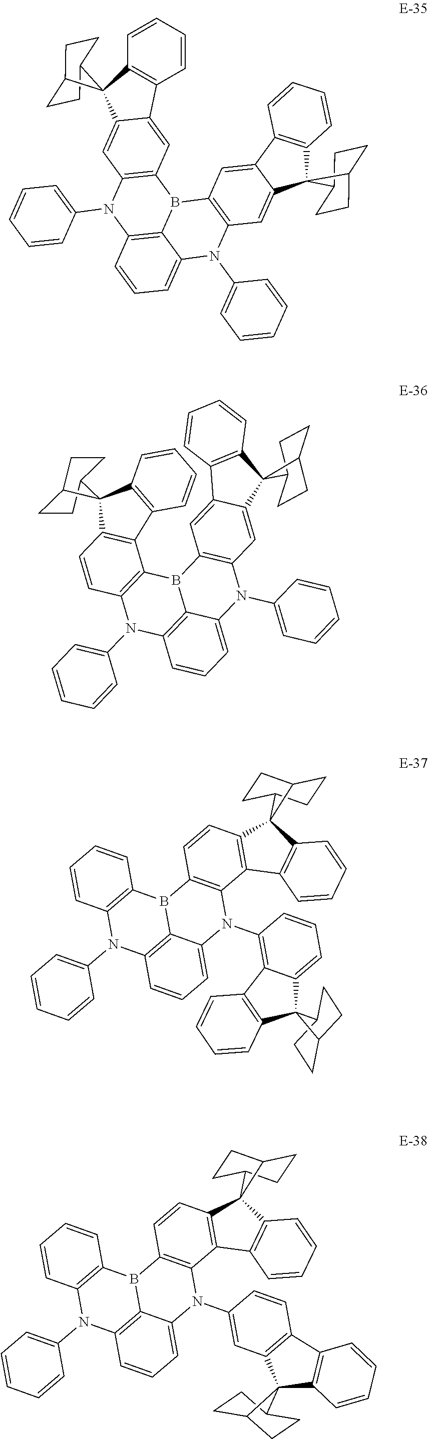

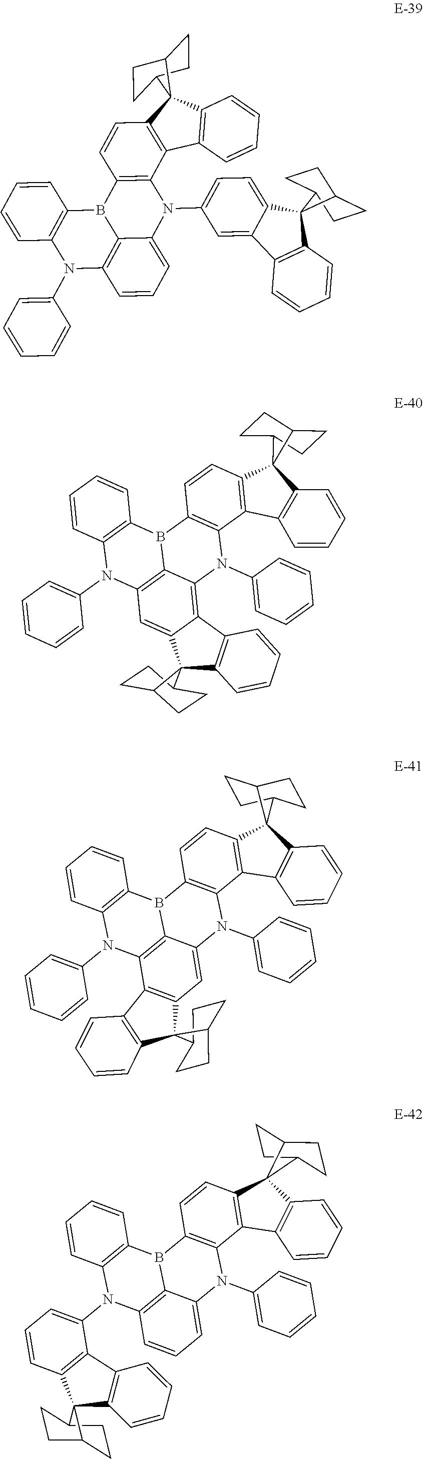

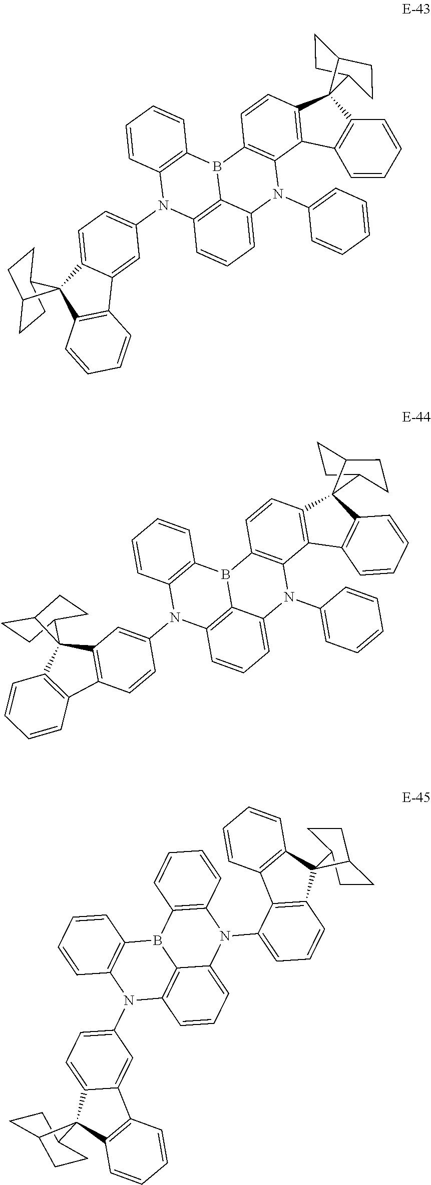

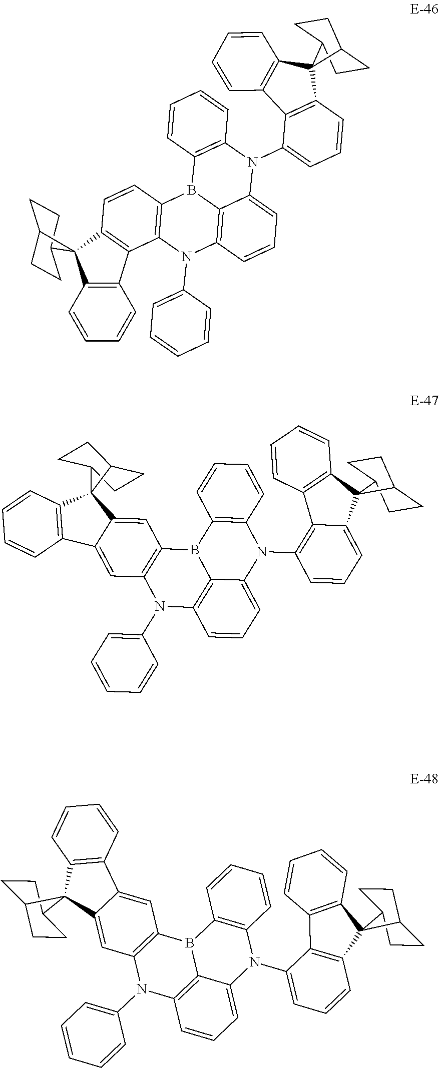

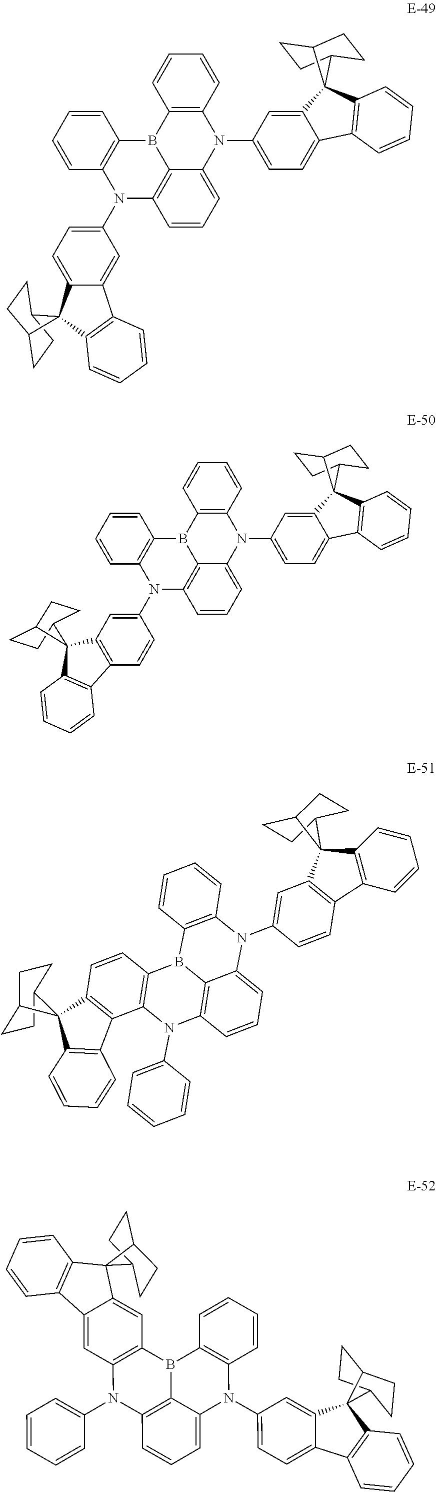

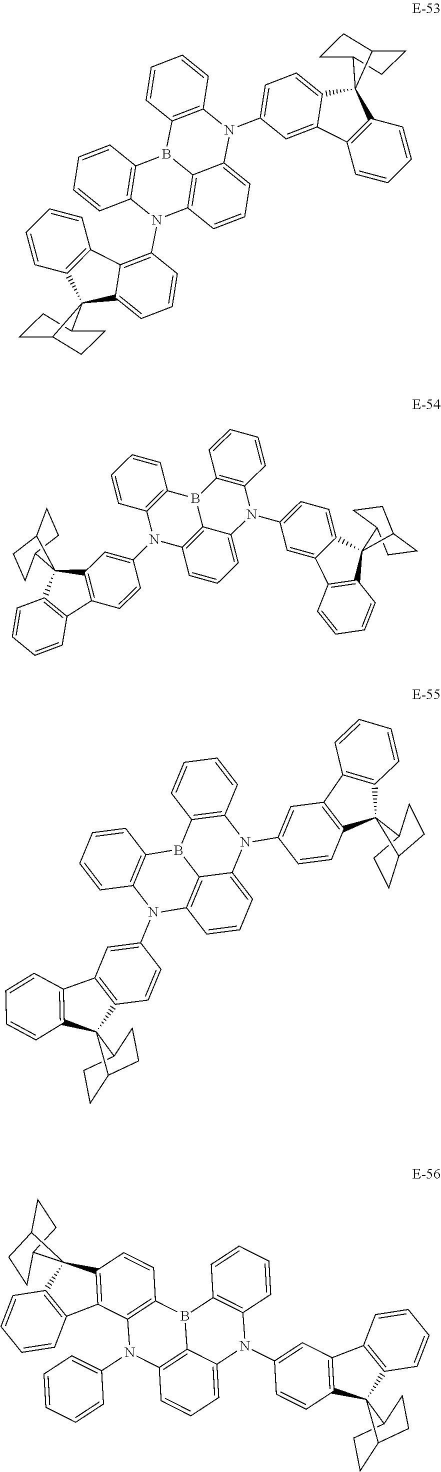

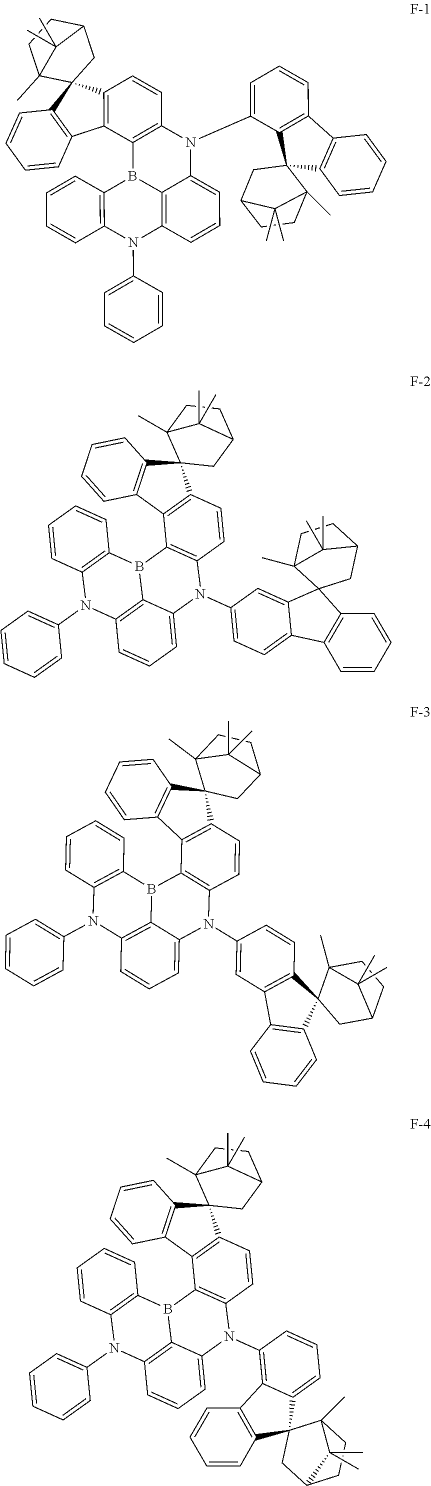

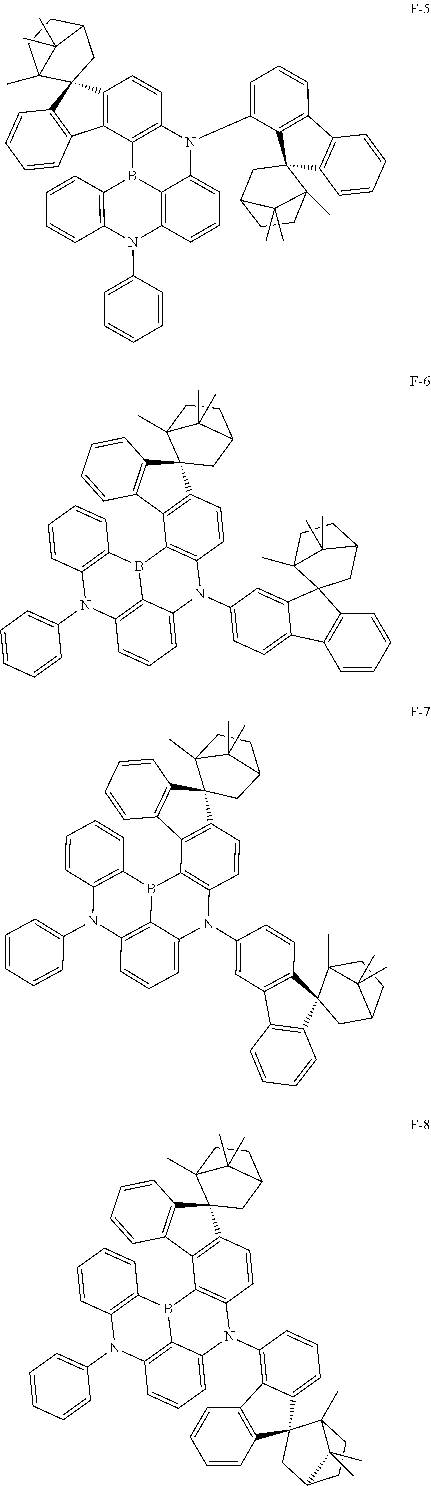

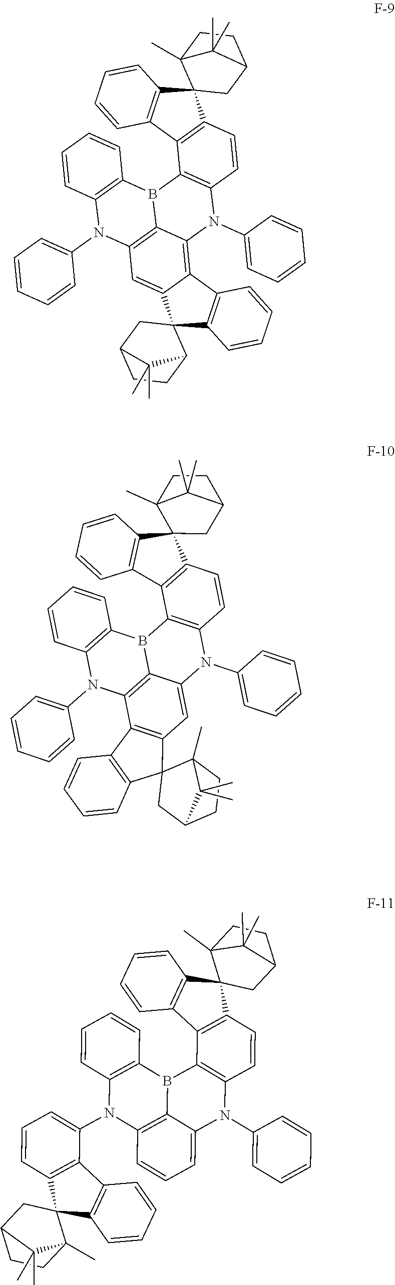 [SMILES: CC1(C)C2CC[C@@H]1[C@@]1(C2)c2ccccc2-c2c1cc1c3c2N(c2ccccc2)c2ccc4c(c2B3c2ccccc2N1c1ccccc1)-c1ccccc1[C@@]41CC2CCC1(C)C2(C)C ; CC1(C)C2CCC1(C)[C@@]1(C2)c2ccccc2-c2c1ccc1c2B2c3ccccc3N(c3ccccc3)c3c2c(cc2c3-c3ccccc3C23C[C@@H]2CCC3(C)C2(C)C)N1c1ccccc1 ; CC1(C)C2CCC1(C)[C@@]1(C2)c2ccccc2-c2c1ccc1c2B2c3ccccc3N(c3cccc4c3-c3ccccc3[C@@]43CC4CC[C@@]3(C)C4(C)C)c3cccc(c32)N1c1ccccc1]

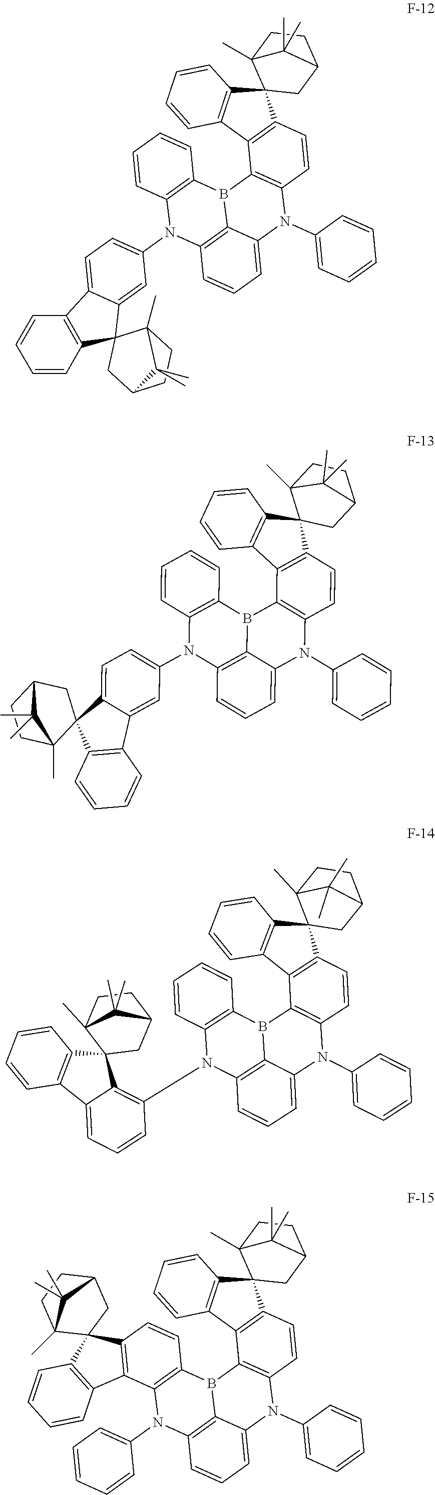

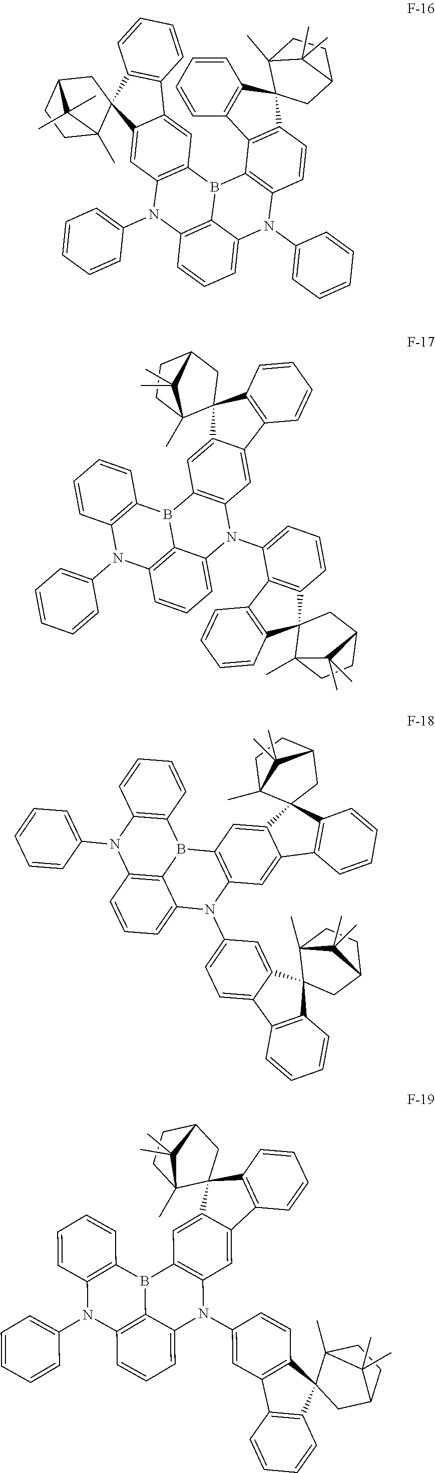

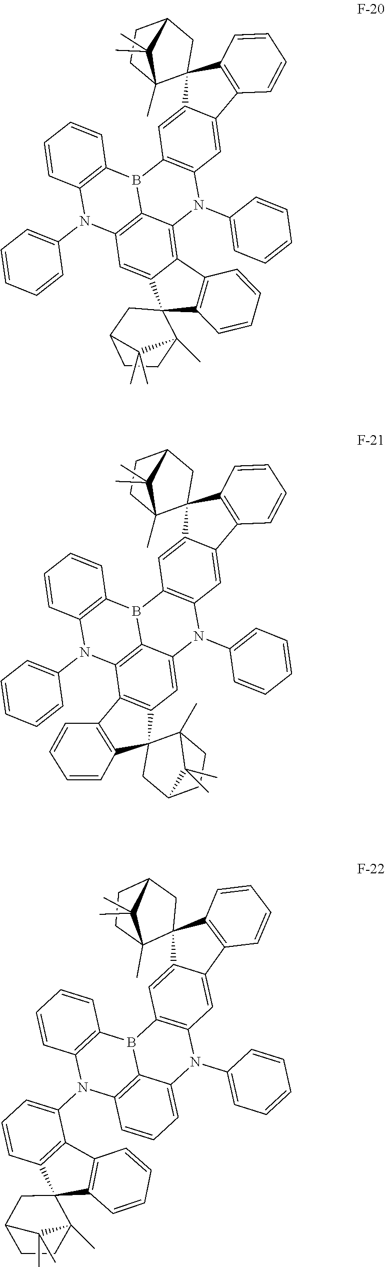 [SMILES: CC1(C)C2CC[C@]1(C)[C@@]1(C2)c2ccccc2-c2c1cc1c3c2N(c2ccccc2)c2cc4c(cc2B3c2ccccc2N1c1ccccc1)[C@]1(C[C@H]2CC[C@]1(C)C2(C)C)c1ccccc1-4 ; CC1(C)[C@H]2CCC1(C)[C@@]1(C2)c2ccccc2-c2c1cc1c3c2N(c2ccccc2)c2ccccc2B3c2cc3c(cc2N1c1ccccc1)-c1ccccc1[C@@]31C[C@H]2CC[C@]1(C)C2(C)C ; CC1(C)C2CC[C@]1(C)[C@@]1(C2)c2ccccc2-c2c(N3c4ccccc4B4c5cc6c(cc5N(c5ccccc5)c5cccc3c54)-c3ccccc3[C@@]63C[C@H]4CC[C@]3(C)C4(C)C)cccc21]

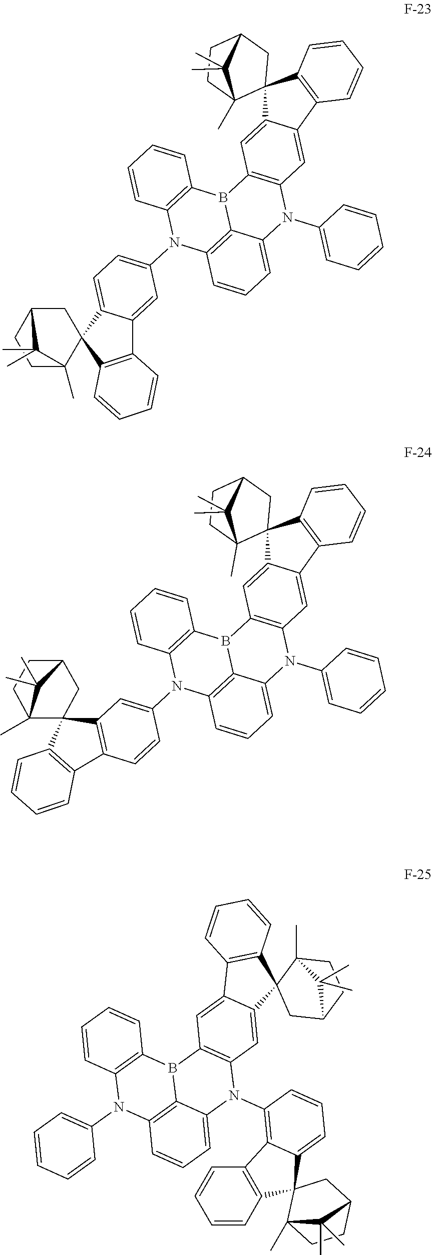 [SMILES: CC1(C)[C@@H]2CCC1(C)[C@@]1(C2)c2ccccc2-c2cc(N3c4ccccc4B4c5cc6c(cc5N(c5ccccc5)c5cccc3c54)-c3ccccc3[C@@]63C[C@H]4CC[C@]3(C)C4(C)C)ccc21 ; CC1(C)[C@@H]2CC[C@@]1(C)[C@@]1(C2)c2ccccc2-c2cc3c(cc21)B1c2ccccc2N(c2ccc4c(c2)[C@@]2(C[C@H]5CC[C@]2(C)C5(C)C)c2ccccc2-4)c2cccc(c21)N3c1ccccc1 ; CC1(C)[C@H]2CC[C@]1(C)[C@@]1(C2)c2ccccc2-c2cc3c(cc21)N(c1cccc2c1-c1ccccc1[C@@]21C[C@@H]2CC[C@@]1(C)C2(C)C)c1cccc2c1B3c1ccccc1N2c1ccccc1]

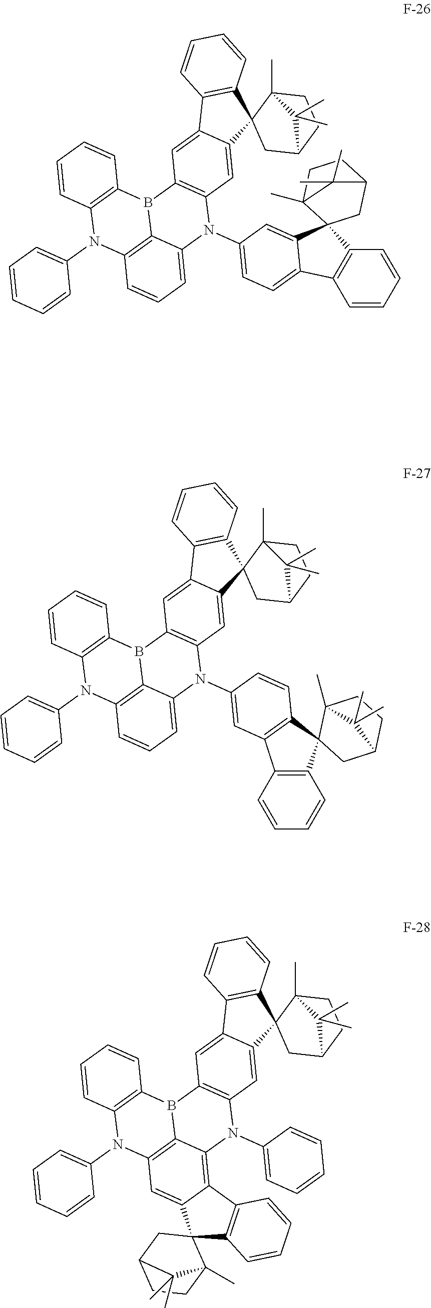 [SMILES: CC1(C)C2CCC1(C)[C@]1(C2)c2ccccc2-c2ccc(N3c4cc5c(cc4B4c6ccccc6N(c6ccccc6)c6cccc3c64)-c3ccccc3[C@@]53C[C@@H]4CC[C@@]3(C)C4(C)C)cc21 ; CC1(C)[C@H]2CCC1(C)[C@]1(C2)c2ccccc2-c2cc3c(cc21)N(c1ccc2c(c1)-c1ccccc1[C@]21C[C@@H]2CC[C@@]1(C)C2(C)C)c1cccc2c1B3c1ccccc1N2c1ccccc1 ; CC1(C)C2CC[C@]1(C)[C@@]1(C2)c2ccccc2-c2c1cc1c3c2N(c2ccccc2)c2cc4c(cc2B3c2ccccc2N1c1ccccc1)-c1ccccc1[C@@]41C[C@@H]2CC[C@@]1(C)C2(C)C]

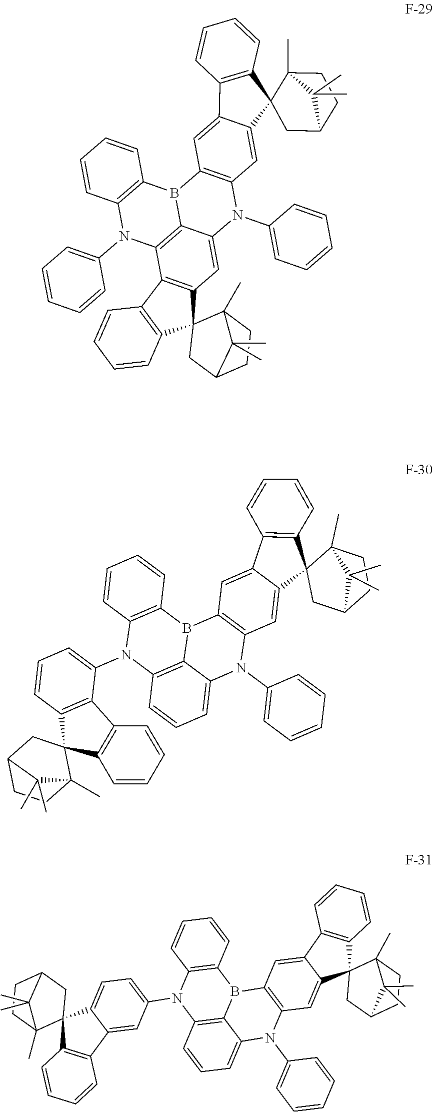

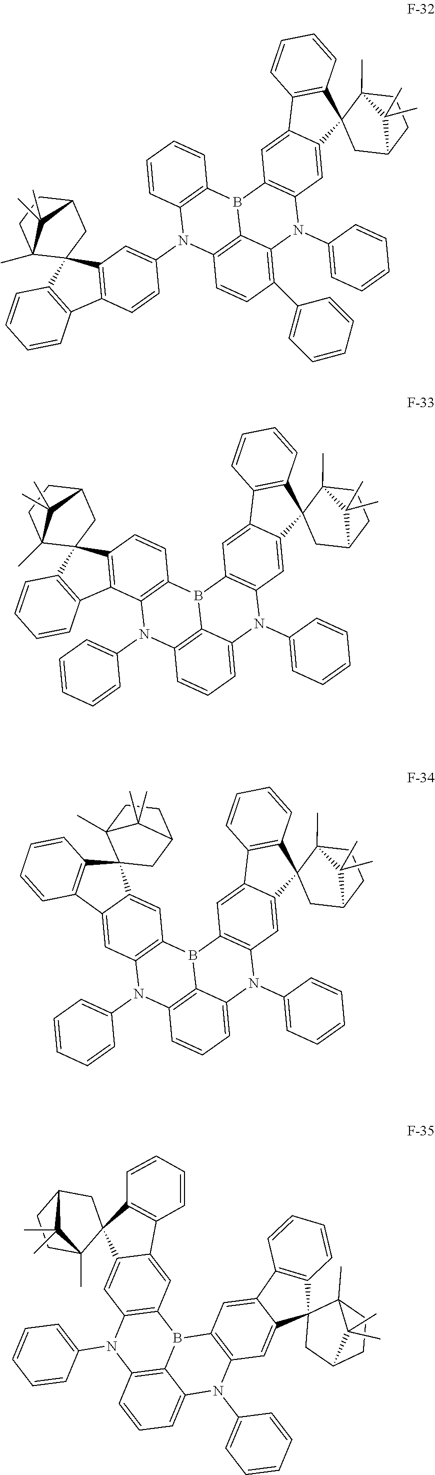

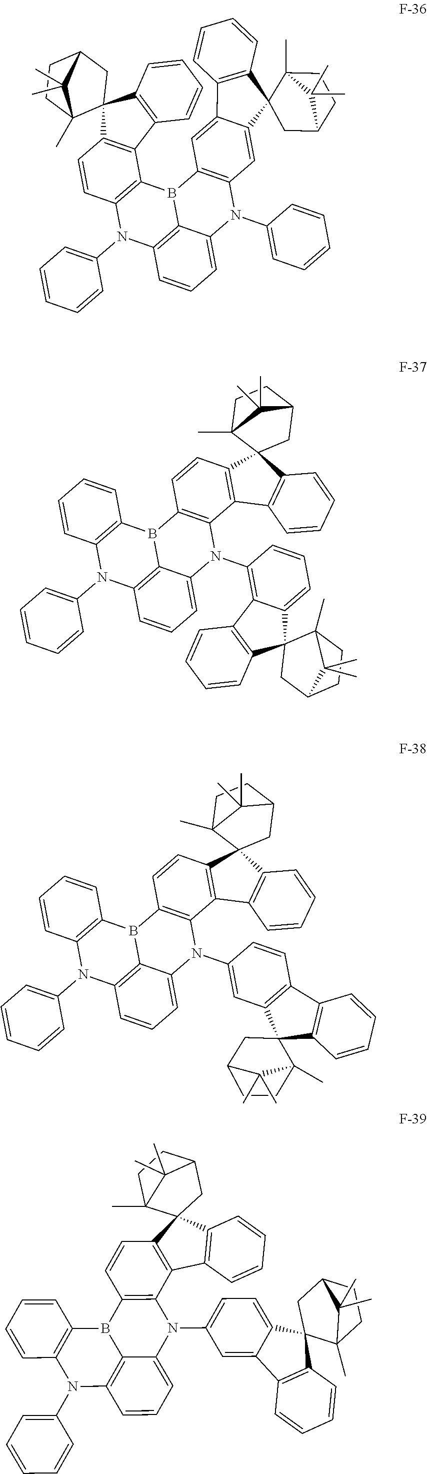

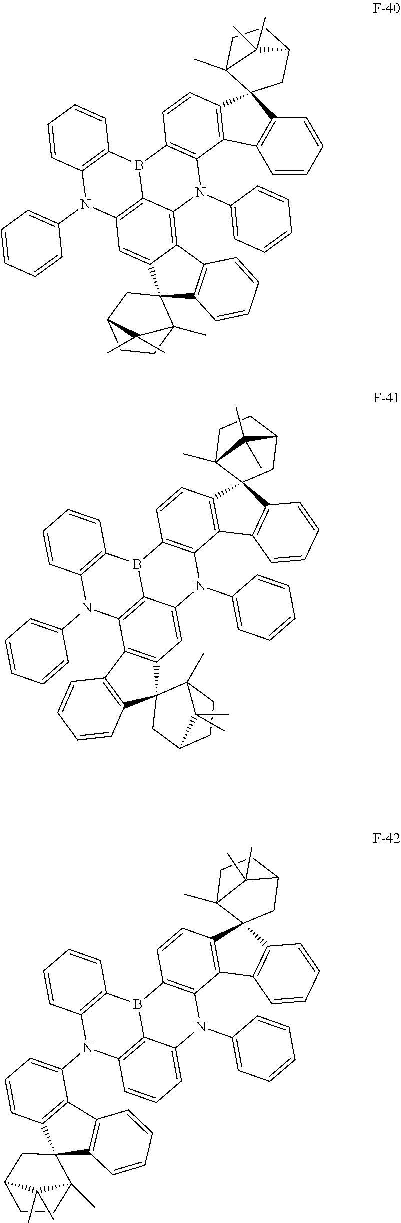 [SMILES: CC1(C)[C@H]2CCC1(C)[C@@]1(C2)c2ccccc2-c2c1ccc1c2N(c2ccccc2)c2c3c(cc4c2-c2ccccc2[C@@]42C[C@H]4CCC2(C)C4(C)C)N(c2ccccc2)c2ccccc2B13 ; CC1(C)[C@H]2CCC1(C)[C@@]1(C2)c2ccccc2-c2c1cc1c3c2N(c2ccccc2)c2ccccc2B3c2ccc3c(c2N1c1ccccc1)-c1ccccc1[C@@]31C[C@H]2CC[C@]1(C)C2(C)C ; CC1(C)C2CCC1(C)[C@]1(C2)c2ccccc2-c2c1ccc1c2N(c2ccccc2)c2cccc3c2B1c1ccccc1N3c1cccc2c1-c1ccccc1[C@@]21C[C@@H]2CC[C@@]1(C)C2(C)C]

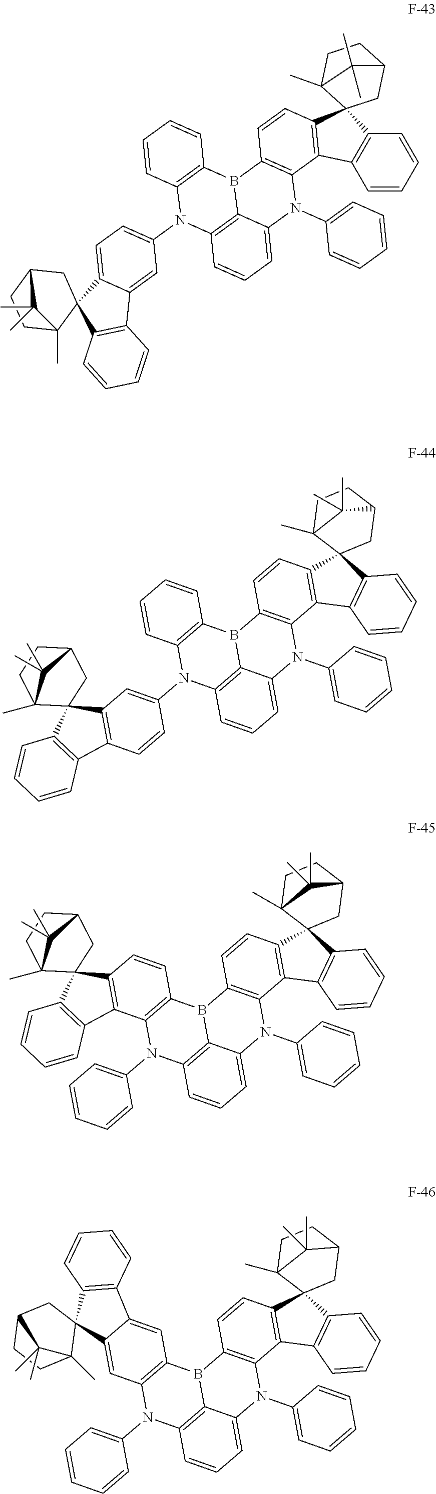

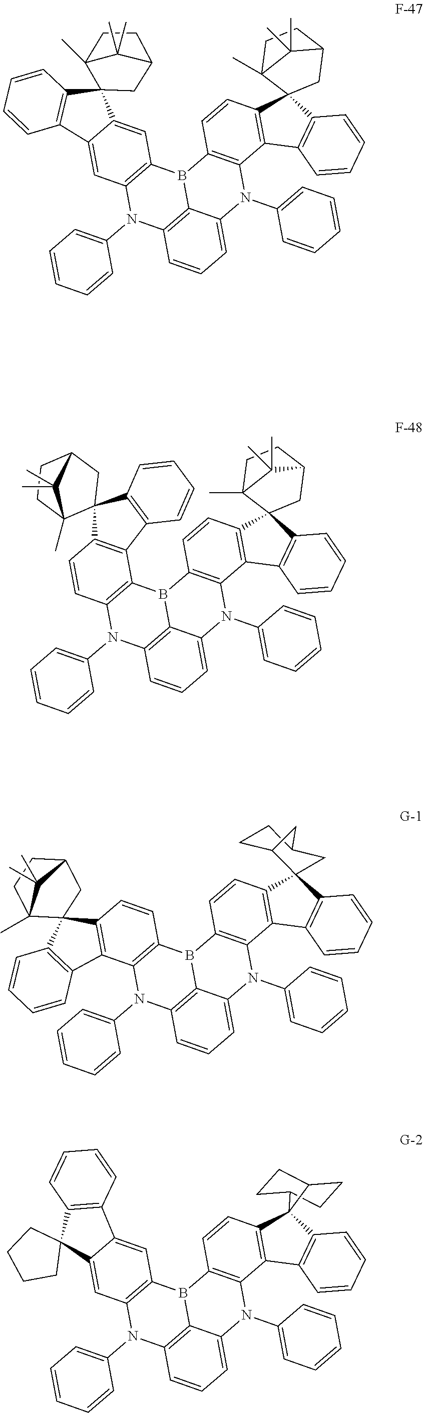 [SMILES: CC1(C)C2CCC1(C)[C@@]1(C2)c2ccccc2-c2cc3c(cc21)B1c2ccc4c(c2N(c2ccccc2)c2cccc(c21)N3c1ccccc1)-c1ccccc1[C@]41CC2CCC1(C)C2(C)C ; CC1(C)[C@H]2CCC1(C)[C@@]1(C2)c2ccccc2-c2c1ccc1c2N(c2ccccc2)c2cccc3c2B1c1c(ccc2c1-c1ccccc1[C@@]21C[C@H]2CC[C@]1(C)C2(C)C)N3c1ccccc1 ; CC1(C)[C@@H]2CC[C@@]1(C)[C@]1(C2)c2ccccc2-c2c1ccc1c2N(c2ccccc2)c2cccc3c2B1c1ccc2c(c1N3c1ccccc1)-c1ccccc1[C@@]21CC2CCC1C2 ; c1ccc(N2c3cc4c(cc3B3c5ccc6c(c5N(c5ccccc5)c5cccc2c53)-c2ccccc2[C@]62C3CCC2CC3)-c2ccccc2[C@]42CCCC2)cc1]

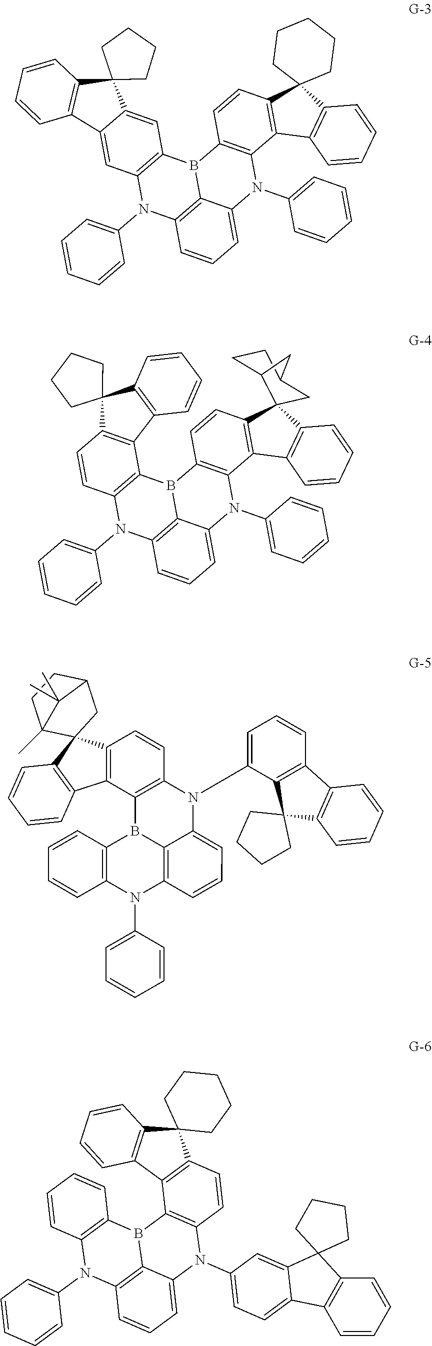

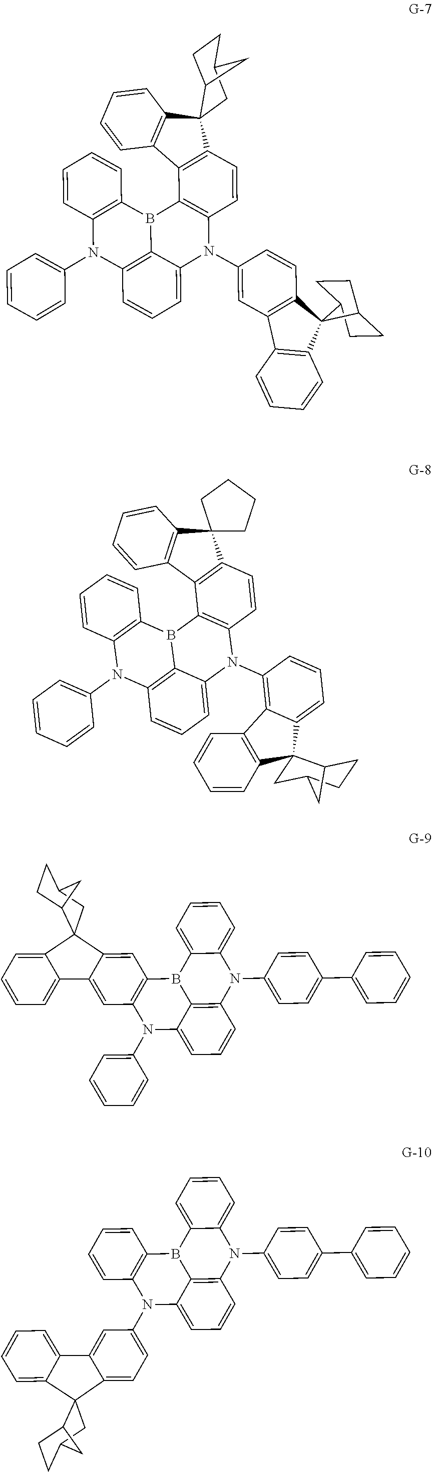

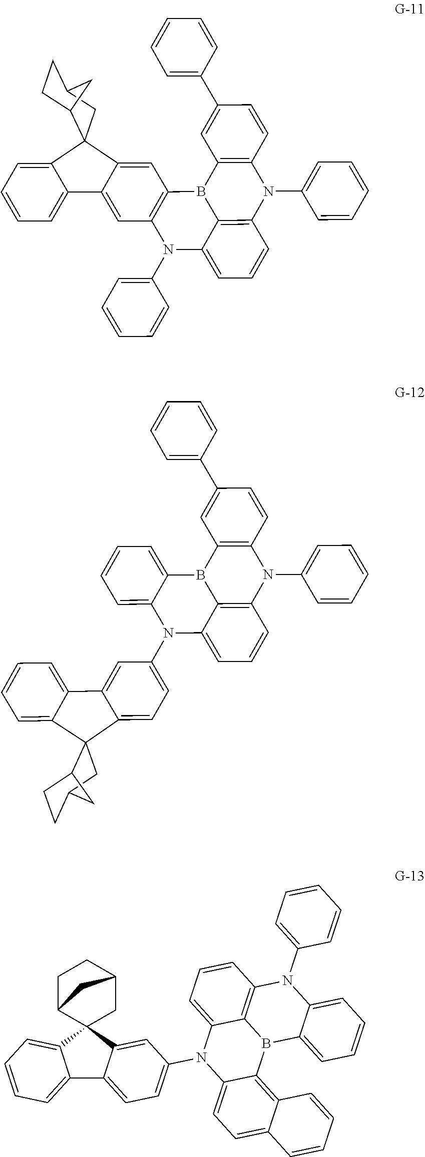

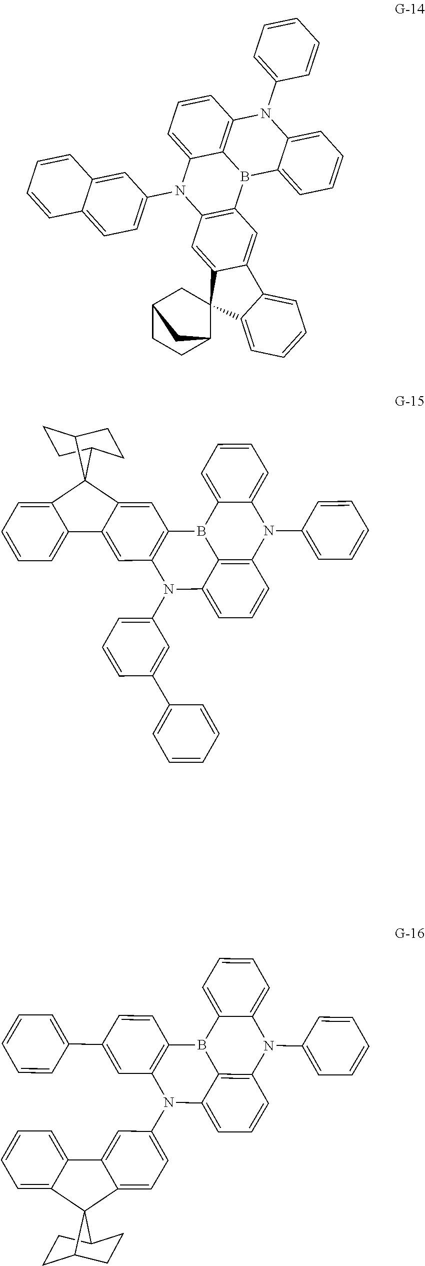

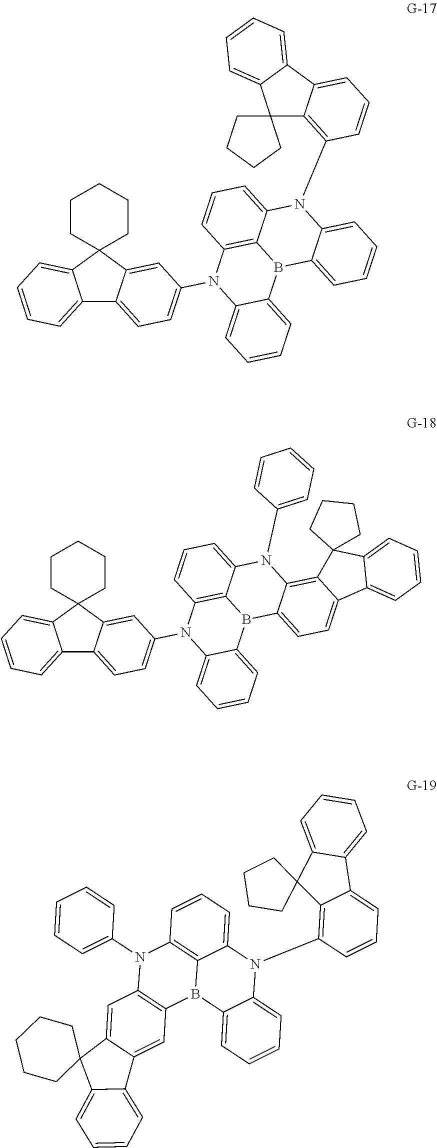 [SMILES: c1ccc2c(c1)B1c3ccccc3N(c3cccc4c3C3(CCCC3)c3ccccc3-4)c3cccc(c31)N2c1ccc2c(c1)C1(CCCCC1)c1ccccc1-2 ; c1ccc(N2c3cccc4c3B(c3ccccc3N4c3ccc4c(c3)C3(CCCCC3)c3ccccc3-4)c3ccc4c(c32)C2(CCCC2)c2ccccc2-4)cc1 ; c1ccc(N2c3cc4c(cc3B3c5ccccc5N(c5cccc6c5C5(CCCC5)c5ccccc5-6)c5cccc2c53)-c2ccccc2C42CCCCC2)cc1]

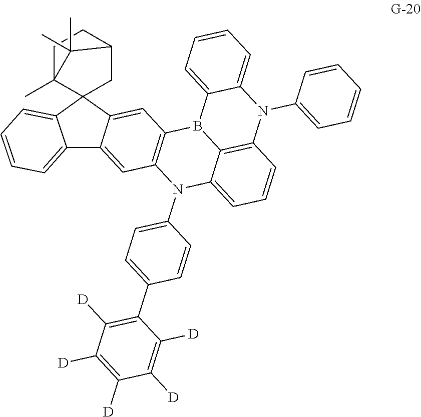 [SMILES: [2H]c1c([2H])c([2H])c(-c2ccc(N3c4cc5c(cc4B4c6ccccc6N(c6ccccc6)c6cccc3c64)C3(CC4CCC3(C)C4(C)C)c3ccccc3-5)cc2)c([2H])c1[2H]]

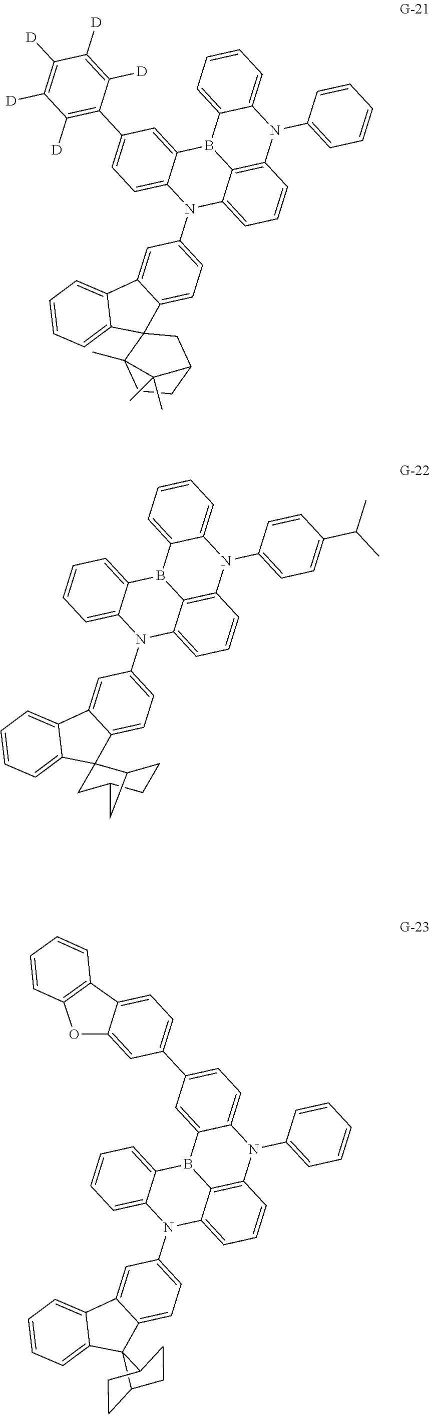 [SMILES: [2H]c1c([2H])c([2H])c(-c2ccc3c(c2)B2c4ccccc4N(c4ccccc4)c4cccc(c42)N3c2ccc3c(c2)-c2ccccc2C32CC3CCC2(C)C3(C)C)c([2H])c1[2H] ; CC(C)c1ccc(N2c3ccccc3B3c4ccccc4N(c4ccc5c(c4)-c4ccccc4C54CC5CCC4C5)c4cccc2c43)cc1 ; c1ccc(N2c3ccc(-c4ccc5c(c4)oc4ccccc45)cc3B3c4ccccc4N(c4ccc5c(c4)-c4ccccc4C54C5CCC4CC5)c4cccc2c43)cc1]

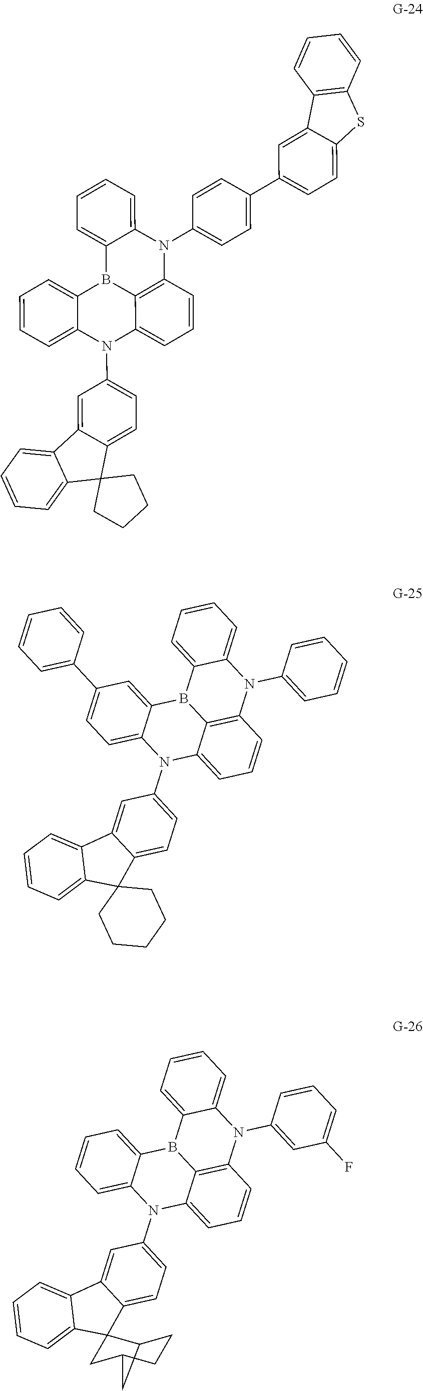 [SMILES: c1ccc2c(c1)B1c3ccccc3N(c3ccc4c(c3)-c3ccccc3C43CCCC3)c3cccc(c31)N2c1ccc(-c2ccc3sc4ccccc4c3c2)cc1 ; c1ccc(-c2ccc3c(c2)B2c4ccccc4N(c4ccccc4)c4cccc(c42)N3c2ccc3c(c2)-c2ccccc2C32CCCCC2)cc1 ; Fc1cccc(N2c3ccccc3B3c4ccccc4N(c4ccc5c(c4)-c4ccccc4C54CC5CCC4C5)c4cccc2c43)c1]

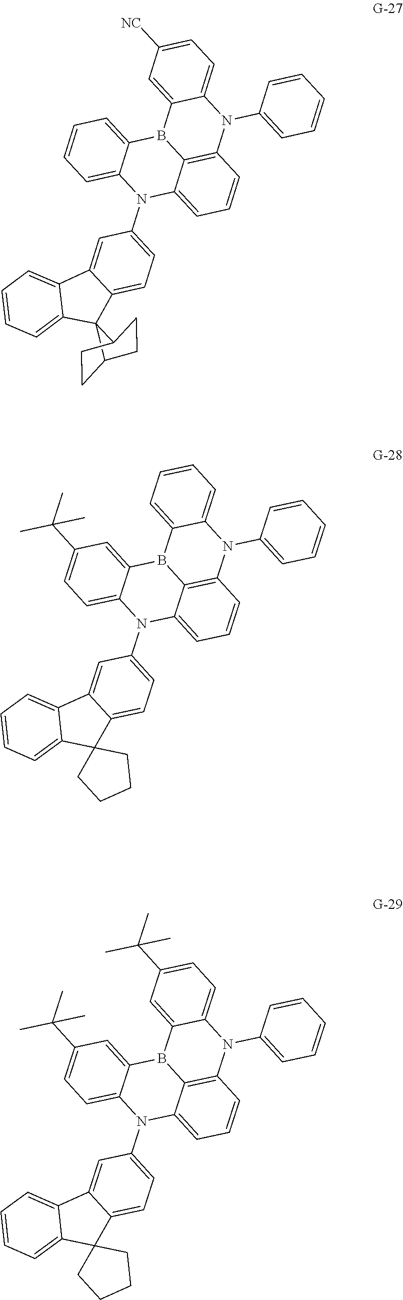 [SMILES: N#Cc1ccc2c(c1)B1c3ccccc3N(c3ccc4c(c3)-c3ccccc3C43C4CCC3CC4)c3cccc(c31)N2c1ccccc1 ; CC(C)(C)c1ccc2c(c1)B1c3ccccc3N(c3ccccc3)c3cccc(c31)N2c1ccc2c(c1)-c1ccccc1C21CCCC1 ; CC(C)(C)c1ccc2c(c1)B1c3cc(C(C)(C)C)ccc3N(c3ccc4c(c3)-c3ccccc3C43CCCC3)c3cccc(c31)N2c1ccccc1]

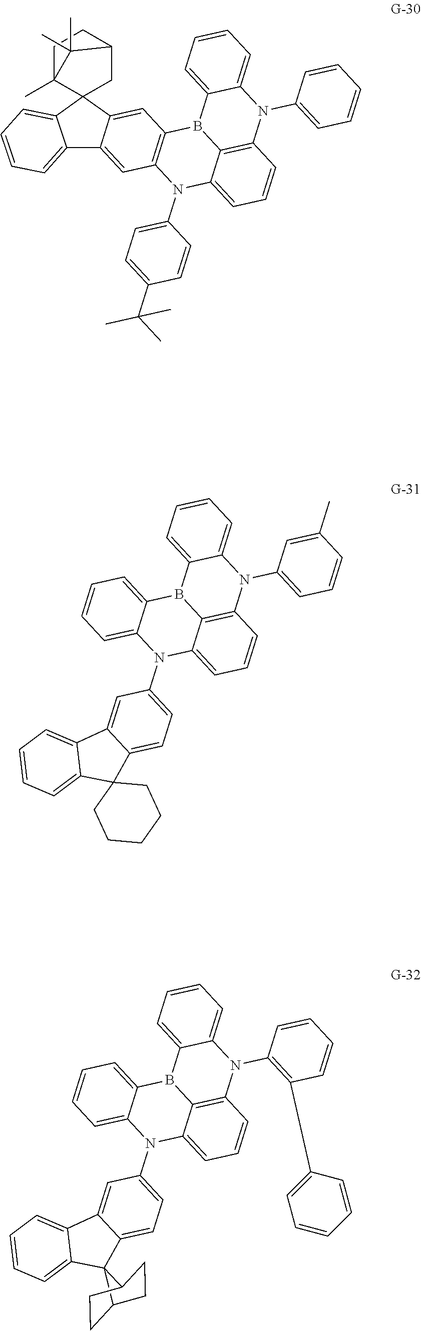 [SMILES: CC(C)(C)c1ccc(N2c3cc4c(cc3B3c5ccccc5N(c5ccccc5)c5cccc2c53)C2(CC3CCC2(C)C3(C)C)c2ccccc2-4)cc1 ; Cc1cccc(N2c3ccccc3B3c4ccccc4N(c4ccc5c(c4)-c4ccccc4C54CCCCC4)c4cccc2c43)c1 ; c1ccc(-c2ccccc2N2c3ccccc3B3c4ccccc4N(c4ccc5c(c4)-c4ccccc4C54C5CCC4CC5)c4cccc2c43)cc1]

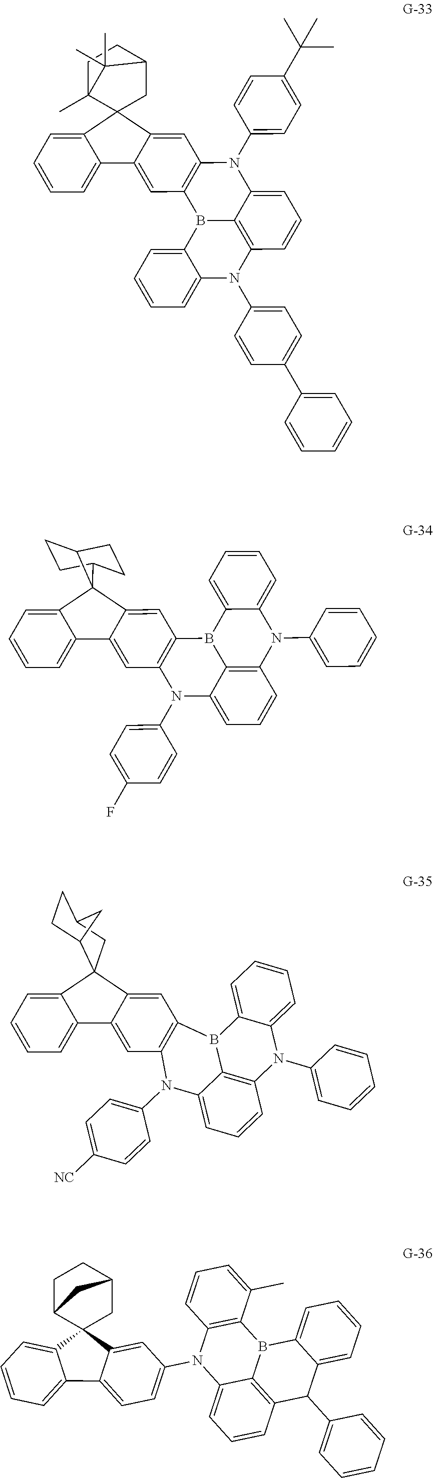

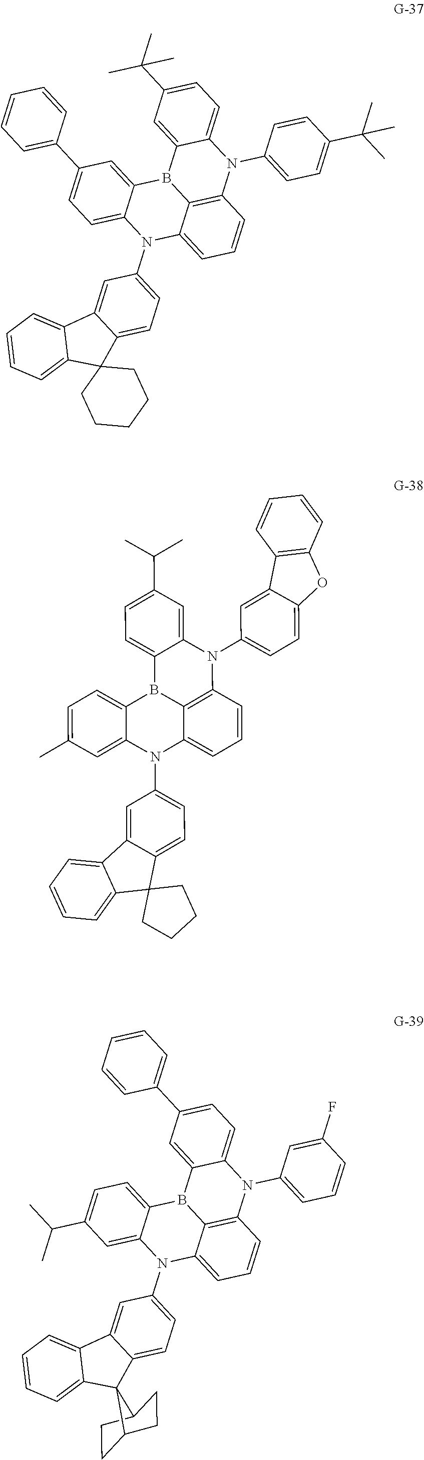

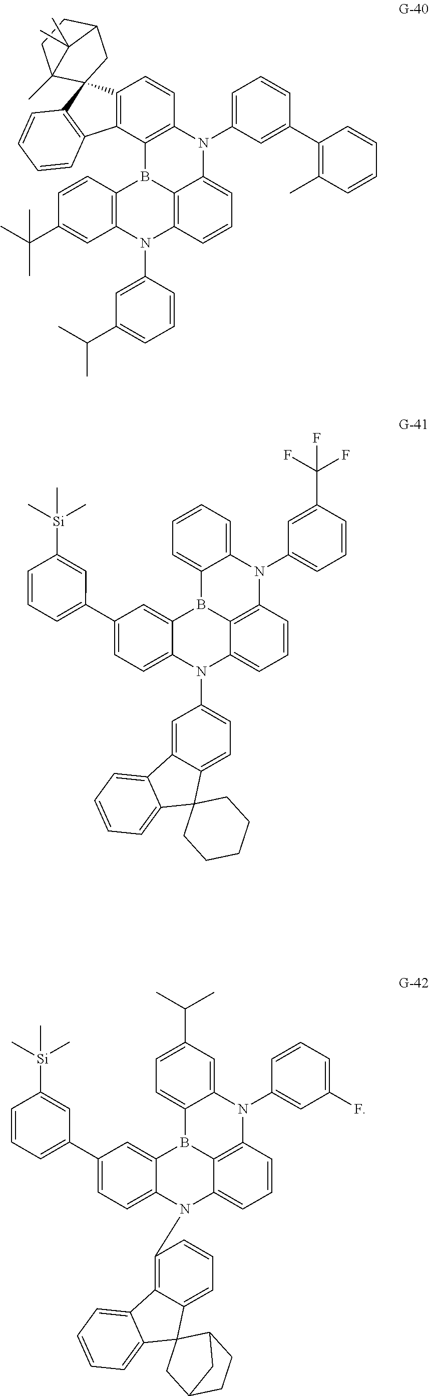 [SMILES: Cc1ccccc1-c1cccc(N2c3cccc4c3B(c3ccc(C(C)(C)C)cc3N4c3cccc(C(C)C)c3)c3c2ccc2c3-c3ccccc3[C@@]23CC2CCC3(C)C2(C)C)c1 ; C[Si](C)(C)c1cccc(-c2ccc3c(c2)B2c4ccccc4N(c4cccc(C(F)(F)F)c4)c4cccc(c42)N3c2ccc3c(c2)-c2ccccc2C32CCCCC2)c1 ; CC(C)c1ccc2c(c1)N(c1cccc(F)c1)c1cccc3c1B2c1cc(-c2cccc([Si](C)(C)C)c2)ccc1N3c1cccc2c1-c1ccccc1C21CC2CCC1C2]

10. An organic electroluminescent device, comprising an anode and a cathode which are oppositely disposed, and a functional layer disposed between the anode and the cathode; wherein
the functional layer comprises the organic compound according to claim 1;
preferably, the functional layer comprises an organic light-emitting layer comprising the organic compound.

11. The organic electroluminescent device according to claim 10, wherein the organic electroluminescent device is a blue organic electroluminescent device.

12. An electronic apparatus, comprising the organic electroluminescent device according to claim 10.
